(19) United States
(12) Patent Application Publication
(10) Pub. No.: US 2007/0200147 A1
(43) Pub. Date: Aug. 30, 2007

(54) Method For Manufacturing An Optical Film, Apparatus For Manufacturing The Same Optical Film, Polarizing Plate And Image Display Device

(75) Inventors: Shigeaki Ohtani, Kanagawa (JP); Makoto Satoh, Kanagawa (JP); Toshihiko Maekawa, Kanagawa (JP); Mayumi Suzuki, Kanagawa (JP); Yuuichi Fukushige, Kanagawa (JP)

Correspondence Address: BUCHANAN, INGERSOLL & ROONEY PC, POST OFFICE BOX 1404, ALEXANDRIA, VA, 22313-1404, US

(73) Assignee: FUJIFILM Corporation, Tokyo (JP)

(21) Appl. No.: 11/659,282

(22) PCT Filed: Jul. 28, 2005
(86) PCT No.: PCT/JP05/14267

§ 371 Date: Apr. 30, 2007

(30) Foreign Application Priority Data
Aug. 4, 2004 (JP) 2004-227605
Aug. 31, 2004 (JP) 2004-252276
Sep. 22, 2004 (JP) 2004-274818
Sep. 24, 2004 (JP) 2004-278238
Sep. 24, 2004 (JP) 2004-278239

(51) Int. Cl. H01L 27/10

(52) U.S. Cl. 257/211

(57) ABSTRACT

A method for manufacturing an optical film comprising a transparent substrate and at least one functional layer on or above the transparent substrate, wherein said at least one functional layer to be laminated on the transparent substrate is formed by a layer-forming method comprising the following steps (1) and (2): (1) step of applying a coated layer on the transparent substrate, and (2) step of curing the coated layer by irradiating ionizing radiation in an oxygen environment in which the oxygen concentration is lower than an atmospheric oxygen concentration.

### TECHNICAL FIELD

The present invention relates to a method for manufacturing an optical film excellent in abrasion/scratch resistance (particularly anti-reflection film excellent in abrasion/scratch resistance at low reflectance), apparatus for manufacturing the same and an optical film obtained by said method. The invention also relates to a polarizing plate and an image display device equipped with said optical film.

### BACKGROUND ART

Various functional optical films such as polarizing plate-protective film, phase contrast plate, reflection plate, viewing angle widening film, optically compensated film, anti-glare film, brightness improved film, color correction filter, color separation film, ultraviolet ray- or infrared ray-protected film, antistatic film and anti-reflection film have been used in display devices such as a cathode ray tube (CRT) display device, plasma display panel (PDP), electroluminescence display (ELD) and liquid crystal display (LCD). These films require a strong abrasion resistance because film damaged during a manufacturing process or after being assembled into products are recognized as defects of an image.

Among the above, an anti-reflection film is usually arrayed on the first surface of a display to reduce the reflectance ratio by utilizing the principle of optical interference for the purpose of preventing reduced contrast due to reflection of ambient light and occurrence of reflected image on display devices such as a cathode ray tube (CRT) display device, plasma display panel (PDP), electroluminescence display (ELD) and liquid crystal display (LCD). Therefore, the film is highly vulnerable to damage and there has been an urgent demand for importing excellent abrasion resistance.

The above anti-reflection film can be prepared by giving an appropriately-thick low refractive layer to the first surface, or forming a high refractive layer, a moderate refractive layer, a hard-coat layer and others between the first surface and a support (substrate), where applicable. It is desirable that the low refractive layer is prepared with materials whose refractive index is as low as possible in order to realize a low reflectance ratio. The anti-reflection film is also required for high abrasion/scratch resistance because it is used on the first surface of a display. In order to provide a film whose thickness is about 100 nm with a high abrasion/scratch resistance, the film must be strong in itself and highly adhesive to an underlying layer.

The refractive index of materials can be reduced by introducing a fluorine atom or reducing the density (introduction of space). Either method tends to affect the film strength and adhesiveness or reduce the abrasion/scratch resistance, thereby making it difficult to realize a low refractive index and a high abrasion/scratch resistance at the same time.

JP-A-11-189621, JP-A-11-228631 and IP-A-2000-313709 disclosed a method in which the structure of polysiloxane was introduced into fluorine-containing polymers to reduce the friction coefficient on the film surface, thereby improving the abrasion/scratch resistance. This method was effective to some extent in improving the abrasion/scratch resistance, however, it was unable to offer a sufficient abrasion/scratch resistance to such films that were essentially lacking in film strength and interface adhesiveness.

On the other hand, JP-A-2002-156508 disclosed that photo curing resins were cured at low oxygen concentrations to increase the hardness. However, there was a limit in concentrations at which nitrogen could be substituted for attaining an effective manufacture of anti-reflection films on a web, and no films with a satisfactory hardness were available.

JP-A-11-268240, JP-A-60-90762, JP-A-59-112870, JP-A-4-301456, JP-A-3-67697 and JP-A-2003-300215 disclosed a specific means to effect nitrogen substitution, which, however, posed problems that a large quantity of nitrogen was needed to reduce the oxygen concentration sufficient to cure thin films such as the low refractive layer, thus resulting in an increased manufacturing cost.

JP-B-7-51641 also disclosed a method for irradiating ionizing radiation, with a film reeled on the surface of a heated roll, which was also insufficient in giving a sufficient cure to a special thin film such as the low refractive layer.

Further, JP-A-2000-80068 and JP-A-2001-264530 disclosed a method in which a radical polymerization initiator was converted to an oxime compound to elevate the curing sensitivity of color filter compositions. This method was also unable to give a sufficient curing particularly to a film whose constituting layer was thin such as anti-reflection film.

At the same time, optical films, particularly anti-reflection films have been manufactured and coated by dip coating, micro-gravure coating and reverse roll coating. Dip coating always requires agitation of a coating solution in a liquid tank, often resulting in step-like irregularities of a coated surface. Reverse roll coating and micro-gravure coating easily results in step-like irregularities of a coated surface due to eccentricity or deflection of a roll on coating. Micro-gravure coating also easily results in an uneven coated quantity due to precision problems of a gravure roll and change over time in a roll and a blade resulting from contact of the blade with the gravure roll. Further, in these coating methods, materials are measured after the operation, therefore making it relatively difficult to secure a stable film thickness. A method for coating anti-reflection films by die coating has been proposed as a way of measuring materials before the operation, but this method was also found difficult to secure a stable film thickness due to marked irregularities of a coated thickness which developed vertically and horizontally in relation to the transporting direction of a support in a case where coating on a thin layer like an anti-reflection layer.

These irregularities of coated thickness of the anti-reflection layer are detected by visual inspection as non-uniform color when the layer is used in an image display device, posing serious problems on quality. It was requested to provide the layer with a stable thickness.

### DISCLOSURE OF THE INVENTION

An object of the present invention is to provide a stable manufacturing method for an optical film with an improved abrasion/scratch resistance and an optical film obtained by the method.

A further object of the present invention is to provide a stable manufacturing method for an anti-reflection film having a sufficient anti-reflection function and also an improved abrasion/scratch resistance and also to provide an anti-reflection film obtained by said method.

Still, a further object of the invention is to provide a stable manufacturing method for an optical film (in particular, anti-reflection film) which is able to provide a high-quality image display device, while non-uniform color resulting from a coating step is prevented and also to provide an optical film obtained by said method.

Another object of the present invention is to provide a polarizing plate and an image display device equipped with the above described reflection film.

After dedicated studies, the inventor found that the above objects were attained by the following methods for manufacturing an anti-reflection film, and the anti-reflection film, polarizing plate and image display device obtained by said method.

[1] A method for manufacturing an optical film comprising a transparent substrate and at least one functional layer on or above the transparent substrate, wherein said at least one functional layer to be laminated on the transparent substrate is formed by a layer-forming method including the following steps (1) and (2) (layer-forming method (I)):

(1) step of applying a coated layer on the transparent substrate, and

(2) step of curing the coated layer by irradiating ionizing radiation in an environment where the oxygen concentration is lower than an atmospheric oxygen concentration.

[2] A method for manufacturing an optical film comprising a transparent substrate and at least one functional layer on or above the transparent substrate, according to the above Item [1], wherein said at least one functional layer to be laminated on the transparent substrate is formed by a layer-forming method in which the following steps (1) to (3) are included and also the following transporting step (2) and curing step (3) are conducted continuously:

(1) step of applying a coated layer on the transparent substrate,

(2) step of transporting a film comprising the coated layer in an environment where the oxygen concentration is lower than an atmospheric oxygen concentration, and

(3) step of curing the coated layer by irradiating ionizing radiation to the film in an environment where the oxygen concentration is not more than 3% by volume.

[3] A method for manufacturing an optical film comprising a transparent substrate and at least one functional layer on or above the transparent substrate, according to the above Item [1], wherein said at least one functional layer to be laminated on the transparent substrate is formed by a layer-forming method in which the following steps (1) to (3) are included and also the following transporting step (2) and curing step (3) are conducted continuously:

(1) step of applying a coated layer on the transparent substrate,

(2) step of transporting a film having the coated layer in an environment in which the oxygen concentration is lower than an atmospheric oxygen concentration, and

(3) step of curing the coated layer by irradiating ionizing radiation to the film in an environment where the oxygen concentration is not more than 3% by volume, while the film is heated so that the film surface temperature is 25° C. or more.

[4] A method for manufacturing an optical film comprising a transparent substrate and at least one layer functional layer on or above the transparent substrate, according to the above Item [1], wherein at least one functional layer to be laminated on the transparent substrate is formed by a layer-forming method in which the following steps (1) to (3) are included and also the following transporting step (2) and curing step (3) are conducted continuously:

(1) step of applying a coated layer on the transparent substrate,

(2) step of transporting a film having the coated layer in an environment in which the oxygen concentration is lower than the atmospheric oxygen concentration, while the film is heated so that the surface temperature is 25° C. or more and

(3) step of curing the coated layer by irradiating ionizing radiation to the film in an environment where the oxygen concentration is not more than 3% by volume.

[5] A method for manufacturing an optical film comprising a transparent substrate and at least one functional layer on or above the transparent substrate, according to the above Item [1], wherein said at least one functional layer to be laminated on the transparent substrate is formed by a layer-forming method in which the following steps (1) to (3) are included and also the following transporting step (2) and curing step (3) are conducted continuously:

(1) step of applying a coated layer on the transparent substrate,

(2) step of transporting a film having the coated layer in an oxygen environment in which the oxygen concentration is lower than the atmospheric oxygen concentration, while the film is heated so that the film surface temperature is 25° C. or more, and

(3) step of curing the coated layer by irradiating ionizing radiation to the film in an environment where the oxygen concentration is not more than 3% by volume, while the film is heated so that the film surface temperature is 25° C. or more.

[6] A method for manufacturing an optical film comprising a transparent substrate and at least one functional layer on or above the transparent substrate, wherein a layer-forming method according to any one of the above Item [1] through Item [5] comprises a step of transporting the film after curing treatment in an environment where the oxygen concentration is not more than 3% by volume, while the film is heated so that the surface temperature is 25° C. or more, in continuation with a step of curing the coated layer by irradiating ionizing radiation.

[7] A method for manufacturing an optical film according to any one of the above Item [3] through Item [6], wherein heating during and/or before irradiation of ionizing radiation and/or heating after irradiation of ionizing radiation are conducted so that the film surface temperature can be kept in the range from 25° C. to 170° C.

[8] A method for manufacturing an optical film according to any one of the above Item [3] through Item [7], wherein heating during and/or before irradiation of ionizing radiation and/or heating after irradiation of ionizing radiation are conducted by allowing the film to contact with a heated roll.

[9] A method for manufacturing an optical film according to any one of the above Item [3] through Item [7], wherein heating during and/or before irradiation of ionizing radiation and/or heating after irradiation of ionizing radiation are conducted by spraying heated nitrogen gas.

[10] A method for manufacturing an optical film according to any one of the above Item [1] through Item [9], wherein the transporting step and/or the curing step of irradiating ionizing radiation are respectively conducted at a low-oxygen concentration zone where substituted by nitrogen, and nitrogen in a zone where the curing step of irradiating ionizing radiation is conducted is exhausted into a zone where prior steps are conducted and/or a zone where subsequent steps are conducted.

[11] A method for manufacturing an optical film comprising a transparent substrate and at least one functional layer on or above the transparent substrate, wherein said at least one functional layer to be laminated on the transparent substrate is formed by a layer-forming method in which the following steps (1) to (3) are included and also the following steps (2) and (3) are conducted continuously (layer-forming method (II)):

(1) step of applying a coated layer on the transparent substrate,

(2) step of irradiating ionizing radiation to a film having the coated layer in an environment where the oxygen concentration is not more than 3% by volume, and

(3) step of keeping the film after irradiation of ionizing radiation so that the surface temperature can be 60° C. or less in an environment where the oxygen concentration is not more than 3% by volume.

[12] A method for manufacturing an optical film according to the above Item [11], further comprising a step of transporting the film in an environment where the oxygen concentration is not more than 3% by volume and also in an environment where the oxygen concentration is higher than that in a step of irradiation of ionizing radiation, prior to a step of irradiating ionizing radiation in an environment where the oxygen concentration is not more than 3% by volume.

[13] A method for manufacturing an optical film according to the above Item [11] or Item [12], wherein a difference in film surface temperature should be within 20° C. between the step of irradiating ionizing radiation and the step of keeping the surface temperature of 60° C. or less in an environment where the oxygen concentration is not more than 3% by volume which continues with the step of irradiating ionizing radiation.

[14] A method for manufacturing an optical film comprising a transparent substrate and at least one functional layer on or above the transparent substrate, wherein said at least one functional layer to be laminated on the transparent support is formed by a layer-forming method including the following steps (1) and (2) (layer-forming method (III)):

(1) step of applying a coating solution containing an ionizing-radiation curable compound on a continuously running web which contains the transparent substrate and drying it to form a coated layer, and

(2) step of irradiating ionizing radiation to the coated layer on the web in an environment where the oxygen concentration is not more than 3% by volume and also keeping the web for 0.5 seconds or longer from the start of irradiation of ionizing radiation in an environment where the oxygen concentration is not more than 3% by volume to cure the coated layer.

[15] A method for manufacturing an optical film comprising a transparent substrate and at least one functional layer on or above the transparent substrate, wherein said at least one functional layer to be laminated on the transparent substrate is formed by a layer-forming method in which the following steps (1) to (3) are included and also the following steps (2) and (3) are conducted continuously (layer-forming method (III-1)):

(1) step of applying a coating solution containing an ionizing-radiation curable compound on a continuously running web which contains the transparent substrate and drying it to form a coated layer,

(2) step of directly spraying an inert gas on the surface of the coated layer on the web, and

(3) step of irradiating ionizing radiation to the coated layer on the web in an environment where the oxygen concentration is not more than 3% by volume and also keeping the web for 0.5 seconds or longer from the start of irradiation of ionizing radiation in an environment where the oxygen concentration is not more than 3% by volume to cure the coated layer.

[16] A method for manufacturing an optical film comprising a transparent substrate and at least one functional layer on or above the transparent substrate, wherein said at least one functional layer to be laminated on the transparent substrate is formed by a layer-forming method including the following steps (1) and (2) (layer-forming method (IV)):

(1) step of applying a coating solution containing an ionizing-radiation curable compound on a continuously running web which contains the transparent substrate and drying it to form a coated layer, and

(2) step of irradiating ionizing radiation to the coated layer on the web in an environment where the oxygen concentration is not more than 3% by volume and also keeping the web in an environment where the oxygen concentration is not more than 3% by volume until polymerization reaction of the ionizing-radiation curable compound completes at least 50% to cure the coated layer.

[17] A method for manufacturing an optical film comprising a transparent substrate and at least one functional layer on or above the transparent substrate, wherein said at least one functional layer to be laminated on the transparent substrate is formed by a layer-forming method in which the following steps (1) to (3) are included and also the following steps (2) and (3) are conducted continuously(layer-forming method (IV-1)):

(1) step of applying a coating solution containing an ionizing-radiation curable compound on a continuously running web which contains the transparent substrate and drying it to form a coated layer,

(2) step of directly spraying an inert gas on the surface of the coated layer on the web, and

(3) step of irradiating ionizing radiation to the coated layer on the web in an environment where the oxygen concentration is not more than 3% by volume and also keeping the web in an environment where the oxygen concentration is not more than 3% by volume until a polymerization reaction of the ionizing-radiation curable compound completes at least 50% to cure the coated layer.

[18] A method for manufacturing an optical film according to the above Item [17], the method having a step of transporting the web in an environment where the oxygen concentration is not more than 3% by volume and also in an environment where the oxygen concentration is higher than that in a step of irradiation of ionizing radiation, prior to a step of irradiating ionizing radiation to the web in an environment where the oxygen concentration is not more than 3% by volume.

[19] A method for manufacturing an optical film according to any one of the above Item [14] through Item [18], wherein in the step of curing the coated layer, ionizing radiation is irradiated a plurality of times to the coated layer on the web in an environment where the oxygen concentration is not more than 3% by volume, of which ionizing radiation is irradiated at least twice in a continuous ionizing radiation reaction chamber where the oxygen concentration is not more than 3% by volume.

[20] A method for manufacturing an optical film according to any one of the above Item [14] through Item [19], wherein the curing step is conducted, while heating is conducted so that temperature on the surface of the coated layer on the web is 60° C. or more.

[21] A method for continuously manufacturing, in a web state, an optical film comprising a transparent substrate and at least one functional layer on or above the transparent substrate, wherein said at least one functional layer to be laminated on the transparent support is formed by a layer-forming method including the following steps (1) and (2) (layer-forming method (V)):

(1) step of applying a coating solution containing at least one type of oxime polymerization initiators on a transparent web substrate and drying it to form a coated layer, and

(2) step of irradiating ionizing radiation to the coated layer on the transparent web substrate in an environment where the oxygen concentration is not more than 3% by volume and also keeping the transparent web substrate for 0.5 seconds or longer from the start of irradiation of ionizing radiation in an environment where the oxygen concentration is not more than 3% by volume to cure the coated layer.

[22] A method for continuously manufacturing, in a web state, an optical film comprising a transparent substrate and at least one functional layer on or above the transparent substrate, wherein at least one functional layer to be laminated on the transparent support is formed by a layer-forming method including the following steps (1) and (2) (layer-forming method (V-1)):

(1) step of applying a coating solution containing at least one type of oxime polymerization initiators on a transparent web substrate and drying it to form a coated layer, and

(2) step of irradiating ionizing radiation to the coated layer on the transparent web substrate in an environment where the oxygen concentration is not more than 3% by volume while heating is conducted so that the film surface temperature is 60° C. or more to cure the coated layer.

[23] A method for continuously manufacturing, in a web state, an optical film comprising a transparent substrate and at least one functional layer on or above the transparent substrate, wherein at least one functional layer to be laminated on the transparent support is formed by a layer-forming method including the following steps (1) and (2) (layer-forming method (V-2)):

(1) step of applying a coating solution containing at least one type of oxime polymerization initiators on a transparent web substrate and drying it to form a coated layer, and

(2) step of irradiating ionizing radiation to the coated layer on the transparent web substrate in an environment where the oxygen concentration is not more than 3% by volume while heating is conducted so that the film surface temperature is 60° C. or more and also keeping the transparent web substrate for 0.5 seconds or longer from the start of irradiation of ionizing radiation in an environment where the oxygen concentration is not more than 3% by volume to cure the coated layer.

[24] A method for manufacturing an optical film according to any one of the above Item [21] through Item [23], wherein in the step of curing the coated layer, ionizing radiation is irradiated a plurality of times to the coated layer on the web in an environment where the oxygen concentration is not more than 3% by volume, of which ionizing radiation is irradiated at least twice in a continuous ionizing radiation reaction chamber where the oxygen concentration is not more than 3% by volume.

[25] A method for manufacturing an optical film according to any one of the above Item [14] through Item [24], wherein the continuously running web having a coated layer is passed through an anterior chamber into which an inert gas is fed to reduce the oxygen concentration, the web is then transported into an ionizing radiation reaction chamber installed continuously with the anterior chamber into which the inert gas is fed and where the oxygen concentration is not more than 3% by volume, and the step of curing the coated layer is conducted at the ionizing radiation reaction chamber.

[26] A method for manufacturing an optical film according to the above Item [25], wherein the inert gas fed into the ionizing radiation reaction chamber is allowed to come out at least from a web inlet side in the ionizing radiation reaction chamber.

[27] A method for manufacturing an optical film according to the above Item [25] or Item [26], wherein a gap with the surface of the coated layer on the web is 0.2 to 15 mm on at least one of: a plane constituting a web inlet side of the ionizing radiation reaction chamber; and a plane constituting a web inlet side of the anterior chamber.

[28] A method for manufacturing an optical film according to any one of the above Item [25] through Item [27], wherein at least one of: a plane constituting a web inlet side of the ionizing radiation reaction chamber; and a plane constituting a web inlet side of the anterior chamber is at least partially movable and structured so as to accept at least a thickness of a joint member when the joint member jointed with the web is passed (in other words, so as to the gap increases by a thickness of a joint member).

[29] A method for manufacturing an optical film according to any one of the above Item [1] through Item [28], wherein ionizing radiation is an ultraviolet ray.

[30] A method for manufacturing an optical film according to any one of the above Item [1] through Item [29],

wherein the method for manufacturing an optical film comprises a step of applying a coating solution from a slot of a front-end lip, with a land of the front-end lip of a slot die being allowed to come close to a surface of a continuously running web supported by a back-up roll, and the coating solution is applied by using a coating apparatus, and

wherein the coating apparatus comprises the slot die including a first front-end lip on the side of a web advancement direction and a second front-end lip opposite to the web advancement direction, the first front-end lip having a land length of from 30 μm to 100 μm, and the coating apparatus is designed so that a clearance between the second front-end lip and the web is greater by 30 μm or more but 120 μm or less than a clearance between the first front-end lip and the web, when the slot die is set at a coating position.

[31] A method for manufacturing an optical film according to the above Item [30], wherein a viscosity of the coating solution is not more than 2.0 [mPa·sec] when applied and an amount of the coating solution applied on the web surface is from 2.0 to 5.0 [mL/m²].

[32] A method for manufacturing an optical film according to the above Item [30] or Item [31], wherein the coating solution is applied on the surface of a continuously running web at a speed of 25 [m/min] or more.

[33] An optical film which is prepared by a method described in any one of the above Item [1] through Item [32].

[34] An apparatus for manufacturing an optical film comprising a transparent substrate and at least one functional layer on or above the transparent substrate, wherein the apparatus comprises: an ionizing radiation reaction chamber where ionizing radiation is irradiated; and an anterior chamber in front of the ionizing radiation reaction chamber (an anterior chamber next to the ionizing radiation reaction chamber, in which the web is passed through the anterior chamber before being passed through the ionizing radiation reaction chamber), each of the ionizing radiation reaction chamber and the anterior chamber comprising a web inlet for carrying in a continuously running web having the transparent substrate and a coated layer, and wherein an inert gas is fed into the ionizing radiation reaction chamber and the anterior chamber, thereby keeping the oxygen concentration lower therein and the inert gas fed in the ionizing radiation reaction chamber comes out from the web inlet of the ionizing radiation reaction chamber.

[35] An apparatus for manufacturing an optical film according to the above Item [34], wherein a gap with the surface of the coated layer on the web is 0.2 to 15 mm on at least one of: a plane constituting a web inlet side of the ionizing radiation reaction chamber; and a plane constituting a web inlet side of the anterior chamber.

[36] An apparatus for manufacturing an optical film according to the above Item [34] or [35], wherein at least one of: a plane constituting a web inlet side of the ionizing radiation reaction chamber; and a plane constituting a web inlet side of the anterior chamber is at least partially movable and structured so as to accept at least a thickness of a joint member when the joint member jointed with the web is passed (in other words, so as to the gap increase by a thickness of a joint member).

[37] An anti-reflection film manufactured by a method according to any one of the above Item [1] through Item [32].

[38] An anti-reflection film manufactured by a method according to any one of the above Item [1] through [32], wherein said functional layer comprises a low refractive layer having the film thickness of 200 nm or less, and the low refractive layer is formed by the above described layer-forming method.

[39] An anti-reflection film according to the above Item [38], wherein the low refractive layer constituting the anti-reflection film comprises a fluorine-containing polymer.

[40] An anti-reflection film according to the above Item [39], wherein the fluorine-containing polymer is a fluorine-containing polymer expressed by the following general formula 1.

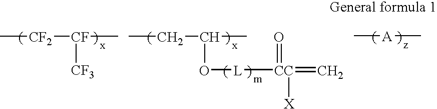

[In the general formula 1, L denotes a coupling group with a carbon number of 1 to 10 and m denotes 0 or 1. X denotes a hydrogen atom or methyl group. A denotes a polymerization unit of any optional vinyl monomer, which may be constituted with a single component or plural components. x, y and z denote mole % for the respective components, and values satisfying 30≦x≦60, 5≦y≦70 and 0≦z≦65.]

[41] An anti-reflection film according to any one of the above Item [38] through Item [40], wherein the low refractive layer contains hollow silica fine particles.

[42] A polarizing plate comprising: a polarizing film; two protective films that sandwich the polarizing film from both sides; and an anti-reflection film according to any one of the above Item [37] through Item [41], the anti-reflection film being provided on at least one of the two protective films.

[43] An image display device comprising: a display; and one of: an anti-reflection film according to any one of the above item [37] through Item [41]; and a polarizing plate according to the above Item [42], on an outer surface of the display.

### BRIEF DESCRIPTION OF THE DRAWINGS

FIG. 1 is a pattern diagram showing the apparatus equipped with the ionizing radiation reaction chamber and the anterior chamber to be used in the layer forming methods (III) to (V).

FIG. 2 is a side view showing one movement example of the web inlet plane of the apparatus equipped with the ionizing radiation reaction chamber and the anterior chamber to be used in the layer forming methods (III) to (V).

FIG. 3 is a pattern diagram showing one example of the web inlet plane of the anterior chamber of the apparatus equipped with the ionizing radiation reaction chamber and the anterior chamber to be used in the layer forming methods (III) to (V).

FIG. 4 is a side view of FIG. 3 showing schematically the movement of the web of the anterior chamber.

FIG. 5 is a sectional view showing schematically an example of the anti-reflection film having the anti-glare property.

FIG. 6 is a pattern diagram showing one example of the structure of the apparatus for manufacturing anti-reflection films of the present invention.

FIG. 7 is a schematic sectional view of one embodiment of die coaters preferably used in the present invention.

FIG. 8(A) is a schematic sectional view of the die coater of FIG. 7, and (B) is a schematic view of a conventional slot die.

FIG. 9 is a perspective view showing the slot die and the vicinity in the coating step for manufacturing an anti-reflection film of the present invention.

FIG. 10 is a sectional view showing schematically the relationship between the vacuum chamber and the web in FIG. 9.

FIG. 11 is a sectional view showing schematically the relationship between the vacuum chamber and the web in FIG. 9.

1 denotes an anti-glare anti-reflection film; 2 denotes a transparent substrate; 3 denotes an anti-glare layer; 4 denotes a low refractive layer; 5 denotes a light-transmitting fine particles; W denotes a web; 6 denotes a roll of substrate film; 7 denotes a reeling up roll; 100, 200, 300 and 400 denote film forming units; 101, 201, 301 and 401 denotes coating parts; 102, 202, 302 and 402 denote drying parts; 103, 203, 303 and 403 denote curing devices; 10 denotes a coater; 11 denotes a back-up roll; 13 denotes a slot die; 14 denotes a coating solution; 14a denotes a bead shape; 14b denotes a coated film; 15 denotes a pocket; 16 denotes a slot; 16a denotes a slot opening; 17 denotes a front-end lip; 18 denotes a land (flat part); 18a denotes a up-stream lip land; 18b denotes a down-stream lip land; I_{LO} denotes a land length of down-stream lip land 18b; I_{UP} denotes a land length of up-stream lip land 18a; LO denotes an overbite length; G_{L} denotes a clearance between front-end lip 17 and web W; 30 denotes a slot die; 31a denotes a up-stream lip land; 31b denotes a down-stream lip land; 32 denotes a pocket; 33 denotes a slot; 40 denotes a decompression chamber; 40a denotes a back plate; 40b denotes a side plate; 40c denotes a screw; G_{B} denotes a clearance between back plate 40a and web W; and Gₛ denotes a clearance between side plate 40b and web W.

### BEST MODE FOR CARRYING OUT THE INVENTION

Hereinafter, a detailed explanation will be made for the present invention. In this Description, when values referring to physical property values, characteristic values, etc., “(value 1) to (value 2)” means “not less than (value 1) but not more than (value 2).”

[Laminar Structure of Optical Film]

An optical film of the present invention is provided with at least one layer of functional layers on a transparent substrate (hereinafter sometimes referred to as substrate film). In this instance, the functional layer includes, for example, antistatic layer, hard-coat layer(cured resin layer), anti-reflection layer, anti-glare layer, optically compensated layer, orientation layer and liquid crystal layer. Among these, the anti-reflection film of the present invention is provided, whenever necessary, with a hard-coat layer to be explained later on the transparent substrate and also provided with an anti-reflection layer laminated thereon in such a way that the reflectance ratio can be reduced by optical interference, with consideration given to refractive index, film thickness, number of layers, sequence of layers and others. Hereinafter, a detailed explanation will be made for the optical film of the present invention by referring to examples of the anti-reflection film. The method for manufacturing optical films of the present invention can be applied to the method for manufacturing optically compensated films disclosed in Japanese Published Unexamined Patent Application No Hei-9-73081 and No. Hei-9-73016 and also to the method for manufacturing films high in surface hardness disclosed in Japanese Published Unexamined Patent Application No. 2003-335984 and No. 2003-341006.

The most simply constituted anti-reflection film is a film in which only a low refractive layer is applied on a substrate. In order to further reduce the reflectance ratio, it is preferable to constitute an anti-reflection layer by combining a high refractive layer whose refractive index is higher than that of a substrate with a low refractive layer whose refractive index is lower than that of the substrate. Examples of the constitution include a two-layered constitution of high refractive layer/low refractive layer from the side of the substrate and a three-layered constitution different in refractive index, namely, moderate refractive layer (layer whose refractive index is higher than that of the substrate or a hard-coat layer but lower than that of a high refractive layer)/high refractive layer/low refractive layer, are laminated in this order and more examples of lamination of anti-reflection layers have been proposed. In view of durability, optical characteristics, cost, productivity and others, particularly preferable is that having an anti-reflection layer in which layers are laminated on a substrate having a hard-coat layer in the order of moderate refractive layer/high refractive layer/low refractive layer. Further, the anti-reflection film of the present invention may have an anti-glare layer, an antistatic layer and others.

The following are preferable compositions of anti-reflection films of the present invention.

Substrate film/low refractive layer,

Substrate film/anti-glare layer/low refractive layer,

Substrate film/hard-coat layer/anti-glare layer/low refractive layer,

Substrate film/hard-coat layer/high refractive layer/low refractive layer,

Substrate film/hard-coat layer/moderate refractive layer/high refractive layer/low refractive layer,

Substrate film/anti-glare layer/high refractive layer/low refractive layer,

Substrate film/anti-glare layer/moderate refractive layer/high refractive layer/low refractive layer,

Substrate film/antistatic layer/hard-coat layer/moderate refractive layer/high refractive layer/low refractive layer,

Antistatic layer/substrate film/hard-coat layer/moderate refractive layer/high refractive layer/low refractive layer.

Substrate film/antistatic layer/anti-glare layer/moderate refractive layer/high refractive layer/low refractive layer,

Antistatic layer/substrate film/anti-glare layer/moderate refractive layer/high refractive layer/low refractive layer, and

Antistatic layer/substrate film/anti-glare layer/high refractive layer/low refractive layer/high refractive layer/low refractive layer.

The above anti-glare layer may be an inner light scattering layer without irregularities on the surface.

The anti-reflection film of the present invention is not particularly restricted to the compositions shown above, as long as the reflectance ratio can be reduced by optical interference. The high refractive layer may be a light diffusion layer which is without anti-glare property. It is also preferable that the antistatic layer includes electric conductive polymer particles or metal oxide fine particles (for example, SnO₂ and ITO), which can be provided by coating, atmospheric plasma treatment and others.

[Film Forming Method]

A method for manufacturing an optical film of the present invention is a method wherein at least one layer of layers to be laminated on a transparent substrate on the optical film is provided by using any one of the film forming methods of (I) to (V) shown below. It is preferable that a low refractive layer which is the outermost layer is prepared by the following layer forming method, in particular, where the optical film is an anti-reflection film.

(Layer Forming Method (I))

Layer forming method including the following steps of (1) and (2)

(1) step of applying a coated layer on the transparent substrate, and

(2) step of curing the coated layer by irradiating ionizing radiation in an environment in which the oxygen concentration is lower than the atmospheric oxygen concentration.

Hereinafter, an explanation will be made for the layer forming method (I) related to the present invention.

The coated layer on a transparent substrate is formed by applying to the transparent substrate a coating composition (coating solution) of a layer to be formed and drying the resultant. There are no particular restrictions on the method for applying the coating solution. Further, the transparent substrate of the present invention may be that cut out or that in a web state. However, the substrate in a web state is preferable in view of manufacturing cost.

A step of irradiating ionizing radiation is conducted in an environment where the oxygen concentration is lower than the atmospheric oxygen concentration in view of the film hardness, preferably at not more than 3% by volume, more preferably at not more than 1% by volume and still more preferably at not more than 0.1% by volume.

It is necessary that the step of irradiating ionizing radiation is conducted in an environment where the oxygen concentration is lower than the atmospheric oxygen concentration.

It is preferable that the above layer forming method (I) is provided with a step of transporting the film in an environment where the oxygen concentration is lower than the atmospheric oxygen concentration (hereinafter also referred to as low-oxygen concentration zone prior to irradiation of ionizing radiation), immediately before a step of irradiating ionizing radiation to the film on which a coated layer is applied (coated and dried). The curing step by irradiation of ionizing radiation is conducted continuously with the transporting step, thereby effectively reducing the oxygen concentration on and inside the coated film and promoting the curing step.

Here, a mode for conducting the curing step continuously with the transporting step is a mode in which the film transported into an environment of low oxygen-concentration (hereinafter also referred to as ionizing radiation irradiation zone) where the curing step is conducted is passed through the low oxygen-concentration zone where the oxygen concentration is lower than the atmospheric oxygen concentration immediately before advancement into the ionizing radiation irradiation zone, and there may be, for example, a mode in which the transporting step and the curing step are conducted in turn at the same chamber kept at low oxygen concentrations. The transporting step may include a step of drying the film.

The upper limit of the oxygen concentration in said transporting step before irradiation of ionizing radiation may be acceptable as long as it is lower than the atmospheric oxygen concentration, preferably not more than 15% by volume, more preferably not more than 10% by volume and most preferably not more than 5% by volume.

Further, the lower limit of the oxygen concentration in said transporting step before irradiation of ionizing radiation may be acceptable as long as it is higher than the oxygen concentration in the step of irradiating ionizing radiation in view of cost factors.

In the above layer forming method, it is also preferable to heat the film at the step of irradiating ionizing radiation and/or the transporting step before irradiation of ionizing radiation are conducted. It is preferable to heat the film so that the film surface temperature is 25° C. or more. Namely, heating is conducted to keep the film surface more preferably at 25° C. to 170° C., still more preferably at 60° C. to 170° C. and most preferably from 80° C. to 130° C. Heating conducted in the transporting step before irradiation of ionizing radiation can promote a smooth heating during irradiation of ionizing radiation. Heating during irradiation of ionizing radiation can thermally accelerate the curing reaction initiated by irradiation of ionizing radiation, thereby providing a film excellent in physical strength and drug resistance. Heating to the temperature of 25° C. or more can easily obtain heating effects and keeping the temperature below 170° C. makes it possible to avoid problems such as deformation of a substrate. Here, the film surface means a vicinity of the film surface of the layer to be cured.

Further, the film surface is kept at the above-described temperature preferably for 0.1 seconds or longer but 300 seconds or less from the start of irradiation of ionizing radiation and more preferably from 0.1 seconds or longer but 10 seconds or less. Keeping the film surface at the above temperature range for an excessively short time will result in poor progress of the reaction of film forming curing compositions. In contrast, keeping the film surface at the above temperature range for an excessively long time will result in a reduced optical performance of the film, posing manufacturing problems such as the necessity for larger facilities.

There are no particular restrictions on how to conduct heating. Preferable are a method in which the film is allowed to contact with a heated roll, that in which heated nitrogen is sprayed to the film and that in which a far-infrared ray or infrared ray is radiated. Also applicable is a method in which warm water or steam is fed into a rotating metal roll to conduct heating as disclosed in Patent No. 2523574.

The following is a more preferable mode of the layer forming method (I).

(Layer Forming Method (I)-1)

The layer forming method in which the following steps (1) to (3) are included and the following transporting step (2) and the curing step (3) are conducted continuously:

(1) step of applying a coated layer on the transparent substrate,

(2) step of transporting a film having the coated layer in an environment in which the oxygen concentration is lower than the atmospheric oxygen concentration, and

(3) step of curing the coated layer by irradiating ionizing radiation to the film in an environment where the oxygen concentration is not more than 3% by volume.

(Layer Forming Method (I)-2)

The layer forming method in which the following steps (1) to (3) are included and also the following transporting step (2) and curing step (3) are conducted continuously:

(1) step of applying a coated layer on the transparent substrate,

(2) step of transporting a film having the coated layer in an environment in which the oxygen concentration is lower than the atmospheric oxygen concentration, and

(3) step of curing the coated layer by irradiating ionizing radiation to the film in an environment where the oxygen concentration is not more than 3% by volume, while the film is heated so that the surface temperature is 25° C. or more.

(Layer Forming Method (I)-3)

Layer-forming method in which the following steps (1) to (3) are included and also the following transporting step (2) and curing step (3) are conducted continuously:

(1) step of applying a coated layer on the transparent substrate,

(2) step of transporting a film having the coated layer in an environment in which the oxygen concentration is lower than the atmospheric oxygen concentration, while the film is heated so that the surface temperature is 25° C. or more, and

(3) step of curing the coated layer by irradiating ionizing radiation to the film in an environment where the oxygen concentration is not more than 3% by volume.

(Layer Forming Method (I)-4)

The layer-forming method in which the following steps (1) to (3) are included and also the following transporting step (2) and curing step (3) are conducted continuously:

(1) step of applying a coated layer on the transparent substrate,

(2) step of transporting a film having the coated layer in an oxygen environment in which the oxygen concentration is lower than the atmospheric oxygen concentration, while the film is heated so that the surface temperature is 25° C. or more, and

(3) step of curing the coated layer by irradiating ionizing radiation to the film in an environment where the oxygen concentration is not more than 3% by volume, while the film is heated so that the surface temperature is 25° C. or more.

The above layer forming methods (layer forming method and layer forming method (I)-1 to -4) may be provided with a step of transporting the film after curing treatment in an environment where the oxygen concentration is not more than 3% by volume, while the film is heated so that the surface temperature is 25° C. or more in continuation with a curing step irradiating ionizing radiation.

The oxygen concentration in the transporting step after the curing step is more preferably at not more than 3% by volume and still more preferably at not more than 1% by volume. Film surface temperature on heating, retention time of the film surface temperature, heating methods and others are the same as those in the transporting step prior to the curing step as described before.

Heating the film after irradiation of ionizing radiation is also effective in allowing the polymerization reaction to proceed further even in a polymer film developed with the lapse of time.

The above-described layer forming methods are able to provide an anti-reflection film with a sufficient anti-reflection function and also an improved abrasion/scratch resistance.

As a means to reduce the oxygen concentration, it is preferable to substitute an atmosphere (nitrogen concentration, about 79% by volume; oxygen concentration, about 21% by volume) with another inert gas, and it is particularly preferable to substitute it with nitrogen (nitrogen purge).

In the above manufacturing methods according to the present invention, a step of irradiating ionizing radiation, a transporting step before irradiation of the ionizing radiation and a heating step which is conducted, whenever necessary, after irradiation of the ionizing radiation may be conducted in an individually separated manner or continuously as long as these are conducted in a low oxygen-concentration environment (low oxygen-concentration zone) where the oxygen concentration is controlled to a desired level. In view of reduced manufacturing costs, it is desirable that an inert gas used for reducing the oxygen concentration in the ionizing radiation zone is exhausted into a low oxygen-concentration zone (low-oxygen concentration zone prior to irradiation of ionizing radiation) where prior steps are conducted and/or a low oxygen concentration zone (low oxygen concentration zone after irradiation of ionizing radiation) where subsequent steps are conducted, thereby attaining an effective use of the inert gas.

Any step including the above-described steps may be conducted in a low oxygen concentration environment. Where ionizing radiation is irradiated at plural divided zones of irradiation of ionizing radiation, a low oxygen concentration zone may be provided each between these divided zones.

(Layer Forming Method (II))

The layer forming method (II) is a method for manufacturing an optical film having at least one layer of functional layers on a transparent substrate, the method for manufacturing an optical film wherein at least one layer of layers to be laminated on the transparent substrate (at least one layer of functional layers) is formed by a layer-forming method in which the following steps (1) to (3) are included and also the steps (2) and (3) are conducted continuously.

(1) step of applying a coated layer on the transparent substrate,

(2) step of irradiating ionizing radiation to a film having the coated layer in an environment where the oxygen concentration is not more than 3% by volume, and

(3) step of keeping the film after irradiation of ionizing radiation so that the surface temperature is 60° C. or less in an environment where the oxygen concentration is not more than 3% by volume.

Hereinafter, an explanation will be made for the layer forming method (II).

At least one layer of the above functional layers of an optical film, or of an anti-reflection film in particular is cured and formed by a step of keeping the layer so that the film surface temperature is kept 60° C. or less in an environment where the oxygen concentration is not more than 3% by volume in continuation with a step of irradiating ionizing radiation in an environment where the oxygen concentration is not more than 3% by volume.

As explained above, the film can be sufficiently cured to form a film excellent in physical strength and drug resistance by providing a step of keeping the film so that the film surface temperature is 60° C. or less in an environment where the oxygen concentration is not more than 3% by volume in continuation with a step of irradiation of ionizing radiation at the oxygen concentration of not more than 3% by volume. Further, the film surface is kept at a low temperature of 60° C. or less during curing, thereby not only contributing to a stable film formation and excellent surface finish, but also providing a film with a uniform abrasion/scratch resistance on the film surface.

The oxygen concentration during irradiation of ionizing radiation is not more than 3% by volume, preferably at not more than 1% by volume and more preferably at not more than 0.1%. The oxygen concentration in a step after irradiation of ionizing radiation is 3% by volume, preferably not more than 1% by volume and more preferably not more than 0.1% by volume.

As a means to reduce the oxygen concentration, it is preferable to substitute an atmosphere (nitrogen concentration, about 79% by volume; oxygen concentration, about 21% by volume) with another inert gas, and it is particularly preferable to substitute it with nitrogen (nitrogen purge).

In the layer forming method (II), an optical film is kept so that the surface temperature can be within 60° C. in an environment where the oxygen concentration is not more than 3% by volume in continuation with irradiation of ionizing radiation. The surface temperature of the optical film is kept preferably between 30° C. and 60° C. and more preferably between 40° C. and 60° C. An excessively low temperature will slow the curing progress and deterioration of the abrasion resistance, whereas an excessively high temperature will cause handling problems such as crimps on the surface and deterioration of the in-plane performance.

There are no particular restrictions on the film surface temperatures during irradiation of ionizing radiation. However, in view of easy handling and in-plane performance, a difference between the film surface temperature in a step of keeping the film surface temperature of 60° C. or less after irradiation of ionizing radiation and that during irradiation of ionizing radiation is preferably within 20° C. and more preferably within 10° C.

Further, the film after irradiation of ionizing radiation is kept at the above-described temperature preferably for 0.1 seconds or longer but 300 seconds or less from the start of irradiation of ionizing radiation and more preferably from 0.1 seconds or longer but 10 seconds or less. Keeping the film surface at the above temperature range for an excessively short time will result in a poor progress of the reaction of film forming curing compositions. In contrast, keeping the film surface at the above temperature range for an excessively long time will result in a reduced optical performance of the film, posing manufacturing problems such as the necessity for larger facilities.

There are no particular restrictions on how to keep the film surface temperature to a desired temperature of not more than 60° C. However, preferable are a method in which the film is allowed to contact with a heated roll, that in which heated nitrogen is sprayed to the film and that in which a far-infrared ray or infrared ray is radiated. Also applicable is a method in which warm water or steam is fed into a rotating metal roll to conduct heating as disclosed in Japanese Patent No. 2523574. A method is applicable in which the roll is cooled and allowed to contact with a film where the film surface temperature may exceed 60° C. due to irradiation to ionizing radiation.

It is preferable that a low refractive layer which is the outermost layer in particular is prepared by this method, where the optical film is an anti-reflection film.

Further, the layer forming method (II) may preferably be provided with a step of transporting a coated film not yet subjected to a step of irradiating ionizing radiation in an environment where the oxygen concentration is not more than 3% by volume and also higher than the oxygen concentration in the step of irradiating ionizing radiation (hereinafter referred to as low oxygen zone prior to irradiation of ionizing radiation) before the step of irradiating ionizing radiation. The step of transporting the film at a low oxygen concentration environment is conducted before the step of irradiating ionizing radiation, thereby effectively reducing the oxygen concentration on the surface of and inside the coated film and also promoting the curing step. The transport in this instance may assume a mode in which a step of passing a film having a coated layer on a transparent substrate through the low oxygen concentration zone prior to irradiation of ionizing radiation and continuously irradiating ionizing radiation is conducted, and the drying step and heating step may be included in the low oxygen concentration zone prior to irradiation of ionizing radiation.

The oxygen concentration in the transporting step before irradiation of ionizing radiation is preferably at not more than 3% by volume, more preferably at not more than 1% by volume and still more preferably at not more than 0.1%. Further, the lower limit of oxygen concentration in the transporting step before irradiation of ionizing radiation can be optimized, whenever necessary, in view of investment in facilities and running costs, however, preferably higher than the oxygen concentration in the step of irradiating ionizing radiation.

(Layer Forming Method (III))

A method for manufacturing an optical film according to the layer forming method (III) is provided with a step of forming at least one layer of functional layers on a transparent substrate by the following steps of (1) and (2).

(1) step of applying a coating solution containing an ionizing-radiation curable compound on a continuously running web which contains the transparent substrate and drying it to form a coated layer, and

(2) step of irradiating ionizing radiation to the coated layer on the web in an environment where the oxygen concentration is not more than 3% by volume and also keeping the web for 0.5 seconds or longer from the start of irradiation of the ionizing radiation in an environment where the oxygen concentration is not more than 3% by volume to cure the coated layer (hereinafter, (2) step of curing the coated layer is also referred to as “curing step”).

Hereinafter, an explanation will be made for the layer forming method (III).

Irradiation of ionizing radiation is conducted in an environment where the oxygen concentration is not more than 3% by volume, more preferably at not more than 1% by volume and more preferably at not more than 0.1% by volume. Reduction in oxygen concentration more than necessary will result in a larger consumption of inert gas, which is not favorable in terms of manufacturing costs. As a means to reduce the oxygen concentration, it is preferable to substitute an atmosphere (nitrogen concentration, about 79% by volume; oxygen concentration, about 21% by volume) with another inert gas, and it is particularly preferable to substitute it with nitrogen (nitrogen purge).

In the layer forming method (III), ionizing radiation is irradiated to the coated layer on the web in an environment where the oxygen concentration is not more than 3% by volume and the web is retained for 0.5 seconds or longer from the start of irradiation of ionizing radiation in an environment where the oxygen concentration is not more than 3% by volume to cure the coated layer. In the layer forming method (III), it is preferable that the web is retained in an environment where the oxygen concentration is not more than 3% by volume after completion of irradiation of ionizing radiation in particular. The retention time is preferably for 0.7 seconds or longer but for 60 seconds or less from the start of irradiation of ionizing radiation and more preferably for 0.7 seconds or longer but for 10 seconds or shorter. The retention time of less than 0.5 seconds will fail in completion of the curing reaction, resulting in an insufficient cure. The oxygen concentration during such retention is more preferably not more than 1% by volume and still more preferably not more than 0.1% by volume. Retaining low-oxygen concentration conditions for a long time will result in larger facilities and consequently require a larger amount of inert gas, which is not favorable.

Here, the web in this instance may be a substrate in itself or that prepared by forming other functional layers on the substrate.

In the layer forming method (III), it is preferable that the above-described curing step is conducted in an ionizing radiation irradiation reaction chamber (hereinafter also referred to as simply “reaction chamber”) where the oxygen concentration is controlled to a desired level. Removal of conducting air in association with transport of a web makes it possible to effectively reduce the oxygen concentration in the reaction chamber and also efficiently lower the actual oxygen concentration on the immediate surface which greatly contributes to oxygen-derived curing inhibition, under the condition that the air may slightly come out from the web inlet side (an inlet for transporting the web) in the reaction chamber in supplying an inert gas to the ionizing radiation reaction chamber. Flowing direction of the inert gas at the web inlet side in the reaction chamber can be controlled by adjusting supply and discharge of air in the reaction chamber. It is also preferable that the inert gas is sprayed directly to the surface of the coated layer on the web immediately before irradiation of ionizing radiation to the coated layer on the web, as a method for removing the conducting air.

In particular, it is preferable that a low refractive layer which is the outermost layer and also whose film thickness is thin is cured by this method.

Further, it is preferable to provide an anterior chamber in front of the reaction chamber. Air in the anterior chamber should be substituted with an inert gas and kept at low oxygen concentrations, and the oxygen concentration of the anterior chamber is preferably at not more than 3% but higher than that of the reaction chamber. The web before irradiation of ionizing radiation may be passed through (transported) the chamber or an inert gas may be directly sprayed to the surface of the coated layer on the web, which is the above-described method for removing the conducting air.

Providing an anterior chamber for removing oxygen on the surface of the coated layer on the web in advance makes it possible to keep the reaction chamber at low oxygen concentrations and effectively promote the curing step.

Further, a gap with the surface of the coated layer on the web is preferably from 0.2 to 15 mm at least on one of the side planes constituting the web inlet side of the ionizing radiation reaction chamber or the anterior chamber for attaining an effective use of an inert gas, more preferably from 0.2 to 10 mm and most preferably from 0.2 to 5 mm. The gap in this instance means a length between the surface of the coated layer on the web and the upper end of the web inlet on the side plane constituting the web inlet side.

A continuous manufacturing of webs, however, requires jointing and connecting the webs, which is performed widely by a method of affixing them using an adhesive tape and others. Therefore, an excessively small gap between the inlet of the ionizing radiation reaction chamber or the anterior chamber and the surface of the coated layer on the web will pose a problem that joint members such as adhesive tape may be caught. Thus, in making the gap small, it is preferable that a plane constituting the inlet side of the ionizing radiation reaction chamber or the anterior chamber is at least partially movable and structured so as to widen the gap by the amount of thickness of a joint member when the joint part is passed. For this purpose, the following methods can be employed: (A) method in which the plane constituting the inlet of the ionizing radiation reaction chamber or the anterior chamber is rendered movable back and forth in the direction of movement so as to move back and forth on passage of the joint part, thereby widening the gap, or (B) method in which the plane constituting the inlet of the ionizing radiation reaction chamber or the anterior chamber is rendered vertically movable in relation to the web surface so as to move up and down on passage of the joint part, thereby widening the gap.

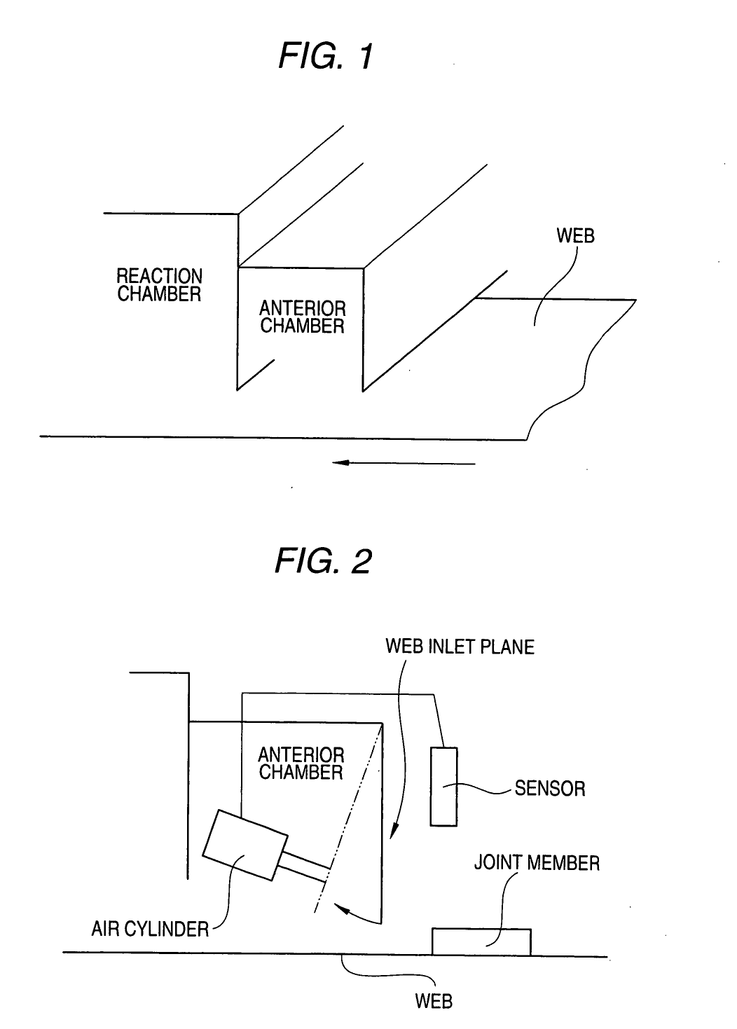

Hereinafter, an explanation will be made for movement examples of the plane constituting the web inlet of the reaction chamber or the anterior chamber, which is applicable to the layer forming method (III) on the basis of FIG. 1 to FIG. 4, by referring to the movement of the plane constituting the web inlet of the anterior chamber (in the following explanation on the figures, a web having a coated layer (not illustrated) is simply referred to as “web”).

FIG. 1 is a pattern diagram of the manufacturing apparatus equipped with the ionizing radiation reaction chamber and the anterior chamber to be used in the layer forming method (III).

FIG. 2 is a side view showing one movement example of a web inlet plane of the manufacturing apparatus equipped with the ionizing radiation reaction chamber and the anterior chamber to be used in the layer forming method (III). This view illustrates a mode of the above (A). The apparatus constituted as explained in FIG. 2 is designed to detect a joint member by using a sensor before advancement of the joint member jointing and connecting the webs into an inlet of the anterior chamber at the time of transporting webs and move the inlet plane back and forth in the direction of movement of webs by an air cylinder installed at least at a part of the web inlet plane of the anterior chamber actuating in conjunction with the sensor via a control part (not illustrated), by which the thickness of the joint member can be accepted.

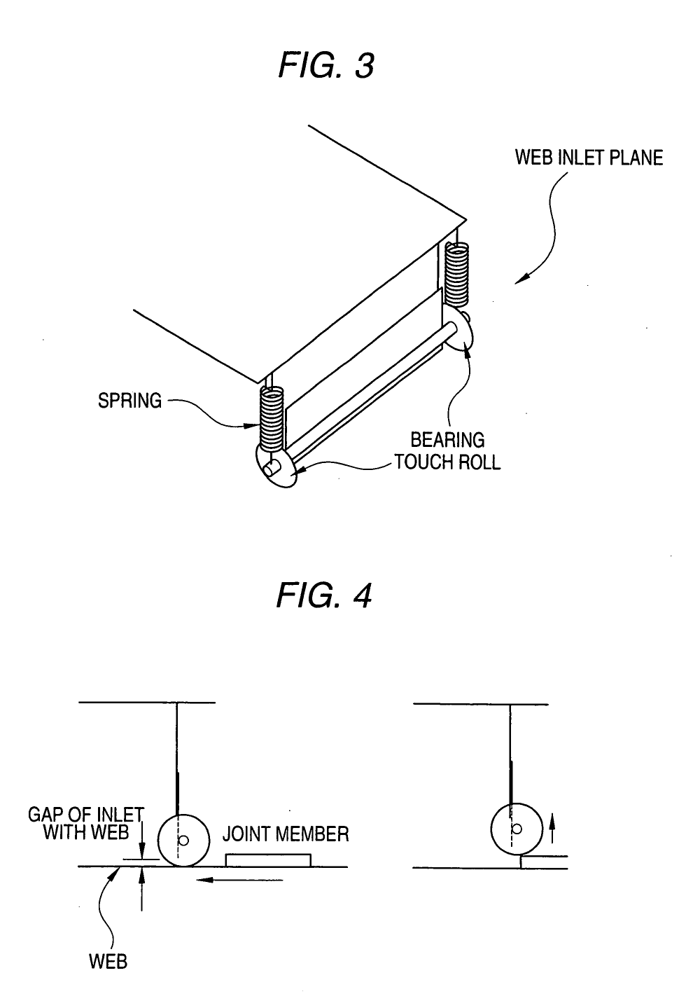

FIG. 3 and FIG. 4 are views showing a mode of the above (B), FIG. 3 is a pattern diagram showing the web inlet plane of the anterior chamber and FIG. 4 is a pattern diagram showing a movement of the web inlet plane of the anterior chamber. A gap of the inlet plane with a web can be determined by making the web inlet plane of the anterior chamber partially movable and allowing both ends of the web on the width direction to contact by using a bearing touch roll. When a joint member is passed, the bearing touch roll rides over the joint member to keep a gap of the web inlet plane constant. There are no restrictions on a means of moving the inlet, as long as it is designed to accept the joint part.

In the layer forming method (III), when a step of curing a coated layer on a web is conducted, it is preferable to conduct a plurality of times irradiation of ionizing radiation which is performed at the oxygen concentration of not more than 3% by volume in the curing step.

In this instance, it is also preferable that irradiation of ionizing radiation is conducted at least twice in a continuous reaction chamber where the oxygen concentration is not more than 3% by volume. The reaction time necessary for curing can be effectively secured by conducting a plurality of times irradiation of ionizing radiation in the reaction chamber where low oxygen concentrations are kept the same. In particular, where the manufacturing speed is increased for attaining a higher productivity, it is necessary to conduct a plurality of times irradiation of ionizing radiation for securing energy of ionizing radiation needed for the curing reaction, and the above mode is effective also in view of securing the time necessary for the curing reaction.

“Continuous reaction chamber” is a mode in which irradiation of ionizing radiation is conducted at least twice in a reaction chamber where the oxygen concentration is not more than 3% by volume and a mode in which at least two reaction chambers where the oxygen concentration is not more than 3% by volume are provided and a low oxygen zone where the oxygen concentration is not more than 3% by volume is installed between the reaction chambers. In the latter mode, the reaction chambers may have different oxygen concentrations, as long as the oxygen concentration is not more than 3% by volume.

It is also preferable that the above curing step is conducted while a web is heated so that the surface temperature of a coated layer is 60° C. or more, according to the layer forming method (III). Conducting the above curing step at heating makes it possible to thermally accelerate the curing reaction, thereby providing a film excellent in physical strength and drug resistance.

It is preferable to conduct heating so that the surface temperature of the coated layer is in the range from 60° C. to 170° C. Thermal cure will proceed to a less extent at temperatures of less than 60° C., whereas problems occur such as deformation of a substrate at temperatures exceeding 170° C. It is more preferable to conduct heating at temperatures from 60° C. to 100° C. Further, the surface of the coated layer is retained at the temperature range preferably for 0.1 seconds or longer but for 300 seconds or less from the start of irradiation of ionizing radiation and more preferably for 10 seconds or less. An excessively short time for retaining the surface of the coated layer at the above temperature range will result in failure in promoting the reaction of curing compositions constituting a film, whereas an excessively long time will reduce the optical performance of a film and also pose manufacturing problems such as the necessity for larger facilities.

There are no particular restrictions on how to conduct heating. Preferable are a method in which the film is allowed to contact with a heated roll, that in which heated nitrogen is sprayed to the film and that in which a far-infrared ray or infrared ray is radiated. Also applicable is a method in which a medium such as warm water, steam or oil is fed into a rotating metal roll to conduct heating as disclosed in the U.S. Pat. No. 2,523,574. A dielectric heating roll and others may be used as heating means.

(Layer Forming Method (IV))

A method for manufacturing an optical film according to the layer forming method (IV) is provided with a step of forming at least one layer of functional layers on a transparent substrate by the following steps of (1) and (2).

(1) step of applying a coating solution containing an ionizing-radiation curable compound on a continuously running web which contains the transparent substrate and drying it to form a coated layer,

(2) step of irradiating ionizing radiation to the coated layer on the web in an environment where the oxygen concentration is not more than 3% by volume and also keeping the web in an environment where the oxygen concentration is not more than 3% by volume until polymerization reaction of the ionizing-radiation curable compound completes at least 50% to cure the coated layer (hereinafter also referred to as “curing step” for (2) step of curing the coated layer).

Hereinafter, an explanation will be made for the layer forming method (IV).

The rate of polymerization reaction (polymerization rate) of ionizing-radiation curable compounds can be determined by the method for measuring infrared absorption described in Polymer Analysis Handbook (edited by the Research Committee of Polymer Analysis, the Japan Society for Analytical Chemistry). To be specific, said functional layer is coated on polyethylene terephthalate or tri-acetyl cellulose as a single layer, which is then dried and subjected to irradiation of ionizing radiation under predetermined conditions to prepare samples. KBr powder is rubbed onto the sample and the rubbed KBr powder is thoroughly mixed in a mortar and determined for infrared absorption. The determination is made by using FT-I R model AVATAR360 manufactured by Nicolet Corporation 40 times to obtain integrated values. A similar determination is also made for another sample not subjected to irradiation of ionizing radiation, and the determination ratio obtained by these two samples is designated as the polymerization rate.

When a film whose polymerization rate is less than 50% is placed in an environment where the oxygen concentration is 3% by volume or higher, the reaction will cease and problems such as lowering of abrasion/scratch resistance will occur. The polymerization rate is preferably between 70% and 98% and more preferably between 80% and 98%. However, an excessively high polymerization rate may cause problems such as a larger low oxygen zone and an increased consumption of an inert gas.

Irradiation of ionizing radiation should be conducted in an environment where the oxygen concentration is not more than 3% by volume, more preferably not more than 1% by volume and still more preferably not more than 0.1% by volume. Reduction in oxygen concentration more than necessary will result in a larger consumption of an inert gas, which is not favorable in terms of manufacturing costs. As a means to reduce the oxygen concentration, it is preferable to substitute an atmosphere (nitrogen concentration, about 79% by volume; oxygen concentration, about 21% by volume) with another inert gas, and it is particularly preferable to substitute it with nitrogen (nitrogen purge).

The web in this instance may be a substrate in itself or that prepared by forming other functional layers on the substrate.

In the layer forming method (IV), it is preferable that the above-described curing step is conducted in an ionizing radiation irradiation reaction chamber (hereinafter also referred to as simply “reaction chamber”) where the oxygen concentration is controlled to a desired level. Removal of conducting air in association with transport of a web makes it possible to effectively reduce the oxygen concentration in the reaction chamber and also efficiently lower the actual oxygen concentration on the immediate surface which greatly contributes to oxygen-derived curing inhibition, under the condition that some of the air may come out from a web inlet (an inlet for transporting the web) in the reaction chamber in supplying an inert gas to the ionizing radiation reaction chamber. Flowing direction of the inert gas at the web inlet in the reaction chamber can be controlled by adjusting supply and discharge of air in the reaction chamber. It is also preferable that the inert gas is sprayed directly to the surface of the coated layer on the web immediately before irradiation of ionizing radiation to the coated layer on the web, as a method for removing the conducting air.

It is preferable that a low refractive layer which is the outermost layer in particular and also whose film thickness is thin is cured by this method.

Further, it is preferable to provide an anterior chamber in front of the reaction chamber. Air in the anterior chamber should be substituted with an inert gas and kept at low oxygen concentrations, and the oxygen concentration of the anterior chamber is preferably not more than 3% but higher than that of the reaction chamber. The web before irradiation of ionizing radiation may be just passed through (transported) the chamber or an inert gas may be directly sprayed to the surface of the coated layer on the web, which is the above-described method for removing the conducting air.

Providing an anterior chamber for removing oxygen on the surface of the coated layer on the web in advance makes it possible to keep the reaction chamber at low oxygen concentrations and effectively promote the curing step.

Further, a gap with the surface of the coated layer on the web is preferably from 0.2 to 15 mm at least on one of the side planes constituting the web inlet side of the ionizing radiation reaction chamber or the anterior chamber for attaining an effective use of an inert gas, more preferably from 0.2 to 10 mm and most preferably from 0.2 to 5 mm. The gap in this instance means a length between the surface of the coated layer on the web and the upper end of the web inlet on the side plane constituting the web inlet side.

A continuous manufacturing of webs, however, requires jointing and connecting the webs, which is done widely by a method of affixing them using an adhesive tape and others. Therefore, an excessively small gap between the inlet of the ionizing radiation reaction chamber or the anterior chamber and the surface of the coated layer on the web will pose a problem that joint members such as adhesive tape may be caught. Thus, in making the gap small, it is preferable that a plane constituting the inlet side of the ionizing radiation reaction chamber or the anterior chamber is at least partially movable and structured so as to widen the gap by the amount of thickness of a joint member when the joint part is passed. For this purpose, the following methods can be employed: (A) method in which the plane constituting the inlet of the ionizing radiation reaction chamber or the anterior chamber is rendered movable back and forth in the direction of movement so as to move back and forth on passage of the joint part, thereby widening the gap, or (B) method in which the plane constituting the inlet of the ionizing radiation reaction chamber or the anterior chamber is rendered vertically movable in relation to the web surface so as to move up and down on passage of the joint part, thereby widening the gap.

Hereinafter, an explanation will be made for movement examples of a plane constituting the web inlet of the reaction chamber or the anterior chamber which is applicable to the layer forming method (IV) on the basis of FIGS. 1 to 4, by referring to the movement of the plane constituting the web inlet of the anterior chamber (in the following explanation on the figures, a web having a coated layer (not illustrated) is simply referred to as “web”).

FIG. 1 is a pattern diagram of the manufacturing apparatus equipped with the ionizing radiation reaction chamber and the anterior chamber to be used in the layer forming method (IV).

FIG. 2 is a side view showing one movement example of a web inlet plane of the manufacturing apparatus equipped with the ionizing radiation reaction chamber and the anterior chamber to be used in the layer forming method (IV). This view illustrates a mode of the above (A). The apparatus constituted as explained in FIG. 2 is designed to detect a joint member by using a sensor before advancement of the joint member jointing and connecting webs into an inlet of the anterior chamber at the time of transporting webs and move the inlet plane back and forth in the direction of movement of webs by an air cylinder installed at least at a part of the web inlet plane of the anterior chamber actuating in conjunction with the sensor via a control part (not illustrated), by which the thickness of the joint member can be accepted.

FIG. 3 and FIG. 4 are views showing a mode of the above (B), FIG. 3 is a pattern diagram showing the web inlet plane of the anterior chamber and FIG. 4 is a pattern diagram showing a movement of the web inlet plane of the anterior chamber. A gap of the inlet plane with a web can be determined by making the web inlet plane of the anterior chamber partially movable and allowing both ends of the web on the width direction to contact by using a bearing touch roll. When a joint member is passed, the bearing touch roll rides over the joint member to keep a gap of the web inlet plane constant. There are no restrictions on a means of moving the inlet, as long as it is designed to accept the joint member.

In the layer forming method (IV), when a step of curing a coated layer on a web is conducted, it is preferable to conduct a plurality of times irradiation of ionizing radiation which is conducted at the oxygen concentration of not more than 3% by volume in the curing step.

In this instance, it is also preferable that irradiation of ionizing radiation is conducted at least twice in a continuous reaction chamber where the oxygen concentration is not more than 3% by volume. The reaction time necessary for curing can be effectively secured by conducting a plurality of times irradiation of ionizing radiation in the reaction chamber where low oxygen concentrations are kept the same. In particular, where the manufacturing speed is increased for attaining a higher productivity, it is necessary to conduct a plurality of times irradiation of ionizing radiation for securing energy of ionizing radiation needed for the curing reaction, and the above mode is effective also in view of securing the time necessary for the curing reaction.

“Continuous reaction chamber” is a mode in which irradiation of ionizing radiation is conducted at least twice in a reaction chamber where the oxygen concentration is not more than 3% by volume or a mode in which at least two reaction chambers where the oxygen concentration is not more than 3% by volume are provided and a low oxygen zone where the oxygen concentration is not more than 3% by volume is installed between the reaction chambers. In the latter mode, the reaction chambers may have different oxygen concentrations, as long as the oxygen concentration is not more than 3% by volume.

In the layer forming method (IV), it is also preferable that the above curing step is conducted while a web is heated so that the surface temperature of a coated layer is 60° C. or more. Conducting the above curing step while heating makes it possible to thermally accelerate the curing reaction, thereby providing a film excellent in physical strength and drug resistance. Further, the low oxygen zone can be made smaller due to a smooth progress of the polymerization, which is another advantage.

It is preferable to conduct heating so that the surface temperature of the coated layer is in the range from 60° C. to 170° C. Thermal curing will proceed to a lesser extent at temperatures of less than 60° C., whereas problems occur such as deformation of a substrate at temperatures exceeding 170° C. It is more preferable to conduct heating at temperatures from 60° C. to 100° C. Further, the surface of the coated layer is retained at the temperature range preferably for 0.1 seconds or longer but for 300 seconds or less from the start of irradiation of ionizing radiation and more preferably for 10 seconds or less. An excessively short time for retaining the surface of the coated layer at the above temperature range will result in failure in promoting the reaction of curing compositions constituting a film layer, whereas an excessively long time will reduce the optical performance of a film and also pose manufacturing problems such as the necessity for larger facilities.

There are no particular restrictions on how to conduct heating. Preferable are a method in which the film is allowed to contact with a heated roll, that in which heated nitrogen is sprayed to the film and that in which a far-infrared ray or infrared ray is radiated. Also applicable is a method in which a medium such warm water, steam or oil is fed into a rotating metal roll to conduct heating as disclosed in Japanese Patent No. 2523574. A dielectric heating roll and others may be used as heating means.

(Layer Forming Method (V))

The layer forming method (V) is a method for continuously manufacturing an optical film having at least one layer of functional layers on a transparent substrate in a web state, wherein at least one layer of layers to be laminated on the transparent substrate is formed by a layer-forming method including the following steps (1) and (2):

(1) step of applying a coating solution containing at least one type of oxime polymerization initiators on a transparent-web substrate and drying it to form a coated layer, and

(2) step of irradiating ionizing radiation to a coated layer on the transparent web substrate in an environment where the oxygen concentration is not more than 3% by volume and also keeping the transparent web substrate for 0.5 seconds or longer from the start of irradiation of the ionizing radiation in an environment where the oxygen concentration is not more than 3% by volume to cure the coated layer.

Hereinafter, an explanation will be made for the layer forming method (V).

The layer forming method (V) is a method by which at least one layer of constituting layers on a transparent web substrate is cured and formed by a step of applying a coating solution containing at least one type of oxime polymerization initiators, particularly those described in the general formulae (1) through (4) shown below, on the transparent web substrate and drying it, then, irradiating ionizing radiation in an environment where the oxygen concentration is not more than 3% by volume, and also keeping it for 0.5 seconds or longer from the start of irradiation of ionizing radiation in an environment where the oxygen concentration is not more than 3% by volume.

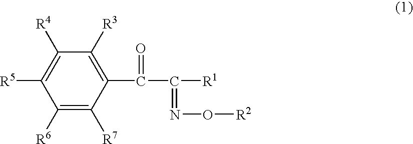

[In the formula (1), R¹ denotes a phenyl group (however, it may be substituted with one or more alkyl groups having a carbon number of 1 to 6, phenyl groups, halogen atoms, —OR⁸, —SR⁹ or —N(R¹⁰)(R¹¹)), alkyl groups having a carbon number of 1 to 20 (however, in a case where an alkyl group having a carbon number of 2 to 20, it may be provided with one or more oxygen atoms between main chains of carbon atoms and/or substituted with one or more hydroxyl groups), cycloalkyl group having a carbon number of 5 to 8, alkanoyl group having a carbon number of 2 to 20 and benzoyl group (however, they may be substituted with one or more alkyl groups having a carbon number of 1 to 6, phenyl groups, —OR⁸, —SR⁹ or —N(R¹⁰)(R¹¹)), alkoxycarbonyl group having a carbon number of 2 to 12 (however, in a case where an alkoxy group having a carbon number of 2 to 11, the alkoxy group may be provided with one or more oxygen atoms between main chains of carbon atoms and/or substituted with one or more hydroxyl groups), phenoxycarbonyl group (however, it may be substituted with one or more alkyl group having a carbon number of 1 to 6, phenyl group, halogen atom, —OR⁸ or —N(R¹⁰)(R¹¹)), cyano group, nitro group, —CON(R¹⁰)(R¹¹), haloalkyl group having a carbon number of 1 to 4, —S(O)ₘ—R¹² (however, R¹² denotes an alkyl group having a carbon number of 1 to 6, and m is 1 or 2), —S(O)ₘ—R¹³ (however, R¹³ denotes aryl group having a carbon number of 6 to 12, which may be substituted with an alkyl group having a carbon number of 1 to 12, and m is 1 or 2), alkoxysulfonyl group having a carbon number of 1 to 6, aryloxysulfonyl group having a carbon number of 6 to 10 or diphenylsulfonyl group;

R² denotes an alkanoyl group having a carbon number of 2 to 12 (however, it may be substituted with one or more halogen atoms or cyano groups), alkenoyl group, having a carbon number of 4 to 6 whose double bond is not conjugated with a carbonyl group, benzoyl group (however, it may be substituted with one or more alkyl groups having a carbon number of 1 to 6, halogen atoms, cyano groups, —OR⁸, —SR⁹ or —N(R¹⁰)(R¹¹)), alkoxycarbonyl group having a carbon number of 2 to 6 or phenoxycarbonyl group (however, they may be substituted with one or more alkyl groups having a carbon number of 1 to 6 or halogen atoms);

R³, R⁴, R⁵, R⁶ and R⁷ denote in a mutually independent manner a hydrogen atom, halogen atom, an alkyl group having a carbon number of 1 to 12, cyclopentyl group, cyclohexyl group, or phenyl group (they may be substituted with one or more —OR⁸, —SR⁹ or —N(R¹⁰)(R¹¹)), benzyl group, benzoyl group, alkanoyl group having a carbon number of 2 to 12 and alkoxycarbonyl group having a carbon number of 2 to 12 (however, in a case where alkoxy group having a carbon number of 2 to 11, the alkoxy group may be provided with one or more oxygen atoms between main chains of carbon atoms and/or substituted with one or more hydroxyl groups), phenoxycarbonyl group, —OR⁸ (however, R⁸ may form 5-membered rings or 6-membered rings, together with one carbon atom in phenyl ring or in substituent to phenyl ring), —SR⁹ (however, R⁹ may form 5-membered rings or 6-membered rings, together with one carbon atom in phenyl ring or in substituent to phenyl ring), —S(O)R⁹ (however R⁹ may form 5-membered rings or 6-membered rings, together with one carbon atom in a phenyl ring or in substituent to a phenyl ring), —SO₂R⁹ (however R⁹ may form 5-membered rings or 6-membered rings, together with one carbon atom in a phenyl ring or in substituent to a phenyl ring) or —N(R¹⁰)(R¹¹) (however R¹⁰ and /or R¹¹ may form 5-membered rings or 6-membered rings, together with one carbon atom in a phenyl ring or in substituent to a phenyl ring) and also at least any one of R³, R⁴, R⁵, R⁶ and R⁷ is —OR⁸, —SR⁹ or —N(R¹⁰)(R¹¹);

R⁸ denotes a hydrogen atom, an alkyl group having a carbon number of 1 to 12, substituted alkyl group having a carbon number of 2 to 6 (however, the substitutent consists of one or more hydroxyl groups, mercapto groups, cyano groups, alkoxy groups having a carbon number of 1 to 4, alkenyloxy groups having a carbon number of 3 to 6, 2-cyanoetoxy groups, 2-(alkoxycarbonyl)etoxy groups having a carbon number of 4 to 7, alkylcarbonyloxy groups having a carbon number of 2 to 5, phenylcarbonyloxy groups, carboxyl groups or alkoxycarbonyl groups having a carbon number of 2 to 5), alkyl group with carbon number of 2 to 6 having one or more oxygen atoms between main chains of carbon atoms, alkanoyl group having a carbon number 2 to 8, —(CH₂CH₂O)ₙH (however, n is an integral number from 1 to 20), alkenyl group having a carbon number of 3 to 12, alkenoyl group having a carbon number of 3 to 6, cyclohexyl group, phenyl group (however, they may be substituted with a halogen atom, alkyl group having a carbon number of 1 to 12 or alkoxy group having a carbon number of 1 to 4), phenylalkyl group having a carbon number of 7 to 9, —Si(R¹⁴)ᵣ(R¹⁵)₃₋ᵣ (however, R¹⁴ denotes an alkyl group having a carbon number of 1 to 8, R¹⁵ denotes a phenyl group, and r is an integral number from 1 to 3),

the group expressed by the following formula, 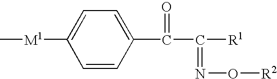
or the group expressed by the following formula,

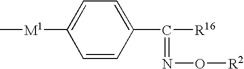

R⁹ denotes a hydrogen atom, a alkyl group having a carbon number of 1 to 12, alkenyl group having a carbon number of 3 to 12, cyclohexyl group, substituted alkyl group having a carbon number of 2 to 6 (however, the substitutent consists of one or more hydroxyl groups, mercapto groups, cyano groups, alkoxy groups having a carbon number of 1 to 4, alkenyloxy groups having a carbon number of 3 to 6, 2-cyanoetoxy groups, 2-(alkoxycarbonyl)etoxy groups having a carbon number of 4 to 7, alkylcarbonyloxy groups having a carbon number of 2 to 5, phenylcarbonyloxy groups, carboxyl groups or alkoxycarbonyl groups having a carbon number of 2 to 5), alkyl group of having a carbon number of 2 to 12 having one or more oxygen atoms or sulfur atoms between main chains of carbon atoms, phenyl group (however, they may be substituted with a halogen atom, alkyl group having a carbon number of 1 to 12 or alkoxy group having a carbon number of 1 to 4), phenylalkyl group having a carbon number of 7 to 9,

the group expressed by the following formula,

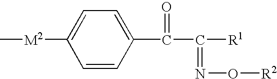

or the group expressed by the following formula,

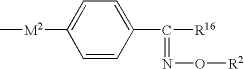

R¹⁰ and R¹¹ denote in a mutually independent manner a hydrogen atom, alkyl group having a carbon number of 1 to 12, hydroxyalkyl group having a carbon number of 2 to 4, alkoxyalkyl group having a carbon number of 2 to 10, alkenyl group having a carbon number of 3 to 5, cycloalkyl group having a carbon number of 5 to 12, phenylalkyl group having a carbon number of 7 to 9, phenyl group (however, they may be substituted with one or more alkyl groups having a carbon number of 1 to 12 or alkoxy groups having a carbon number of 1 to 4), alkanoyl group having a carbon number of 2 to 3, alkenoyl group having a carbon number of 3 to 6 and benzoyl group, or R¹⁰ and R¹¹ jointly denote an alkylene group having a carbon number of 2 to 6 (however, they may be provided with one or more oxygen atoms or —NR⁸— between main chains of carbon atoms and/or substituted with one or more hydroxyl groups, alkoxy groups having a carbon number of 1 to 4, alkanoyloxy groups having a carbon number of 2 to 4 or benzoyloxy groups), or when R¹⁰ is hydrogen atom, R¹¹ denotes

the group expressed by the following formula,

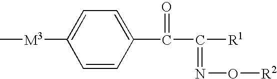

or the group expressed by the following formula,

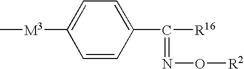

R¹⁶ denotes an alkoxycarbonyl group having a carbon number of 2 to 12 (however, in a case where the alkoxy group having a carbon number of 2 to 11, the alkoxy group may be provided with one or more oxygen atoms between main chains of carbon atoms and/or substituted with one or more hydroxyl groups), phenoxycarbonyl group (however, it may be substituted with one or more alkyl groups having a carbon number of 1 to 6, halogen atoms, phenyl groups, —OR⁸ or —N(R¹⁰)(R¹¹)), cycloalkyl group having a carbon number of 5 to 8, —CON(R¹⁰)(R¹¹), cyano group, substituted phenyl group (however, the substitutent is —SR⁹), or alkyl group having a carbon number of 1 to 12 (however, it may be substituted with one or more halogen atoms, hydroxyl groups, —OR², phenyl group, halogenated phenyl group or —SR⁹ and/or provided with one or more oxygen atoms or —NH(CO)— between main chains of carbon atoms);

M¹ denotes a direct bond or —R¹⁷—O—; M² denotes direct bond or —R¹⁷—S—; M³ denotes direct bond or piperazine group or —R¹⁷—NH—; R¹⁷ denotes alkylene group having a carbon number of 1 to 12 (however, where it has a carbon number of 2 to 12, it may be provided with one to five of oxygen atom, sulfur atoms or —NR¹⁰— between main chains of carbon atoms)]

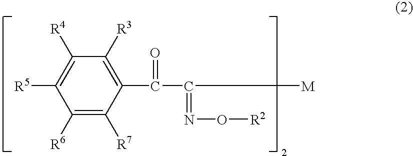

[In the formula (2), R², R³, R⁴, R⁵, R⁶ and R⁷ are respectively synonymous with R², R³, R⁴, R⁵, R⁶ and R⁷ in the formula (1), M denotes an alkylene group having a carbon number of 1 to 12, cyclohexylene group, phenylene group, —COO—R¹⁸—OCO—, —COO—(CH₂CH₂O)ₙ—CO-(however, n is an integral number from 1 to 20) or —CO—R¹⁸—CO—; R¹⁸ denotes an alkylene group having a carbon number of 2 to 12]

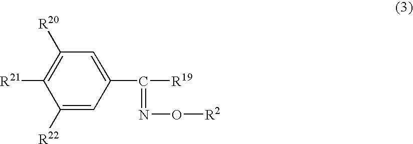

[In the formula (3), R² is synonymous with R² in the formula (1); R¹⁹ denotes an alkoxycarbonyl group having a carbon number of 2 to 12 (however, in a case where alkoxy group having a carbon number of 2 to 11, the alkoxy group concerned may be provided with one or more oxygen atoms between main chains of carbon atoms and/or substituted with one or more hydroxyl groups), phenoxycarbonyl group (however, it may be substituted with one or more alkyl groups having a carbon number of 1 to 6, halogen atoms, phenyl groups, —OR⁸ or —N(R¹⁰)(R¹¹)), cycloalkyl group having a carbon number of 5 to 8, —CON(R¹⁰)(R¹¹), cyano group, or substituted phenyl group (however, the substitutent is —SR⁹) or it may bond to carbon atoms in a phenyl ring having R²⁰, R²¹ and R²², and form 5-membered rings or 6-membered rings via the group R⁹, or R¹⁹ denotes alkyl groups having a carbon number of 1 to 12 when at least any one of R²⁰, R²¹ and R²² is —SR⁹, (however, where a carbon number is 2 to 12, it may be provided with one or more oxygen atoms or —NH(CO)— between main chains of carbon atoms and/or substituted with one or more halogen atoms, hydroxyl groups, —OR², phenyl group, halogenated phenyl group or substituted phenyl groups (however, the substituent is —SR⁹));

R²⁰, R²¹ and R²² denote in a mutually independent manner a hydrogen atom, halogen atom, alkyl group having a carbon number of 1 to 12, cyclopentyl group, cyclohexyl group, phenyl group (however, they may be substituted with one or more —OR⁸, —SR⁹ or —N(R¹⁰)(R¹¹)), benzyl group, benzoyl group, alkanoyl group having a carbon number of 2 to 12, alkoxycarbonyl group having a carbon number of 2 to 12 (however, in a case where the alkoxy group having a carbon number of 2 to 11, the alkoxy group concerned may be provided with one or more oxygen atoms between main chains of carbon atoms and/or substituted with one or more hydroxyl group), phenoxycarbonyl group, —OR⁸ (however, R⁸ may form 5-membered rings or 6-membered rings together with one carbon atom in a phenyl ring or in substituent to a phenyl ring), —SR⁹ (however, R⁹ may form 5-membered rings or 6-membered rings together with one carbon atom in a phenyl ring or in substituent to a phenyl ring), —S(O)R⁹, —SO₂R⁹ or —N(R¹⁰)(R¹¹) (however, R¹⁰ and/or R¹¹ may form 5-membered rings or 6-membered rings together with one carbon atom in a phenyl ring or in substituent to a phenyl ring), and at least any one of R²⁰, R²¹ and R²² is —OR⁸, —SR⁹ or —N(R¹⁰)(R¹¹), and R⁸, R⁹, R¹⁰ and R¹¹ are respectively synonymous with R⁸, R⁹, R¹⁰ and R¹¹ in the formula (1)]

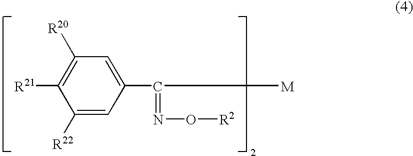

[In the formula (4), R² and M are respectively synonymous with R² in the formula (1) and M in the formula (2); and R²⁰, R²¹ and R²² are respectively synonymous with R²⁰, R²¹ and R²² in the formula (3)]

There are no particular restrictions on a quantity of initiators. They are preferably added in 0.1 to 15 parts by mass to 100 parts by mass of multifunctional monomer and more preferably in 1 to 10 parts by mass. Further, initiators shown in (1) to (4) may be used in plural types or in combination with other radical polymerization initiators or photosensitizing agents.

Specific compounds include those disclosed in Japanese Published Unexamined Patent Application No. 2000-80068 and No. 2001-264530 but shall not be restricted thereto.

The following show compounds disclosed in Japanese Published Unexamined Patent Application No. 2000-80068 (exemplified compounds 1 to 21)

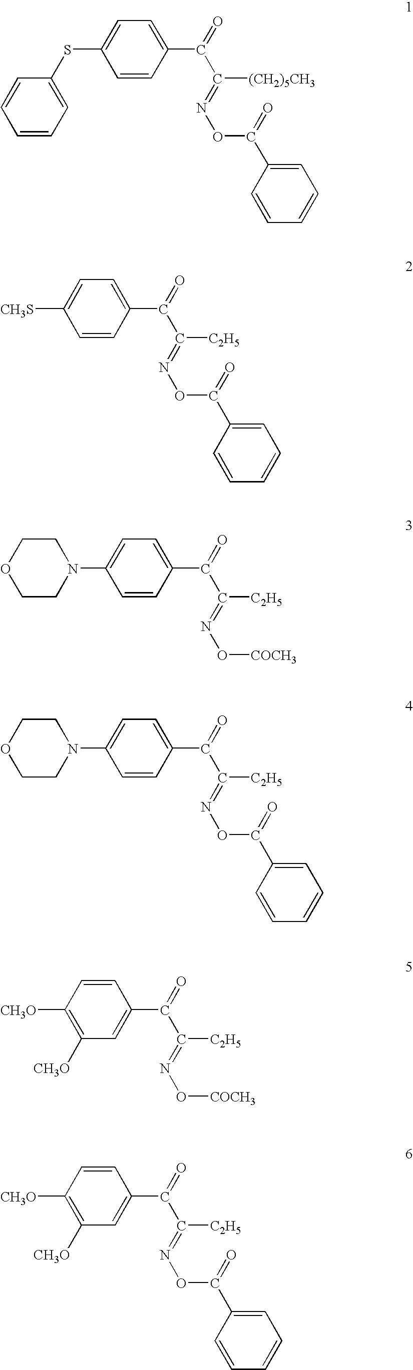

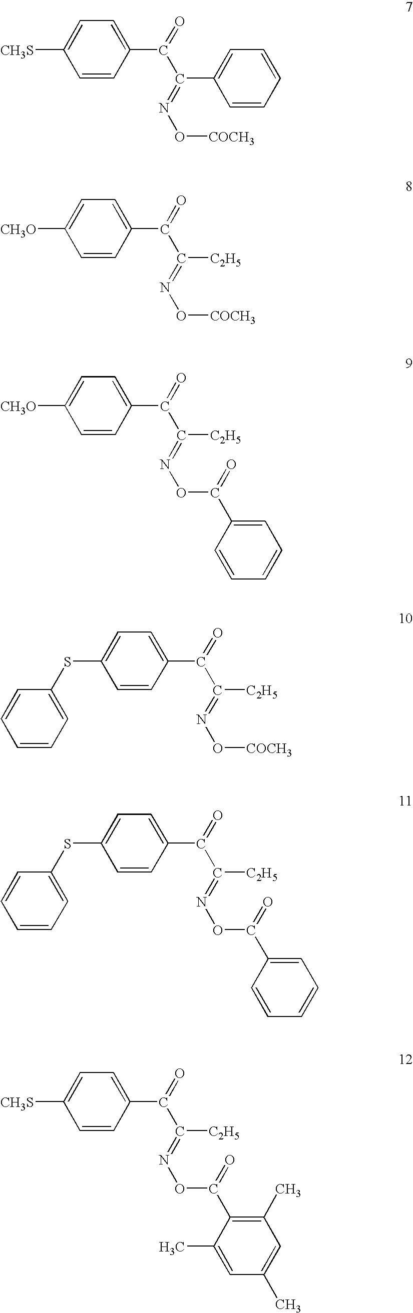

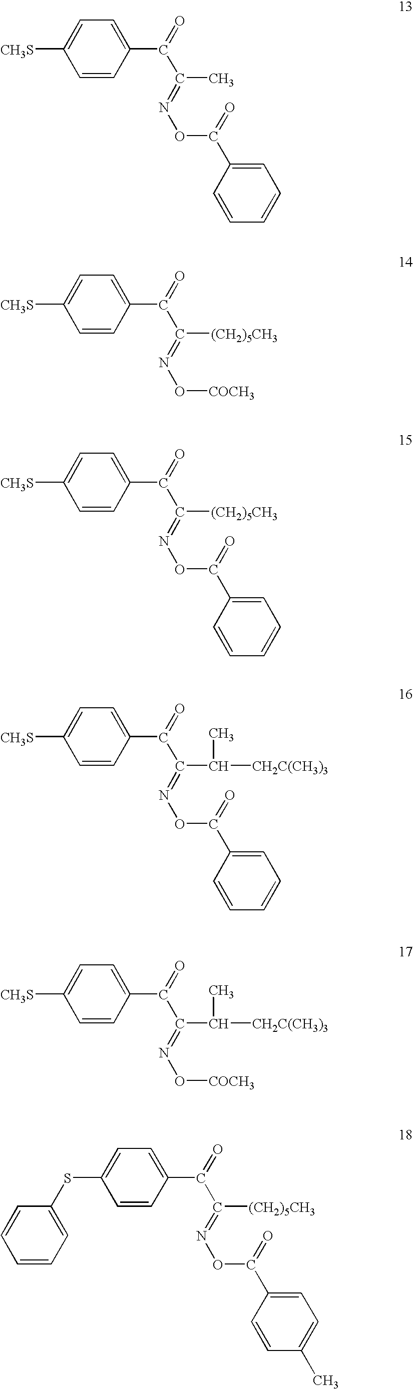

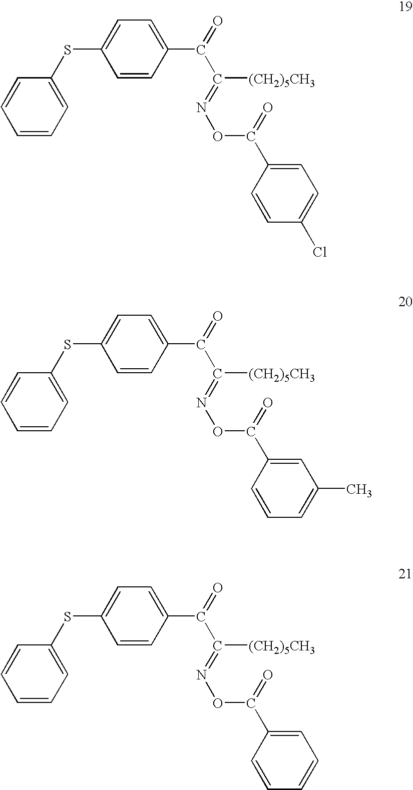

In the layer forming method (V), after a coating solution containing said initiators is applied on a web substrate and dried, a step of irradiating ionizing radiation in the environment where the oxygen concentration is not more than 3% by volume and keeping a film for 0.5 seconds or longer from the start of irradiation of ionizing radiation in the environment where the oxygen concentration is not more than 3% by volume is conducted to cure the film. Removal of conducting air in association with transport of a web makes it possible to effectively reduce the oxygen concentration in the reaction chamber and also efficiently lower the oxygen concentration on the immediate surface which greatly contributes to oxygen-derived curing inhibition, under the condition that an inert gas is supplied to the ionizing radiation reaction chamber and some of the air may come out from the web inlet side in the reaction chamber. Flowing direction of the inert gas at the web inlet side in the reaction chamber can be controlled by adjusting supply and discharge of air in the reaction chamber.

It is also preferable that the inert gas is sprayed directly to the surface of the web as a method for removing the conducting air.

It is preferable that a low refractive layer which is the outermost layer in particular and also whose film thickness is thin is cured by this method.

An anterior chamber is provided in front of the reaction chamber to remove the oxygen on the web surface in advance, by which the curing reaction can be promoted more effectively. Further, a gap with the surface of the web is preferably from 0.2 to 15 mm on a side plane constituting the web inlet side of the ionizing radiation reaction chamber or the anterior chamber for attaining an effective use of an inert gas, more preferably from 0.2 to 10 mm and most preferably from 0.2 to 5 mm. A continuous manufacturing of webs, however, requires jointing and connecting the webs, which is performed widely by a method of affixing them using an adhesive tape and others. Therefore, an excessively small gap between the plane constituting the inlet of the ionizing radiation reaction chamber or the anterior chamber and the surface of the coated layer on the web will pose a problem that joint members such as adhesive tape may be caught. Thus, in making the gap small, it is preferable that a plane constituting the inlet of the ionizing radiation reaction chamber or the anterior chamber is at least partially movable and structured so as to widen the gap by the amount of thickness of a joint member when the joint part is passed. For this purpose, the following methods can be employed: a method in which the plane constituting the inlet of the ionizing radiation reaction chamber or the anterior chamber is rendered movable back and forth in the direction of movement so as to move back and forth on passage of the joint part, thereby widening the gap, or a method in which the plane constituting the inlet of the ionizing radiation reaction chamber or the anterior chamber is rendered vertically movable in relation to the web surface so as to move up and down on passage of the joint part, thereby widening the gap (refer Embodiment E-14 and FIG. 1 to FIG. 4).

Irradiation of ionizing radiation is conducted in an environment where the oxygen concentration is not more than 3% by volume, more preferably not more than 1% by volume and more preferably not more than 0.1% by volume. Reduction in oxygen concentration more than necessary will result in a larger consumption of inert gas, which is not favorable in terms of manufacturing costs. As a means to reduce the oxygen concentration, it is preferable to substitute an atmosphere (nitrogen concentration, about 79% by volume; oxygen concentration, about 21% by volume) with another inert gas, and it is particularly preferable to substitute it with nitrogen (nitrogen purge).

In the layer forming method (V), at least one layer of layers laminated on a transparent substrate is subjected to irradiation of ionizing radiation in an environment where the oxygen concentration is not more than 3% by volume and retained for 0.5 seconds or longer from the start of irradiation of ionizing radiation in an environment where the oxygen concentration is not more than 3% by volume. The retention time is preferably for 0.7 seconds or longer but 60 seconds or less and more preferably for 0.7 seconds or longer but 10 seconds or less. The retention time of less than 0.5 seconds will fail in completion of the curing reaction, resulting in an insufficient cure. Retaining low oxygen concentration conditions for a long time will result in larger facilities and consequently require a larger amount of inert gas, which is not favorable.

In the layer forming method (V), at least one layer of layers laminated on a transparent substrate can be cured by irradiation of ionizing radiation a plurality of times. In this instance, it is preferable that ionizing radiation is irradiated at least twice in a continuous reaction chamber where the oxygen concentration is not more than 3% by volume. The reaction time necessary for curing can be effectively secured by conducting a plurality of times irradiation of ionizing radiation in the reaction chamber where low oxygen concentrations are kept the same.

In particular, where the manufacturing speed is increased for attaining a higher productivity, it is necessary to conduct a plurality of times irradiation of ionizing radiation for securing energy of ionizing radiation needed for the curing reaction, and the above mode is effective also in view of securing the time necessary for the curing reaction.

In the layer forming method (V), it is preferable that at least one layer laminated on a transparent substrate is cured by a step of heating the surface at temperature of 60° C. or more and irradiation of ionizing radiation is conducted in an environment where the oxygen concentration is not more than 3% by volume. It is also preferable that heating is conducted in an environment where the oxygen concentration is not more than 3% by volume at the same time and/or in continuation with irradiation of ionizing radiation. Heating can promote the curing reaction to provide a film excellent in physical strength and drug resistance.

It is preferable to heat the film surface in the range from 60° C. to 170° C. Thermal curing will proceed to a lesser extent at temperatures of less than 60° C., whereas problems occurs such as deformation of a substrate at temperature of 170° C. or more. It is more preferable to conduct heating at temperatures between 60° C. and 100° C. The film surface is defined as surface temperature of a layer to be cured. Further, the film is retained at the above temperature range preferably for 0.1 seconds or longer but 300 seconds or less from the start of UV radiation and more preferably for 10 seconds or less. An excessively short time for retaining the film surface at the temperature range will result in failure in promoting the reaction of curing compositions constituting a film, whereas an the excessively long time will reduce the optical performance of the film and also pose manufacturing problems such as the necessity for larger facilities.

There are no particular restrictions on how to conduct heating. Preferable are a method in which the film is allowed to contact with a heated roll, that in which heated nitrogen is sprayed to the film and that in which a far-infrared ray or infrared ray is radiated. Also applicable is a method in which a medium such as warm water, steam or oil is fed into a rotating metal roll to conduct heating as disclosed in the U.S. Pat. No. 2,523,574. A dielectric heating roll and others may be used as heating means.

[Type of Ionizing Radiation]

There are no particular restrictions on the type of ionizing radiation used in the present invention, and any type can be selected from an ultraviolet ray, electron ray, near-ultraviolet ray, visible light, near-infrared ray, infrared ray and x ray, depending on the types of curing compositions which form a film. It is preferable to irradiate ultraviolet ray in the present invention. Curing by ultraviolet ray is desirable because this ray is faster in polymerization speed (helpful in making facilities compact), able to deal with a large variety of compounds and also less expensive.

Light sources of a raviolet ray include a rcury-vapor lamp (ultrahigh pressure, high pressure and low pressure), carbon arc lamp, xenon arc lamp and metal halide lamp. Light sources of an electron ray include an electron ray having energy of 50 to 1000 keV released from various types of electron beam accelerators such as the Cockroft Walton type, Van de Graaf type, resonance transform type, insulation core transform type, linear type, Dynamitron type and high frequency type.

[Film Forming Binders]

In the present invention, ionizing-radiation curable compounds are used as main film forming binder compositions for film forming ingredients, and it is preferable to use compounds having an ethylene unsaturated group in terms of film strength, stability of coating solution and productivity of coated films. Main film forming binder compositions for film forming ingredients are those accounting for 10% by mass or more but 100% by mass or less, of film forming compositions excluding inorganic particles. They are preferably from 20% by mass or more to 100% by mass or less, more preferably from 30% by mass or more to 95% or less.

In the present Description, “ionizing-radiation curable compounds” may be any compounds that can be cured by irradiation of ionizing radiation, including monomers, oligomers and polymers.

Preferable main film forming binders include polymers having saturated hydrocarbon chains or polyether chains as main chains, and more preferable binders include polymers having saturated hydrocarbon chains as main chains. It is also preferable that these polymers have a cross linkage structure.

Binder polymers having saturated hydrocarbon chains as main chains and also having a cross linkage structure are preferred to be (co)polymers of monomers having two or more ethylene unsaturated groups.

Further, where a high refractive index is imparted, it is preferable that an aromatic ring and at least one type of atoms selected from a halogen atom, sulfur atom, phosphorus atom and nitrogen atom, excluding an aromatic ring and fluorine, is contained in the monomer structure.

Monomers having two or more ethylene unsaturated groups include esters of polyvalent alcohol (meth)acrylic acid (for example, ethylene glycol di(meth)acrylate, 1,4-cyclohexane diacrylate, penta erythritol tetra(meth)acrylate), pentaerythritol tri(meth)acrylate, trimethyrolpropane tri(meth)acrylate, trimethyrolethane tri(meth)acrylate, dipentaerythritol tetra(meth)acrylate, dipentaerythritol penta(meth)acrylate, dipentaerythritol hexa(meth)acrylate, pentaerythritol hexa(meth)acrylate, 1,2,3-cyclohexanetetramethacrylate, polyurethane polyacrylate, polyester polyacrylate), vinyl benzene and its derivatives (for example, 1,4-divinyl benzene, 4-vinyl benzoic acid-2-acryloyl ethyl ester, 1,4-divinyl cyclohexanone), vinyl sulfone(for example, divinyl sulfone), acrylamide (for example, methylenebisacrylamide) and methacrylamide.

The above monomers may be used in combination with two or more types of them. In the present Description, “(meth)acrylate,” “(meth)acryloy” and “(meth)acrylic acid” respectively denote “acrylate or methacrylate,” “acryloyl or methacryloyl” and “acrylic acid or methacrylic acid.”

Further, examples of high refractive index monomers include bis(4-methacryloylthiophenyl)sulfide, vinylnaphthalene, vinylphenyl sulfide, 4-methacryloxy phenyl 4′-methoxyphenylthioether. These monomers may be also used in combination with two or more types of them.

These monomers having ethylene unsaturated groups can be polymerized by irradiation of ionizing radiation or heating in the presence of photo radical initiators or thermal radical initiators.

Photo radical polymerization initiators include acetophenones, benzoins, benzophenones, phosphine oxides, ketals, anthraquinones, thioxanthones, azo compounds, peroxides, 2,3-dialkyzion compounds, disulfide compounds, fluoroamine compounds and aromatic sulfoniums.

Acetophenones include 2,2-dietoxyacetophenone, p-dimethy acetophenone, 1-hydroxy-dimethylphenyl ketone, 1-hydroxy cyclohexylphenyl ketone, 2-methyl-4-methylthio-2-morpholynopropiofenone, 2-benzil-2-dimethylamino-1-(4-morpholynophenyl)-butanone. They also include 2,2-dimethoxyacetophenone, 1-hydroxy-dimethyl-p-isopropyl phenyl ketone, 4-phenoxy dichloroacetophenone, 4-t-butyl-dichloroacetophenone.

Benzoins include benzoin benzene sulfonic ester, benzoin toluene sulfonic ester, benzoin methylether, benzoin ethylether and benzoin isopropyl ether. Further, they include benzoin, benzoin methyl ether, benzoin ethyl ether, benzoin isopropyl ether and benzyl dimethyl ketal.

Benzophenones include benzophenone, 2,4-dichlorobenzophenone, 4,4-dichlorobenzophenone, p-chlorobenzophenone and hydroxybenzophenone. They also include 4-benzoyl-4′-methyl diphenyl sulfide, 4,4′-dimethyl amino benzophenone (Michiler's ketone), 3,3′,4,4′-tetra(t-butyl peroxy carbonyl)benzophenone.

Phosphine oxides include 2,4,6-trimethylbenzoyl-diphenylphosphine oxide.

Photo radical polymerization initiators include Rofin dimers, onium salts, borate salts, activated esters, activated halogens, inorganic complexes and coumarin compounds.

Activated esters include 1,2-octanedione, 1-[4-(phenylthio)-,2-(0-benzoyl oxime)], sulfonic esters, cyclic activated ester compounds. To be specific, particularly preferable examples are compounds disclosed in the embodiments of 1 to 21 in Japanese Published Unexamined Patent Application No. 2000-80068.

Onium salts include aromatic diazonium salt, aromaic iodonium salt and aromatic sulfonium salt.

Borate salts include ion complexes with cation pigments.

S-triazine and oxathiazole compounds are known as activated halogens, which include 2-(p-methoxyphenyl)-4,6-bis(trichloromethyl)-s-triazine, 2-(p-methoxyphenyl)-4,6-bis(trichloromethyl)-S-triazine, 2-(p-styrylfenyl)-4,6-bis(trichloromethyl)-s-triazine, 2-(3-Br-4-di(ethyl acetate ester)amino)phenyl)-4,6-bis(trichloromethyl)-s-triazine, 2-trihalomethyl-5-(p-methoxyphenyl)-1,3,4-oxadiazole. To be specific, particularly preferable examples are compounds disclosed on pages 14 to 30 in the Description of Japanese Published Unexamined Patent Application No. Sho-58-15503; on pages 6 to 10 in Japanese Published Unexamined Patent Application No. Sho-55-77742; No. 1 to No. 8 on pages 287 in Japanese Published Examined Patent Application No. Sho-60-27673; No. 1 to No. 17 on pages 443 to 444 in Japanese Published Unexamined Patent Application No. Sho-60-239736; and No. 1 to 19 in U.S. Pat. No. 4,701,399.

Inorganic complexes include bis(η⁵-2,4-cyclopentadiene-1-yl)-bis(2,6-difluoro-3-(1H-pirol-1-yl)-phenyl)titanium.

Coumarin compounds include 3-ketocoumarin.

These initiators may be used solely or in combination.

Various examples are described on p. 159, “Latest UV Curing Technology” published by the Technical Information Institute Co., Ltd. in 1991 and on pages 65 to 148 “Ultraviolet Ray Curing System” published by the United Technical Center in 1989 and compiled by Kato Seiki, these are helpful in understanding the present invention.

The following commercially-available photo-cleaving photo radical polymerization initiators and their combinations are favorably used in the present invention. They are: Irgacure (651, 184, 819, 907, 1870 (CGI-403/Irg184=7/3 mixing initiator, 500, 369, 1173, 2959, 4265, 4263 etc.) OXE 01) etc., made by Ciba Specialty Chemicals, Kayacure (DETX-S, BP-100, BDMK, CTX,BMS, 2-EAQ, ABQ, CPTX, EPD, ITX, QTX, BTC, MCA etc.) made by Nippon Kayaku Co., Ltd. and Esacure (KIP100F, KB1, EB3, BP, X33, KTO46, KT37, KIP150, TZT) etc., made by Sartomer Company.

A photo radical initiator is used preferably in a quantity of 0.1 to 15 parts by mass in relation to a multifunctional monomer of 100 parts by mass, and more preferably in a quantity of 1 to 10 parts by mass.

A photosensitizing agent may be used in addition to a polymerization initiator. Photosensitizing agents include n-butylamine, triethylamine, tri-n-butylphosphine, Michiler's ketone and thioxanthone.

Further, auxiliary agents such as azide compounds, thiourea compounds and mercapto compounds may be used in combination with one or more types of them.

Commercially-available photosensitizing agents include Kayacure (DMBI, EPA) made by Nippon Kayaku Co., Ltd.

Organic or inorganic peroxides, organic azo and diazo compounds may be used as a thermal radical initiator.

To be specific, they include organic peroxides such as benzoyl peroxide, halogen benzoyl peroxide, lauroyl peroxide, acetyl peroxide, dibutyl peroxide, cumene hydroperoxide and butyl hydroperoxide, inorganic peroxides such as hydrogen peroxide, ammonium persulfate and potassium persulfate, organic azo compounds such as 2,2′-azobis(isobutylnitrile), 2,2′-azobis(ptopionitrile), 1,1′-azobis(cyclohexane carbonitrile) and diazo compounds such as diazoaminobenzene and p-nitrobenzenediazonium.

Polymers having polyether as a main chain may be used in the present invention, and preferable are ring-opening polymers of multifunctional epoxy compounds. Ring-opening polymerization of multifunctional epoxy compounds can be performed by irradiation of ionizing radiation or heating in the presence of photo acid generators or thermal acid generators. Any known photo acid generators and thermal acid generators may be used for this purpose.

In place of a monomer having two or more ethylene unsaturated groups or in addition thereto, a monomer having a cross-linked functional group is used to introduce the cross-linked functional group into a polymer, by which the cross linkage structure may be introduced into a binder polymer by utilizing the reaction of the cross-linked functional group.

Cross-linked functional groups include an isocyanato group, epoxy group, aziridine group, oxazoline group, aldehyde group, carbonyl group, hydrazine group, carboxyl group, methyrol group and activated methylene group. Metal alcoxides such as vinyl sulfonic acid, acid anhydride, cyanoacrylate derivative, melamine, etherified methyrol, ester, urethane and tetramethoxy silane may be used as a monomer for introducing the cross linkage structure. Also usable is a functional group showing cross linkage as a result of a decomposition reaction, such as a block isocyanato group. In other words, a cross-linked functional group which will not react instantly but will become reactive as a result of decomposition may be used in the present invention.

Binder polymers having these cross-linked functional groups may form a cross linkage structure on heating after coating.

The present invention shall not be restricted to the above ionizing-radiation curable compounds but curing compositions may be appropriately selected for each functional layer. Hereinafter, a detailed explanation will be made for each functional layer.

[Materials for Low Refractive Layer]

It is preferable that a low refractive layer is formed with a cured film of copolymers having as an essential composition consisting of repeating units introduced from a fluorine-containing vinyl monomer and repeating units having an (meth)acryloyl group on the side chain. Said copolymer-derived composition preferably accounts for not less than 60% by mass on the basis of the film solid content, more preferably not less than 70% by mass and particularly preferably not less than 80% by mass. In view of providing a low refractive index and a higher film hardness at the same time, curing agents such as multifunctional (meth)acrylate are preferably used in a quantity which will not affect the compatibility.

Compounds disclosed in Japanese Published Unexamined Patent Application No. Hei-11-228631 are also used preferably.

The low refractive layer is preferably from 1.20 to 1.46 in refractive index, more preferably from 1.25 to 1.46 and particularly preferably from 1.30 to 1.46.

The thickness of the low refractive layer is preferably not more than 200 nm, more preferably from 50 to 200 nm and still more preferably from 70 to 100 mm. The haze of the low refractive layer is preferably not more than 3%, more preferably not more than 2% and most preferably not more than 1%. Regarding the specific strength of the low refractive layer determined by a pencil hardness test with a load of 500 g, the film is preferably above H in hardness, more preferably above 2H and most preferably above 3H.

Further, for the purpose of improving the antifouling property of the anti-reflection film, the contact angle in relation to water on the surface is preferably 90° or higher, more preferably 95° or higher and particularly preferably 100° or more.

Hereinafter, an explanation will be made for copolymers preferably used as a low-refractive layer in the present invention.

Fluorine-containing vinyl monomers include fluoroolefins (for example, fluoroethylene, vinylidenfluoride, tetrafluoroethylene, hexafluoropropylene), or partially or completely fluorinated alkylester derivatives of (meth)acrylic acid (for example, Viscoat 6FM (trade name) made by Osaka Organic Chemical Industry Ltd.), R-2020 (trade name) made by Daikin Industries Ltd.), and partially or completely fluorinated vinyl ethers. Preferably there are perfluoroolefins, and particularly preferably there are hexafluoropropylene in terms of refractive index, solubility transparency, easy availability and others. If these fluorine-containing vinyl monomers are increased in percentage, the refractive index can be lowered but the film strength is also lowered. In the present invention, fluorine-containing vinyl monomers should be introduced to give preferably 20 to 60% by mass in fluorine a content of copolymer, more preferably from 25 to 55% by mass and particularly preferably from 30 to 50% by mass.

It is preferable that copolymers of the present invention are made up of repeating units having an (meth)acryloyl group on the side chain as an essential composition. If these (meth)acryloyl group-containing repeating units are increased in percentage, the film strength is improved but the refractive index is also elevated. Depending on types of repeating units introduced from fluorine-containing vinyl monomers. In general, (meth)acryloyl group-containing repeating units preferably account for from 5 to 90% by mass, more preferably from 30 to 70% by mass and particularly preferably from 40 to 60% by mass.

Copolymers effectively used in the present invention may undergo co-polymerization with other vinyl monomers, whenever necessary, besides repeating units introduced from the above fluorine-containing vinyl monomers and repeating units having (meth)acryloyl on the side chain, in view of adhesiveness to a substrate, Tg of a polymer (helpful in improving film hardness), solubility in solvent, transparency, slip properties, dust prevention, antifouling property and others. These vinyl monomers may be used in combination with two or more types of them, depending on an object, and they are introduced into copolymers preferably from 0 to 65 mole % in relation to a total percentage, more preferably from 0 to 40 mole % and particularly preferably from 0 to 30 mole %.

There are no particular restrictions on vinyl monomer units that can be used together, and they include, for example, olefins (ethylene, propylene, isoprene, vinyl chloride, vinyliden chloride, etc.), acrylic esters (methyl acrylate, ethyl acrylate, acrylic acid-2-ethylhexyl, acrylic acid -2-hydroxyethyl), methacrylic esters (methyl methacrylate, ethyl methacrylate, butyl methacrylate, methacrylic acid-2-hydroxyethyl, etc.), styrene derivatives (styrene, p-hydroxymethyl styrene, p-methoxy styrene, etc.), vinyl ethers, (methyl vinyl ether, ethyl vinyl ether, cyclohexyl vinyl ether, hydroxyl ethyl vinyl ether, hydroxyl butyl vinyl ether, etc.), vinylesters (vinyl acetate, vinyl propionate, vinyl cinnamate, etc.), unsaturated carboxylic acids (acryic acid, methacrylic acid, crotonic acid, maleic acid, itaconic acid, etc.), acrylamides (N,N-dimethylacrylamide, N-tert-butylacrylamide, N-cyclohexylacrylamide, etc.), methacryl amides (N,N-dimethylmethacrylamide), acrylonitrile and others.

Preferably used in the present invention are fluorine-containing polymers expressed by the following general formula 1.

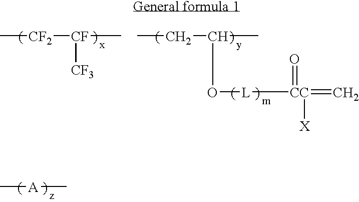

In the general formula 1, L denotes a coupling group having a carbon number of 1 to 10, more preferably a coupling group having a carbon number of 1 to 6 and still more preferably a coupling group having a carbon number of 2 to 4, which may be of a straight structure, chained structure, branched structure or ring structure. It may have a hetero atom selected from O, N or S.

Preferable examples of the coupling are *—(CH₂)₂—O-**, *-(CH₂)₂—NH-**, *-(CH₂)₄—O-**, *-(CH₂)₆—O-**, —(CH₂)₂—O—(CH₂)₂-O-**, *-CONH—(CH₃)₃—O-**, *-CH₂CH(OH)CH₂—O-**, *-CH₂CH₂OCONH(CH₂)₃—O-** (in which * denotes a coupling site on polymer main chain side, ** denotes a coupling site on (meth)acryloyl group side). m denotes 0 or 1.

In the general formula 1, X denotes a hydrogen atom or methyl group. A hydrogen atom is more preferable in view of favorable progress of curing reaction.

In the general formula 1, A denotes repeating units introduced from any given vinyl monomer, there are no restrictions on the repeating units as long as they are monomer compositions which can co-polymerize with hexafluoro propylene. They can be appropriately selected in view of adhesiveness to a substrate, Tg of a polymer (helpful in improving film hardness), solubility in solvent, transparency, slip properties, dust prevention, antifouling property, etc., and may be constituted with a single or plural vinyl monomers.

Preferable examples of vinyl monomers include vinyl ethers such as methyl vinyl ether, ethyl vinyl ether, t-butyl vinyl ether, cyclohexyl vinyl ether, isopropyl vinyl ether, hydroxyethyl vinyl ether, hydroxylbutyl vinyl ether, glycigyl vinyl ether, allyl vinyl ether, vinyl esters such as vinyl acetate, vinyl propionate, vinyl butyrate, (meth)acrylates such as methyl (meth)acrylate, ethyl (meth)acrylate, hydroxylethyl(meth)acrylate, glycigyl methacrylate, allyl (meth)acrylate, (meth)acryloyl oxypropyl trimethoxysilane, styrene derivatives such as styrene, p-hydroxymethyl styrene, unsaturated carboxylic acids such as crotonic acid, maleic acid and itaconic acid and their derivatives. Vinyl ether derivatives and vinyl ester derivatives are preferable and vinyl ether derivatives are particularly preferable.

x, y and z denote the respective compositions in mole% and denote the values satisfying 30≦x≦60, 5≦y≦70 and 0≦z≦65, which are preferably 35≦x≦55, 30≦y≦60 and 0≦z≦20 and particularly preferably 40≦x≦55, 40≦y≦55 and 0≦z≦10.

The general formula 2 is a particularly preferable mode of copolymers used in the present invention.

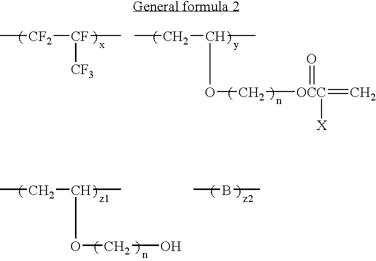

In the general formula 2, X, x and y are the same in meaning as those used in the general formula 1 and also the same in the preferable range. n denotes an integral number of 2≦n≦10. 2≦n≦6 is preferable and 2≦n≦4 is particularly preferable.

B denotes repeating units introduced from any given vinyl monomer and may be constituted solely or in plural combinations. Their examples are those explained as A in the general formula 1.

z1 and z2 denote the respective repeating units in mol % and denote the values satisfying 0≦z1≦65 and 0≦z2≦65. The respective values are preferably 0≦z1≦30 and 0≦z2≦10, and particularly preferably 0≦z1≦10 and 0≦z2≦5.

The copolymer expressed by the general formula 1 or 2 can be synthesized by introducing the (meth)acryloyl group into a copolymer containing hexafluoropropylene composition and hydroxyalkyl vinyl ether composition, for example.

Hereinafter, shown are preferable examples of copolymers which are effectively used in a low refractive layer of the present invention. However, the present invention shall not be restricted thereto.

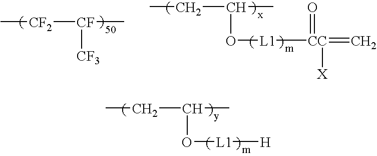

| | x | y | m | L1 | X |
|---|---|---|---|---|---|
| P-1 | 50 | 0 | 1 | *-CH₂CH₂O-** | H |
| P-2 | 50 | 0 | 1 | *-CH₂CH₂O-** | CH₃ |
| P-3 | 45 | 5 | 3 | *-CH₂CH₂O-** | H |
| P-4 | 40 | 10 | 1 | *-CH₂CH₂O-** | H |
| P-5 | 30 | 20 | 1 | *-CH₂CH₂O-** | H |
| P-6 | 20 | 30 | 1 | *-CH₂CH₂O-** | H |
| P-7 | 50 | 0 | 0 | — | H |
| P-8 | 50 | 0 | 1 | *-C₄H₈O-** | H |
| P-9 | 50 | 0 | 1 | 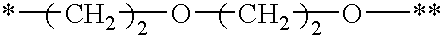 | H |
| P-10 | 50 | 0 | 1 | 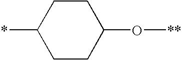 | H |
| P-11 | 50 | 0 | 1 | *-CH₂CH₂NH-** | H |
| P-12 | 50 | 0 | 1 | 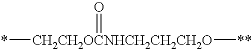 | H |
| P-13 | 50 | 0 | 1 | 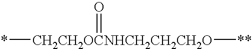 | CH₃ |
| P-14 | 50 | 0 | 1 | 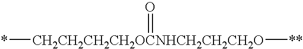 | CH₃ |
| P-15 | 50 | 0 | 1 | 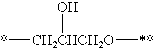 | H |
| P-16 | 50 | 0 | 1 | 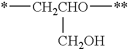 | H |
| P-17 | 50 | 0 | 1 | 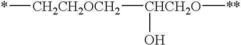 | H |
| P-18 | 50 | 0 | 1 | 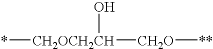 | CH₃ |
| P-19 | 50 | 0 | 1 | 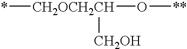 | CH₃ |
| P-20 | 40 | 10 | 1 | *-CH₂CH₂O-** | CH₃ |

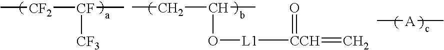

| | a | b | c | L1 | A |
|---|---|---|---|---|---|
| P-21 | 55 | 45 | 0 | *-CH₂CH₂O-** | — |
| P-22 | 45 | 55 | 0 | *-CH₂CH₂O-** | — |
| P-23 | 50 | 45 | 5 | 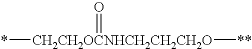 | 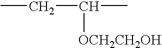 |
| P-24 | 50 | 45 | 5 | 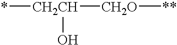 | 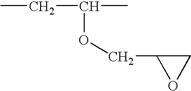 |
| P-25 | 50 | 45 | 5 | 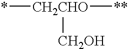 | 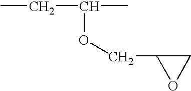 |
| P-26 | 50 | 40 | 10 | *-CH₂CH₂O-** | 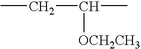 |
| P-27 | 50 | 40 | 10 | *-CH₂CH₂O-** | 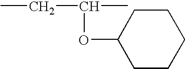 |
| P-28 | 50 | 40 | 10 | *-CH₂CH₂O-** | 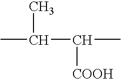 |

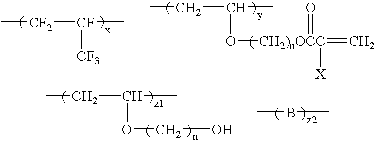

| | x | y | z1 | z2 | n | X | B |
|---|---|---|---|---|---|---|---|
| P-29 | 50 | 40 | 5 | 5 | 2 | H | 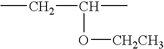 |
| P-30 | 50 | 35 | 5 | 10 | 2 | H | 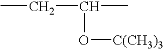 |
| P-31 | 40 | 40 | 10 | 10 | 4 | CH₃ | 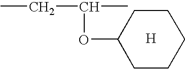 |

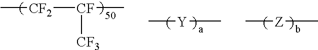

| | a | b | Y | Z |
|---|---|---|---|---|
| P-32 | 45 | 5 | 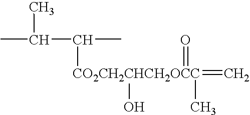 | 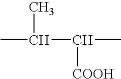 |
| P-33 | 40 | 10 | 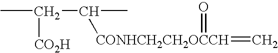 | 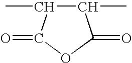 |

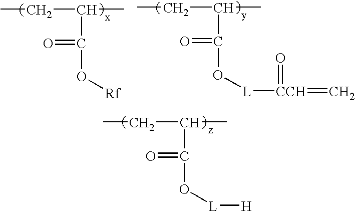

| | x | y | z | Rf | L |
|---|---|---|---|---|---|
| P-34 | 60 | 40 | 0 | —CH₂CH₂C₈F₁₇-n | —CH₂CH₂O— |
| P-35 | 60 | 30 | 10 | —CH₂CH₂C₄F₈H-n | —CH₂CH₂O— |
| P-36 | 40 | 60 | 0 | —CH₂CH₂C₆F₁₂H | —CH₂CH₂CH₂CH₂O— |

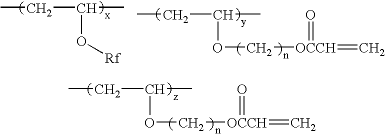

| | x | y | z | n | Rf |
|---|---|---|---|---|---|
| P-37 | 50 | 50 | 0 | 2 | —CH₂C₄F₈H-n |
| P-38 | 40 | 55 | 5 | 2 | —CH₂C₄F₈H-n |
| P-39 | 30 | 10 | 0 | 4 | —CH₂C₈F₁₇-n |
| P-40 | 60 | 40 | 0 | 2 | —CH₂CH₂C₈F₁₆H-n |

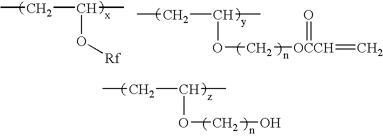

| | x | y | z | n | Rf |
|---|---|---|---|---|---|
| P-41 | 50 | 50 | 0 | 2 | —CH₂C₄F₈H-n |
| P-42 | 40 | 55 | 5 | 2 | —CH₂C₄F₈H-n |
| P-43 | 30 | 70 | 0 | 4 | —CH₂C₈F₁₇-n |
| P-44 | 60 | 40 | 0 | 2 | —CH₂CH₂C₈F₁₆H-n |

*denotes polymer main chain side, and **denotes (meth)acryloyl group side.

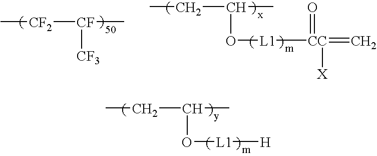

| | | | | | | Number average |
|---|---|---|---|---|---|---|
| | | | | | | molecular weight |
| | x | y | m | L1 | X | Mn (x10⁴) |
| P-1-1 | 50 | 0 | 1 | *-CH₂CH₂O— | H | 3.1 |
| P-2-1 | 50 | 0 | 1 | *-CH₂CH₂O— | CH₃ | 4.0 |
| P-3-1 | 45 | 5 | 3 | *-CH₂CH₂O— | H | 2.8 |
| P-4-1 | 40 | 10 | 1 | *-CH₂CH₂O— | H | 3.8 |
| P-5-1 | 30 | 20 | 1 | *-CH₂CH₂O— | H | 5.0 |
| P-6-1 | 20 | 30 | 1 | *-CH₂CH₂O— | H | 4.0 |
| P-7-1 | 50 | 0 | 0 | — | H | 11.0 |
| P-8-1 | 50 | 0 | 1 | *-C₄H₈O— | H | 0.8 |
| P-9-1 | 50 | 0 | 1 | 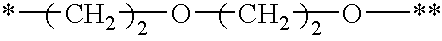 | H | 1.0 |
| P-10-1 | 50 | 0 | 1 | 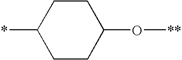 | H | 7.0 |
| P-11-1 | 50 | 0 | 1 | *-CH₂CH₂NH— | H | 4.0 |
| P-12-1 | 50 | 0 | 1 | 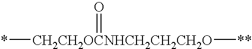 | H | 4.5 |
| P-13-1 | 50 | 0 | 1 | 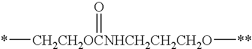 | CH₃ | 4.5 |
| P-14-1 | 50 | 0 | 1 | 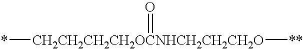 | CH₃ | 5.0 |
| P-15-1 | 50 | 0 | 1 | 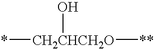 | H | 3.5 |
| P-16-1 | 50 | 0 | 1 | 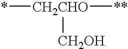 | H | 3.0 |
| P-17-1 | 50 | 0 | 1 | 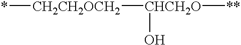 | H | 3.0 |
| P-18-1 | 50 | 0 | 1 | 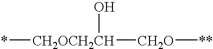 | CH₃ | 3.0 |
| P-19-1 | 50 | 0 | 1 | 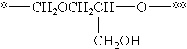 | CH₃ | 3.0 |
| P-20-1 | 40 | 10 | 1 | *-CH₂CH₂O— | CH₃ | 0.6 |

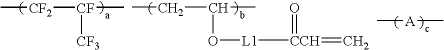

| | | | | | | Number average |
|---|---|---|---|---|---|---|
| | | | | | | molecular weight |
| | a | b | c | L1 | A | Mn (x10⁴) |
| P-21 | 55 | 45 | 0 | *-CH₂CH₂O-** | — | 1.8 |
| P-22-1 | 45 | 55 | 0 | *-CH₂CH₂O-** | — | 0.9 |
| P-23-1 | 50 | 45 | 5 | 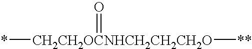 | 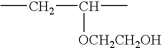 | 0.7 |
| P-24-1 | 50 | 45 | 5 | 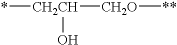 | 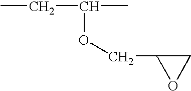 | 4.0 |
| P-25-1 | 50 | 45 | 5 | 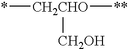 | 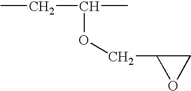 | 4.0 |
| P-26-1 | 50 | 40 | 10 | *-CH₂CH₂O-** | 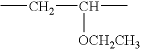 | 4.0 |
| P-27-1 | 50 | 40 | 10 | *-CH₂CH₂O-** | 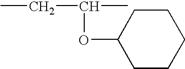 | 4.0 |
| P-28-1 | 50 | 40 | 10 | *-CH₂CH₂O-** | 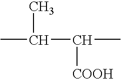 | 5.0 |

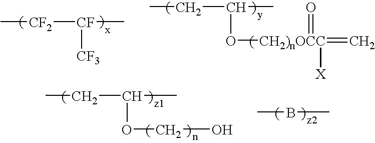

| | | | | | | | | Number average |
|---|---|---|---|---|---|---|---|---|
| | | | | | | | | molecular weight |
| | x | y | z1 | z2 | n | X | B | Mn (x10⁴) |
| P-29-1 | 50 | 40 | 5 | 5 | 2 | H | 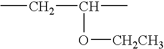 | 5.0 |
| P-30-1 | 50 | 35 | 5 | 10 | 2 | H | 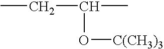 | 5.0 |
| P-31-1 | 40 | 40 | 10 | 10 | 4 | CH₃ | 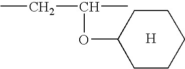 | 4.0 |

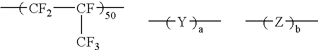

| | | | | | Number average |
|---|---|---|---|---|---|
| | | | | | molecular weight |
| | a | b | Y | Z | Mn (x10⁴) |
| P-32-1 | 45 | 5 | 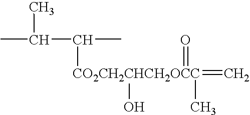 | 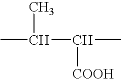 | 4.0 |
| P-33-1 | 40 | 10 | 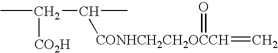 | 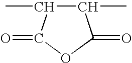 | 4.0 |

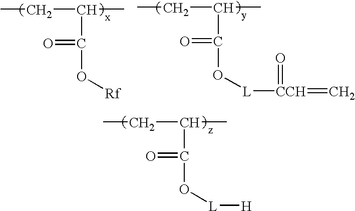

| | | | | | | Number average |
|---|---|---|---|---|---|---|
| | | | | | | molecular weight |
| | x | y | z | Rf | L | Mn (x10⁴) |
| P-34-1 | 60 | 40 | 0 | —CH₂CH₂C₈F₁₇-n | —CH₂CH₂O— | 11 |
| P-35-1 | 60 | 30 | 10 | —CH₂CH₂C₄F₈H-n | —CH₂CH₂O— | 30 |
| P-36-1 | 40 | 60 | 0 | —CH₂CH₂C₆F₁₂H | —CH₂CH₂CH₂CH₂O— | 4.0 |

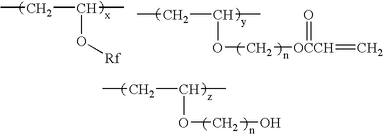

| | | | | | | Number average |
|---|---|---|---|---|---|---|
| | | | | | | molecular weight |
| | x | y | z | n | Rf | Mn (x10⁴) |
| P-37-1 | 50 | 50 | 0 | 2 | —CH₂C₄F₈H-n | 5.0 |
| P-38-1 | 40 | 55 | 5 | 2 | —CH₂C₄F₈H-n | 4.0 |
| P-39-1 | 30 | 70 | 0 | 4 | —CH₂C₈F₁₇-n | 10 |
| P-40-1 | 60 | 40 | 0 | 2 | —CH₂CH₂C₈F₁₆H-n | 5.0 |

*denotes polymer main chain side, and **denotes (meth)acryloyl group side.

A copolymer to be used in the present invention can be synthesized by the method disclosed in Japanese Published Unexamined Patent Application No. 2004-45462. Further, the copolymer to be used in the present invention can also be synthesized through introduction of the (meth)acryloyl group by the above-described polymer reaction after synthesis of precursors of hydroxyl group-containing polymers, etc., according to various polymerization methods other than that described above, for example, solution polymerization, precipitation polymerization, suspension polymerization, mass polymerization, emulsion polymerization. Polymerization reaction can be carried out by known operations such as batch-wise, semi-continuous and continuous operations.

Polymerization can be initiated by using radical initiators, by irradiating light or radial ray or by irradiating ionizing radiation.

Methods for polymerizating and initiating polymerization are described in “Polymer Synthesis Method” authored by Tsuruta Teiji (revised version) published by Nikkan Koghyo Shinbun Ltd. in 1971 and on pages 124 to 154 in “Experiments on Polymer Synthesis” co-authored by Otsu Takayuki and Kinoshita Masayuki published in 1972 by Kagaku-dojin Publishing Company.

Of the above polymerization methods, particularly preferable is solution polymerization in which a radical initiator is used. Solvents used in the solution polymerization method include various organic solvents such as ethyl acetate, butyl acetate, acetone, methy ethyl ketone (MEK), methyl isobutyl ketone (MIBK), cyclohexanone, tetrahydrofuran, dioxane, N,N-dimethylformamide, N,N-dimethylacetoamide, benzene, toluene, acetonitrile, methylene chloride, chloroform, dichloroethane, methanol, ethanol, 1-propanol, 2-propanol and 1-butanol. They may be used solely or in combination with two or more types of them, or they may be mixed with water to give a mixed solvent.

Polymerization temperatures must be set, in association with molecular weight of a polymer to be produced and types of initiators, and can be established from 0° C. or lower to 100° C. or higher. It is preferable to conduct polymerization in the temperature range of 50° C. to 100° C.

Reaction pressure can be selected appropriately. The pressure is usually from about 1 to 100 kPa and particularly preferably from 1 to 30 kPa. Reaction time is from about 5 to 30 hours.

Isopropanol, hexane, methanol and others are preferable as a solvent for re-precipitating a resultant polymer.

Further, favorable modes of copolymers used as a low refractive layer are those expressed by the above-described general formula 1, namely, those expressed by the general formulae 1 and 2 in Japanese Published Unexamined Patent Application No. 2004-45462. Preferable examples are described in paragraph [0043] to [0047] and methods for synthesis are in paragraph [0048] to [0053] in the same Japanese Published Unexamined Patent Application.

Next, an explanation will be made for inorganic particles that are favorably used in a low refractive layer laminated on an anti-reflection film of the present invention.

A coating quantity of inorganic fine particles is preferably from 1 mg/m² to 100 mg/m², more preferably from 5 mg/m² to 80 mg/m² and still more preferably from 1 mg/m² to 60 mg/m². An excessively small quantity will reduce an improving effect of abrasion/scratch resistance, whereas an excessively large quantity will form minute irregularities on the surface of a low refractive layer, deteriorating black sharp appearance and integral reflectance ratio.

Said inorganic fine particles are preferably of low refractive index because they are contained in the low refractive layer, and preferable examples of them include fine particles of silica or hollow silica.

In the present invention, it is preferable to use fine particles of hollow silica in order to reduce the refractive index of the low refractive layer. These hollow-silica fine particles are preferably from 1.15 to 1.40 in refractive index, more preferably from 1.17 to 1.40, still more preferably from 1.17 to 1.35, and most preferably from 1.17 to 1.30. The refractive index means a refractive index in terms of whole particles and does not mean a refractive index of silica shell alone constituting hollow-silica fine particles. In this instance, where radius of void space inside particles is defined as a, and radius of particle shell is defined as b, void ratio x expressed by the following mathematical formula (VIII) is:
x=(4πa³/3)/(4πb³/3)×100 (Mathematical formula VIII)

The void ratio x is preferably from 10 to 60%, more preferably from 20 to 60% and most preferably from 30 to 60%. An attempt of making lower the refractive index of hollow-silica fine particles and making the void ratio greater would reduce the thickness of the shell and lower the strength of particles. Therefore, particles with low refractive index of less than 1.15 are not desirable in view of abrasion/scratch resistance.

Methods for manufacturing hollow silica have been disclosed, for example, in Japanese Published Unexamined Patent Application No. 2001-233611 or No. 2002-79616. Particularly preferable particles are those having a void cavity inside the shell whose fine pores are closed. Further, the refractive index of these hollow silica fine particles can be calculated by the method disclosed in Japanese Published Unexamined Patent Application No. 2002-79616. The refractive index of these hollow silica particles was also determined by using an Abbe refractometer (Atago Co., Ltd).

A coating quantity of the hollow silica fine particles is preferably from 1 mg/m² to 100 mg/m², more preferably from 5 mg/m² to 80 mg/m² and still more preferably from 10 mg/m² to 60 mg/m². An excessively small quantity will reduce the effect of lowering the refractive index and improving the effect of abrasion/scratch resistance, whereas an excessively large quantity will form minute irregularities on the surface of a low refractive layer, deteriorating black sharp appearance and integral reflectance ratio.

The mean particle diameter of the hollow-silica fine particles is preferably from 30% to 150% in relation to the thickness of the low refractive layer, more preferably from 35% to 80%, still more preferably from 40% to 60%. In other words, where the low refractive layer is 100 nm in thickness, the particle diameter of hollow silica is preferably from 30 nm to 150 nm, more preferably from 35 nm to 80 nm and still more preferably from 40 nm to 60 mm.

An excessively small particle diameter of the hollow-silica fine particles will reduce the percentage of void space and fail in lowering the refractive index, whereas an excessively large particle diameter will produce minute irregularities on the surface of a low refractive layer, deteriorating black sharp appearance and integral reflectance ratio. The hollow-silica fine particles may be either in crystalline or amorphous form, and mono-dispersion particles are preferable. Spherical form is most preferable but amorphous form is also acceptable.

Hollow silica may be used in combination with two or more types of the silica different in mean particle diameter. The hollow silica can be evaluated for mean particle diameter by referring to electron microscopic pictures.

In the present invention, the surface area of the hollow-silica fine particles is preferably from 20 to 300 m²/g, more preferably from 30 to 120 m²/g and most preferably from 40 to 90 m²/g. The surface area can be determined by BET method using nitrogen.

The refractive index of a low refractive layer can be lowered by incorporating hollow particles into the layer. When hollow particles are used, the layer is preferably from 1.20 to 1.46 in refractive index, more preferably from 1.25 to 1.41 and most preferably from 1.30 to 1.39.

In the present invention, silica fine particles which have no void space may be used together with hollow-silica fine particles. The mean particle diameter of silica fine particles which have no void space is preferably from 30% to 150% in relation to the thickness of the low refractive layer, more preferably from 35% to 80% and still more preferably from 40% to 60%. In other words, where the low refractive layer is 100 mm in thickness, the particle diameter of silica fine particles is preferably from 30 nm to 150 nm, more preferably from 35 nm to 80 nm and still more preferably from 40 mm to 60 nm.

An excessively small particle diameter of the silica fine particles will lower an improving effect of refractive index, whereas an excessively large particle diameter will form minute irregularities on the surface of a low refractive layer, deteriorating black sharp appearance and integral reflectance ratio.

Silica fine particles may be either in crystalline or amorphous form, and mono-dispersion particles, and even agglomerated particles are acceptable as long as they satisfy a predetermined particle diameter. Spherical form is most preferable but amorphous form is also acceptable.

In this instance, the mean particle diameter of inorganic fine particles is determined by the Coulter counter.

Further, at least one type of silica fine particles whose mean particle diameter is less than 25% in relation to thickness of a low refractive layer (referred to as “silica fine particles with small particle diameter”) may be used together with the silica fine particles having the above described particle diameter (referred to as “silica fine particles with large particle diameter”).

Since silica fine particles with small particle diameter can be placed into a clearance between silica fine particles with large particle diameter, it can act as a retaining agent for silica fine particles with large particle diameter.

Where a low refractive layer is 100 nm in thickness, the mean particle diameter of silica fine particles with small particle diameter is preferably from 1 nm to 20 nm, more preferably from 5 nm to 15 nm and particularly preferably from 10 nm to 15 nm. Use of such silica fine particles is favorable in terms of lowering raw material costs and retaining agent effect.

Hollow-silica fine particles and silica fine particles may be subjected to physical surface treatments such as plasma discharge treatment and corona discharge treatment or chemical surface treatment by surface active agents or coupling agents to attain a stable dispersion in a dispersing or coating solution, or increase affinity or bonding with binder compositions. It is particularly preferable to use coupling agents. Preferable coupling agents include alkoxymetal compounds (such as titanium coupling agent, silane coupling agent). Particularly preferable is treatment with a silane coupling agent having acryloyl group or methacryloyl group.

The above coupling agents are used as a surface treatment agent for inorganic fine particles of a low refractive layer to provide a preliminary surface treatment prior to preparation of a coating solution for said layer. In this instance, it is preferable that coupling agents are additionally given as an additive in preparation for the coating solution and contained into said layer.

In lowering the burden on surface treatment, it is preferable that hollow-silica fine particles and silica fine particles are dispersed in advance into a medium prior to the surface treatment. Specific compounds of surface treating agents and catalysts favorably used in the present invention are, for example, organosilane compounds and catalysts disclosed in WO 2004/017105.

In the present invention, it is preferable to add hydrolyzates and/or partial condensates (sol) of organosilane for improving the film strength. The sol is added preferably from 2 to 200% by mass in relation to inorganic oxide particles, more preferably from 5 to 100% by mass and most preferably from 10 to 50% by mass. Favorable organosilanes include those disclosed in Paragraphs [0028] to [0045] in Japanese Published Unexamined Patent Application No. 2004-170901.

In the present invention, it is preferable to reduce free energy on the surface of an anti-reflection film in view of improving the antifouling property. To be specific, it is preferable to use fluorine-containing compounds or compounds having a polysiloxane structure (silicone compounds) in a low refractive layer.

As additives having a polysiloxane structure, it is preferable to add reactive group-containing polysiloxanes (for example, KF-100T, X-22-169AS, KF-102, X-22-3701IE, X-22-164B, X-22-5002, X-22-173B, X-22-174D, X-22-167B, X-22-161AS (they are all trade names, Shin-Etsu Chemical Co., Ltd.), AK-5, AK-30, AK-32 (all trade names, Toagosei Co., Ltd.), SILAPLANE FM0725, SILAPLANE FM0721 (all trade names, Chisso Corporation), DMS-U22, RMS-033, RMS-083, UMS-182, DMS-H21, DMS-H31, HMS-301, FMS121, FMS123, FMS131, FMS141, FMS221 (all trade names, Gelest Inc.).

The following are also preferably used: X-22-174DX, X-22-2426, X-22-164B, X22-164C, X-22-170DX, X-22-176D, X-22-1821 (all trade names, Shin-Etsu Chemical Co., Ltd.), FM-0725, FM-7725, FM-4421, FM-5521, FM6621, FM-1121(Chisso Corporation) and DMS-U22, RMS-033, RMS-083, UMS-182, DMS-H21, DMS-H31, HMS-301, FMS121, FMS123, FMS131, FMS141, FMS221 (all trade names, Gelest Inc.). However, the present invention shall not be restricted to them.

Further, preferably used are silicone compounds disclosed in [Table 2] and [Table 3] in Japanese Published Unexamined Patent Application No. 2003-112383. In addition, preferably used are compounds disclosed in Paragraphs [0031] to [0044] in Japanese Published Unexamined Patent Application No. 2003-329804. These polysiloxanes are added preferably from 0.1 to 10% by mass in relation to a total solid content of a low refractive layer and particularly preferably from 1 to 5% by mass.

The above fluorine-containing polymers can be polymerized by irradiation of ionizing radiation or heating in the presence of photo radical initiators or thermal radical initiators.

Therefore, a low refractive layer can be formed by preparing a coating solution containing the above-described fluorine-containing polymers, photo radical initiators, thermal radical initiators and inorganic fine particles, applying the coating solution on a transparent substrate, then curing the resultant by irradiation of ionizing radiation or heating to effect polymerization reaction.

[Hard-Coat Layer]

A hard-coat layer is provided with hard-coat properties for improving abrasion/scratch resistance of a film. This layer is also favorably used for imparting to a film light scattering properties due to scattering coming from at least either surface scattering or internal scattering. Therefore, curing compositions for forming a hard-coat layer are preferred to have light transmitting resins for imparting hard-coat properties and light transmitting particles for imparting light diffusion properties. They are also preferred to have inorganic fillers for attaining a high refractive index, preventing cross-linking contraction and providing a high strength, when necessary.

For the purpose of imparting hard-coat properties, the hard-coat layer is preferably from 1 to 10 μm in film thickness and more preferably from 1.2 to 6 μm. Where the film thickness is in the above range, the film is provided with sufficient hard-coat properties and free of decrease in workability due to development of curl or deterioration of brittleness.

These light transmitting resins are preferred to be binder polymers having saturated hydrocarbon chains or polyether chains as main chains, and more preferred to be binder polymers having saturated hydrocarbon chains as main chains. It is also preferable that the binder polymers have a cross linkage structure.

Polymers of ethylene unsaturated monomers are preferable as binder polymers having saturated hydrocarbon chains as main chains. (Co)polymers of monomers having two or more ethylene unsaturated groups are preferable as binder polymers having saturated hydrocarbon chains as main chains and also having a cross linkage structure.

Aromatic rings and high refractive-index monomers having at least one type of atoms selected from a halogen atom, sulfur atom, phosphorus, atom and nitrogen atom excluding fluorine in the structure of the monomer may be selected in order to impart a high refractive index to binder polymers.

Monomers having two or more ethylene unsaturated groups include esters of polyvalent alcohol and (meth)acrylic acid [for example, ethyleneglycol di(meth)acrylate, butane diol di(meth)acrylate, hexanediol di(meth)acrylate, 1,4-cyclohexane diacrylate, pentaerythritol tetra(meth)acrylate, pentaerythritol tri(meth)acrylate, trimethyrol propane tri(meth)acrylate, trimethyrol ethaneatri(meth)acrylate, dipentaerythritol tetra(meth)acrylate, dipentaerythritol penta (meth)acrylate, dipentaerythritol hexa(meth)acrylate, pentaerythritol hexa(meth)acrylate, 1,2,3-cyclohexane tetramethacrylate, polyurethane polyacrylate, polyester polyacrylate], ethylene oxide degenerated products of the above esters, vinyl benzenes and their derivatives [for example, 1,4-divinyl benzene, 4-vinyl benzoic acid-2-acryloyl ethyl ester, 1,4-divinyl cyclohexanone], vinyl sulfones [for example, divinyl sulfone], acrylamides [for example, methylenebisacrylamide] and methacrylamide. These monomers may be used in combination with two or more types of them.

High-refractive monomers include bis(4-methacryloyl thiophenyl)sulfide, vinyl naphthalene, vinyl phenyl sulfide, 4-methacryloxy phenyl-4′-methoxy phenyl thioether. These monomers may also be used in combination with two or more types of them.

These monomers having ethylene unsaturated groups can be polymerized by irradiation of ionizing radiation or heating in the presence of polymerization initiators contained in the above-described low refractive layer.

Therefore, the hard-coat layer can be formed by preparing a coating solution containing monomers for forming a light transmitting resin such as the above ethylene unsaturated monomer, initiators for producing radicals by ionizing radiation or heating, light transmitting particles and inorganic fine particles, applying the coating solution on a transparent substrate and curing the resultant through polymerization reaction by ionizing radiation or heating.

In addition to a polymerization initiator which generates radicals by irradiation of ionizing radiation or heating, a photosensitizing agent which is allowed to be contained in the above low refractive layer may be used.

Ring-opening polymers of multifunctional epoxy compounds are preferable as a polymer having polyether as a main chain. Ring-opening polymerization of multifunctional epoxy compounds can be conducted by irradiation of ionizing radiation or heating in the presence of photo acid generators or thermal acid generators.

Therefore, the hard-coat layer can be formed by preparing a coating solution containing multifunctional epoxy compounds, photo acid generators, thermal acid generators, light transmitting particles and inorganic fine particles, applying the coating solution on a transparent substrate and curing the resultant through polymerization reaction by ionizing radiation or heating.

In place of a monomer having two or more ethylene unsaturated groups or in addition thereto, a monomer having a cross-linked functional group is used to introduce the cross-linked functional group into a polymer, by which the cross linkage structure may be introduced into a binder polymer by utilizing the reaction of the cross-linked functional group.

Cross-linked functional groups include the isocyanato group, epoxy group, aziridine group, oxazoline group, aldehyde group, carbonyl group, hydrazine group, carboxyl group, methyrol group and activated methylene group. Metal alcoxides such as the vinyl sulfonic acid, acid anhydride, cyanoacrylate derivative, melamine, etherified methyrol, ester, urethane and tetramethoxy silane may be used as a monomer for introducing the cross linkage structure. Also usable is a functional group showing cross linkage as a result of decomposition reaction such as block isocyanato group. In other words, a cross-linked functional group which will not react instantly but will become reactive as a result of decomposition may be used in the present invention.

A binder polymer having these cross-linked functional groups may form a cross linkage structure by heating after coating.

Haze of a hard-coat layer varies, depending on functions to be imparted to an anti-reflection film.

Where sharpness of an image is maintained, the surface reflectance ratio is kept low and light scattering function is not needed, a lower haze value is more preferable. To be specific, the haze is preferably 10% or less, more preferably 5% or less and most preferably 2% or less.

On the other hand, where such functions are provided that patterns, non-uniform color and non-uniform luminance on a liquid panel are made less visible by scattaring or the viewing angle is enlarged by scattering, in addition to the function of lowering the reflectance ratio on the surface, the haze value is preferably from 10% to 90%, more preferably from 15% to 80% and most preferably from 20% to 70%.

Light transmitting particles to be used in the hard-coat layer are added for the purpose of imparting anti-glare or light diffusion properties. The mean particle diameter is from 0.5 to 5 μm and preferably from 1.0 to 4.0 μm.

Where the mean particle diameter is less than 0.5 μm, the scattering angle distribution of light is widened to a wide field view, thereby reducing the character resolution of a display or resulting in insufficient anti-glare property due to difficulty in forming irregularities on the surface, which is not favorable. Where the mean particle diameter is more than 5 μm, it is necessary to increase the thickness of the hard-coat layer, posing problems such as development of large curl and increased material costs.

Specific examples of the foregoing light transmitting particles include inorganic compound particles such as silica particles and TiO₂ particles, and resin particles such as acrylic particles, cross-linked acrylic particles, methacrylic particles, cross-linked methacrylic particles, polystyrene particles, cross-linked styrene particles, melamine resin particles, benzo guanamine resin particles. Among these, preferable are cross-linked styrene particles, cross-linked acrylic particles, cross-linked acrylicstyrene particles and silica particles.

Light transmitting particles may be available either in spherical form or in amorphous form.

Light-transmitting particles with a different particle diameter may be used in combination with two or more types of them. It is also possible that light transmitting particles with larger particle diameter are used to impart anti-glare property, and light transmitting particles with smaller particle diameter are used to impart another optical characteristic. For example, where an anti-reflection film is attached to a highly fine display (133 ppi or over), the film must be free of an optical performance defect called glaring. Glaring is due to an increase or a decrease in pixels by irregularities (contributed to anti glare) present on a film surface and a subsequent failure in uniform brightness. The glaring is greatly improved by a combined use of light transmitting particles which are smaller in particle diameter than light transmitting particles contributing to anti glare and also different in the refractive index of binders.

Further, the particle diameter distribution of the light transmitting particles is most preferred to be a mono-dispersion. The closer to the same size in individual particles, the better is the result. For example, where coarse particles are defined as those whose particle diameter is greater by 20% or more than the mean particle diameter, these coarse particles are preferably not more than 1% in relation to a total percentage of particles, more preferably not more than 0.1% and still more preferably not more than 0.01%. Light transmitting particles having such particle diameter distribution are usually obtained by classification according to the size after usual synthesis reaction. Particles with more preferable size distribution can be obtained by increasing the number of classification or conducting the classification more elaborately.

The foregoing light transmitting particles are incorporated into the formed hard-coat layer preferably in content of 3 to 30% by mass on the total solid basis of the hard-coat layer, with consideration given to the light scattering effect, image resolution, surface opaque whitening, glaring and others. A more preferable content is from 5 to 20% by mass.

The density of the light transmitting particles is preferably from 10 to 1000 mg/m² and more preferably from 100 to 700 mg/m².

The light transmitting particles are determined for particle diameter distribution by the Coulter counter method and the determined distribution is converted to number distribution of particles.

In order to elevate the refractive index of the hard-coat layer, it is preferable to add to the layer inorganic fine particles consisting of at least one type of metal oxides selected from titanium, zirconium, aluminum, indium, zinc, tin and antimony and in which the mean particle diameter is not more than 0.2 μm, preferably not more than 0.1 μm and more preferably not more than 0.06 μm, in addition to the foregoing light transmitting particles.

In contrast, in order to increase the difference in refractive index in relation to light transmitting particles, it is preferable to use silicon oxide in the hard-coat layer in which light transmitting particles having a high refractive index are used in order to keep lower the refractive index of the layer. Preferable particle diameter is the same as that of inorganic fine particles.

Concrete examples of inorganic fine particles used in the hard-coat layer include TiO₂, ZrO₂, Al₂O₃, In₂O₃, ZnO, SnO₂, Sb₂O₃, ITO and SiO₂, etc. TiO₂ and ZrO₂ are particularly preferable in making the refractive index higher. It is also preferable that said inorganic fine particles are treated for the surface by silane coupling or titanium coupling. Surface treating agents having on the surface of fine particles a functional group reactive with binder seeds are preferably used.

Where these inorganic fine particles are used, they are added preferably from 10 to 90% by mass in relation to a total mass of the hard-coat layer, more preferably from 20 to 80% by mass and particularly preferably from 30 to 75% by mass.

These inorganic fine particles are sufficiently smaller in particle diameter than the wavelength of light and free of scattering, and a dispersant in which said fine particles are dispersed in binder polymers can act as an optically uniform substance.

At least either of hydrolyzates and/or partial condensates (sol) of organosilane compounds or organosilane may be also used in the hard-coat layer.

The sol composition is added to layers other than the low refractive layer preferably from 0.001 to 50% by mass in relation to a total solid content of contained layers (added layers), more preferably from 0.01 to 20% by mass, still more preferably from 0.05 to 10% by mass and particularly preferably from 0.1 to 5% by mass. Said organosilane compounds are preferably used in the hard-coat layer where addition of the organosilane compounds or the sol compositions is not severely restricted, as compared with a low refractive layer.

Mixtures of light transmitting resins and light transmitting particles are preferably from 1.48 to 2.00 in bulk refractive index and more preferably from 1.50 to 1.80. In order to keep the refractive index within the above range, the light transmitting resins and light transmitting particles may be appropriately selected by taking into account their types and quantity ratios. Such selection can be easily made by conducting a preliminary experiment.

The difference in refractive index between the light transmitting resins and the light transmitting particles (refractive index of light transmitting particles—refractive index of light transmitting resin) is preferably from 0.02 to 0.2 and more preferably from 0.05 to 0.15. Keeping the difference within the above range can make the internal scattering fully effective and prevent glaring or opaque whitening on a film surface.

The foregoing light transmitting resin is preferably from 1.45 to 2.00 in refractive index and more preferably from 1.48 to 1.70.

In this instance, the refractive index of light transmitting resins is directly determined by using an Abbe refractometer and also quantitatively determined by spectroreflectometry or spectroellipsometry.

In order to secure uniformity in the surface state so as to be free of, in particular, non-uniform coating, non-uniform drying or dot defect, the hard-coat layer contains either a fluorine-based or a silicone-based surface active agent or both of them in a coating solution for forming the hard-coat layer. In particular, the fluorine-based surface active agent is effective in improving even in a smaller quantity surface-state defects such as non-uniform coating, non-uniform drying, and dot defect which may be found in the anti-reflection film of the present invention, and therefore preferably used.

An object is to improve the productivity by increasing the surface-state uniformity and imparting high-speed coating properties.

[Anti-Glare Layer]

Hereinafter, an explanation will be made for an anti-glare layer.

An anti-glare layer is formed for the purpose of imparting to a film the antiglare property resulting from surface scattering and preferably the hard-coat property for improving abrasion/scratch resistance of the film. Therefore, the layer is preferred to contain light transmitting resins capable of imparting the hard-coat property, light-transmitting fine particles for imparting the anti-glare property and solvents as essential compositions. Light transmitting resins and light-transmitting fine particles may be the same as those used in the foregoing hard-coat.

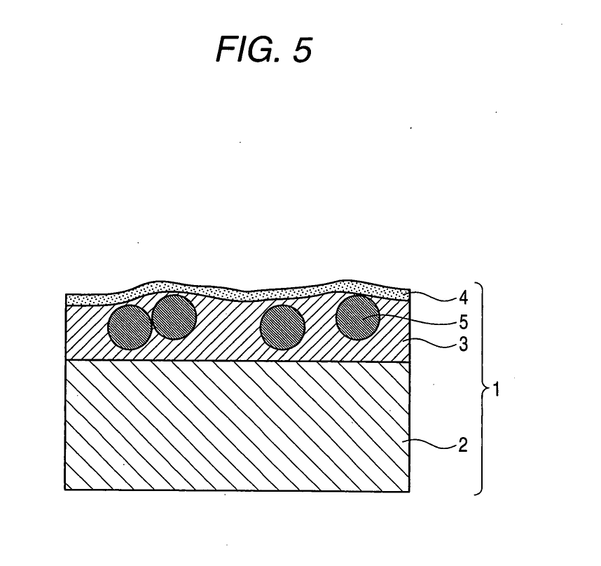

Hereinafter, an explanation will be made for preferable constitution examples of an anti-reflection film in the present invention by referring to the figures. In this instance, FIG. 5 is a sectional view showing an example of the anti-reflection film having the anti glare property in a diagrammatic manner.

The anti-glare anti-reflection film 1 shown in FIG. 5 consists of a transparent substrate 2, an anti-glare layer 3 formed on the transparent substrate 2 and a low refractive layer 4 formed on the anti-glare layer 3. Surface reflection can be reduced according to the principle of thin-film interference by forming the low refractive layer on the anti-glare layer by film thickness equivalent to about ¼ of light wavelength.

The anti-glare layer 3 consists of a light transmitting resin and light-transmitting fine particles 5 dispersed in the light transmitting resin.

The above constituted anti-reflection film is preferred to have individual layers with the refractive index which satisfies the following relationships.

Refractive index of anti-glare layer> refractive index of transparent substrate> refractive index of low refractive layer

In the present invention, the anti-glare layer having the anti glare property is preferred to have both anti-glare and hard-coat properties. In the present embodiment, the layer is formed with one layer but may be constituted with a plurality of layers, for example, two to four layers. Further, as shown in the present embodiment, it may be provided directly on the transparent substrate but provided via other layers such as an antistatic layer or moisture-preventive layer.

Where the anti-reflection film of the present invention is provided with an anti-glare layer, it is preferable in attaining a sufficient anti glare property and a uniform mat feeling which can be confirmed visibly that the film is made irregular on the surface, center line mean roughness Ra is designed to be from 0.08 to 0.30 μm, ten-point mean roughness Rz is to be ten times Ra or lower, mean convex/concave distance Sm is to be from 1 to 100 μm, standard deviation of convex part height from the deepest irregular part is to be 0.5 μm or lower, standard deviation of mean convex/concave distance Sm based on the center line is to be 20 μm or lower, plane of inclination angle from 0 to 5 degrees is to be 10% or more. Where Ra is less than 0.08, a sufficient anti glare property is not obtained. Where it exceeds 0.30, problems take place such as glaring, whitening on the surface on reflection of ambient light.

If the ratio of minimum reflectance value to maximum reflectance value is designed to be from 0.5 to 0.99, while the color of reflected light at CIE 1976L*a*b* color space under C light source is within a* value, −2 to 2; b* value, −3 to 3; 380 nm to 780 nm, color of the reflected light is made neutral, which is favorable. Further, where b* value of transmitted light under C light source is within 0 to 3, yellow color on a white display when applied on a display device is reduced, which is also preferable.

Where the anti-glare property is imparted to the anti-reflection film of the present invention, haze with its optical characteristics resulting from internal scattering (hereinafter referred to as internal haze) is from 5% to 20% and more preferably from 5% to 15%. Where the internal haze is made less than 5%, combination with usable materials is restricted, thereby making it difficult to adjust the anti-glare property and other characteristic values and also resulting in a higher cost. Where the internal scattering exceeds 20%, dark room contrast is greatly deteriorated. Further, haze resulting from surface scattering (hereinafter, referred to as surface haze) is preferably from 1% to 10% and more preferably from 2% to 7%. It is preferable to keep the transmitted image distinction at comb width 0.5 mm from 5% to 30% in attaining at the same time a sufficient anti-glare property and improving blurred image and dark room contrast. Where the surface haze is less than 1%, the anti-glare property is insufficient, but where it exceeds 10%, problems take place such as whitening on the surface on reflection of ambient light. It is also preferable to keep the specular reflectance ratio 2.5% or lower and the transmittance 90% or greater in preventing reflection of ambient light and improving visibility.

[High (Moderate) Refractive Layer]

It is preferable that the anti-reflection film of the present invention is provided with a high refractive layer and/or a moderate refractive layer to impart better anti-reflection functions. The high refractive layer to be used in the anti-reflection film of the present invention is preferably from 1.60 to 2.40 in refractive index and more preferably from 1.70 to 2.20. The moderate refractive layer is adjusted so that the refractive index is between that of the low refractive layer and that of the high refractive layer. The moderate refractive layer is preferably from 1.55 to 1.80 in refractive index. It is preferable that haze of the high refractive layer and that of the moderate refractive layer are 3% or less. The refractive index can be appropriately adjusted by changing quantities of added inorganic fillers and binders.

In order to improve the refractive index of the high (moderate) refractive layer, it is preferable to add to the layer inorganic fillers consisting of at least one type of metal oxides selected from titanium, zirconium, aluminum, indium, zinc, tin and antimony and in which the mean particle diameter is not more than 0.2 μm, preferably not more than 0.1 μm and more preferably not more than 0.06 μm.

Further, in order to increase the difference in refractive index in relation to mat particles contained in the high (moderate) refractive layer, it is preferable to use silicon oxide in the high (moderate) refractive layer in which high refractive mat particles are used in order to keep lower the refractive index of the layer. Preferable particle diameter is the same as that of the inorganic filler used in the foregoing hard-coat layer.

Concrete examples of inorganic fillers used in the high (moderate) refractive layer include TiO₂, ZrO₂, Al₂O₃, In₂O₃, ZnO, SnO₂, Sb₂O₃, ITO and SiO₂. TiO₂ and ZrO₂ are particularly preferable in making the refractive index higher. It is also preferable that said inorganic fillers are treated for the surface by silane coupling or titanium coupling. Surface treating agents having on the filler surface a functional group reactive with binder seeds are preferably used.

These inorganic fillers are added appropriately according to the necessary refractive index. The high refractive layer is added preferably in the range from 10 to 90% in relation to a total mass, more preferably in the range from 20 to 80% and particularly preferably from 30 to 70%.

These fillers are sufficiently smaller in particle diameter than the wavelength of light and free of scattering, and a dispersant in which said fillers are dispersed in binder polymers can act as an optically uniform substance.

It is preferable that the high (moderate) refractive layer used in the present invention is formed by preparing a coating composition for forming the high refractive layer in which preferably a film forming binder composition (monomers having two or more ethylene unsaturated groups as explained in the foregoing hard-coat layer, etc.) necessary for forming a matrix and photo polymerization initiators, etc., is added to a dispersion solution where inorganic fine particles are dispersed in the dispersant as explained above, applying the coating composition for the high refractive layer on a transparent substrate, and curing the resultant through the cross-linked reaction with ionizing-radiation curable compounds (for example, multifunctional monomers and multifunctional oligomers) or polymerization reaction.

It is preferable to use photo polymerization initiators in polymerization reaction with photo polymerization multifunctional monomers. Photo polymerization initiators are preferably photo radical polymerization initiators and photo cation polymerization initiators, and particularly preferably photo radical polymerization initiators. Photo radical polymerization initiators used here are the same as those used in the foregoing low refractive layer.

In addition to the foregoing compositions (inorganic fine particles, polymerization initiators, photosensitizing agents, etc.), the high (moderate) refractive layer may have resins, surface active agents, antistatic agents, coupling agents, thickeners, color protection agents, coloring agents (pigments and dyes), anti-glare imparting agents, antifoaming agents, leveling agents, flame retardants, ultraviolet-ray absorbing agents, infrared-ray absorbing agents, adhesiveness-imparting agents, polymerization preventing agents, antioxidants, surface modifiers and electric conductive metal fine particles.

Film thickness of the high (moderate) refractive layer can be appropriately designed depending on the use. Where the high (moderate) refractive layer is used as an optical interference layer, the layer is preferably from 30 to 200 mm in film thickness, more preferably from 50 to 170 nm and particularly preferably from 60 to 150 mm.

[Transparent Substrate]

It is preferable to use plastic film as a transparent substrate for the anti-reflection film of the present invention. Polymers constituting plastic film include cellulose acylates (for example, cellulose triacetate, cellulose diacetate, cellulose acetate propionate, cellulose acetate butylate, representative ones are TAC-TD80U, TD80UF made by Fuji Photo Film Co., Ltd.), polyamide, polycarbonate, polyester (for example, polyethylene terephthalate, polyethylene naphthalate), polystyrene, polyolefin, norbornene resins (“Arton”: trade name made by JSR Co., Ltd.), non-crystalline polyolefin (“Zeonex”: trade name made by Zeon Corporation). Of these polymers, triacetyl cellulose, polyethylene terephthalate, polyethylene naphthalate are preferable, and triacetylcellulose is particularly preferable. Cellulose acylate films practically free of halogenated hydrocarbons such as dichloromethane and the manufacturing methods for the same have been described in the Journal of Technical Disclosure published by the Japan Institute of Invention and Innovation (Journal of Technical Disclosure No. 2001-1745 published on Mar. 15, 2001, hereinafter abbreviated as JTD No. 2001-1745). Cellulose acylates disclosed herein may also be preferably used in the present invention.

[Method for Forming Coated Film]

The optical film of the present invention, in particular, the anti-reflection film can be formed by the following method, to which the present invention shall not be restricted. Hereinafter, an explanation will be made for the method for forming a coated film of the optical film of the present invention by referring to the anti-reflection film.

[Method for Manufacturing Anti-Reflection Film]

<Method for Forming Anti-Reflection Film by Coating>

In the case of a multi-layered anti-reflection film, individual layers laminated on a transparent substrate can be formed by dip coating, air-knife coating, curtain coating, roller coating, die coating, wire bar coating, gravure coating and extrusion coating (disclosed in the Description of the U.S. Pat. No. 2,681,294). Two or more layers may be coated simultaneously. Simultaneous coating methods are disclosed in the respective Description of U.S. Pat. No. 2,761,791, No. 2,941,898, No. 3,508,947 and No. 3,526,528, and on page 253 “Coating Engineering” authored by Harasaki Yuji and published by Asakura Shoten (1973).

The anti-reflection film of the present invention is continuously manufactured by a step of continuously reeling out a roll-shaped substrate film, that of applying and drying a coating solution (namely, step of forming a coated layer), that of curing a coated film (coated layer) and that of reeling up a substrate film having the cured layer.

The substrate film is continuously reeled out from the roll-shaped substrate film into a clean room, static electricity charged on the substrate film is eliminated by using a charge neutralizer in the clean room, foreign substances still attached on the substrate film are removed by the dust collector. Then, a coating solution is applied on the substrate film at a coating part installed in the clean room, and the coated substrate film is fed into a drying room for drying.

The substrate film having the dried coated layer is reeled out from the drying room to a irradiation curing room, where a radiant ray is irradiated to cure a monomer contained in the coated layer through polymerization. Further, whenever necessary, the substrate film having the radiant ray-cured layer is fed into a thermal curing part, where curing is completed by heating, and the substrate film having the curing-completed layer is reeled up and made into a roll shape.

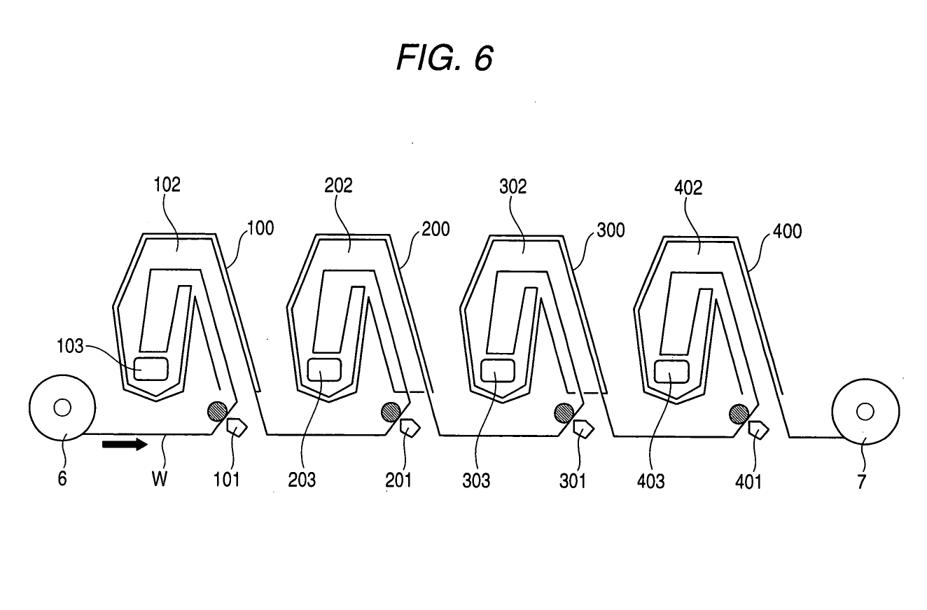

The above steps may be conducted for each formation of individual layers. It is also possible to provide plural sets of a coating part, drying room, radiant ray-curing part and thermal curing room to continuously form individual layers. However, in view of productivity, it is preferable to form individual layers continuously. FIG. 6 shows an example of the apparatus for continuously conducting a coating of individual layers. This apparatus is appropriately provided with a necessary number of film-forming units 100, 200, 300 and 400 between the step 6 of continuously reeling out the roll-shaped substrate film and the step 7 of reeling up the rolled-shaped substrate film. The apparatus shown in FIG. 6 is an example of the constitution for conducting a continuous coating without reeling up four layers. As a matter of course, it is possible to change the number of film forming units, depending on the layers to be constituted. The film forming unit 100 is made up of the step 101 of applying a coating solution, the step 102 of drying a coated film and the step 103 of curing the coated film. In manufacturing an anti-reflection film having, for example, a hard-coat layer, moderate refractive layer, high refractive layer and low refractive layer, it is preferable to continuously reel out a roll-shaped substrate film on which the hard-coat layer is coated by using the apparatus with three film-forming units, provide sequentially a moderate refractive layer, a high refractive layer and a low refractive layer by using these film forming units, and then reel up the film. It is more preferable to continuously reel out a roll-shaped substrate film by using the apparatus with four film-forming units (shown in FIG. 6), provide sequentially a hard-coat layer, a moderate refractive layer, a high refractive layer and a low refractive layer by using these film forming units and then reel up the film.

Hereinafter, an explanation will be made individually for the coating, transporting and curing steps.

In the present invention, it is preferred to conduct die coating in view of attaining high productivity. Die coating is also preferably conducted for attaining both a high productivity and high surface state free of non-uniform coating.

The following coating method (die coating) is a preferred method for manufacturing the anti-reflection film of the present invention.

To be specific, this is a film manufacturing method provided with a step of applying a coating solution from a slot of the front-end lip, with the front-end lip land of a slot die being allowed to come close to the surface of a continuously running web supported by a back-up roll, and in the present invention it is preferable to coat individual layers on a transparent substrate of an anti-reflection film by using coating apparatus in which the land length of the slot die in the web running direction of the front-end lip in the web advancement direction is in a range from 30 cm to 100 μm and which is designed so that a clearance between the front-end lip and the web opposite the web advancement direction is greater by 30 μm or more but 120 μm or less (hereinafter this numerical limitation is referred to as “overbite length”) than a clearance between the front-end lip and the web in the web advancement direction, when the slot die is set at a coating position.

Hereinafter, an explanation will be made for a die coater that can be in particular preferably used in manufacturing methods of the present invention by referring to the figures. A die coater can be used when the wet coating quantity is small (20 ml/m² or less), which is preferable.

<Constitution of Die Coater>

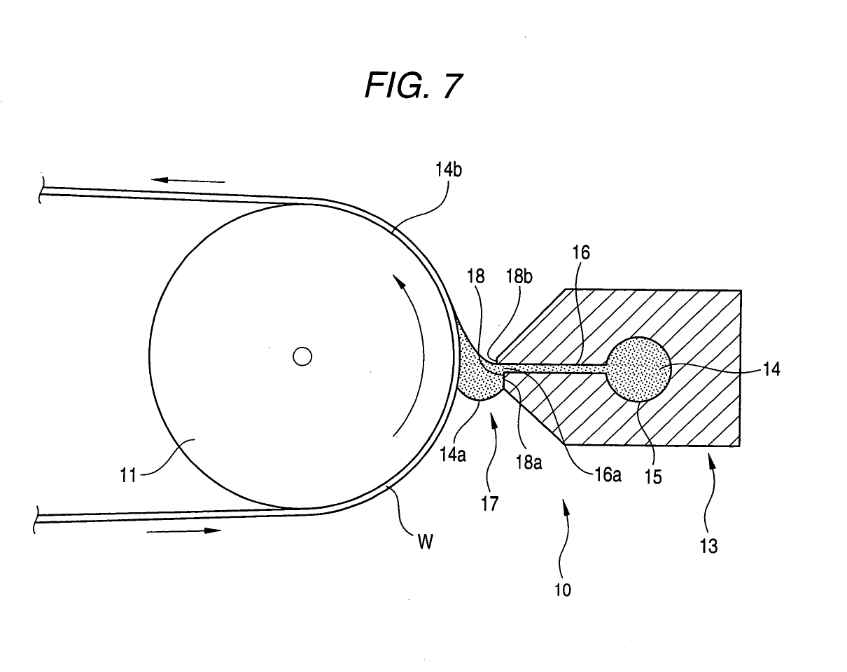

FIG. 7 is a sectional view of a coater (coating apparatus) with a slot die which is preferably used in the present invention.

The coater 10 consists of a back-up roll 11 and a slot die 13, forming a coated film 14b on a web W by applying a coating solution 14 discharged from the slot die 13 in a bead form 14a on the continuously running web W which is supported by the back-up roll 11.

A pocket 15 and a slot 16 are formed inside the slot die 13. The pocket 15 has a curved or straight-lined cross section, which may be approximately circular or semi-circular. The pocket 15 is a space for reserving a coating solution extended in the cross-sectional configuration along the width direction of the slot die 13 (in this instance, the width direction of the slot die 13 is the direction toward the front side or the rear side in relation to the drawing given in FIG. 7). The operative extended length is in general made the same as the coating width or slightly longer. A coating solution 14 is supplied to the pocket 15 from the side of the slot die 13 or from the center of the plane opposite a slot opening 16a. The pocket 15 is also provided with a stopper (not illustrated) for preventing leakage of the coating solution 14.

A slot 16 is a path for supplying the coating solution 14 from the pocket 15 to the web W, and provided with the cross section along the width direction of the slot die 13, as with the pocket 15. The opening 16a positioned on the web side is generally adjusted so as to be roughly the same in length to the coating width by using a width-restricting plate (not illustrated). An angle formed with a tangent line in the web W running direction of the back-up roll 11 at the front end of the slot 16 is preferably from 30° to 90°.

A front-end lip 17 of the slot die 13 where the opening 16a of the slot 16 is located is tapered, the front end of which is given as a flat part 18, which is called a land. In the land 18, the up-stream side of the web W advancement direction in relation to the slot 16 (opposite the advancement direction, or to the direction indicated by arrows in the drawing) is called up-stream lip land 18a and the down-stream side (in the advancement direction) is called down-stream lip land 18b.

A clearance between the up-stream lip land 18a and the web W is greater by the above-described range than that between the down-stream lip land 18b and the web W. Further, the length of the down-stream lip land 18b is in the above range.

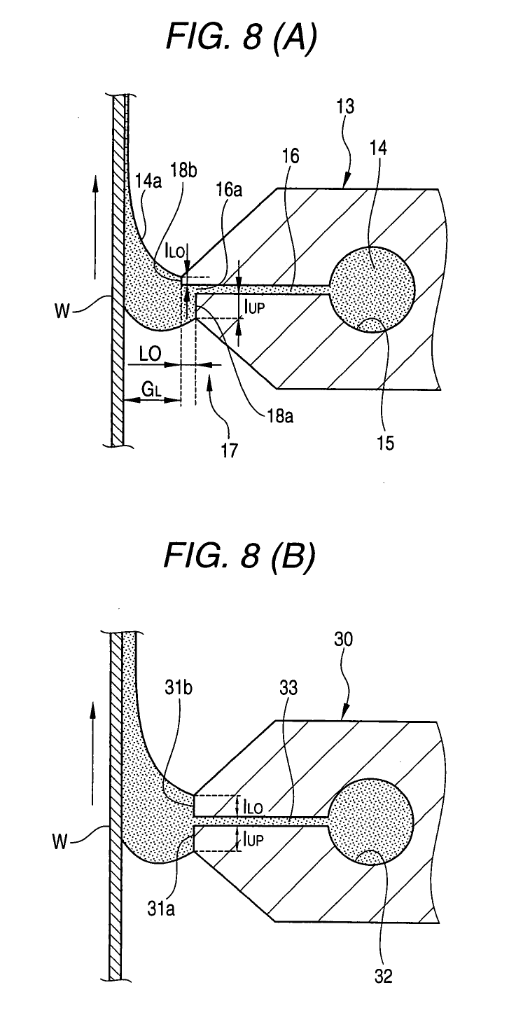

Next, an explanation will be made for a part related to the above numerical limitation by referring to FIG. 8(A). The land length in the web advancement direction is a part indicated by I_{LO} in FIG. 8(A), and the above overbite length is a part indicated by LO in FIG. 8.

Next, an explanation will be made by comparing the coating apparatus preferably used in manufacturing the anti-reflection film of the present invention with the related-art coating apparatus by referring to FIG. 8. In this instance, FIG. 8 shows the cross-sectional configuration of the slot die 13 in comparison with that of a conventional slot die, in which (A) represents the slot die 13 of the present invention and (B), the conventional slot die 30.

In the conventional slot die 30, the distance between the up-stream lip land 31a and the web is equal to that between the down-stream lip land 31b and the web. Here, the symbol 32 represents the pocket, and 33, the slot.

In contrast, in the slot die 13 of the present invention, the distance of the down-stream lip land length, I_{LO} is made shorter, by which coating at wet film thickness of 20 μm or less can be conducted accurately.

There are no particular restrictions on the land length Iᵤₚ of the up-stream lip land 18a, however, it is preferably used in a range from 500 μm to 1 mm. As explained above, land length I_{LO} of the down-stream lip land 18b is preferably from 30 μm to 100 μm, more preferably from 30 μm to 80 μm, and most preferably from 30 μm to 60 μm. Where the land length I_{LO} of the down-stream lip is 30 μm or more, an edge or land of the front-end lip is hardly broken to prevent streaks that may generated on a coated film, which is preferable. A wetting line can be easily set on the down stream side.

Further, it is possible to prevent a coating solution from spreading to the down stream side, which is preferable. Spread of the coating solution to the down stream side due to wetting conditions will result in an uneven wetting line, posing problems such as defects, for example, streaks on a coated surface. In contrast, where the land length I_{LO} of the down-stream lip is below 100 μm or less, the bead 14a can be formed. Thin film coating can be realized, if the bead 14a can be formed by the coating solution.

In addition, the down-stream lip land 18b is of an overbite configuration which comes closer to the web W than the up-stream lip land 18a, thus making it possible to reduce the pressure and also provide the bead 14a suitable for thin film coating. A difference in the distance between the down-stream lip land 18b with the web W and the up-stream lip land 18a with the web W (hereinafter, referred to as overbite length LO) is preferably from 30 μm to 120 μm, more preferably from 30 μm to 100 μm and most preferably from 30 μm to 80 μm. Where the slot die 13 is of an overbite configuration, the clearance G_{L} between the front-end lip 17 and the web W means a clearance between the down-stream lip land 18b and the web W.

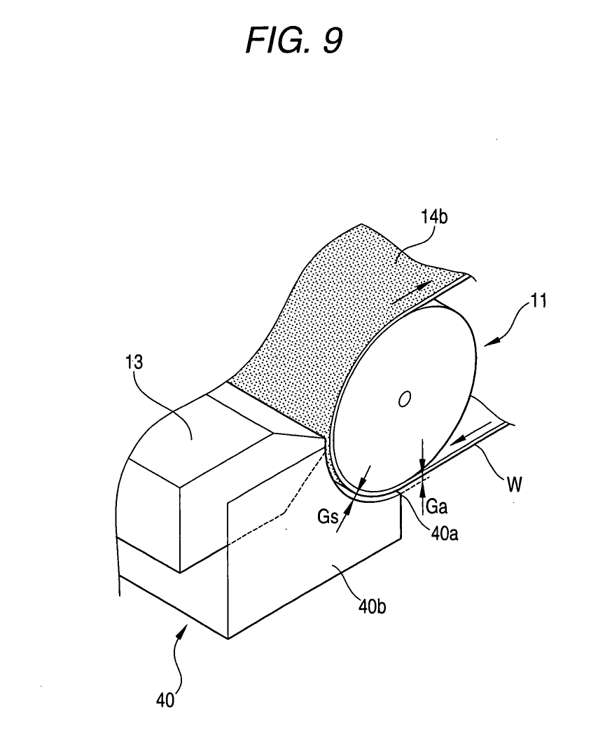

Next, an overall explanation will be made for the above coating step by referring to FIG. 9.

FIG. 9 is a perspective view showing the slot die 13 and its vicinity in the coating step conducted in manufacturing the anti-reflection film of the present invention. A decompression chamber 40 is installed at a position which will not come into contact with and give a sufficient reduction in pressure to the bead 14a on the side opposite the web W advancement direction (namely, an upper stream greater than the bead 14a) in relation to the slot die 13. The decompression chamber 40 is provided with a back plate 40a and a side plate 40b for keeping operational efficiency, and the clearance G_{B} and the clearance G_{S} are provided respectively between the back plate 40a and the web W and between the side plate 40b and the web W.

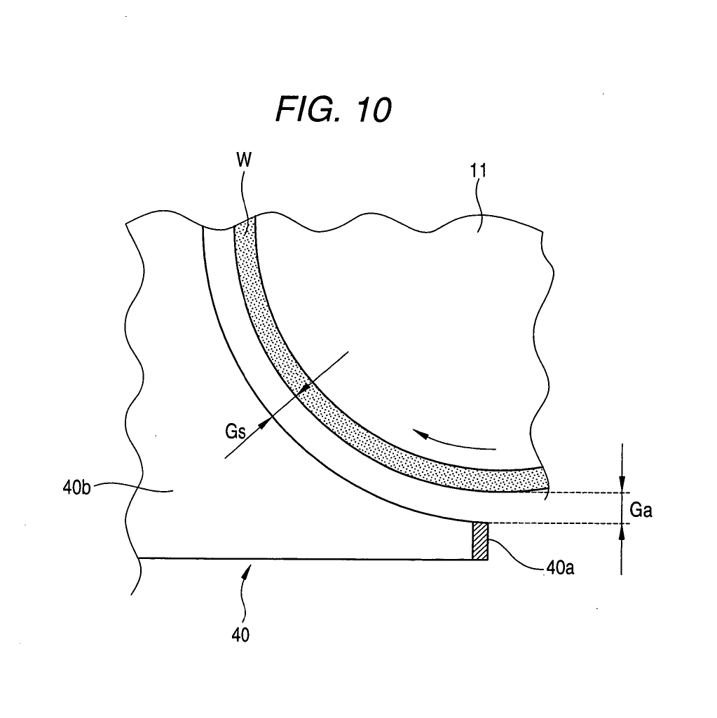

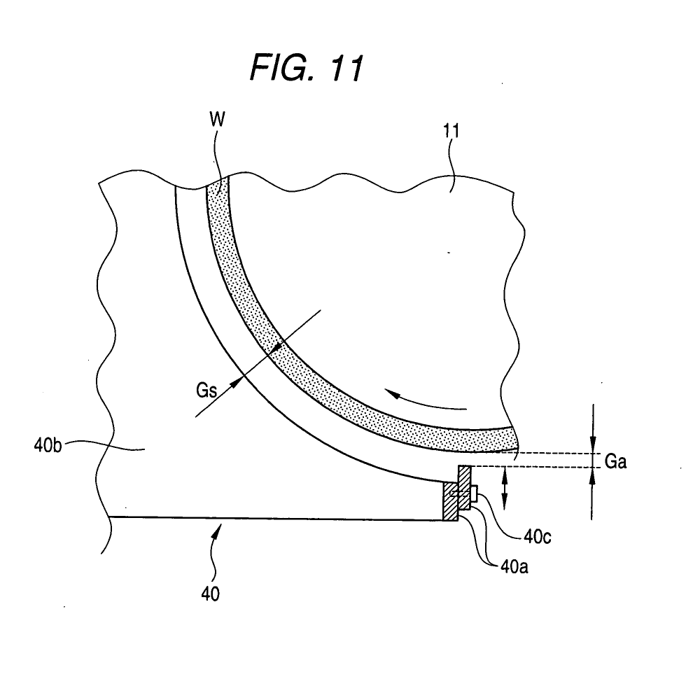

An explanation will be made for the relation between the decompression chamber 40 and the web W by referring to FIG. 10 and FIG. 11. FIG. 10 and FIG. 11 are sectional views showing the adjacent decompression chamber 40 and the web W.

As shown in FIG. 10, the side plate 40b and the back plate 40a may be structured to be integral with the chamber 40, or as shown in FIG. 11, the back plate 40a may be structured to attach to the chamber 40 by using screws 40c or others so as to change the clearance G_{B}, whenever necessary. In any structure, the actually opened part between the back plate 40a and the web W and part between the side plate 40b and the web W are respectively defined as clearance G_{B} and G_{S}. The clearance G_{B} between the back plate 40a of the decompression chamber 40 and the web W means a clearance from the uppermost end of the back plate 40a to the web W, when the decompression chamber 40 is installed below the web W and the slot die 13 as shown in FIG. 9.

It is preferable that the clearance G_{B} between the back plate 40a and the web W is made larger than the clearance G_{L} (refer to FIG. 8) between the front-end lip 17 of the slot die 13 and the web W, thereby preventing variation in the decompression degree which may occur in the vicinity of the bead due to eccentricity of the back-up roll 11. For example, where the clearance G_{L} between the front-end lip 17 of the slot die 13 and the web W is from 30 μm to 100 μm, the clearance G_{B} between the back plate 40a and the web W is preferred to be from 100 μm to 500 μm.

<Material Quality and Accuracy>

The length of the front-end lip in the web running direction along the foregoing web advancement direction side (length of the down-stream lip land I_{LO} shown in FIG. 8(A)) is preferably within the above range, and variation width of I_{LO} in the width direction of the slot die is also preferably within 20 μm. When they are within these ranges, the coating speed will not be made unstable by a slight disturbance, which is therefore favorable.

If the front-end lip of the slot die is made with stainless steel and the like, it would be slack during die processing and not favorable. Where stainless steel and the like are used, it is difficult to satisfy the accuracy of the front-end lip, even with the down-stream lip land length I_{LO} kept in the above range of 30 to 100 μm. It is preferable in keeping a high processing accuracy to use ultrahard metals disclosed in the Description of U.S. Pat. No. 2,817,053. To be specific, it is preferable that at least the front-end lip of the slot die is made with cemented carbides prepared by binding to carbide crystals with a mean particle diameter of 5 μm or less. Cemented carbides include those prepared by combining carbide crystal particles such as wolfram carbide (hereinafter abbreviated as WC) with a binder metal such as cobalt. Binder metals include titanium, tantalum, niobium and their mixtures. WC crystal is more preferably 3 μm or lower in mean particle diameter.

The down-stream lip land length I_{LO} is important in attaining coating at a high accuracy. It is also desirable to control the varying range in the slot die width direction of the clearance G_{L}. It is desirable that the back-up roll 11 and the front-end lip 17 achieve straightness in a range that the varying range in slot die width direction of the clearance G_{L} can be controlled. It is preferable that the front-end lip 17 and the back-up roll 11 are made straight so that the varying range in slot die width direction of the clearance G_{L} becomes 5 μm or less.

The anti-reflection film of the present invention is preferred to have at least a high refractive layer and low refractive layer laminated, and such lamination will make the illumination defect easily visible in the presence of foreign matter such as dirt and dust. Illumination defect in the present invention is a visible defect on a coated film on reflection, as explained above. This defect can be detected by visual inspection by operations in which the back plane of an anti-reflection film after coating is black-painted. A visually detected illumination defect is in general 50 μm or larger. Many illumination defects would reduce the yield ratio in the manufacturing, thus making it impossible to manufacture a large-area anti-reflection film.

The anti-reflection film of the present invention should be 20 or less per cubic meter in number of illumination defects, preferably 10 or less, more preferably 5 or less and particularly preferably 1 or less.

In order to prepare anti-reflection film less the illumination defect, it is necessary to control precisely the dispersion of high-refractive super-fine particles in a coating solution for a high refractive layer and conduct appropriately precise-filtration of the coating solution.

It is preferable that individual layers constituting an anti-reflection layer are treated in a highly purified environment at the coating part in the coating step and the drying room in the drying step, and dirt or dust on a film is sufficiently removed prior to coating. Air cleanliness in the coating and drying steps is preferably class 10 (particles with 0.5 μm or greater are not more than 353/(cubic meter)) or higher on the basis of air cleanliness specifications of the Federal Specifications and Standards 209E and more preferably class 1 (particles with 0.5 μm or greater are not more than 35.5/(cubic meter)) or higher. Further, it is preferable that the air cleanliness is high at reeling-out and reel-up parts in steps other than the coating and drying steps.

A dust-removing method employed in a dust-removing step prior to coating includes a dry dust-removing method in which non-woven cloth, blade, etc., are pressed to the film surface (Japanese Published Unexamined Patent Application No. Sho-59-150571), that in which air with high cleanliness is blown at a high speed to remove attached substances from the film surface and the attached substances are sucked into a nearby suction hole (Japanese Published Unexamined Patent Application No. Hei-10-309553) and that in which compressed air with supersonic vibration is blown to remove attached substances and the substances are sucked (New Ultra Cleaner manufactured by Shinko Co., Ltd.) (Japanese Published Unexamined Patent Application No. 7-333613).

The dust-removing method also includes a wet dust-removing method in which a film is introduced into a cleaning tank to remove attached substances by using an ultrasonic vibrator, that in which a cleaning solution is supplied to a film, air is then blown thereto at a high speed, and substances are sucked (Japanese Published Examined Patent Application No. Sho-49-13020) and that in which a web is continuously rubbed with a roll wetted with a liquid and the liquid is then sprayed to the rubbed surface to conduct cleaning (Japanese Published Unexamined Patent Application No. 2001-38306). Of these dust removing methods, the ultrasonic dust-removing method or the wet dust-removing method is particularly preferable in view of effective dust removal.

Further, for the purpose of effectively removing dust and preventing attachment of dirt, it is particularly preferable that static electricity on a substrate film is eliminated, prior to the dust removing step in the view of dust removing efficiency and dust attachment prevention. Such static electricity eliminating methods include use of an ionizer by corona discharge and use of an ionizer by irradiation of UV and soft x-ray. The charged voltage of a substrate film before and after dust removal and coating should be 10000V or less, preferably 300V or less and particularly preferably 100V or less.

(Dispersion Medium for Coating)

There are no particular restrictions on the dispersion medium for coating. They may be used solely or in combination with two or more types of them. A preferable dispersion medium include aromatic hydrocarbons such as toluene, xylene and styrene, chloroaromatic hydrocarbons such as chlorobenzene and orthodichloro benzene, chloroaliphatic hydrocarbons including methane derivatives such as monochloromethane and ethane derivatives such as monochloroethane, alcohols such as methanol, isopropyl alcohol and isobutyl alcohol, esters such as methyl acetate and ethyl acetate, ethers such as ethyl ether and 1,4-dioxane, ketones such as acetone, methyl ethyl ketone, methyl isobutyl ketone and cyclohexanone, glycol ethers such as ethyleneglycol monomethyl ether, alicyclic hydrocarbons such as cyclohexane, aliphatic hydrocarbons such as normal-hexane and mixtures of aliphatic hydrocarbons and aromatic hydrocarbons. Of these mediums, particularly preferable are dispersion mediums for coating prepared by using ketone alone or mixing two or more types of ketones.

[Physical Properties of Coating Solution]

The above-described coating method is greatly influenced by the physical properties of a coating solution regarding the upper-limit speed at which coating can be conducted. Therefore, control should be given to physical properties of the coating solution immediately before coating, particularly viscosity and surface tension.

The viscosity is preferably not more than 2.0 [mPa·sec], more preferably not more than 1.5 [mPa·sec]and most preferably not more than 1.0 [mPa·sec].

Some coating solutions may change in viscosity, depending on the shear rate. Therefore, the above values indicate the viscosity at the shear rate immediately before coating. By adding a thixotropy agent to the coating solution, a coating solution is kept low in viscosity at the time of coating when a high shearing strength is applied but kept high in viscosity at the time of drying when substantially no shearing strength is applied to the coating solution, thereby preventing non-uniformity on drying, which is favorable. The viscosity is determined by using a vibrating viscometer CJV-5000 (manufactured by A & D Co., Ltd.) in the range of 50 mV at a measured temperature 25° C.

A coating solution quantity to be applied on a web will influence the upper-limit speed at which coating can be conducted, which is, however, not related to the physical properties. The coating solution quantity to be applied on a web is preferably from 2.0 to 5.0 [mL/m²] and more preferably from 3.0 to 5.0 [mL/m²]. An increase in the coating solution quantity to be applied on a web would increase the upper-limit speed at which coating can be conducted, but an excessive increase in the coating solution quantity to be applied on a web would increase the burden on drying. It is, therefore, preferable to determine an optimal coating solution quantity to be applied on a web, depending on the formula of the coating solution and step requirements.

The surface tension of the coating solution is preferably from 15 to 36 [mN/m].

The addition of a leveling agent can reduce the surface tension, thereby preventing non-uniformity on drying, which is also preferable. An excessively reduced surface tension would lower the upper-limit speed at which coating can be conducted. Thus, the surface tension is more preferably from 17 to 32 [mN/m] and still more preferably from 19 to 26 [mN/m].

Speed at which a coating solution is applied on a web surface is preferably 25 [m/min] or greater and more preferably from 40 to 100 [m/min].

<Coating Speed>

A coating method employed in the present invention is able to provide a stable film thickness even at high speed coating by using the back-up roller 11 and the front-end lip 17, thereby attaining the above-described accuracy. Further, a coating method employed in the present invention where the coating quantity is determined before operation is able to secure a stable film thickness at high speed coating.

A coating method employed in the present invention is able to provide high speed coating, with the film thickness kept stable, in dealing with a coating solution to be used at a small quantity like the anti-reflection film of the present invention. Coating can be conducted by other methods. However, dip coating always requires to vibrate a coating solution in a liquid reserving tank and tends to develop step-like irregularities on the coated surface. Reverse roll coating and micro-gravure coating tend to develop irregularities on the coated surface due to eccentricity of a roll related to coating.

Micro-gravure coating also easily results in non-uniformity of a coating quantity due to accuracy problems in manufacturing a gravure roll and change over time in a roll and a blade resulting from contact of the blade with the gravure roll. Further, in these coating methods, materials are measured after the operation, therefore making it relatively difficult to secure a stable film thickness. It is preferable to conduct the manufacturing method of the present invention at the coating speed of 25 m/min or faster in view of higher productivity.

(Filtration)

It is preferable to filter a coating solution before coating. In this filtration, preferably used is a filter with the smallest possible pore diameter as long as the compositions of the coating solution are not removed. A filter to be used in the filtration is preferably from 0.1 to 10 μm in absolute filtration accuracy and more preferably from 0.1 to 5 μm. The filter is preferably from 0.1 to 10 mm in thickness and more preferably from 0.2 to 2 mm. In this instance, the filtration pressure is preferably not more than 1.5 MPa, more preferably not more than 1.0 MPa and still more preferably not more than 0.2 MPa.

No particular restriction is placed on filter members as long as they will not affect a coating solution. To be specific, they include filter members similar to those used for filtering wet dispersions of the above-described inorganic compounds.

It is also preferable that the filtered coating solution is subjected to ultrasonic dispersion to effectively remove foams and keep a better dispersion.

[Polarizing Plate]

A polarizing plate is manly constituted with two sheets of protective films sandwiching a polarizing film from both sides. It is preferable that the anti-reflection film of the present invention is used as at least one of two protective films sandwiching the polarizing film from both sides. In the present invention, the anti-reflection film is also used as a protective film, by which the cost of manufacturing a polarizing plate can be reduced. Further, the anti-reflection film of the present invention is used in the uttermost layer, thereby preventing reflection of ambient light and others, providing a polarizing plate excellent in abrasion/scratch resistance and antifouling property.

A polarizing film may be any known polarizing film or a polarizing film cut out from a long polarizing film whose absorption axis is not horizontal or vertical in the longitudinal direction. The long polarizing film whose absorption axis is not horizontal or vertical in the longitudinal direction is prepared by the following method.

To be specific, the film can be prepared by a stretching method in which a polymer film supplied continuously is stretched by applying tensile force, while being retained on both ends by using retaining means, to prepare a polarizing film, the thus prepared film is stretched at least 1.1 to 20.0 times in the film width direction and bent, with both ends of the film retained, under the conditions where a difference in advancement speed toward the longitudinal direction in the retaining means on both end of the film is within 3% and in such a way that an angle between the film advancement direction at the outlet in the step of retaining the both ends of the film and the actual stretching direction of the film is slanted from 20 to 70°. The film prepared under the condition that the angle is slanted at 45° is particularly preferable in view of high productivity.

Stretching methods for polymer films have been described in detail in Paragraphs [0020] to [0030] in Japanese Published Unexamined Patent Application No. 2002-86554.

[Saponification]

Where the anti-reflection film of the present invention is used in a liquid display device, it is arrayed on the first surface of the display by providing an adhesive layer on one surface. Further, the anti-reflection film of the present invention may be used in combination with a polarizing plate. Where a transparent substrate is triacetylcellulose, it is preferable to use the anti-reflection film of the present invention as a protective film in view of cost, because triacetylcellulose is used as a protective film for protecting a polarizing layer of the polarizing plate.

Where the anti-reflection film of the present invention is arrayed on the first surface of a display by providing an adhesive layer on one surface or used as a protective film for the polarizing plate as it is, it is, preferable that saponification is conducted after an outermost layer mainly made of fluorine-containing polymers is formed on a transparent substrate for attaining a sufficient attachment. Saponification can be conducted by a known method, for example, that in which the film is submerged into an alkaline solution for an appropriate time. After submersion into an alkaline solution, it is preferable that the film is thoroughly washed with water so that no alkaline compositions are left therein or it is submerged into a diluted acid solution to neutralize alkaline compositions.

Saponification makes the surface of a transparent substrate hydrophilic on the side opposite that having the outermost layer.

The hydrophilic surface is particularly effective in improving the adhesiveness with a polarizing film mainly made of polyvinyl alcohol. Further, the hydrophilic surface tends to catch dust in the air to a lesser extent, hardly having dust in a space between a polarizing film and an anti-reflection film when attached on the polarizing film, thereby effectively preventing a dot defect resulting from dust.

Saponification is conducted preferably in such a way that the water contact angle on the surface of a transparent substrate opposite the side having the outermost layer is not more than 40°, more preferably not more than 30° and particularly preferably not more than 20°.

Specific means of conducting alkaline saponification can be selected from the following two means of (1) and (2). The means (1) is advantageous in that saponification can be conducted in the same step of treating triacetylcellulose films for general use. However, this means giving saponification to the surface of anti-reflection layer as well, by which the surface undergoes alkaline hydrolysis to deteriorate the anti-reflection layer and a remaining saponification solution may cause problems such as development of dirt.

In this instance, the means (2) is advantageous, although it needs a special step.

(1) After formation of an anti-reflection layer on a transparent substrate, a film is submerged into alkaline solution at least once to give saponification to the back face of said film,

(2) Before or after formation of an anti-reflection layer on a transparent substrate, alkaline solution is coated on the plane opposite that on which an anti-reflection film of the anti-reflection film is formed, and heating, washing with water and/or neutralization are conducted to give saponification only to the back face of the film.

[Image Display Device]

The image display device of the present invention is a device wherein at least either the foregoing anti-reflection film or the polarizing plate (polarizing plate having anti-reflection function) is arrayed on an image display plane. The anti-reflection film and the polarizing plate of the present invention are applicable to image display devices such as liquid display device (LCD) and organic EL (Electronic Luminescence) display.

The liquid crystal display devices may include any publicly known conventional ones. They are, for example, those described in “Comprehensive technology of reflective-type color LCD,” Uchida Tatauo, [CMC Publishing Co., Ltd, 1999], “New development of flat panel displays,” [Research Department, Toray Research Center Ltd., 1996], “Present status and prospect of liquid crystal-related market (lower and upper volumes)” [Fuji Chimera Research Institute, Inc., 2003] and others.

Where the anti-reflection film of the present invention is used as one surface protective film of polarizing films, it is preferably applicable to a transmissive type, reflective-type and semi-transmissive type liquid crystal display devices based on modes of twisted nematic (TN), super-twisted nematic (STN), vertical alignment (VA), in-plane switching (IPS), optically compensated bend cell (OCB).

Further, the polarizing plate of the invention is favorable because it is able to provide a well-contrasted and wider viewing angle and prevent a change in hue and reflection of ambient light, and is also excellent in durability even when installed on a liquid crystal display device with the display image size of 17 inches or more.

<Liquid Crystal Display Device Based on VA Mode>

In the liquid crystal cell based on the VA mode, rod-like liquid crystal molecules are substantially in a vertical orientation when no voltage is applied.

The liquid crystal cell based on the VA mode includes in addition to (1) liquid crystal cell based on the VA mode in a narrow sense in which rod-like liquid crystal molecules are oriented in a substantially vertical direction when no voltage is applied and in a substantially horizontal direction when voltage is applied (described in Japanese Published Unexamined Patent Application No. Hei-2-176625), (2) liquid crystal cell (MVA mode) in which the VA mode is multi-domained for widening the viewing angle [SID97 described in Digest of Tech. Papers (preliminary reports), 28, 845, (1997)], (3) liquid crystal cell (n-ASM mode) in which rod-like liquid crystal molecules are oriented in a substantially vertical direction when no voltage is applied and subjected to twisted multi-domain orientation when voltage is applied (described in the preliminary report on a discussion in the Japan Liquid Crystal Society, 58-59 (1998)), and (4) liquid crystal cell based on survival mode (published in the LCD International 98).

A polarizing plate prepared in combination of a biaxially-stretched triacetylcellulose film with the anti-reflection film of the present invention is preferably used in the liquid crystal cell based on the VA mode. Methods for manufacturing biaxially-stretched triacetylcellulose films disclosed in Japanese Published Unexamined Patent Application No. 2001-249223 and Japanese Published Unexamined Patent Application No. 2003-170492 are preferably used.

<Liquid Crystal Display Device Based on OCB Mode>

The liquid crystal cell based on the OCB mode is a liquid display device wherein the liquid crystal cell based on the bend orientation mode is used in which rod-like liquid crystal molecules are oriented in a substantially opposite direction (symmetrical) between the upper and lower part of the liquid crystal cell. This liquid crystal display device has been disclosed in the specification of U.S. Pat. No. 4,583,825 and U.S. Pat. No. 5,410,422. Since the rod-like liquid crystal molecules are oriented symmetrically between the upper and lower parts of the liquid crystal cell, the liquid crystal cell based on the bend orientation mode is provided with self optical compensation. Therefore, this liquid crystal mode is also called the OCB (optically compensatory bend) liquid crystal mode. The liquid display device based on the bend orientation mode is advantageous in a faster response speed.

As with the liquid crystal cell based on the TN mode, orientation in the liquid crystal cell based on the OCB mode is also in a state where rod-like liquid crystal molecules are raised on a black display at the center of the cell and laid in the vicinity of the cell substrate.

<Liquid Crystal Display Device Based on TN Mode>

The liquid crystal cell based on the TN mode is most commonly used as a color TFT liquid crystal display device and described in various literature. Orientation in the liquid crystal cell based on the TN mode on a black display is in a state where rod-like liquid crystal molecules are raised at the center of the cell and laid in the vicinity of the cell substrate.

The liquid crystal cell based on the TN mode where rod-like liquid crystal molecules are practically oriented horizontally on application of no voltage is most commonly used as a color TFT liquid crystal display device and described in various literature. It has been described, for example, in “EL, PDP, LCD display” published by Toray Research Center Ltd. (2001).

<Liquid Crystal Display Device Based on IPS Mode>

The liquid crystal cell based on the IPS mode is a mode in which liquid crystal molecules are rotated always in the horizontal plane in relation to the substrate and oriented in such a way to exhibit some angles in the longitudinal direction of the electrode when no electric field is applied. Application of the electric field will allow liquid crystal molecules to face toward the electric field. Light transmittance can be changed by arraying the polarizing plate sandwiching the liquid crystal cell at a predetermined angle. Liquid crystal molecules usable in the invention are nematic liquid crystals having a positive dielectric anisotropy Δε. The liquid crystal layer (gap) is in the range from above 2.8 μm to below 4.5 μm in thickness. Where retardation Δn·d is in the range from above 0.25 μm to below 0.32 μm, provided is a transmittance property substantially free of long-wave dependence within a visible light range. A proper combination of polarizing plates makes it possible to attain the maximum transmittance when the liquid crystal molecules are turned by 45 degrees from the rubbing direction to the electric field direction. Here, the liquid crystal layer is adjusted for thickness (gap) by using polymer beads. As a matter of course, glass beads, fibers and column-like resin spacers may be used to provide a similar gap. No particular restriction is placed on liquid crystal molecules as long as they are nematic liquid crystals. A higher dielectric anisotropy Δε is able to further reduce the drive voltage, whereas a smaller refractive index dielectric anisotropy An is able to further increase the thickness of the liquid crystal layer, by which liquid crystal-sealing time can be reduced and variation in liquid crystal layer thickness can be made smaller.

Regarding liquid display devices based on the TN mode and IPS mode in particular, as disclosed in Japanese Published Unexamined Patent Application No. 2001-100043, an optically compensated film having the effect of widening a viewing angle is used on the plane opposite the anti-reflection film of the present invention, among two protective films on the front and back faces of the polarizing film, thereby providing a polarizing plate having the anti-reflection effect and viewing-angle widening effect by the thickness of one sheet of a polarizing plate, which is particularly preferable.

<Other Liquid Crystal Modes>

Liquid crystal display devices based on the ECB mode or STN mode can be provided with the polarizing plate of the invention, according to the similar idea described in the above.

<Display Device>

The liquid crystal display device can be assembled according to conventional procedures. In general, a liquid crystal display device is made of liquid crystal cells, optical films and other parts such as lighting system when needed in an appropriate combination with a driving circuit. No particular restriction is placed on the display device of the invention. It may be assembled according to conventional procedures except for the liquid crystal display element in the invention is used.

In assembling of the liquid crystal display device, for example, parts such as prism array, lens array sheet, light diffusion plate, light guiding plate and back light can be appropriately arranged at a suitable site in one layer or two or more layers. The polarizing plate of the invention combined with λ/4 can be used as a polarizing plate for a reflective-type liquid crystal display or a surface-protective plate for an organic EL display to reduce reflected light coming from surface and inside.

### EXAMPLES

### Examples of Layer Forming Method (I)

### Example: A-1

Hereinafter, the present invention will be explained in detail by referring to the following examples. However, it shall be construed that the present invention is not limited to these examples. Parts are based on mass in present examples.

(Preparation of Coating Solution for Hard-Coat Layer)

The following compositions were put into a mixing tank and agitated to give a coating solution for hard-coat layer.

Polyglycidyl methacrylate of mass-average molecular weight 15000, 270.0 parts by mass; methyl ethyl ketone, 730.0 parts by mass; cyclohexanone 500.0 parts by mass and photo polymerization initiator (Irgacure 184, manufactured by Ciba Speciality Chemicals), 50.0 parts by mass were added to trimethyrolpropane triacrylate (Viscoat No. 295 (Osaka Organic Chemical Industry, Ltd.), 750.0 parts by weight and agitated. The resultant was filtered through a polypropylene filter with a pore diameter of 0.4 μm to prepare a coating solution for a hard-coat layer. Glycidyl methacrylate was dissolved in methyl ethylketone (MEK), thermal polymerization initiator (V-65 (Wako Pure Chemical Industries, Ltd.) was dropped to conduct the reaction at 80° C. for two hours, the thus obtained reaction solution was dropped to hexane, and the precipitate was dried under reduced pressure to obtain polyglycidyl methacrylate.

(Preparation of Titanium Dioxide Fine Particles Dispersing Solution)

Titanium dioxide fine particles (MPT-129C, manufactured by Ishihara Sangyo Kaisha, Ltd. TiO₂:Co₃O₄:Al₂O₃:ZrO₂=90.5:3.0:4.0:0.5 mass ratio) which contained cobalt and received surface-treatment with aluminum hydroxide and zirconium hydroxide was used as titanium dioxide fine particles.

The following dispersing agent, 41.1 parts by mass, and cyclohexanone, 701.8 parts by mass, were added to the above particles, 257.1 parts by mass, and the resultant was dispersed by using a dynomill to prepare titanium dioxide dispersing solution with weight mean pore diameter of 70 nm.

Dispersing Agent 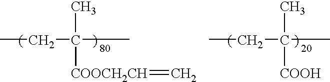
(Preparation of Coating Solution for Moderate Refractive Layer)

A mixture of dipentaerythritol pentaacrylate and dipentaerythritol hexaacrylate (DPHA, Nippon Kayaku Co., Ltd), 68.0 parts by mass; photo polymerization initiator (Irgacure 907, manufactured by Ciba Specialty Chemicals), 3.6 parts by mass; photosensitizing agent (Kayacure-DETX, manufactured by Nippon Kayaku Co., Ltd.), 1.2 parts by mass; methyl ethyl ketone 279.6 parts by mass and cyclohexanone, 1049.0 parts by mass were added to the above titanium dioxide dispersing solution, 99.1 parts by mass and agitated. After a sufficient agitation, the resultant was filtered through a polypropylene filter with a pore diameter of 0.4 μm to prepare a coating solution for a moderate refractive layer.

(Preparation of Coating Solution for High Refractive Layer)

A mixture of dipentaerythritol penta acrylate and dipentaerythritol hexaacrylate (DPHA, manufactured by Nippon Kayaku Co., Ltd.), 40.0 parts by mass; photo polymerization initiator (Irgacure 907, manufactured by Ciba Specialty Chemicals), 3.3 parts by mass; photosensitizing agent (Kayacure-DETX, manufactured by Nippon Kayaku Co., Ltd.), 1.1 parts by mass; methyl ethyl ketone, 526.2 parts by mass and cyclohexanone, 459.6 parts by mass were added to the above titanium dioxide dispersing solution, 469.8 parts by mass, and agitated. The resultant was filtered through a polypropylene filter with a pore diameter of 0.4 μm to prepare a coating solution for high refractive layer.

(Preparation of Coating Solution for Low Refractive Layer)

The copolymer P-3 described herein was added to methyl isobutyl ketone (MIK) so as to give 7% by mass concentration, silicone resin X-22-164C (manufactured by Shin-Etsu Chemical Co., Ltd.) containing terminal methacrylate group and the foregoing photo radical initiator Irgacure OXE 01 (trade name) were added respectively at 3% and 5% by mass in relation to the solid base content to prepare a coating solution for low refractive layer.

(Preparation of Anti-Reflection Film 101)

A coating solution for hard-coat layer was coated by using a gravure coater on triacetylcellulose film (TD80UF, manufactured by Fuji Photo Film Co., Ltd.) with a film thickness of 80 μm. After being dried at 100° C., an air-cooled metal halide lamp (manufactured by Eye Graphics Co., Ltd.) with 160 W/cm was used to irradiate an ultraviolet ray at an irradiance of 300 mJ/cm² and illuminance of 400 mW/cm² so as to give the oxygen concentration of not more than 1.0% by volume under nitrogen purge, thereby curing a coated layer to form a 8 μm-thick hard-coat layer.

The coating solution for the moderate refractive layer, coating solution for high refractive layer and coating solution for low refractive layer were continuously coated on a hard-coat layer by using a gravure coater equipped with three coating stations.

The moderate refractive layer was dried at 90° C. for 30 seconds and subjected to irradiation of an ultraviolet ray at an irradiance of 400 mJ/cm² and illuminance of 400 mW/cm² by using an air-cooled metal halide lamp (manufactured by Eye Graphics Co., Ltd.) with 180 W/cm so as to give the oxygen concentration below 1.0% by volume under nitrogen purge.

The moderate refractive layer after curing was 1.630 in refractive index and 67 nm in film thickness.

The high refractive layer was dried at 90° C. for 30 seconds and subjected to irradiation of an ultraviolet ray at an exposure dose of 400 mJ/cm² and illuminance of 600 mW/cm² by using an air-cooled metal halide lamp (manufactured by Eye Graphics Co., Ltd.) with 240 W/cm so as to give the oxygen concentration below 1.0% by volume under nitrogen purge.

The high refractive layer after curing was 1.905 in refractive index and 107 mm in film thickness.

The low refractive layer was dried at 90° C. for 30 seconds and subjected to irradiation of an ultraviolet ray at an exposure dose of 600 mJ/cm² and illuminance of 600 mW/cm² by using an air-cooled metal halide lamp (manufactured by Eye Graphics Co., Ltd.) with 240 W/cm so as to give the oxygen concentration of 0.1% or less by volume under nitrogen purge.

The low refractive layer after curing was 1.440 in refractive index and 85 nm in film thickness. The anti-reflection film 101 was prepared as above.

Samples No. 102 through 112 were prepared in the same manner except that only the curing condition of the low refractive layer was changed as shown in Table 1. Where a film was to be heated after irradiation of an ultraviolet ray, heating was conducted by allowing the film after irradiation to contact with a rotating metal roll into which warm water or pressurized steam was passed. Film temperatures of unheated samples (for example, sample No. 101) were derived from reaction heat on ultraviolet-ray irradiation.

TABLE 1

| | | | | | | Step conditions subsequent | | | | |
|---|---|---|---|---|---|---|---|---|---|---|
| | Conditions of UV irradiation | | | | | to UV irradiation step | | | | |
| | Oxygen | | | Film | | Oxygen | | Film | | |
| Sample | concentration | Irradiance | | temperature | | concentration | | temperature | Heating | |
| No. | (% by vol) | (mJ/cm²) | Heating | (° C.) | Heating time (sec) | (% by vol) | Heating | (° C.) | time (sec) | Remarks |
| 101 | 0.1 | 600 | Not | 25 | — | 21 | Not | — | — | Present |
| | | | heated | | | | heated | | | invention |
| 102 | 21 | 600 | Not | 25 | — | 21 | Not | — | — | Comparative |
| | | | heated | | | | heated | | | example |
| 103 | 0.1 | 600 | Heated | 30 | 30 | 21 | Not | — | — | Present |
| | | | | | | | heated | | | invention |
| 104 | 0.1 | 600 | Heated | 60 | 30 | 21 | Not | — | — | Present |
| | | | | | | | heated | | | invention |
| 105 | 0.1 | 600 | Heated | 100 | 30 | 21 | Not | — | — | Present |
| | | | | | | | heated | | | invention |
| 106 | 0.1 | 600 | Heated | 100 | 30 | 0.1 | Heated | 30 | 30 | Present |
| | | | | | | | | | | invention |
| 107 | 0.1 | 600 | Heated | 100 | 30 | 0.1 | Heated | 60 | 30 | Present |
| | | | | | | | | | | invention |
| 108 | 0.1 | 600 | Heated | 100 | 30 | 0.1 | Heated | 100 | 30 | Present |
| | | | | | | | | | | invention |
| 109 | 21 | 600 | Heated | 100 | 30 | 0.1 | Heated | 100 | 30 | Comparative |
| | | | | | | | | | | example |
| 110 | 21 | 600 | Heated | 100 | 30 | 21 | Heated | 100 | 30 | Comparative |
| | | | | | | | | | | example |
| 111 | 0.1 | 300 | Heated | 100 | 30 | 0.1 | Heated | 100 | 30 | Present |
| | | | | | | | | | | invention |
| 112 | 0.1 | 300 | Heated | 100 | 30 | 0.1 | Not | — | — | Present |
| | | | | | | | heated | | | invention |

The thus obtained films were evaluated for the following items, the results of which are shown in Table 2.

[Specular Reflectivity]

A spectrophotometer V-550 [manufactured by JASCO Corporation] equipped with an adaptor ARV-474 was used to determine the specular reflectivity at an incident angle of 5 degrees and at an emergence angle of −5 degrees in wavelength from 380 to 780 nm, by which the mean reflectance ratio in wavelength from 450 to 650 nm was calculated to evaluate the anti-reflection property.

[Pencil Hardness]

The pencil hardness was evaluated according to the specification of JIS K5400. After anti-reflection films were kept for two hours at a temperature of 25° C. and humidity of 60% RH to adjust the condition, test pencils (H to 5H) specified in JIS S6006 were used to conduct the test under a 500 g load, from which the following results were obtained. The evaluation was made on the basis of the highest acceptable hardness.

Where no scratch was found or one scratch was found in the evaluation based on n=5: acceptable

Where three or more scratches were found in the evaluation based on n=5: not acceptable

[Steel-Wool Scratch Resistance]

Steel-wool (No. 0000) was used to conduct rubbing test under a load of 1.96 N/cm² and evaluation was made on the basis of the following five ranks by observing scratches formed after the steel wool was reciprocated 30 times.
A: no scratch was found at all,
B: hardly-visible scratches were found to a slight extent,
C: clearly visible scratches were found,
D: clearly visible scratches were markedly found, and

E: film was peeled off

TABLE 2

| | | | Steel-wool | |
|---|---|---|---|---|
| Sample | Reflectance ratio | Pencil | rubbing | |
| No. | (%) | hardness | resistance | Remarks |
| 101 | 0.32 | 2H-3H | C | Present invention |
| 102 | 0.32 | 2H | E | Comparative |
| | | | | example |
| 103 | 0.32 | 2H-3H | C | Present invention |
| 104 | 0.32 | 2H-3H | C-B | Present invention |
| 105 | 0.32 | 3H | B | Present invention |
| 106 | 0.32 | 3H | A | Present invention |
| 107 | 0.32 | 3H | A | Present invention |
| 108 | 0.32 | 3H | A | Present invention |
| 109 | 0.32 | 2H | D | Comparative |
| | | | | example |
| 110 | 0.32 | 2H | D | Comparative |
| | | | | example |
| 111 | 0.32 | 3H | B-A | Present invention |
| 112 | 0.32 | 2H-3H | B | Present invention |

Anti-reflection films prepared under the forming conditions of the present invention were found to have an excellent abrasion/scratch resistance, while keeping a sufficient anti-reflection property. Further, post-heating time is preferred to be 0.1 seconds or longer.

Further, the present invention is able to secure stable film properties even on variation in oxygen concentration or irradiance on UV irradiation.

### Example-2

Samples No. 113 through 118 were prepared in the same manner as in the samples No. 102, 103, 104, 105, 108 and 109 of Example A-1, except that they were passed through a nitrogen-replaced zone prior to a UV irradiation zone, and evaluated similarly. The preparing method of samples No. 119 and 120 were different from that of the sample No. 105 of Example A-1 only in that they were passed through a nitrogen-replaced zone prior to a UV irradiation zone. Where a film was to be heated after UV irradiation, heating was conducted by allowing the film after irradiation to contact with a rotating metal roll into which warm water or pressurized steam was passed.

TABLE 3

| | Conditions of nitrogen | | | | | | | |
|---|---|---|---|---|---|---|---|---|
| | replacement zone | | | | | | | |
| | prior to UV irradiation | | Conditions of UV irradiation | | | | | |
| Sample | Oxygen concentration | Passage | Oxygen concentration | Irradiance | | Film | Heating | |
| No. | (% by vol) | time (sec) | (% by vol) | (mJ/cm²) | Heating | temperature (° C.) | time (sec) | Remarks |
| 102 | — | — | 21 | 600 | Not heated | 25 | — | Comparative |
| | | | | | | | | example |
| 103 | — | — | 0.1 | 600 | Heated | 30 | 30 | Present |
| | | | | | | | | invention |
| 104 | — | — | 0.1 | 600 | Heated | 60 | 30 | Present |
| | | | | | | | | invention |
| 105 | — | — | 0.1 | 600 | Heated | 100 | 30 | Present |
| | | | | | | | | invention |
| 108 | — | — | 0.1 | 600 | Heated | 100 | 30 | Present |
| | | | | | | | | invention |
| 109 | — | — | 21 | 600 | Heated | 100 | 30 | Comparative |
| | | | | | | | | example |
| 113 | 0.1 | 1 | 21 | 600 | Not heated | 25 | — | Comparative |
| | | | | | | | | example |
| 114 | 0.1 | 1 | 0.1 | 600 | Heated | 30 | 30 | Present |
| | | | | | | | | invention |
| 115 | 0.1 | 1 | 0.1 | 600 | Heated | 60 | 30 | Present |
| | | | | | | | | invention |
| 116 | 0.1 | 1 | 0.1 | 600 | Heated | 100 | 30 | Present |
| | | | | | | | | invention |
| 117 | 0.1 | 1 | 0.1 | 600 | Heated | 100 | 30 | Present |
| | | | | | | | | invention |
| 118 | 0.1 | 1 | 21 | 600 | Heated | 100 | 30 | Comparative |
| | | | | | | | | example |
| 119 | 10 | 1 | 0.1 | 600 | Heated | 100 | 30 | Present |
| | | | | | | | | invention |
| 120 | 15 | 1 | 0.1 | 600 | Heated | 100 | 30 | Present |
| | | | | | | | | invention |

The results are shown in Table 4. Prior to UV irradiation, the samples were allowed to pass through a nitrogen-replaced low-oxygen concentration zone, by which abrasion/scratch resistance was improved. Curing occurs remarkably when the process is combined with a step of allowing the samples to pass through the nitrogen-replaced low-oxygen concentration zone which was heated after UV irradiation.

Further, abrasion/scratch resistance was also improved by heating the nitrogen-replaced low-oxygen concentration zone prior to UV irradiation.

TABLE 4

| | | | Steel-wool | |
|---|---|---|---|---|
| Sample | Reflectance ratio | Pencil | rubbing | |
| No. | (%) | hardness | resistance | Remarks |
| 102 | 0.32 | 2H | E | Comparative |
| | | | | example |
| 103 | 0.32 | 2H-3H | C | Present invention |
| 104 | 0.32 | 2H-3H | C-B | Present invention |
| 105 | 0.32 | 3H | B | Present invention |
| 108 | 0.32 | 3H | A | Present invention |
| 109 | 0.32 | 2H | D | Comparative |
| | | | | example |
| 113 | 0.32 | 3H | D-C | Comparative |
| | | | | example |
| 114 | 0.32 | 3H | A | Present invention |
| 115 | 0.32 | 3H | A | Present invention |
| 116 | 0.32 | 4H | A | Present invention |
| 117 | 0.32 | 4H | A | Present invention |
| 118 | 0.32 | 2H-3H | B | Comparative |
| | | | | example |
| 119 | 0.32 | 4H | B-A | Present invention |
| 120 | 0.32 | 4H | B-A | Present invention |

### Example-3

Similar evaluation was made for Example A-3 in which P-1 and P-2 described in the text (equivalent mass replacement) were used respectively in place of fluorine-containing polymers used in the low refractive layer of Example A-1 to 2 to obtain similar effects as those found in Example A-1 to 2.

### Example A-4

(Preparation of Coating Solution for Hard-Coat Layer)

The following compositions were put into a mixing tank and agitated to give a coating solution for hard-coat layer.

Compositions of coating solution for hard-coat layer

| | |
|---|---|
| DeSolite Z7404 (Zirconia fine particles-containing | 100 parts by mass |
| hard-coat composition solution: 60 wt % on solid | |
| basis; Zirconia fine particle content, 70 wt % on | |
| solid basis; mean particle diameter of about 20 nm; | |
| solvent compositions, MIBK:MEK = 9:1, including | |
| initiators, manufactured by JSR corporation) | |
| DPHA (UV cure resin: Nippon Kayaku Co., Ltd.) | 31 parts by mass |
| KBM-5103 (silane coupling agent: Shin-Etsu | 10 parts by mass |
| Chemical Co., Ltd.) | |
| KE-P150 (1.5 μm silica particles: Nippon Shokubai | 8.9 parts by mass |
| Co., Ltd.) | |
| MXS-300(3 μm cross-linked PMMA particles: | 3.4 parts by mass |
| Soken Chemical & Engineering Co., Ltd.) | |
| MEK | 29 parts by mass |
| MIBK | 13 parts by mass |

(Preparation of Coating Solution for Low Refractive Layer)

A coating solution for low refractive layer was prepared according to the method similar to that used in the Example A-1.

(Preparation of Anti-Reflection Film 401)

Triacetylcellulose film (TD80U, manufactured by Fuji Photo Film Co., Ltd.) was reeled out as a transparent substrate in a roll form, on which the above coating solution for a hard-coat layer was coated by using a 50 mm-across microgravure roll having the gravure pattern of 135 lines per inch and 60 μm in depth and a doctor blade at a transport speed of 10 m/min and dried at 60° C. for 150 seconds, an air-cooled metal halide lamp (manufactured by Eye Graphics Co., Ltd.) (160 W/cm) was then used to conduct UV irradiation at illuminance of 400 mW/cm² and irradiance of 250 mJ/cm² under nitrogen purge, thereby curing the coated layer to form a hard-coat layer, which was then reeled up. The gravure roll was adjusted for the rotation number so that the hard-coat layer was given a thickness of 3.6 μm after curing.

The above hard-coat layer-coated transparent substrate was again reeled out, on which the above coating solution for a low refractive layer was coated by using a 50 mm-across microgravure roll having the gravure pattern of 200 lines per inch and 30 μm in depth and a doctor blade at a transport speed of 10 m/min and dried at 90° C. for 30 seconds, an air-cooled metal halide lamp (manufactured by Eye Graphics Co., Ltd.) (240 W/cm) was then used to conduct UV irradiation at illuminance of 600 mW/cm² and irradiance of 400 mJ/cm² at oxygen concentration of 0.1% by volume, thereby forming a low refractive layer, which was then reeled up. The gravure roll was adjusted for the rotation number so that the low refractive layer was given a thickness of 100 nm after curing. Where a film was to be heated after UV irradiation, heating was conducted by allowing the film after irradiation to contact with a rotating metal roll into which warm water or pressurized steam was passed.

The samples No. 402 through 412 were prepared by changing the curing conditions of the low refractive layer as shown in Table 5.

TABLE 5

| | | | | | | Step conditions subsequent | | | | |
|---|---|---|---|---|---|---|---|---|---|---|
| | Conditions of UV irradiation | | | | | to UV irradiation step | | | | |
| | Oxygen | | | Film | | Oxygen | | | | |
| | concentration | Irradiance | | temperature | Heating | concentration | | Film | Heating | |
| Sample No. | (% by vol) | (mJ/cm²) | Heating | (° C.) | time (sec) | (% by vol) | Heating | temperature (° C.) | time (sec) | Remarks |
| 401 | 0.1 | 600 | Not | 25 | — | 21 | Not | — | — | Present |
| | | | heated | | | | heated | | | invention |
| 402 | 21 | 600 | Not | 25 | — | 21 | Not | — | — | Comparative |
| | | | heated | | | | heated | | | example |
| 403 | 0.1 | 600 | Heated | 30 | 30 | 21 | Not | — | — | Present |
| | | | | | | | heated | | | invention |
| 404 | 0.1 | 600 | Heated | 60 | 30 | 21 | Not | — | — | Present |
| | | | | | | | heated | | | invention |
| 405 | 0.1 | 600 | Heated | 100 | 30 | 21 | Not | — | — | Present |
| | | | | | | | heated | | | invention |
| 406 | 0.1 | 600 | Heated | 100 | 30 | 0.1 | Heated | 30 | 30 | Present |
| | | | | | | | | | | invention |
| 407 | 0.1 | 600 | Heated | 100 | 30 | 0.1 | Heated | 60 | 30 | Present |
| | | | | | | | | | | invention |
| 408 | 0.1 | 600 | Heated | 100 | 30 | 0.1 | Heated | 100 | 30 | Present |
| | | | | | | | | | | invention |
| 409 | 21 | 600 | Heated | 100 | 30 | 0.1 | Heated | 100 | 30 | Comparative |
| | | | | | | | | | | example |
| 410 | 21 | 600 | Heated | 100 | 30 | 21 | Heated | 100 | 30 | Comparative |
| | | | | | | | | | | example |
| 411 | 0.1 | 300 | Heated | 100 | 30 | 0.1 | Heated | 100 | 30 | Present |
| | | | | | | | | | | invention |
| 412 | 0.1 | 300 | Heated | 100 | 30 | 0.1 | Not | — | — | Present |
| | | | | | | | heated | | | invention |

These samples were evaluated similarly as in Example A-1, the results of which are shown in Table 6. Anti-reflection films prepared according to the method of the present invention were found to have excellent abrasion/scratch resistance, while keeping the anti-reflection performance.

TABLE 6

| | | | Steel-wool | |
|---|---|---|---|---|
| Sample | Reflectance ratio | Pencil | rubbing | |
| No. | (%) | hardness | resistance | Remarks |
| 401 | 1.5 | 2H-3H | C | Present invention |
| 402 | 1.5 | 2H | E | Comparative |
| | | | | example |
| 403 | 1.5 | 2H-3H | C | Present invention |
| 404 | 1.5 | 2H-3H | C-B | Present invention |
| 405 | 1.5 | 3H | B | Present invention |
| 406 | 1.5 | 3H | A | Present invention |
| 407 | 1.5 | 3H | A | Present invention |
| 408 | 1.5 | 3H | A | Present invention |
| 409 | 1.5 | 2H | D | Comparative |
| | | | | example |
| 410 | 1.5 | 2H | D | Comparative |
| | | | | example |
| 411 | 1.5 | 3H | B-A | Present invention |
| 412 | 1.5 | 2H-3H | B | Present invention |

### Example-5

The samples No. 413 through 418 were prepared in the same manner as in the sample No. 402, 403, 404, 405, 408 and 409 of Example A-4, except that they were passed through a nitrogen-replaced zone prior to a UV irradiation zone. These samples were also evaluated similarly. The preparing method of samples No. 419 and 420 were different from that of the sample No. 405 of Example A-3 only in that they were passed through a nitrogen-replaced zone prior to a UV irradiation zone.

TABLE 7

| | Conditions of nitrogen | | | | | | | |
|---|---|---|---|---|---|---|---|---|
| | replacement zone | | | | | | | |
| | prior to UV irradiation | | Conditions of UV irradiation | | | | | |
| Sample | Oxygen concentration | Passage | Oxygen concentration | Irradiance | | Film | Heating | |
| No. | (% by vol) | time (sec) | (% by vol) | (mJ/cm²) | Heating | temperature (° C.) | time (sec) | Remarks |
| 402 | — | — | 21 | 600 | Not heated | 25 | — | Comparative |
| | | | | | | | | example |
| 403 | — | — | 0.1 | 600 | Heated | 30 | 30 | Present |
| | | | | | | | | invention |
| 404 | — | — | 0.1 | 600 | Heated | 60 | 30 | Present |
| | | | | | | | | invention |
| 405 | — | — | 0.1 | 600 | Heated | 100 | 30 | Present |
| | | | | | | | | invention |
| 408 | — | — | 0.1 | 600 | Heated | 100 | 30 | Present |
| | | | | | | | | invention |
| 409 | — | — | 21 | 600 | Heated | 100 | 30 | Comparative |
| | | | | | | | | example |
| 413 | 0.1 | 1 | 21 | 600 | Not heated | 25 | — | Comparative |
| | | | | | | | | example |
| 414 | 0.1 | 1 | 0.1 | 600 | Heated | 30 | 30 | Present |
| | | | | | | | | invention |
| 415 | 0.1 | 1 | 0.1 | 600 | Heated | 60 | 30 | Present |
| | | | | | | | | invention |
| 416 | 0.1 | 1 | 0.1 | 600 | Heated | 100 | 30 | Present |
| | | | | | | | | invention |
| 417 | 0.1 | 1 | 0.1 | 600 | Heated | 100 | 30 | Present |
| | | | | | | | | invention |
| 418 | 0.1 | 1 | 21 | 600 | Heated | 100 | 30 | Comparative |
| | | | | | | | | example |
| 419 | 10 | 1 | 0.1 | 600 | Heated | 100 | 30 | Present |
| | | | | | | | | invention |
| 420 | 15 | 1 | 0.1 | 600 | Heated | 100 | 30 | Present |
| | | | | | | | | invention |

The results are shown in Table 8. Prior to UV irradiation, the samples were allowed to pass through a nitrogen-replaced low-oxygen concentration zone, by which abrasion/scratch resistance was improved. Curing occurs remarkably when the process is combined with a step of allowing the samples to pass through the nitrogen-replaced low-oxygen concentration zone which was heated after UV irradiation.

TABLE 8

| | | | Steel-wool | |
|---|---|---|---|---|
| Sample | Reflectance ratio | Pencil | rubbing | |
| No. | (%) | hardness | resistance | Remarks |
| 402 | 1.5 | 2H | E | Comparative |
| | | | | example |
| 403 | 1.5 | 2H-3H | C | Present invention |
| 404 | 1.5 | 2H-3H | C-B | Present invention |
| 405 | 1.5 | 3H | B | Present invention |
| 408 | 1.5 | 3H | A | Present invention |
| 409 | 1.5 | 2H | D | Comparative |
| | | | | example |
| 413 | 1.5 | 3H | D-C | Comparative |
| | | | | example |
| 414 | 1.5 | 3H | A | Present invention |
| 415 | 1.5 | 3H | A | Present invention |
| 416 | 1.5 | 4H | A | Present invention |
| 417 | 1.5 | 4H | A | Present invention |
| 418 | 1.5 | 2H-3H | B | Comparative |
| | | | | example |
| 419 | 1.5 | 4H | B-A | Present invention |
| 420 | 1.5 | 4H | B-A | Present invention |

### Example-6

Evaluation was made for anti-reflection films prepared by using the following coating solutions A and B for a low refractive layer respectively in place of the coating solutions for a low refractive layer used in Examples A-1 to 5 to confirm similar effects as those found in the present invention.

Use of hollow silica fine particles led to preparation of anti-reflection films low in reflectance and more excellent in abrasion/scratch resistance.

(Preparation of sol Solution a)

Methyl ethyl ketone, 120 parts, acryloyloxypropyl trimethoxysilane (KBM-5103, manufactured by Shin-Esu Chemical Co., Ltd.), 100 parts, diisopropoxy aluminum ethyl acetoacetate (trade name: Kelope EP-12, manufactured by Hope Chemical Co., Ltd. ), 3 parts, were added to a reaction vessel equipped with an agitator and a reflux condenser, and mixed. Ion-exchanged water, 30 parts, was then added and the resultant was allowed to react at 60° C. for 4 hours, and cooled down to room temperature, thereby obtaining a sol solution a. The mass-average molecular weight was 1600, and of compositions higher than oligomer compositions, the compositions with molecular weight from 1000 to 20000 were 100%. Gas chromatography analysis revealed that acryloyloxypropyl trimethoxysilane resulting from raw materials did not remain at all.

(Preparation of Dispersion Solution of Hollow-Silica Fine Particles)

Acryloyloxypropyl trimethoxysilane (KBM-5103, manufactured by Shin-Etsu Chemical Co., Ltd.), 30 parts, and diisopropoxy aluminum ethyl acetoacetate (trade name: Kelope EP-12, manufactured by Hope Chemical Co., Ltd.), 1.5 parts, were added to hollow-silica fine particle sol (isopropyl alcohol silica sol, manufactured by Catalysts & Chemicals Industries Co., Ltd., CS60-IPA, mean particle diameter of 60 nm, shell thickness of 10 nm, silica concentration of 20%, refractive index of silica particle of 1.31), 500 parts and mixed. Then, ion exchange water, 9 parts, was added thereto. After reaction at 60° C. for 8 hours, the resultant was cooled to room temperature, and actylacetone, 1.8 parts, was added to obtain a dispersion solution of hollow silica. The tus obtained dispersion solution of hollow silica was 18% by mass on solid basis and 1.31 in the refractive index after the solvents were dried.

(Preparation of coating solution A for low refractive layer)
Compositions of coating solution A for low refractive layer

| | |
|---|---|
| DPHA | 3.3 g |
| Dispersion solution of hollow-silica fine particles | 40.0 g |
| RMS-033 | 0.7 g |
| Irgacure OXE01 | 0.2 g |
| Sol solution a | 6.2 g |
| Methyl ethyl ketone | 290.6 g |
| Cyclohexanone | 9.0 g |

(Preparation of coating solution B for low refractive layer)
Compositions of coating solution B for low refractive layer

| | |
|---|---|
| DPHA | 1.4 g |
| Copolymer P-3 | 5.6 g |
| Dispersion solution of hollow-silica fine particles | 20.0 g |
| RMS-033 | 0.7 g |
| Irgacure OXE01 | 0.2 g |
| Sol solution a | 6.2 g |
| Methyl ethyl ketone | 306.9 g |
| Cyclohexanone | 9.0 g |

Compounds used are shown below.

KBM-5103: silane coupling agent (Shin-Etsu Chemical Co., Ltd.)

DPHA: mixture of dipentaerythritol pentaacryl ate with dip entaerythritol hexaacryl ate (Nippon Kayaku Co., Ltd.)

RMS-033: reactive silicone (Gelest Inc.)

Irgacure OXE01: photo polymerization initiator (Ciba Specialty Chemicals)

### Example A-7

Evaluation was made for anti-reflection films prepared by using the following coating solutions C for a low refractive layer respectively in place of the coating solutions for low refractive layer used in Examples A-1 to 5 to confirm similar effects as those found in the present invention. Similar effects were also confirmed in low refractive layers in which Opstar JN7228A was replaced with JTA 113 (manufactured by JSR Corporation) for which its degree of cross linkage was increased with respect to JN7228A, in the same mass quantity.

(Preparation of Coating Solution C for Low Refractive Layer)

The following compositions were put into a mixing tank, agitated, and then filtered through a polypropylene filter with a pore diameter of 1 μm to prepare a coating solution C for a low refractive layer.

Compositions of coating solution C for low refractive layer

| | | |
|---|---|---|
| Opstar JN7228A (composition solution of | 100 | parts by mass |
| thermally cross-linked fluorine-containing | | |
| polymer which contains polysiloxane and | | |
| hydroxyl group, manufactured by JSR | | |
| Corporation) | | |
| MEK-ST (silica dispersion, mean particle | 4.3 | parts by mass |
| diameter of 15 nm, manufactured by Nissan | | |
| Chemical Industries Ltd.) | | |
| MEK-ST with different particle diameter (silica | 5.1 | parts by mass |
| dispersion, mean particle diameter of 45 nm, | | |
| manufactured by Nissan Chemical Industries Ltd.) | | |
| Sol solution a | 2.2 | parts by mass |
| MEK | 15 | parts by mass |
| Cyclohexanone | 3.6 | parts by mass |

The above coating solution for a low refractive layer was coated by using a 50 mm-across microgravure roll having the gravure pattern of 200 lines per inch and 30 μm in depth and a doctor blade at a transport speed of 10 m/min, dried at 120° C. for 150 seconds and further dried at 140° C. for 12 minutes, and then irradiating an ultraviolet ray as in Example A-1 to prepare samples. The gravure roll was adjusted for the rotation number so that the low refractive layer was given a thickness of 100 nm after curing.

### Example A-8

(Preparation of Protective Film for Polarizing Plate)

A saponification solution was prepared in which sodium hydroxide solution (1.5 mol/L) was kept at 50° C.

Diluted sulfuric acid solution (0.005 mol/L) was also prepared.

The above saponification solution was used to give saponification to the surface of the transparent substrate opposite the side having the cured layer of the present invention on anti-reflection films prepared respectively in Examples A-1 to 7.

After the sodium hydroxide solution on the surface of the saponified transparent substrate was sufficiently washed with water, the surface was washed with the above diluted sulfuric acid solution which was then sufficiently washed away with water, and the surface was thoroughly dried at 100° C.

Evaluation was made for the water contact angle on the surface of the saponified transparent substrate opposite the side having the cured layer on the anti-reflection films, finding that the angle was 40 degrees or lower. Protective films for polarizing plate were thus prepared.

### Example A-9

(Preparation of Polarizing Plate)

Polyvinyl alcohol film with thickness of 75 μm (manufactured by Kuraray Co., Ltd.) was submerged for 5 minutes into an aqueous solution consisting of water, 1000 parts by mass; iodine, 7 parts by mass, and potassium iodide, 105 parts by mass, by which iodine was adsorbed.

Then, after the film was stretched mono-axially 4.4 times in a longitudinal direction in 4% by mass boric acid solution, it was dried still in a stretched state to prepare a polarizing film.

A polyvinyl alcohol-based adhesive agent was used to attach one side of the polarizing film with saponified triacetylcellulose of the anti-reflection film (protective film for polarizing plate) saponified in Example A-8 and prepared in Examples A-1 to 7. Further, the polyvinyl alcohol-based adhesive agent was used to attach the other side of the polarizing film with the triacetylcellulose film saponified similarly as above.

(Evaluation of Image Display Devices)

Transmissive type, reflective type or semi-transmissive type liquid crystal display devices based on the TN, STN, IPS, VA or OCB mode in which the thus prepared polarizing plate of the present invention was attached so that an anti-reflection film was arrayed on the first surface of the display were excellent in anti-reflection performance and also quite excellent in visibility. The effect was particularly remarkable in the VA mode.

### Example A-10

(Preparation of Polarizing Plate)

In an optically compensated film (wide-view film SA12B, manufactured by Fuji Photo Film Co., Ltd.), saponification was given to the surface opposite that having an optically compensated layer under the same conditions as in Example A-8. A polyvinyl alcohol-based adhesive agent was used to attach one side of the polarizing film prepared in Example A-9 with saponified triacetylcellulose of the respective anti-reflection films (protective film for polarizing plate) saponified in Example A-8 and prepared in Examples A-1 to 7. Further, the polyvinyl alcohol-adhesive agent was used to attach the other side of the polarizing film with the triacetylcellulose side of the saponified optically-compensated film.

(Evaluation of Image Display Devices)

Transmissive-type, reflective-type or semi-transmissive-type liquid crystal display devices based on the TN, STN, IPS, VA or OCB mode in which the thus prepared polarizing plate of the present invention was attached so that an anti-reflection film arrayed on the first surface of the display were more excellent in contrast in a bright room than a liquid display device equipped with a polarizing plate on which the optically compensated film was not used, and provided with a very wide field angle at every respect, excellent anti-reflective performance and quite excellent visibility and display quality. The effect was particularly remarkable in the VA mode.

### Example A-11

In preparing the anti-reflection film 108, the coating solution for a low refractive layer was changed to the formulation of the following LL-61 and coated at a coating speed of 25 m/min by using the following die coater. After being dried at 90° C. for 30 seconds, an air-cooled metal halide lamp (manufactured by Eye Graphics Co., Ltd.) (240 W/cm) was used to conduct UV irradiation at an illuminance of 600 mW/cm² and irradiance of 400 mJ/cm² under nitrogen purge so as to give the oxygen concentration of 0.1% by volume or less, thereby forming a low refractive layer (refractive index of 1.45, film thickness of 83 nm). The anti-reflection film (11-1) was prepared as above.

Anti-reflection films of (11-2) to (11-5) were also prepared by changing the coating solutions for the low refractive layer to LL-62 to 65.

(Constitution of Dye Coater)

The slot die 13 was 0.5 mm in up-stream lip land length of I_{UP}, 50 μm in lower-stream lip land length of I_{LO}, and the slot 16 was 50 mm in length and 150 μm in the web-running direction of an opening. A clearance between the up-stream lip land 18a and the web was made longer by 50 μm than a clearance between the down-stream lip land 18b and the web (hereinafter referred to as overbite length 50 μm), and clearance G_{L} between the down-stream lip land 18b and the web was established to be 50 μm. Further, clearance Gₛ between the side plate 40b in the reduced-pressure chamber 40 and the web and clearance G_{B} between the back plate 40a and the web were both established to be 200 μm.

(Preparation of Coating Solution (LL-61) for Low Refractive Layer)

A solution in which the copolymer P-3 described in the literature was dissolved in methyl ethyl ketone so as to give 23.7% by mass concentration, 152.4 parts by mass, terminal methacrylate group-containing silicone resin X-22-164C (manufactured by Shin-Etsu Chemical Co., Ltd.), 1.1 parts by mass, photo radical initiator, Irgacure 1870 (manufactured by Ciba Speciality Chemicals), 1.8 parts by mass, methyl ethyl ketone, 815.9 parts by mass, and cyclohexanone, 28.8 parts by mass were added and agitated. A PTFE filter with a pore diameter of 0.45 μm was used to conduct filtration to prepare a coating solution (LL-61) for a low refractive layer. The coating solution was 0.61 [mPa·sec] in viscosity and 24 [mN/m] in surface tension. An amount of the coating solution to be applied on a transparent substrate was 2.8 [mL/M²].

(Preparation of Coating Solution (LL-62) for Low Refractive Layer)

A solution in which the above copolymer P-3 was dissolved in methyl ethyl ketone so as to give 23.7% by mass concentration, 426.6 parts by mass, terminal methacrylate group-containing silicone resin X-22-164C (manufactured by Shin-Etsu Chemical Co., Ltd.), 3.0 parts by mass, photo radical initiator, Irgacure 1870 (manufactured by Ciba Speciality Chemicals), 5.1 parts by mass, methyl ethyl ketone, 538.6 parts by mass and cyclohexanone, 26.7 parts by mass, were added and agitated. A PTFE filter with a pore diameter of 0.45 μm was used to conduct filtration to prepare a coating solution (LL-62) for a low refractive layer. The coating solution was 1.9 [mPa·sec] in viscosity and 24 [mN/m] in surface tension. An amount of the coating solution to be applied on a transparent substrate was 1.5 [mL/M²].

(Preparation of Coating Solution (LL-63) for Low Refractive Layer)

A solution in which the above copolymer P-3 was dissolved in methyl ethyl ketone so as to give 23.7% by mass concentration, 213.3 parts by mass, terminal methacrylate group-containing silicone resin X-22-164C (manufactured by Shin-Etsu Chemical Co., Ltd.), 1.5 parts by mass, photo radical initiator, Irgacure 1870 (manufactured by Ciba Specialty Chemicals), 2.5 parts by mass, methyl ethyl ketone, 754.3 parts by mass, and cyclohexanone, 28.4 parts by mass, were added and agitated. A PTFE filter with a pore diameter of 0.45 μm was used to conduct filtration to prepare a coating solution (LL-63) for a low refractive layer. The coating solution was 0.76 [mPa·sec] in viscosity and 24 [mN/m] in surface tension. An amount of the coating solution to be applied on a transparent substrate was 2.0 [mL/m²].

(Preparation of Coating Solution (LL-64) for Low Refractive Layer)

A solution in which the above copolymer P-3 was dissolved in methyl ethyl ketone so as to give 23.7% by mass concentration, 85.3 parts by mass, terminal methacrylate group-containing silicone resin X-22-164C (manufactured by Shin-Etsu Chemical Co., Ltd.), 0.6 parts by mass, photo radical initiator, Irgacure 1870 (manufactured by Ciba Speciality Chemicals), 1.0 parts by mass, methyl ethyl ketone, 883.7 parts by mass, and cyclohexanone 29.3 parts by mass, were added and agitated. A PTFE filter with a pore diameter of 0.45 μm was used to conduct filtration to prepare a coating solution (LL-64) for a low refractive layer. The coating solution was 0.49 [mPa·sec] in viscosity and 24 [mN/m] in surface tension. An amount of the coating solution to be applied on a transparent substrate was 5.0 [nL/m²].

(Preparation of Coating Solution (LL-65) for Low Refractive Layer)

A solution in which the above copolymer P-3 was dissolved in methyl ethyl ketone so as to give 23.7% by mass concentration, 71.1 parts by mass, terminal methacrylate group-containing silicone resin X-22-164C (manufactured by Shin-Etsu Chemical Co., Ltd.), 0.5 parts by mass, photo radical irradiator, Irgacure 907 (manufactured by Ciba Specialty Chemicals), 0.8 parts by mass, methyl ethyl ketone 898.1 parts by mass and cyclohexanone, 29.5 parts by mass, were added and agitated. A PTFE filter with a pore diameter of 0.45 μm was used to conduct filtration to prepare a coating solution (LL-65) for a low refractive layer. The coating solution was 0.46 [mPa·sec] in viscosity and 24 [mN/m] in surface tension. An amount of the coating solution to be applied on a transparent substrate was 6.0 [mL/m²].

Evaluation was made for the surface state of the anti-reflection films (11-1) to (11-5) which was made by using the coating solutions for a low refractive layer, the formulation of which was changed to LL-61 to LL-65. The results are shown in Table 9. The coating solution was able to be applied where the coating solution to be applied on a transparent substrate was 2 mL/m² or more. However, it was not applied all over the surface uniformly in an amount of 1.5 ml/m², thus resulting in failure in preparing anti-reflection films. Further, the coating solution was able to be applied where the coating solution to be applied on a transparent substrate was 6 mL/m², but drying was not conducted in a timely manner due to a larger amount of the coating solution, resulting in development of vertical streaks all over the surface due to drying-related air.

The thus obtained anti-reflection films (11-1), (11-3) and (11-4) were used to prepare display devices according to the procedures similar to those of Example A-10. These devices were lower in frequency of developing non-uniform color than those of Example A-10 prepared by using a gravure coater and better in quality.

TABLE 9

| | | | | Application of | |
|---|---|---|---|---|---|
| | Coating | | | coating | Surface state |
| | solution for | | Coated | solution, | of |
| Anti-reflection | low-refractive | Viscosity | amount | acceptable or | anti-reflection |
| film | layer | (mPa · sec) | (mL/m²) | not | film |
| 11-1 | LL-61 | 0.61 | 2.8 | ∘ | ∘ |
| 11-2 | LL-62 | 1 | 1.5 | x | x |
| 11-3 | LL-63 | 0.76 | 2.0 | ∘ | ∘ |
| 11-4 | LL-64 | 0.49 | 5.0 | ∘ | ∘ |
| 11-5 | LL-65 | 0.46 | 6.0 | ∘ | x |

### Example A-12

Anti-reflection films (12-1) to (12-4) were prepared similarly as in the anti-reflection film (11-1), except that the down-stream lip land length I_{LO} was changed to 10 μm, 30 μn, 100 μm or 120 μm. The results are shown in Table 10. Where the down-stream lip land length was in the range of 30 μm to 100 μm, anti-reflection films free of surface defect were obtained. In the anti-reflection film (12-1), streak-like irregularities developed in the longitudinal direction of the base. In the anti-reflection film (12-4), the bead 14a was not formed at a speed similar to that of the anti-reflection film (11-1), resulting in a failure of coating. After the coating speed was reduced by half, coating was able to be conducted, but streak-like irregularities developed in the longitudinal direction of the base. The anti-reflection films (12-2) and (12-3) were used to prepare display devices similarly as in Example A-10. These devices were quite small in reflection of the background, extremely reduced in color of reflected light and also secured for uniformity inside the display surface, and therefore quite high in quality. In contrast, when the anti-reflection films (12-1) and (12-4) were used to prepare devices similarly as in Example A-10, these devices developed macroscopically visible non-uniform color inside the displays, and were therefore not high in quality.

TABLE 10

| | Down-stream | Overbite | |
|---|---|---|---|
| | lip land | length LO | Surface state of |
| Anti-reflection film | length I_{LO} (μm) | (μm) | anti-reflection film |
| (12-1) | 10 | 50 | x |
| (12-2) | 30 | 50 | ∘ |
| (12-3) | 100 | 50 | ∘ |
| (12-4) | 120 | 50 | x |

### Example A-13

Anti-reflection films (13-1) to (13-4) were prepared similarly as in the anti-reflection film (11-1), except that the overbite length LO of the die coater was changed to 0 μm, 30 μm, 120 μm or 150 μm. The results are shown in Table 11. Where the overbite length was in the range of 30 μm to 120 μm, anti-reflection films free of surface defect were obtained. In the anti-reflection film (13-1) coating was able to be conducted but irregularities of the coated surface developed in the width direction of the base. In the anti-reflection film (13-4) the bead 14a was not formed at a speed similar to that of the anti-reflection film (13-1), resulting in a failure of the coating. After the coating speed was reduced by half, coating was able to be conducted, but streak-like irregularities developed in the longitudinal direction of the base. The anti-reflection films (13-2) and (13-3) were used to prepare display devices similarly as in Example A-10. These devices were quite small in reflection of the background, extremely reduced in color of reflected light and also secured for uniformity inside the display surface, and therefore quite high in quality. In contrast, when the anti-reflection films (13-1) and (13-4) were used to prepare devices similarly as in Example A-10, these devices developed macroscopically visible non-uniform color inside the displays, and were therefore not high in quality.

TABLE 11

| | Down-stream | Overbite | |
|---|---|---|---|
| | lip land | length LO | Surface state of |
| Anti-reflection film | length I_{LO} (μm) | (μm) | anti-reflection film |
| (13-1) | 50 | 0 | x |
| (13-2) | 50 | 30 | ∘ |
| (13-3) | 50 | 120 | ∘ |
| (13-4) | 50 | 150 | x |

Even where the curing conditions in preparing the anti-reflection films, 11-1, 3 and 4 in Table 9 were changed to those of the samples No. 105 to 107, 111 and 112 in Table 1, evaluation results of these films were the same as those shown in Table 9, Table 10 and Table 11.

### Example of Layer Forming Method (II)

### Example B-1

(Preparation of Coating Solution for Hard-Coat Layer)

The following compositions were put into a mixing tank and agitated to give a coating solution for a hard-coat layer.

Polyglycidyl methacrylate of mass-average molecular weight 15000, 270.0 parts by mass; methyl ethyl ketone, 730.0 parts by mass; cyclohexanone 500.0 parts by mass and photo polymerization initiator (Irgacure 184, manufactured by Ciba Specialty Chemicals), 50.0 parts by mass, were added to trimethyrolpropane triacrylate (Viscoat No. 295, manufactured by Osaka Organic Chemical Industry Ltd.), 750.0 parts by weight, and agitated. The resultant was filtered through a polypropylene filter with a pore diameter of 0.4 μm to prepare a coating solution for a hard-coat layer. Glycidyl methacrylate was dissolved in methyl ethylketone (MEK), and thermal polymerization initiator (V-65, manufactured by Wako Pure Chemical Industries Ltd.) was added to conduct the reaction at 80° C. for two hours, the thus obtained reaction solution was dropped to hexane, and the precipitate was dried under reduced pressure to obtain polyglycidyl methacrylate.

(Preparation of Dispersing Solution of Titanium Dioxide Fine Particles)

Titanium dioxide fine particles (MPT-129C, manufactured by Ishihara Sangyo Kaisha, Ltd. TiO₂:Co₃O₄:Al₂O₃:ZrO₂=90.5:3.0:4.0:0.5 mass ratio) which contained cobalt and underwent surface-treatment with aluminum hydroxide and zirconium hydoxide were used as titanium dioxide fine particles.

The following dispersing agent, 41.1 parts by mass, and cyclohexanone, 701.8 parts by mass, were added to the above particles, 257.1 parts by mass, and the resultant was dispersed by using a dynomill to prepare a titanium dioxide dispersing solution with a weight mean pore diameter of 70 nm.
<Dispersing Agent> 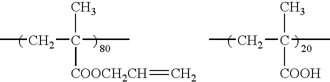
(Preparation of Coating Solution for a Moderate Refractive Layer)

A mixture of dipentaerythritol pentaacrylate and dipentaerythritol hexaacrylate (DPHA, manufactured by Nippon Kayaku Co., Ltd), 68.0 parts by mass, photo polymerization initiator (Irgacure 907, manufactured by Ciba Specialty Chemicals), 3.6 parts by mass, photosensitizing agent (Kayacure-DETX, manufactured by Nippon Kayaku Co., Ltd.), 1.2 parts by mass, methyl ethyl ketone 279.6 parts by mass, and cyclohexanone, 1049.0 parts by mass, were added to the above titanium dioxide dispersing solution, 99.1 parts by mass and agitated. After a sufficient agitation, the resultant was filtered through a polypropylene filter with a pore diameter of 0.4 μm to prepare a coating solution for a moderate refractive layer.

(Preparation of Coating Solution for a High Refractive Layer)

A mixture of dipentaerythritol pentaacrylate and dipentaerythritol hexaacrylate (DPHA, manufactured by Nippon Kayaku Co., Ltd.), 40.0 parts by mass, photo polymerization initiator (Irgacure 907, manufactured by Ciba Specialty Chemicals), 3.3 parts by mass, photosensitizing agent (Kayacure-DETX, manufactured by Nippon Kayaku Co., Ltd.), 1.1 parts by mass; methyl ethyl ketone, 526.2 parts by mass and cyclohexanone, 459.6 parts by mass, were added to the above titanium dioxide dispersing solution, 469.8 parts by mass, and agitated. The resultant was filtered through a polypropylene filter with a pore diameter of 0.4 μm to prepare a coating solution for a high refractive layer.

(Preparation of Coating Solution for Low Refractive Layer)

The copolymer P-3 described in Japanese Published Unexamined Patent Application No. 2004-45462 was added to methyl isobutyl ketone so as to give 7% by mass concentration, terminal methacrylate group-containing silicone resin X-22-164C (manufactured by Shin-Etsu Chemical Co., Ltd.) and the foregoing photo radical initiator Irgacure 907 (manufactured by Ciba Specialty Chemicals) were added respectively at 3% and 5% by mass in relation to the solid base content to prepare a coating solution for a low refractive layer.

(Preparation of Anti-Reflection Film 101)

A coating solution for a hard-coat layer was coated by using a gravure coater on triacetylcellulose film with a thickness of 80 μm (TD80UF, manufactured by Fuji Photo Film Co., Ltd.). After dried at 100° C., an air-cooled metal halide lamp (manufactured by Eye Graphics Co., Ltd.) with 160 W/cm was used to conduct UV irradiation at irradiance of 300 mJ/cm² and illuminance of 400 mW/cm² so as to give the oxygen concentration below 1.0% by volume under nitrogen purge, thereby curing a coated layer to form a 8 μm-thick hard-coat layer.

The coating solution for a moderate refractive layer, coating solution for a high refractive layer and coating solution for a low refractive layer were continuously coated on a hard-coat layer by using a gravure coater equipped with three coating stations.

The moderate refractive layer was dried at 90° C. for 30 seconds and subjected to UV irradiation at irradiance of 400 mJ/cm² and illuminance of 400 mW/cm² by using an air-cooled metal halide lamp (manufactured by Eye Graphics Co., Ltd.) with 180 W/cm so as to give the oxygen concentration of not more than 1.0% by volume under nitrogen purge.

The moderate refractive layer after curing was 1.630 in refractive index and 67 nm in film thickness.

The high refractive layer was dried at 90° C. for 30 seconds and subjected to UV irradiation at irradiance of 400 mJ/cm² and illuminance of 600 mW/cm² by using an air-cooled metal halide lamp (manufactured by Eye Graphics Co., Ltd.) with 240 W/cm so as to give the oxygen concentration of not more than 1.0% by volume under nitrogen purge.

The high refractive layer after curing was 1.905 in refractive index and 107 mm in film thickness.

The low refractive layer was dried at 90° C. for 30 seconds and subjected to UV irradiation at irradiance of 600 mJ/cm² and illuminance of 600 mW/cm² by using an air-cooled metal halide lamp (manufactured by Eye Graphics Co., Ltd.) with 240 W/cm so as to give the oxygen concentration of not more than 0.1% by volume under nitrogen purge.

The low refractive layer after curing was 1.440 in refractive index and 85 nm in film thickness. The anti-reflection film 101 was prepared as above.

The samples No. 102 through 116 were prepared similarly, except only that the curing condition of the low refractive layer was changed as shown in Table 12. Where a film was to be heated after UV irradiation, heating was conducted by allowing the film after irradiation to contact with a rotating metal roll into which warm water or pressurized steam was passed.

TABLE 12

| | Conditions of UV | | | | | | |
|---|---|---|---|---|---|---|---|
| | irradiation | | Conditions after UV irradiation | | | | |
| | Oxygen | | Presence or | Oxygen | Film surface | Passage time | |
| | concentration | Irradiance | absence of nitrogen | concentration | temperature | through nitrogen | |
| Sample No. | (% by vol) | (mJ/cm²) | replacement zone | (% by vol) | (° C.) | replacement zone (sec) | Remarks |
| 101 | 0.1 | 600 | Not | 21 | 30 | — | Comparative |
| | | | replaced | | | | example |
| 102 | 0.1 | 600 | Not | 21 | 55 | — | Comparative |
| | | | replaced | | | | example |
| 103 | 0.1 | 600 | Not | 21 | 80 | — | Comparative |
| | | | replaced | | | | example |
| 104 | 0.1 | 600 | Replaced | 5 | 55 | 5 | Comparative |
| | | | | | | | example |
| 105 | 0.1 | 600 | Replaced | 2 | 40 | 5 | Present |
| | | | | | | | invention |
| 106 | 0.1 | 600 | Replaced | 2 | 55 | 5 | Present |
| | | | | | | | invention |
| 107 | 0.1 | 600 | Replaced | 2 | 80 | 5 | Comparative |
| | | | | | | | example |
| 108 | 0.1 | 600 | Replaced | 0.1 | 40 | 5 | Present |
| | | | | | | | invention |
| 109 | 0.1 | 600 | Replaced | 0.1 | 55 | 5 | Present |
| | | | | | | | invention |
| 110 | 0.1 | 600 | Replaced | 0.1 | 80 | 5 | Comparative |
| | | | | | | | example |
| 111 | 0.1 | 600 | Replaced | 0.1 | 55 | 0.1 | Present |
| | | | | | | | invention |
| 112 | 0.1 | 600 | Replaced | 0.1 | 55 | 1 | Present |
| | | | | | | | invention |
| 113 | 0.1 | 600 | Replaced | 0.1 | 55 | 30 | Present |
| | | | | | | | invention |
| 114 | 2 | 600 | Replaced | 0.1 | 40 | 5 | Present |
| | | | | | | | invention |
| 115 | 2 | 600 | Replaced | 0.1 | 80 | 5 | Comparative |
| | | | | | | | example |
| 116 | 5 | 600 | Replaced | 0.1 | 55 | 5 | Comparative |
| | | | | | | | example |

The obtained films were evaluated for the following items, the results of which are shown in Table 13.

[Specular Reflectivity]

A spectrophotometer V-550 (manufactured by JASCO Corporation) equipped with an adaptor ARV-474 was used to determine the specular reflectivity at an incident angle of 5 degrees and at an emergence angle of −5 degrees in wavelength from 380 to 780 nm, by which the mean reflectance ratio in wavelength from 450 to 650 nm was calculated to evaluate the anti-reflection property.

[Pencil Hardness]

The pencil hardness evaluation was made according to the specification of JIS K5400. After an anti-reflection film was kept for two hours at a temperature of 25° C. and humidity of 60% RH to adjust the condition, test pencils (H to 5H specified in JIS S6006 were used to conduct the test under a 500 g load, from which the following results were obtained. The evaluation was made on the basis of the highest acceptable hardness.

Where no scratch was found or one scratch was found in the evaluation based on n=5: acceptable

Where three or more scratches were found in the evaluation based on n=5: not acceptable

TABLE 13

| | | | Steel-wool | | | | |
|---|---|---|---|---|---|---|---|
| | Reflectance ratio | | rubbing | Uniformity of | | Change in size | |
| Sample No. | (%) | Pencil hardness | resistance | work | Surface state | (%) | Remarks |
| 101 | 0.32 | 2H | E | B | No problem | 0.0 | Comparative |
| | | | | | | | example |
| 102 | 0.32 | 2H | E | B | No problem | 0.0 | Comparative |
| | | | | | | | example |
| 103 | 0.32 | 2H | E | D | Crimp | 0.2 | Comparative |
| | | | | | found | | example |
| 104 | 0.32 | 2H | D | B | No problem | 0.0 | Comparative |
| | | | | | | | example |
| 105 | 0.32 | 2H-3H | C-B | B | No problem | 0.0 | Present |
| | | | | | | | invention |
| 106 | 0.32 | 2H-3H | C-B | B | No problem | 0.0 | Present |
| | | | | | | | invention |
| 107 | 0.32 | 2H-3H | C-B | D | Crimp | 0.2 | Comparative |
| | | | | | found | | example |
| 108 | 0.32 | 3H | B | B | No problem | 0.0 | Present |
| | | | | | | | invention |
| 109 | 0.32 | 3H | B-A | B | No problem | 0.0 | Present |
| | | | | | | | invention |
| 110 | 0.32 | 3H | A | D | Crimp | 0.2 | Comparative |
| | | | | | found | | example |
| 111 | 0.32 | 3H | B | B-C | No problem | 0.0 | Present |
| | | | | | | | invention |
| 112 | 0.32 | 3H | B-A | B | No problem | 0.0 | Present |
| | | | | | | | invention |
| 113 | 0.32 | 3H | B-A | B | No problem | 0.0 | Present |
| | | | | | | | invention |
| 114 | 0.32 | 2H-3H | C | B | No problem | 0.0 | Present |
| | | | | | | | invention |
| 115 | 0.32 | 2H-3H | C | D | Crimp | 0.2 | Comparative |
| | | | | | found | | example |
| 116 | 0.32 | 1H-2H | E | B | No problem | 0.0 | Comparative |
| | | | | | | | example |

Anti-reflection films prepared under the curing conditions of the present invention were found to have an excellent abrasion/scratch resistance, while keeping a sufficient anti-reflection performance. Higher temperatures after UV irradiation failed in obtaining the uniform performance of a film and posed problems on the surface state such as development of crimp.

Further, in the present invention, stable film properties were secured even when the oxygen concentration or irradiance on UV irradiation varied.

### Example B-2

The samples No. 119 through 122 (samples No. 119 and 120 were prepared according to the method for preparing the sample No. 109, and the samples No. 121 and 122 were prepared according to that for preparing the sample No. 116) were prepared similarly as in the samples No. 109 and 116 of Example B-1, except that surface temperatures of the films on UV irradiation were elevated, and evaluated similarly. The film surface temperatures were adjusted by changing the temperature of a metal plate contacting with the back face of the films. The results are shown in Table 14.

TABLE 14

| | Film surface | Reflectance | | | | | | |
|---|---|---|---|---|---|---|---|---|
| | temperature of UV | ratio | Pencil | Steel-wool rubbing | Uniformity of | | | |
| Sample No. | irradiation | (%) | hardness | resistance | work | Surface state | Change in size (%) | Remarks |
| 109 | 40° C. | 0.32 | 3H | B-A | B | No problem | 0.0 | Present |
| | | | | | | | | invention |
| 119 | 60° C. | 0.32 | 3H | A | B | No problem | 0.0 | Present |
| | | | | | | | | invention |
| 120 | 80° C. | 0.32 | 3H | A | C | Slightly | 0.2 | Present |
| | | | | | | crimped | | invention |
| 116 | 40° C. | 0.32 | 1H-2H | E | B | No problem | 0.0 | Comparative |
| | | | | | | | | example |
| 121 | 60° C. | 0.32 | 1H-2H | E | B | No problem | 0.0 | Comparative |
| | | | | | | | | example |
| 122 | 80° C. | 0.32 | 2H | D | C | Slightly | 0.2 | Comparative |
| | | | | | | crimped | | example |

It was preferably found by observing the uniformity of a work and the surface state that the surface temperature on UV irradiation and that in the subsequent steps are different by 20° C. or less.

### Example B-3

The samples No. 123 through 128 were prepared in the same manner as in the samples No. 108 and 109 of Example B-1, except that they were passed through a nitrogen-replaced zone prior to passage through a UV irradiation zone, and evaluated similarly. Retention time means a time for retaining the surface temperature of a film at a desired temperature.

TABLE 15

| | Conditions of nitrogen | | | | | |
|---|---|---|---|---|---|---|
| | replacement zone prior | | Conditions after UV irradiation | | | |
| | to UV irradiation | | Presence or | | | |
| | Oxygen | | absence of nitrogen | Oxygen | Film surface | |
| Sample | concentration | Passage | replacement | concentration | temperature | Retention |
| No. | (% by vol) | time (sec) | zone | (% by vol) | (° C.) | time (sec) |
| 108 | — | — | Present | 0.1 | 40 | 5 |
| 109 | — | — | Present | 0.1 | 55 | 5 |
| 123 | 0.1 | 5 | Present | 0.1 | 40 | 5 |
| 124 | 0.1 | 5 | Present | 0.1 | 55 | 5 |
| 125 | 2 | 5 | Present | 0.1 | 40 | 5 |
| 126 | 2 | 5 | Present | 0.1 | 55 | 5 |
| 127 | 5 | 5 | Present | 0.1 | 40 | 5 |
| 128 | 5 | 5 | Present | 0.1 | 55 | 5 |

The results are shown in Table 16. Passage through a zone where the oxygen concentration was not more than 3% led to improvement in abrasion/scratch resistance.

TABLE 16

| | | | Steel-wool | | | | |
|---|---|---|---|---|---|---|---|
| | Reflectance | | rubbing | Uniformity of | | Change in size | |
| Sample No. | ratio (%) | Pencil hardness | resistance | work | Surface state | (%) | Remarks |
| 108 | 0.32 | 3H | B | B | No | 0.0 | Present |
| | | | | | problem | | invention |
| 109 | 0.32 | 3H | B-A | B | No | 0.0 | Present |
| | | | | | problem | | invention |
| 123 | 0.32 | 3H | A | B | No | 0.0 | Present |
| | | | | | problem | | invention |
| 124 | 0.32 | 3H | A | B | No | 0.0 | Present |
| | | | | | problem | | invention |
| 125 | 0.32 | 3H | B-A | B | No | 0.0 | Present |
| | | | | | problem | | invention |
| 126 | 0.32 | 3H | A | B | No | 0.0 | Present |
| | | | | | problem | | invention |
| 127 | 0.32 | 3H | B | B | No | 0.0 | Present |
| | | | | | problem | | invention |
| 128 | 0.32 | 3H | B-A | B | No | 0.0 | Present |
| | | | | | problem | | invention |

### Example B-4

A similar evaluation was made for Example B-4 in which copolymers P-1 and P-2 described in Japanese Published Unexamined Patent Application No. 2004-45462 (equivalent mass replacement) were used respectively in place of fluorine-containing polymers used in the low refractive layer of Examples B-1 to 3, finding that similar effects were obtained as in Examples B-1 to 3.

### Example B-5

(Preparation of Coating Solution for Hard-Coat Layer)

The following compositions were put into a mixing tank and agitated to give a coating solution for hard-coat layer.

Compositions of coating solution for hard-coat layer

| | |
|---|---|
| DeSolite Z7404 | 100 parts by mass |
| (Zirconia fine particles-containing hard-coat | |
| composition solution: 60 wt % on solid basis; | |
| Zirconia fine particle content, 70 wt % on solid | |
| basis; mean particle diameter, about 20 nm; solvent | |
| compositions, MIBK:MEK = 9:1, manufactured by | |
| JSR Corporation) | |
| DPHA (UV cure resin: Nippon Kayaku Co., Ltd.) | 31 parts by mass |
| KBM-5103 (silane coupling agent: Shin-Etsu | 10 parts by mass |
| Chemical Co., Ltd.) | |
| KE-P150 (1.5 μm silica particles: Nippon | 8.9 parts by mass |
| Shokubai Co., Ltd.) | |
| MXS-300 (3 μm cross-linked PMMA particles: | 3.4 parts by mass |
| Soken Chemical & Engineering Co., Ltd.) | |
| MEK | 29 parts by mass |
| MIBK | 13 parts by mass |

(Preparation of Coating Solution for Low Refractive Layer)

A coating solution for a low refractive layer was prepared according to the method similar to that used in Example B-1.

(Preparation of Anti-Reflection Film 501)

Triacetylcellulose film (TD80U, manufactured by Fuji Photo Film Co., Ltd.) was reeled out as a transparent substrate in a roll form, on which the above coating solution for a hard-coat layer was coated by using a 50 mm-across microgravure roll having the gravure pattern of 135 lines per inch and 60 μm in depth and a doctor blade at a transport speed of 10 m/min and dried at 60° C. for 150 seconds, an air-cooled metal halide lamp (manufactured by Eye Graphics Co., Ltd.) (160 W/cm) was then used to conduct UV irradiation at illuminance of 400 mW/cm² and irradiance of 250 mJ/cm² under nitrogen purge, thereby curing the coated layer to form a hard-coat layer, which was then reeled up. The gravure roll was adjusted for the rotation number so that the hard-coat layer was given a thickness of 3.6 μm after curing.

The above hard-coat layer-coated transparent substrate was again reeled out, on which the above coating solution for a low refractive layer was coated by using a 50 mm-across microgravure roll having the gravure pattern of 200 lines per inch and 30 μm in depth and a doctor blade at a transport speed of 10 m/min and dried at 90° C. for 30 seconds, an air-cooled metal halide lamp (manufactured by Eye Graphics Co., Ltd.) (240 W/cm) was then used at an oxygen concentration of 0.1% by volume to conduct UV irradiation at illuminance of 600 mW/cm² and irradiance of 400 mJ/cm², thereby forming a low refractive layer, which was then reeled up. The gravure roll was adjusted for the rotation number so that the low refractive layer after curing was given a thickness of 100 nm. Where a film was to be heated after UV irradiation, heating was conducted by allowing the film after irradiation to contact with a rotating metal roll into which warm water or pressurized steam was passed.

The samples No. 502 through 516 were prepared by changing the curing conditions of the low refractive layer as shown in Table 17.

TABLE 17

| | Conditions of UV | | | | | | |
|---|---|---|---|---|---|---|---|
| | irradiation | | Conditions after UV irradiation | | | | |
| | Oxygen | | | Oxygen | | Passage time through | |
| Sample | concentration (% | Irradiance | Presence or absence of | concentration (% | Film surface | nitrogen replacement zone | |
| No. | by vol) | (mJ/cm²) | nitrogen replacement zone | by vol) | temperature (° C.) | (sec) | Remarks |
| 501 | 0.1 | 600 | Absent | 21 | 30 | — | Comparative |
| | | | | | | | example |
| 502 | 0.1 | 600 | Absent | 21 | 55 | — | Comparative |
| | | | | | | | example |
| 503 | 0.1 | 600 | Absent | 21 | 80 | — | Comparative |
| | | | | | | | example |
| 504 | 0.1 | 600 | Present | 5 | 55 | 5 | Comparative |
| | | | | | | | example |
| 505 | 0.1 | 600 | Present | 2 | 40 | 5 | Present |
| | | | | | | | invention |
| 506 | 0.1 | 600 | Present | 2 | 55 | 5 | Present |
| | | | | | | | invention |
| 507 | 0.1 | 600 | Present | 2 | 80 | 5 | Comparative |
| | | | | | | | example |
| 508 | 0.1 | 600 | Present | 0.1 | 40 | 5 | Present |
| | | | | | | | invention |
| 509 | 0.1 | 600 | Present | 0.1 | 55 | 5 | Present |
| | | | | | | | invention |
| 510 | 0.1 | 600 | Present | 0.1 | 80 | 5 | Comparative |
| | | | | | | | example |
| 511 | 0.1 | 600 | Present | 0.1 | 55 | 0.1 | Present |
| | | | | | | | invention |
| 512 | 0.1 | 600 | Present | 0.1 | 55 | 1 | Present |
| | | | | | | | invention |
| 513 | 0.1 | 600 | Present | 0.1 | 55 | 30 | Present |
| | | | | | | | invention |
| 514 | 2 | 600 | Present | 0.1 | 40 | 5 | Present |
| | | | | | | | invention |
| 515 | 2 | 600 | Present | 0.1 | 80 | 5 | Comparative |
| | | | | | | | example |
| 516 | 5 | 600 | Present | 0.1 | 55 | 5 | Comparative |
| | | | | | | | example |

These samples were evaluated similarly as in Example B-1, the results of which are shown in Table 18. Anti-reflection films prepared according to the method of the present invention were found to have excellent abrasion/scratch resistance, while keeping the anti-reflection performance.

TABLE 18

| | Reflectance ratio | | Steel-wool | Uniformity of | | Change in size | |
|---|---|---|---|---|---|---|---|
| Sample No. | (%) | Pencil hardness | rubbing resistance | work | Surface state | (%) | Remarks |
| 501 | 1.50 | 2H | E | B | No problem | 0.0 | Comparative |
| | | | | | | | example |
| 502 | 1.50 | 2H | E | B | No problem | 0.0 | Comparative |
| | | | | | | | example |
| 503 | 1.50 | 2H | E | D | Crimp | 0.2 | Comparative |
| | | | | | found | | example |
| 504 | 1.50 | 2H | D | B | No problem | 0.0 | Comparative |
| | | | | | | | example |
| 505 | 1.50 | 2H-3H | C-B | B | No problem | 0.0 | Present |
| | | | | | | | invention |
| 506 | 1.50 | 2H-3H | C-B | B | No problem | 0.0 | Present |
| | | | | | | | invention |
| 507 | 1.50 | 2H-3H | C-B | D | Crimp | 0.2 | Comparative |
| | | | | | found | | example |
| 508 | 1.50 | 3H | B | B | No problem | 0.0 | Present |
| | | | | | | | invention |
| 509 | 1.50 | 3H | B-A | B | No problem | 0.0 | Present |
| | | | | | | | invention |
| 510 | 1.50 | 3H | A | D | Crimp | 0.2 | Comparative |
| | | | | | found | | example |
| 511 | 1.50 | 3H | B | B-C | No problem | 0.0 | Present |
| | | | | | | | invention |
| 512 | 1.50 | 3H | B-A | B | No problem | 0.0 | Present |
| | | | | | | | invention |
| 513 | 1.50 | 3H | B-A | B | No problem | 0.0 | Present |
| | | | | | | | invention |
| 514 | 1.50 | 2H-3H | C | B | No problem | 0.0 | Present |
| | | | | | | | invention |
| 515 | 1.50 | 2H-3H | C | D | Crimp | 0.2 | Comparative |
| | | | | | found | | example |
| 516 | 1.50 | 1H-2H | E | B | No problem | 0.0 | Comparative |
| | | | | | | | example |

### Example B-6

The samples No. 517 through 522 were prepared in the same manner as in the samples No. 508 and 509 of Example B-5, except that they were passed through a nitrogen-replaced zone prior to passage through a UV irradiation zone, and evaluated similarly. Retention time means a time for retaining the surface temperature of a film at a desired temperature.

TABLE 19

| | Conditions of nitrogen | | Conditions after UV irradiation | | | |
|---|---|---|---|---|---|---|
| | replacement zone prior to | | Presence or | | | |
| | UV irradiation | | absence of | | | |
| | Oxygen | Passage | nitrogen | Oxygen | Film surface | |
| | concent-ration | time | replacement | concent-ration | temperature | Retention |
| Sample No. | (% by vol) | (sec) | zone | (% by vol) | (° C.) | time (sec) |
| 508 | — | — | Present | 0.1 | 40 | 5 |
| 509 | — | — | Present | 0.1 | 55 | 5 |
| 517 | 0.1 | 5 | Present | 0.1 | 40 | 5 |
| 518 | 0.1 | 5 | Present | 0.1 | 55 | 5 |
| 519 | 2 | 5 | Present | 0.1 | 40 | 5 |
| 520 | 2 | 5 | Present | 0.1 | 55 | 5 |
| 521 | 5 | 5 | Present | 0.1 | 40 | 5 |
| 522 | 5 | 5 | Present | 0.1 | 55 | 5 |

The results are shown in Table 20. Passage through a zone where the oxygen concentration was not more than 3% led to improvement in abrasion/scratch resistance.

TABLE 20

| | Reflectance ratio | | Steel-wool rubbing | Uniformity of | | | |
|---|---|---|---|---|---|---|---|
| Sample No. | (%) | Pencil hardness | resistance | work | Surface state | Change in size (%) | Remarks |
| 508 | 1.50 | 3H | B | B | No problem | 0.0 | Present |
| | | | | | | | invention |
| 509 | 1.50 | 3H | B-A | B | No problem | 0.0 | Present |
| | | | | | | | invention |
| 517 | 1.50 | 3H | A | B | No problem | 0.0 | Present |
| | | | | | | | invention |
| 518 | 1.50 | 3H | A | B | No problem | 0.0 | Present |
| | | | | | | | invention |
| 519 | 1.50 | 3H | B-A | B | No problem | 0.0 | Present |
| | | | | | | | invention |
| 520 | 1.50 | 3H | A | B | No problem | 0.0 | Present |
| | | | | | | | invention |
| 521 | 1.50 | 3H | B | B | No problem | 0.0 | Present |
| | | | | | | | invention |
| 522 | 1.50 | 3H | B-A | B | No problem | 0.0 | Present |
| | | | | | | | invention |

### Example B-7

Evaluation was made for anti-reflection films prepared by using the following coating solutions A and B for a low refractive layer respectively in place of the coating solutions for a low refractive layer used in Examples B-1 to 6 to confirm similar effects as those found in the present invention.

Use of hollow silica fine particles led to preparation of an anti-reflection film low in reflectance and more excellent in abrasion/scratch resistance.

(Preparation of Sol Solution a)

Methyl ethyl ketone, 120 parts, acryloyloxypropyl trimethoxysilane (KBM-5103, manufactured by Shin-Etsu Chemical Co., Ltd.), 100 parts, diisopropoxy aluminum ethyl acetoacetate (trade name: Kelope EP-12, manufactured by Hope Chemical Co., Ltd.), 3 parts, were added to a reaction vessel equipped with an agitator and a reflux condenser, and mixed. Ion-exchanged water, 30 parts, was then added and the resultant was allowed to react at 60° C. for 4 hours, and cooled down to room temperature, thereby obtaining a sol solution a. The mass-average molecular weight was 1600, and of compositions higher than oligomer compositions, the compositions with molecular weight from 1000 to 20000 were 100%. Gas chromatography analysis revealed that acryloyloxypropyltrimethoxysilane resulting from raw materials did not remain at all.

(Preparation of Dispersion Solution of Hollow-Silica Fine Particles)

Acryloyloxypropyl trimethoxysilane (KBM-5103, manufactured by Shin-Etsu Chemical Co., Ltd.), 30 parts, and diisopropoxy aluminum ethyl acetoacetate (trade name: Kelope EP-12, manufactured by Hope Chemical Co., Ltd.), 1.5 parts, were added to hollow-silica fine particle sol (isopropyl alcohol silica sol, manufactured by Catalysts & Chemicals Industries Co., Ltd., CS60-IPA, mean particle diameter of 60 nm, shell thickness of 10 nm, silica concentration of 20%, refractive index of silica particle, 1.31), 500 parts, and mixed. Then, ion exchange water, 9 parts, was added thereto. After reaction at 60° C. for 8 hours, the resultant was cooled to room temperature, and acetylacetone, 1.8 parts, was added to obtain a dispersion solution of hollow silica. The thus obtained dispersion solution of hollow silica was 18% by mass on a solid basis and 1.31 in refractive index after solvents were dried.

(Preparation of coating solution A for low refractive layer)

| | |
|---|---|
| DPHA | 3.3 g |
| Dispersion solution of hollow silica fine particles | 40.0 g |
| RM S-033 | 0.7 g |
| Irgacure 907 | 0.2 g |
| Sol solution a | 6.2 g |
| Methyl ethyl ketone | 290.6 g |
| Cyclohexanone | 9.0 g |

(Preparation of coating solution B for low refractive layer)

| | |
|---|---|
| DPHA | 1.4 g |
| Copolymer P-3 disclosed in Japanese Published | 5.6 g |
| Unexamined Patent Application No. 2004-45462 | |
| Dispersion solution of hollow silica fine particles | 20.0 g |
| RM S-033 | 0.7 g |
| Irgacure 907 | 0.2 g |
| Sol solution a | 6.2 g |
| Methyl ethyl ketone | 306.9 g |
| Cyclohexanone | 9.0 g |

Compounds used are shown below.

KBM-5103: silane coupling agent (manufactured by Shin-Etsu Chemical Co., Ltd.)

DPHA: mixture of dipentaerythritol pentaacrylate with dipentaerythritol hexaacrylate (manufactured by Nippon Kayaku Co., Ltd.)

RMS-033: reactive silicone (manufactured by Gelest Inc.)

Irgacure 907: photo polymerization initiator (manufactured by Ciba Specialty Chemicals)

### Example B-8

Evaluation was made for anti-reflection films prepared by using the following coating solutions C for a low refractive layer respectively in place of the coating solutions for a low refractive layer used in Examples B-1 to 6 to confirm similar effects as those found in the present invention. Similar effects were also confirmed in low refractive layers in which Opstar JN7228A (manufactured by JSR Corporation) was replaced with JTA 113 for which its degree of cross linkage was increased with respect to JN7228A, in the same mass quantity.

(Preparation of Coating Solution C for Low Refractive Layer)

The following compositions were put into a mixing tank, agitated, and then filtered through a polypropylene filter with a pore diameter of 1 μm to prepare a coating solution C for a low refractive layer.

Compositions of coating solution C for low refractive layer

| | |
|---|---|
| Opstar JN7228A (composition solution of | 100 parts by mass |
| thermally cross-linked fluorine-containing | |
| polymer which contains polysiloxane and | |
| hydroxyl group, manufactured by JSR | |
| Corporation) | |
| MEK-ST (silica dispersion, mean particle | 4.3 parts by mass |
| diameter of 15 nm, manufactured by | |
| Nissan Chemical Industries Ltd.) | |
| MEK-ST with different particle diameter | 5.1 parts by mass |
| (silica dispersion, mean particle diameter of | |
| 45 nm, manufactured by Nissan Chemical | |
| Industries Ltd.) | |
| Sol solution a (that prepared in Example B-7) | 2.2 parts by mass |
| MEK | 15 parts by mass |
| Cyclohexanone | 3.6 parts by mass |

The above coating solution for a low refractive layer was coated by using a 50 mm-across microgravure roll having the gravure pattern of 200 lines per inch and 30 μm in depth and a doctor blade at a transport speed of 10 m/min and dried at 120° C. for 150 seconds, and UV irradiation was then conducted as in Examples B-1 to 6 to prepare samples. The gravure roll was adjusted for the rotation number so that the low refractive layer was given a thickness of 100 nm after curing.

### Example B-9

(Preparation of Protective Film for Polarizing Plate)

Saponification solution was prepared in which sodium hydroxide solution (1.5 mol/L) was kept at 50° C.

Diluted sulfuric acid solution (0.005 mol/L) was also prepared.

The above saponification solution was used to give saponification to the surface of the transparent substrate opposite the side having the high refractive layer of the present invention in anti-reflection films prepared respectively in Examples B-1 to 8.

After sodium hydroxide solution on the surface of the saponified transparent substrate was sufficiently washed with water, the surface was washed with the above diluted sulfuric acid solution which was then sufficiently washed away with water, and the surface was thoroughly dried at 100° C.

Evaluation was made for the water contact angle on the surface of the saponified transparent substrate opposite the side having the high refractive layer of the anti-reflection film, finding that the angle was 40 degrees or lower. Protective films for polarizing plate were thus prepared.

### Example B-10

(Preparation of Polarizing Plate)

Polyvinyl alcohol film with a thickness of 75 μm (manufactured by Kuraray Co., Ltd.) was submerged for 5 minutes into an aqueous solution consisting of water, 1000 parts by mass; iodine, 7 parts by mass, and potassium iodide, 105 parts by mass, by which iodine was adsorbed.

Then, after the film was stretched mono-axially 4.4 times in a longitudinal direction in 4-mass % boric acid solution, it was dried still in a stretched state to prepare a polarizing film.

A polyvinyl alcohol-based adhesive agent was used to attach one side of the polarizing film with saponified triacetylcellulose of the anti-reflection film (protective film for polarizing plate) of the present invention. Further, the same polyvinyl alcohol-adhesive agent was used to attach the other side of the polarizing film with the triacetylcellulose film saponified similarly as above.

(Evaluation of Image Display Device)

Transmissive type, reflective type or semi-transmissive type liquid crystal display devices based on the TN, STN, IPS, VA or OCB mode in which the thus prepared polarizing plate of the present invention was attached so that an anti-reflection film arrayed on the first surface of the display were excellent in anti-reflection performance and also quite excellent in visibility. The effect was particularly remarkable in the VA mode.

### Example B-11

(Preparation of Polarizing Plate)

In an optically compensated film (wide-view film SA 12B, manufactured by Fuji Photo Film Co., Ltd.), saponification was given to the surface opposite that having an optically compensated layer under the same conditions as in Example B-9.

A polyvinyl alcohol-based adhesive agent was used to attach one side of the polarizing film prepared in Example B-10 with saponified triacetylcellulose of the anti-reflection film (protective film for polarizing plate) saponified in Example B-9. Further, the same polyvinyl alcohol-adhesive agent was used to attach the other side of the polarizing film with the triacetylcellulose side of the saponified optically-compensated film.

(Evaluation of Image Display Device)

Transmissive type, reflective type or semi-transmissive type liquid crystal display devices based on the TN, STN, IPS, VA or OCB mode in which the thus prepared polarizing plate of the present invention was attached so that an anti-reflection film arrayed on the first surface of the display was more excellent in contrast in a bright room than a liquid display device equipped with a polarizing plate on which the optically compensated film was not used, provided with a very wide field angle at every respect, excellent anti-reflective performance as well as excellent visibility and display quality.

The effect was particularly remarkable in the VA mode.

### Example B-12

In preparing the anti-reflection film 109 in the embodiment B-1, the coating solution for a low refractive layer was changed to the formulation of the following LL-61 and coated at a coating speed of 25 m/min by using the following die coater.

After being dried at 90° C. for 30 seconds, an air-cooled metal halide lamp (manufactured by Eye Graphics Co., Ltd.) (240 W/cm) was used to conduct UV irradiation at illuminance of 600 mW/cm² and irradiance of 400 mJ/cm² under nitrogen purge so as to give the oxygen concentration of 0.1% by volume or less, thereby forming a low refractive layer (refractive index of 1.45, film thickness of 83 nm). The anti-reflection film (11-1) was prepared accordingly.

Anti-reflection films of (11-2) to (11-5) were prepared by changing coating solutions for a low refractive layer to LL-62 to 65.

(Constitution of Dye Coater)

The slot die 13 was 0.5 mm in up-stream lip land length of I_{UP}, 50 μm in lower-stream lip land length of I_{LO}, and the slot 16 was 50 mm in length and 150 μm in length in the web-running direction of an opening. A clearance between the up-stream lip land 18a and the web was made longer by 50 μm than a clearance between the down-stream lip land 18b and the web (hereinafter referred to as overbite length 50 μm), and clearance G_{L} between the down-stream lip land 18b and the web was established to be 50 μm. Further, clearance Gₛ between the side plate 40b in the decompression chamber 40 and the web and clearance G_{B} between the back plate 40a and the web were both established to be 200 μm.

(Preparation of Coating Solution (LL-61) for Low Refractive Layer)

A solution in which the copolymer P-3 described in Japanese Published Unexamined Patent Application No. 2004-45462 was dissolved in methyl ethyl ketone so as to give 23.7% by mass concentration, 152.4 parts by mass, terminal methacrylate group-containing silicone resin X-22-164C (manufactured by Shin-Etsu Chemical Co., Ltd.), 1.1 parts by mass, photo radical initiator, Irgacure 907 (manufactured by Ciba Specialty Chemicals), 1.8 parts by mass, methyl ethyl ketone, 815.9 parts by mass, and cyclohexanone, 28.8 parts by mass were added and agitated. A PTFE filter with a pore diameter of 0.45 μm was used to conduct filtration to prepare a coating solution (LL-61) for a low refractive layer. The coating solution was 0.61 [mPa·sec] in viscosity and 24 [mN/m] in surface tension. An amount of the coating solution to be applied on a transparent substrate was 2.8 [mL/m²].

(Preparation of Coating Solution (LL-62) for Low Refractive Layer)

A solution in which the above copolymer P-3 was dissolved in methyl ethyl ketone so as to give 23.7% by mass concentration, 426.6 parts by mass, terminal methacrylate group-containing silicone resin X-22-164C (manufactured by Shin-Etsu Chemical Co., Ltd.), 3.0 parts by mass, photo radical initiator, Irgacure 907 (manufactured by Ciba Speciality Chemicals), 5.1 parts by mass, methyl ethyl ketone, 538.6 parts by mass and cyclohexanone, 26.7 parts by mass, were added and agitated. A PTFE filter with a pore diameter of 0.45 μm was used to conduct filtration to prepare a coating solution (LL-62) for a low refractive layer. The coating solution was 1.0 [mPa·sec] in viscosity and 24 [mN/m] in surface tension. An amount of the coating solution to be applied on a transparent substrate was 1.5 [mL/m²].

(Preparation of Coating Solution (LL-63) for Low Refractive Layer)

A solution in which the above copolymer P-3 was dissolved in methyl ethyl ketone so as to give 23.7% by mass concentration, 213.3 parts by mass, terminal methacrylate group-containing silicone resion X-22-164C (manufactured by Shin-Etsu Chemical Co., Ltd.), 1.5 parts by mass, photo radical initiator, Irgacure 907 (manufactured by Ciba Speciality Chemicals), 2.5 parts by mass, methyl ethyl ketone, 754.3 parts by mass and cyclohexanone, 28.4 parts by mass, were added and agitated. A PTFE filter with a pore diameter of 0.45 μm was used to conduct filtration to prepare a coating solution (LL-63) for a low refractive layer. The coating solution was 0.76 [mPa·sec] in viscosity and 24 [mN/m] in surface tension. An amount of the coating solution to be applied on a transparent substrate was 2.0 [mL/m²].

(Preparation of Coating Solution (LL-64) for Low Refractive Layer)

A solution in which the above copolymer P-3 was dissolved in methyl ethyl ketone so as to give 23.7% by mass concentration, 85.3 parts by mass, terminal methacrylate group-containing silicone resin X-22-164C (manufactured by Shin-Etsu Chemical Co., Ltd.), 0.6 parts by mass, photo radical initiator, Irgacure 907 (manufactured by Ciba Specialty Chemicals), 1.0 parts by mass, methyl ethyl ketone, 883.7 parts by mass, and cyclohexanone 29.3 parts by mass were added and agitated. A PTFE filter with a pore diameter of 0.45 μm was used to conduct filtration to prepare a coating solution (LL-64) for a low refractive layer. The coating solution was 0.49 [mPa·sec] in viscosity and 24 [mN/m] in surface tension. An amount of the coating solution to be applied on a transparent substrate was 5.0 [mL/m²].

(Preparation of Coating Solution (LL-65) for Low Refractive Layer)

A solution in which the above copolymer P-3 was dissolved in methyl ethyl ketone so as to give 23.7% by mass concentration, 71.1 parts by mass, terminal methacrylate group-containing silicone resin X-22-164C (manufactured by Shin-Etsu Chemical Co., Ltd.), 0.5 parts by mass, photo radical irradiator, Irgacure 907 (manufactured by Ciba Specialty Chemicals), 0.8 parts by mass, methyl ethyl ketone 898.1 parts by mass and cyclohexanone, 29.5 parts by mass, were added and agitated. A PTFE filter with a pore diameter of 0.45 μm was used to conduct filtration to prepare a coating solution (LL-65) for a low refractive layer. The coating solution was 0.46 [mPa·sec] in viscosity and 24 [mN/m] in surface tension. An amount of the coating solution to be applied on a transparent substrate was 6.0 [mL/m²].

Evaluation was made for the surface state of the anti-reflection films (11-1) to (11-5) which was made by using the coating solutions for a low refractive layer, the formulation of which was changed to LL-61 to LL-65. The results are shown in Table 21. The coating solution was able to be applied where the coating solution to be applied on a transparent substrate was 2 mL/m² or more. However, it was not able to be applied all over the surface uniformly in an amount of 1.5 ml/m², thus resulting in failure in preparing anti-reflection films. Further, the coating solution was able to be applied where the coating solution to be applied on a transparent substrate was 6 mL/m², but drying was not conducted in a timely manner due to a larger amount of the coating solution, resulting in development of vertical streaks all over the surface due to drying-related air.

The thus obtained anti-reflection films (11-1), (11-3) and (11-4) were used to prepare display devices according to the procedures similar to those of Example B-11. These devices were lower in frequency of developing non-uniform color than those of Example B-11 prepared by using a gravure coater, and better in quality.

TABLE 21

| | | | | Application of | |
|---|---|---|---|---|---|
| | Coating | | | coating | Surface state |
| | solution for | | Coated | solution, | of |
| Anti-reflection | low-refractive | Viscosity | amount | acceptable or | anti-reflection |
| film | layer | (mPa · sec) | (mL/m²) | not | film |
| 11-1 | LL-61 | 0.61 | 2.8 | ∘ | ∘ |
| 11-2 | LL-62 | 1 | 1.5 | x | x |
| 11-3 | LL-63 | 0.76 | 2.0 | ∘ | ∘ |
| 11-4 | LL-64 | 0.49 | 5.0 | ∘ | ∘ |
| 11-5 | LL-65 | 0.46 | 6.0 | ∘ | x |

### Example B-13

Anti-reflection films (12-1) to (12-4) were prepared similarly as in the anti-reflection film (11-1), except that the down-stream lip land length I_{LO} was changed to 10 μm, 30 μn, 100 μm or 120 μm. The results are shown in Table 22. Where the down-stream lip land length was in the range of 30 μm to 100 μm, anti-reflection films free of surface defect were obtained. In the anti-reflection film (12-1) streak-like irregularities developed in the longitudinal direction of the base. In the anti-reflection film (12-4), the bead 14a was not formed at a speed similar to that of the anti-reflection film (11-1), resulting in a failure of coating. After the coating speed was reduced by half, coating was able to be conducted, but streak-like irregularities developed in the longitudinal direction of the base. The anti-reflection films (12-2) and (12-3) were used to prepare display devices similarly as in Example B-11. These devices were quite small in reflection of the background, extremely reduced in color of reflected light and also secured for uniformity inside the display surface, and therefore quite high in quality. In contrast, the anti-reflection films (12-1) and (12-4) were used to prepare devices similarly as in Example B-11. These devices developed macroscopically visible non-uniform color inside the displays, and were therefore not high in quality.

TABLE 22

| Anti- | Down-stream | Overbite | Surface state |
|---|---|---|---|
| reflection | lip land | length LO | of anti- |
| film | length I_{LO} (μm) | (μm) | reflection film |
| (12-1) | 10 | 50 | x |
| (12-2) | 30 | 50 | ∘ |
| (12-3) | 100 | 50 | ∘ |
| (12-4) | 120 | 50 | x |

### Example B-14

Anti-reflection films (13-1) to (13-4) were prepared similarly as in the anti-reflection film (11-1), except that the overbite length LO of the die coater was changed to 0 μm, 30 μm, 120 μm or 150 μm. The results are shown in Table 23. Where the overbite length was in the range of 30 μm to 120 μm, anti-reflection films free of surface defect were obtained. In the anti-reflection film (13-1) coating was possible but irregularities of the coated surface developed in the width direction of the base. In the anti-reflection film (13-4) the bead 14a was not formed at a speed similar to that of the anti-reflection film (13-1) to result in a failure of the coating. After the coating speed was reduced by half, coating was able to be conducted, but streak-like irregularities developed in the longitudinal direction of the base. The anti-reflection films (13-2) and (13-3) were used to prepare display devices similarly as in Example B-11. These devices were quite small in reflection of the background, extremely reduced in color of reflected light and also secured for uniformity inside the display surface, and therefore quite high in quality. In contrast, the anti-reflection films (13-1) and (13-4) were used to prepare devices similarly as in Example B-11. These devices developed visible non-uniform color inside the displays, and were therefore not high in quality.

TABLE 23

| Anti- | Down-stream | Overbite | Surface state |
|---|---|---|---|
| reflection | lip land | length LO | of anti- |
| film | length I_{LO} (μm) | (μm) | reflection film |
| (13-1) | 50 | 0 | x |
| (13-2) | 50 | 30 | ∘ |
| (13-3) | 50 | 120 | ∘ |
| (13-4) | 50 | 150 | x |

### Example of Layer Forming Method (III)

### Example C-1

(Preparation of Coating Solution for Hard-Coat Layer)

The following compositions were put into a mixing tank and agitated to give a coating solution for a hard-coat layer.

Polyglycidyl methacrylate of mass-average molecular weight 15000, 270.0 parts by mass, methyl ethyl ketone, 730.0 parts by mass, cyclohexanone 500.0 parts by mass, and photo polymerization initiator (Irgacure 184, manufactured by Ciba Speciality Chemicals), 50.0 parts by mass were added to trimethyrolpropane triacrylate (Viscoat No. 295, manufactured by Osaka Organic Chemical Industry Ltd.), 750.0 parts by weight and agitated. The resultant was filtered through a polypropylene filter with a pore diameter of 0.4 μm to prepare a coating solution for a hard-coat layer. Glycidyl methacrylate (manufactured by Daicel Chemical Industries, Ltd.) was dissolved in methyl ethylketone (MEK), thermal polymerization initiator (V-65, manufactured by Wako Pure Chemical Industries Ltd.) was dropped to conduct the reaction at 80° C. for two hours, the thus obtained reaction solution was dropped to hexane, and the precipitate was dried under reduced pressure to obtain polyglycidyl methacrylate.

(Preparation of Dispersing Solution of Titanium Dioxide Fine Particles)

Titanium dioxide fine particles (MPT-129C, manufactured by Ishihara Sangyo Kaisha, Ltd. TiO₂:Co₃O₄:Al₂O₃:ZrO₂=90.5:3.0:4.0:0.5, mass ratio) which contained cobalt and underwent surface-treatment with aluminum hydroxide and zirconium hydroxide were used as titanium dioxide fine particles.

The following dispersing agent, 41.1 parts by mass, and cyclohexanone, 701.8 parts by mass, were added to the above particles, 257.1 parts by mass, and the resultant was dispersed by using a dynomill to prepare titanium dioxide dispersing solution with a weight mean pore diameter of 70 nm. 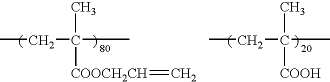
(Preparation of Coating Solution for Moderate Refractive Layer)

A mixture of dipentaerythritol pentaacrylate and dipentaerythritol hexaacrylate (DPHA, manufactured by Nippon Kayaku Co., Ltd), 68.0 parts by mass, photo polymerization initiator (Irgacure 907, manufactured by Ciba Specialty Chemicals), 3.6 parts by mass, photosensitizing agent (Kayacure-DETX, manufactured by Nippon Kayaku Co., Ltd.), 1.2 parts by mass, methyl ethyl ketone 279.6 parts by mass and cyclohexanone, 1049.0 parts by mass, were added to the above titanium dioxide dispersing solution, 99.1 parts by mass and agitated. After a sufficient agitation, the resultant was filtered through a polypropylene filter with a pore diameter of 0.4 μm to prepare a coating solution for a moderate refractive layer.

(Preparation of Coating Solution for a High Refractive Layer)

A mixture of dipentaerythritol penta acrylate and dipentaerythritol hexaacrylate (DPHA, manufactured by Nippon Kayaku Co., Ltd.), 40.0 parts by mass, photo polymerization initiator (Irgacure 907, manufactured by Ciba Specialty Chemicals), 3.3 parts by mass; photosensitizing agent (Kayacure-DETX, manufactured by Nippon Kayaku Co., Ltd.), 1.1 parts by mass, methyl ethyl ketone, 526.2 parts by mass and cyclohexanone, 459.6 parts by mass, were added to the above titanium dioxide dispersing solution, 469.8 parts by mass, and agitated. The resultant was filtered through a polypropylene filter with a pore diameter of 0.4 μm to prepare a coating solution for a high refractive layer.

(Preparation of Coating Solution for Low Refractive Layer)

The copolymer P-3 described in Japanese Published Unexamined Patent Application No. 2004-45462 was added to methyl isobutyl ketone so as to give 7% by mass concentration, silicone resin X-22-164C (manufactured by Shin-Etsu Chemical Co., Ltd.) containing terminal methacrylate group and the foregoing photo radical initiator Irgacure 907 (trade name) were added respectively at 3% and 5% by mass in relation to the solid content to prepare a coating solution for a low refractive layer.

(Preparation of Anti-Reflection Film 101)

A coating solution for a hard-coat layer was coated by using a gravure coater on triacetylcellulose film (TD80UF, manufactured by Fuji Photo Film Co., Ltd.) with a film thickness of 80 μm. After being dried at 100° C., an air-cooled metal halide lamp (manufactured by Eye Graphics Co., Ltd.) with 160 W/cm was used to conduct UV irradiation at irradiance of 300 mJ/cm² and illuminance of 400 mW/cm² so as to give the oxygen concentration of not more than 1.0% by volume under nitrogen purge, thereby curing a coated layer to form a 8 μm-thick hard-coat layer.

The coating solution for a moderate refractive layer, coating solution for a high refractive layer and coating solution for a low refractive layer were continuously coated at a speed of 30 m/min on a hard-coat layer by using a gravure coater equipped with three coating stations.

The moderate refractive layer was dried at 90° C. for 30 seconds and subjected to UV irradiation at irradiance of 400 mJ/cm² and illuminance of 400 mW/cm² by using an air-cooled metal halide lamp (manufactured by Eye Graphics Co., Ltd.) with 180 W/cm so as to give the oxygen concentration not more than 1.0% by volume under nitrogen purge.

The moderate refractive layer after curing was 1.630 in refractive index and 67 nm in film thickness.

The high refractive layer was dried at 90° C. for 30 seconds and subjected to UV irradiation at irradiance of 400 mJ/cm² and illuminance of 600 mW/cm² by using an air-cooled metal halide lamp (manufactured by Eye Graphics Co., Ltd.) with 240 W/cm so as to give the oxygen concentration of not more than 1.0% by volume under nitrogen purge.

The high refractive layer after curing was 1.905 in refractive index and 107 mm in film thickness.

The low refractive layer was dried at 90° C. for 30 seconds and subjected to UV irradiation at irradiance of 600 mJ/cm² and illuminance of 600 mW/cm² by using an air-cooled metal halide lamp (manufactured by Eye Graphics Co., Ltd.) with 240 W/cm so as to give the oxygen concentration below 1.0% by volume under nitrogen purge (nitrogen gas was used at rate of 1.40 m³/min in an 0.2 m³ reaction chamber).

The low refractive layer after curing was 1.440 in refractive index and 85 nm in film thickness. The anti-reflection film 101 was thus prepared.

The samples No. 102 through 116 were prepared similarly, except only that the curing condition of the low refractive layer was changed as shown in Table 24. A continuing anterior chamber was provided immediately in front of a reaction chamber of UV irradiation, where nitrogen gas was sprayed. A nozzle was positioned so that the nitrogen gas was directly sprayed to the film surface. Further, the reaction chamber and the anterior chamber were adjusted for evacuation of air so that the nitrogen gas flowed out from a web inlet of the anterior chamber. A gap between the web inlet and the surface of the coated layer on the web was set to be 4 mm.

Irradiance of UV irradiation associated with change in coating speed was designed to be kept constant by changing illuminance.

TABLE 24

| | | | | | Retention time of low | |
|---|---|---|---|---|---|---|
| | Presence or absence of | | Quantity of nitrogen | Oxygen | oxygen concentration | |
| Sample | anterior chamber and | Quantity of nitrogen | sprayed in the reaction | concentration on | after state of UV | |
| No. | nitrogen sprayed | sprayed (m³/min) | chamber (m³/min) | UV irradiation (%) | irradiation (sec) | Remarks |
| 101 | Absent | 0 | 1.40 | 0.1 | 0.3 | Comparative |
| | | | | | | example |
| 102 | Present | 0.2 | 1.40 | 0.08 | 0.3 | Comparative |
| | | | | | | example |
| 103 | Present | 0.2 | 1.40 | 0.08 | 1 | Present |
| | | | | | | invention |
| 104 | Present | 0.5 | 1.40 | 0.07 | 1 | Present |
| | | | | | | invention |
| 105 | Present | 0.2 | 1.00 | 1 | 1 | Present |
| | | | | | | invention |
| 106 | Present | 0.2 | 0.70 | 5 | 1 | Comparative |
| | | | | | | example |
| 107 | Present | 0.2 | 1.20 | 0.1 | 1 | Present |
| | | | | | | invention |
| 108 | Present | 0.5 | 0.90 | 0.1 | 1 | Present |
| | | | | | | invention |
| 109 | Absent | 0 | 1.40 | 0.15 | 1 | Present |
| | | | | | | invention |
| 110 | Absent | 0 | 2.00 | 0.13 | 1 | Present |
| | | | | | | invention |
| 111 | Present | 0.2 | 1.40 | 0.09 | 1 | Present |
| | | | | | | invention |
| 112 | Present | 0.5 | 1.40 | 0.08 | 1 | Present |
| | | | | | | invention |
| 113 | Present | 0.2 | 1.20 | 0.10 | 1 | Present |
| | | | | | | invention |
| 114 | Present | 0.5 | 0.90 | 0.10 | 1 | Present |
| | | | | | | invention |
| 115 | Absent | 0 | 1.40 | 0.1 | 1 | Present |
| | | | | | | invention |
| 116 | Absent | 0 | 1.40 | 0.1 | 5 | Present |
| | | | | | | invention |

The obtained films were evaluated for the following items, the results of which are shown in Table 25.

[Specular Reflectivity]

A spectrophotometer V-550 (manufactured by JASCO Corporation) equipped with an adaptor ARV-474 was used to determine the specular reflectivity at an incident angle of 5 degrees and at an emergence angle of −5 degrees in the wavelength from 380 to 780 nm, by which the mean reflectance ratio in the wavelength from 450 to 650 nm was calculated to evaluate the anti-reflection property.

[Pencil Hardness]

The pencil hardness evaluation was made according to the specification of JIS K5400. After an anti-reflection film was kept for two hours at temperature of 25° C. and humidity of 60% RH to adjust the condition, test pencils (H to 5H) specified in JIS S 6006 were used to conduct the test under a 500 g load, from which the following results were obtained. The evaluation was made on the basis of the highest acceptable hardness.

Where no scratch was found or one scratch was found in the valuation based on n=5: acceptable

Where three or more scratches were found in the valuation based on n=5: not acceptable

[Steel-Wool Scratch Resistance]

Steel-wool (No. 0000) was used to conduct rubbing test under a load of 1.96 N/cm² and evaluation was made on the basis of the following five ranks by observing scratches formed after the steel wool was reciprocated 30 times.
A: no scratch was found at all,
B: hardly-visible scratches were found to a slight extent,
C: clearly visible scratches were found,
D: clearly visible scratches were markedly found, and

E: film was peeled off

TABLE 25

| | | | Steel-wool | |
|---|---|---|---|---|
| Sample | Reflectance | | rubbing | |
| No. | ratio (%) | Pencil hardness | resistance | Remarks |
| 101 | 0.32 | 2H-3H | D | Comparative |
| | | | | example |
| 102 | 0.32 | 2H-3H | DC | Comparative |
| | | | | example |
| 103 | 0.32 | 3H | B | Present invention |
| 104 | 0.32 | 3H-4H | B-A | Present invention |
| 105 | 0.32 | 2H-3H | C | Present invention |
| 106 | 0.32 | 2H | E | Comparative |
| | | | | example |
| 107 | 0.32 | 3H | C-B | Present invention |
| 108 | 0.32 | 3H | B | Present invention |
| 109 | 0.32 | 2H-3H | C | Present invention |
| 110 | 0.32 | 2H-3H | C | Present invention |
| 111 | 0.32 | 3H | B | Present invention |
| 112 | 0.32 | 3H-4H | B-A | Present invention |
| 113 | 0.32 | 3H | C-B | Present invention |
| 114 | 0.32 | 3H | B | Present invention |
| 115 | 0.32 | 2H-3H | C | Present invention |
| 116 | 0.32 | 3H | C-B | Present invention |

Anti-reflection films prepared under the curing conditions of the present invention were found to have an excellent abrasion/scratch resistance, while keeping a sufficient anti-reflection performance. It was also found that nitrogen purge would provide better abrasion/scratch resistance even at the same oxygen concentration in the reaction chamber.

### Example C-2

The samples No. 117 through 119 (similarly prepared as the sample No. 103 except for elevation of the temperature) and samples No. 120 through 122 (similarly prepared as the sample No. 115 except for elevation of the temperature) were prepared similarly as in the samples No. 103 and 115 of Example C-1, except only that surface temperatures of the films on UV irradiation were elevated, and evaluated similarly.

The surface temperatures were adjusted by changing the temperature of a metal plate contacting with the back face of the films.

TABLE 26

| Sam- | | | | Steel-wool | |
|---|---|---|---|---|---|
| ple | Temperature on | Reflectance | Pencil | rubbing | |
| No. | UV irradiation | ratio (%) | hardness | resistance | Remarks |
| 103 | Not heated | 0.32 | 3H | B | Present |
| | | | | | invention |
| 117 | 40° C. | 0.32 | 3H | B | Present |
| | | | | | invention |
| 118 | 60° C. | 0.32 | 3H-4H | B-A | Present |
| | | | | | invention |
| 119 | 80° C. | 0.32 | 4H | A | Present |
| | | | | | invention |
| 115 | Not heated | 0.32 | 2H-3H | C | Present |
| | | | | | invention |
| 120 | 40° C. | 0.32 | 2H-3H | C | Present |
| | | | | | invention |
| 121 | 60° C. | 0.32 | 3H | C-B | Present |
| | | | | | invention |
| 122 | 80° C. | 0.32 | 3H | B | Present |
| | | | | | invention |

In the present invention, better abrasion/scratch resistance was obtained when the temperature on UV irradiation was elevated to 60° C. or higher.

### Example C-3

The samples No. 123 to 126 of Table 27 were prepared similarly as in the sample No. 103 of Example C-1, except for a change in the number of fractionated UV irradiation and conditions of nitrogen replacement during the irradiation (presence or absence of nitrogen replacement).

These samples were evaluated similarly as in Example C-1. When UV irradiation was fractionated, illuminance was adjusted so as to keep a total irradiance constant. The results are shown n Table 28.

It was found that reduction in abrasion/scratch resistance was prevented and a higher productivity was secured by keeping the oxygen concentration to 3% by volume or lower during the UV irradiation even when UV irradiation was fractionated and illuminance/time was lowered.

TABLE 27

| | | Nitrogen | Oxygen | |
|---|---|---|---|---|
| | Number of | purge | concentration | |
| Sample | fractionated | during UV | during UV | |
| No. | UV irradiation | irradiation | irradiation (%) | Remarks |
| 103 | Once | — | | Present invention |
| 123 | Twice | Not done | 21% | Present invention |
| 124 | Twice | Done | 10% | Present invention |
| 125 | Twice | Done | 1% | Present invention |
| 126 | Twice | Done | 0.1% | Present invention |

TABLE 28

| | | | Steel-wool | |
|---|---|---|---|---|
| Sample | Reflectance ratio | Pencil | rubbing | |
| No. | (%) | hardness | resistance | Remarks |
| 103 | 0.32 | 3H | B | Present invention |
| 123 | 0.32 | 2H-3H | C | Present invention |
| 124 | 0.32 | 2H-3H | C | Present invention |
| 125 | 0.32 | 3H | B | Present invention |
| 126 | 0.32 | 3H | B | Present invention |

### Example C-4

The samples No. 127 to 130 were prepared similarly as in the sample No. 103 of Example C-1, except that the gap between the inlet of the anterior chamber and the surface of the web as well as flow of nitrogen gas on the inlet side were changed and nitrogen gas for the purge was adjusted for the so that the oxygen concentration inside the reaction chamber for UV irradiation was able to be kept constant at 0.08%. These samples were evaluated similarly as in Example C-1.

It was found that the oxygen concentration was kept low at a small quantity of nitrogen gas by narrowing the gap and adjusting ventilation of air so that nitrogen gas came out slightly from the web inlet side.

TABLE 29

| | | | Quantity of nitrogen | | | | |
|---|---|---|---|---|---|---|---|
| | | Direction | gas for purge in | | | | |
| | | of gas flow | reaction chamber | | | Steel-wool rubbing | |
| Sample No. | Gap width | at web inlet | (m³/min) | Reflectance ratio (%) | Pencil hardness | resistance | Remarks |
| 103 | 4 mm | Blow out | 1.40 | 0.32 | 3H | B | Present |
| | | | | | | | invention |
| 127 | 10 mm | Blow out | 1.70 | 0.32 | 3H | B | Present |
| | | | | | | | invention |
| 128 | 20 mm | Blow out | 2.50 | 0.32 | 3H | B | Present |
| | | | | | | | invention |
| 129 | 4 mm | No flow | 1.50 | 0.32 | 3H | B | Present |
| | | | | | | | invention |
| 130 | 4 mm | Blow in | 1.90 | 0.32 | 3H | B | Present |
| | | | | | | | invention |

### Example C-5

Example C-5 was prepared similarly as in Examples C-1 to 4 by using the copolymer P-1 and P-2 described in Japanese Published Unexamined Patent Application No. 2004-45462 (equivalent mass replacement) respectively in place of fluorine-containing polymer P-3 used in the coating solution for a low refractive layer and evaluated. It was then found that similar effects as those obtained in Examples C-1 to 4 were obtained.

### Example C-6

(Preparation of Coating Solution for Hard-Coat Layer)

The following compositions were put into a mixing tank and agitated to give a coating solution for a hard-coat layer.

Compositions of coating solution for hard-coat layer

| | |
|---|---|
| DeSolite Z7404 (Zirconia fine particles-containing | 100 parts by mass |
| hard-coat composition solution: 60 wt % on solid | |
| basis; Zirconia fine particle content, 70 wt % | |
| on solid basis; mean particle diameter, about | |
| 20 nm; solvent compositions, MIBK:MEK = 9:1, | |
| manufactured by JSR Corporation) | |
| DPHA (UV cure resin: Nippon Kayaku Co., Ltd.) | 31 parts by mass |
| KBM-5103 (silane coupling agent: Shin-Etsu | 10 parts by mass |
| Chemical Co., Ltd.) | |
| KE-P150 (1.5 μm silica particles: Nippon | 8.9 parts by mass |
| Shokubai Co., Ltd.) | |
| MXS-300 (3 μm cross-linked PMMA particles: | 3.4 parts by mass |
| Soken Chemical & Engineering Co., Ltd.) | |
| MEK (methylethyl ketone) | 29 parts by mass |
| MIBK (methylisobutyl ketone) | 13 parts by mass |

(Preparation of Coating Solution for Low Refractive Layer)

A coating solution for a low refractive layer was prepared according to the method similar to that used in Example C-1.

(Preparation of Anti-Reflection Film 501)

Triacetylcellulose film (TD80U, manufactured by Fuji Photo Film Co., Ltd.) was reeled out as a transparent substrate in a roll form, on which the above coating solution for a hard-coat layer was coated by using a 50 mm-across microgravure roll having the gravure pattern of 135 lines per inch and 60 μm in depth and a doctor blade at a transport speed of 10 m/min and dried at 60° C. for 150 seconds, an air-cooled metal halide lamp (manufactured by Eye Graphics Co., Ltd.) (160 W/cm) was then used to conduct UV irradiation at illuminance of 400 mW/cm² and irradiance of 250 mJ/cm² under nitrogen purge, thereby curing the coated layer to form a hard-coat layer 1, which was then reeled up. The gravure roll was adjusted for the rotation number so that the hard-coat layer was given a thickness of 3.6 μm after curing.

The above hard-coat layer-coated transparent substrate was again reeled out, on which the above coating solution for a low refractive layer was coated by using a 50 mm-across microgravure roll having the gravure pattern of 200 lines per inch and 30 μm in depth and a doctor blade at a transport speed of 10 m/min and dried at 90° C. for 30 seconds, an air-cooled metal halide lamp (manufactured by Eye Graphics Co., Ltd.) (240 W/cm) was then used at an oxygen concentration of 0.1% by volume to conduct UV irradiation at illuminance of 600 mW/cm² and irradiance of 400 mJ/cm², thereby forming a low refractive layer, which was then reeled up. The gravure roll was adjusted for the rotation number so that the low refractive layer was given a thickness of 100 nm after curing.

Samples No. 502 to 516 were prepared by changing the curing conditions of the low refractive layer as shown in Table 30.

TABLE 30

| | Presence or | Quantity of | Quantity of nitrogen gas | | Retention time of low | |
|---|---|---|---|---|---|---|
| Sample | absence of | nitrogen spray | purge in the reaction | Oxygen concentration on | oxygen concentration after | |
| No. | nitrogen spray | (m³/min) | chamber (m³/min) | UV irradiation (%) | start of UV irradiation (sec) | Remarks |
| 501 | Absent | 0 | 1.40 | 0.1 | 0.3 | Comparative |
| | | | | | | example |
| 502 | Present | 0.2 | 1.40 | 0.08 | 0.3 | Comparative |
| | | | | | | example |
| 503 | Present | 0.2 | 1.40 | 0.08 | 1 | Present |
| | | | | | | invention |
| 504 | Present | 0.5 | 1.40 | 0.07 | 1 | Present |
| | | | | | | invention |
| 505 | Present | 0.2 | 1.00 | 1 | 1 | Present |
| | | | | | | invention |
| 506 | Present | 0.2 | 0.70 | 5 | 1 | Comparative |
| | | | | | | example |
| 507 | Present | 0.2 | 1.20 | 0.1 | 1 | Present |
| | | | | | | invention |
| 508 | Present | 0.5 | 0.90 | 0.1 | 1 | Present |
| | | | | | | invention |
| 509 | Absent | 0 | 1.40 | 0.15 | 1 | Present |
| | | | | | | invention |
| 510 | Absent | 0 | 2.00 | 0.13 | 1 | Present |
| | | | | | | invention |
| 511 | Present | 0.2 | 1.40 | 0.09 | 1 | Present |
| | | | | | | invention |
| 512 | Present | 0.5 | 1.40 | 0.08 | 1 | Present |
| | | | | | | invention |
| 513 | Present | 0.2 | 1.20 | 0.10 | 1 | Present |
| | | | | | | invention |
| 514 | Present | 0.5 | 0.90 | 0.10 | 1 | Present |
| | | | | | | invention |
| 515 | Absent | 0 | 1.40 | 0.1 | 1 | Present |
| | | | | | | invention |
| 516 | Absent | 0 | 1.40 | 0.1 | 5 | Present |
| | | | | | | invention |

These samples were evaluated similarly as in Example C-1, the results of which are shown in Table 31.

Anti-reflection films prepared according to the method of the present invention were found to have excellent abrasion/scratch resistance, while keeping the anti-reflection performance.

TABLE 31

| | | | Steel-wool | |
|---|---|---|---|---|
| Sample | Reflectance ratio | Pencil | rubbing | |
| No. | (%) | hardness | resistance | Remarks |
| 501 | 1.50 | 2H-3H | D | Comparative |
| | | | | example |
| 502 | 1.50 | 2H-3H | DC | Comparative |
| | | | | example |
| 503 | 1.50 | 3H | B | Present invention |
| 504 | 1.50 | 3H-4H | B-A | Present invention |
| 505 | 1.50 | 2H-3H | C | Present invention |
| 506 | 1.50 | 2H | E | Comparative |
| | | | | example |
| 507 | 1.50 | 3H | C-B | Present invention |
| 508 | 1.50 | 3H | B | Present invention |
| 509 | 1.50 | 2H-3H | C | Present invention |
| 510 | 1.50 | 2H-3H | C | Present invention |
| 511 | 1.50 | 3H | B | Present invention |
| 512 | 1.50 | 3H-4H | B-A | Present invention |
| 513 | 1.50 | 3H | C-B | Present invention |
| 514 | 1.50 | 3H | B | Present invention |
| 515 | 1.50 | 2H-3H | C | Present invention |
| 516 | 1.50 | 3H | C-B | Present invention |

### Example C-7

Evaluation was made for anti-reflection films prepared by using the following coating solutions A and B for a low refractive layer respectively in place of the coating solutions for a low refractive layer used in Examples C-1 to 6 to confirm similar effects as those found in the present invention.

Use of hollow silica fine particles led to preparation of an anti-reflection film low in reflectance and more excellent in abrasion/scratch resistance.

(Preparation of Sol Solution a)

Methyl ethyl ketone, 120 parts, acryloyloxypropyl trimethoxysilane (KBM-5103, manufactured by Shin-Etsu Chemical Co., Ltd.), 100 parts, diisopropoxy aluminum ethyl acetoacetate (“Kelope EP-12,” manufactured by Hope Chemical Co., Ltd.), 3 parts, were added to a reaction vessel equipped with an agitator and a reflux condenser, and mixed. Ion-exchanged water, 30 parts, was then added and the resultant was allowed to react at 60° C. for 4 hours, and cooled down to room temperature, thereby obtaining a sol solution a. The mass-average molecular weight was 1600, and of compositions higher than oligomer compositions, the compositions with a molecular weight from 1000 to 20000 were 100%. Gas chromatography analysis revealed that acryloyloxypropyltrimethoxysilane resulting from raw materials did not remain at all.

(Preparation of Dispersion Solution of Hollow-Silica Fine Particles)

Acryloyloxypropyl trimethoxysilane (KBM-5103, manufactured by Shin-Etsu Chemical Co., Ltd.), 30 parts, and diisopropoxy aluminum ethyl acetoacetate (“Kelope EP-12,” manufactured by Hope Chemical Co., Ltd.), 1.5 parts, were added to hollow-silica fine particle sol (particle diameter of about 40 to 50 nm, shell thickness of 6 to 8 nm, refractive index of 1.31, concentration (solid basis) of 20%, major solvent of isopropyl alcohol, prepared by changing particle size according to the example 4 disclosed in Japanese Published Unexamined Patent Application No. 2002-79616), 500 parts, and mixed. Then, ion exchange water, 9 parts, was added thereto. After reaction at 60° C. for 8 hours, the resultant was cooled to room temperature, and acetylacetone, 1.8 parts, was added to obtain a dispersion solution of hollow silica. The thus obtained dispersion solution of hollow silica was 18% by mass on solid basis and 1.31 in refractive index after the solvents were dried.

(Preparation of coating solution A for low refractive layer)

| | |
|---|---|
| DPHA | 3.3 g |
| Dispersion solution of hollow silica fine particles | 40.0 g |
| RMS-033 | 0.7 g |
| Irgacure 907 | 0.2 g |
| Sol solution a | 6.2 g |
| Methyl ethyl ketone | 290.6 g |
| Cyclohexanone | 9.0 g |

(Preparation of coating solution B for low refractive layer)

| | |
|---|---|
| DPHA | 1.4 g |
| Copolymer P-3 disclosed in Japanese Published | 5.6 g |
| Unexamined Patent Application No. 2004-45462 | |
| Dispersion solution of hollow silica fine particles | 20.0 g |
| RMS-033 | 0.7 g |
| Irgacure 907 | 0.2 g |
| Sol solution a | 6.2 g |
| Methyl ethyl ketone | 306.9 g |
| Cyclohexanone | 9.0 g |

Compounds used are shown below.

KBM-5103: silane coupling agent (manufactured by Shin-Etsu Chemical Co., Ltd.)

DPHA: mixture of dipentaerythritol pentaacrylate with dipentaerythritol hexaacrylate (manufactured by Nippon Kayaku Co., Ltd.)

RMS-033: reactive silicone (manufactured by Gelest Inc.)

Irgacure 907: photo polymerization initiator (manufactured by Ciba Specialty Chemicals)

### Example C-8

Preparation and evaluation were made for anti-reflection films prepared by using the following coating solutions C for a low refractive layer respectively in place of the coating solutions for a low refractive layer used in Examples C-1 to 7 to confirm similar effects as those found in the present invention. Similar effects were also confirmed in low refractive layers in which Opstar JN7228A (manufactured by JSR Corporation) was replaced with JTA 113 for which its degree of cross linkage was increased with respect to JN7228A, in the same mass quantity.

(Preparation of Sol Solution a)

Methyl ethyl ketone, 120 parts, acryloyloxypropyl trimethoxysilane (KBM-5103 (trade name), manufactured by Shin-Etsu Chemical Co., Ltd.), 100 parts, diisopropoxy aluminum ethyl acetoacetate (“Kelope EP-12,” manufactured by Hope Chemical Co., Ltd.), 3 parts, were added to a reaction vessel equipped with an agitator and a reflux condenser, and mixed. Ion-exchanged water, 30 parts, was then added and the resultant was allowed to react at 60° C. for 4 hours, and cooled down to room temperature, thereby obtaining a sol solution a. The mass-average molecular weight was 1800, and of compositions higher than oligomer compositions, the compositions with molecular weight from 1000 to 20000 were 100%. Gas chromatography analysis revealed that acryloyloxypropyl trimethoxysilane resulting from raw materials did not remain at all.

(Preparation of Coating Solution C for Low Refractive Layer)

The following compositions were put into a mixing tank, agitated, and then filtered through a polypropylene filter with a pore diameter of 1 μm to prepare a coating solution C for a low refractive layer.

Compositions of coating solution C for low refractive layer

| | |
|---|---|
| Opstar JN7228A (composition solution of thermally | 100 parts by mass |
| cross-linked fluorine-containing polymer which | |
| contains polysiloxane and hydroxyl group, | |
| manufactured by JSR Corporation) | |
| MEK-ST (silica dispersion, mean particle diameter | 4.3 parts by mass |
| of 15 nm, manufactured by Nissan | |
| Chemical Industries Ltd.) | |
| MEK-ST with different particle diameter (silica | 5.1 parts by mass |
| dispersion, mean particle diameter | |
| of 45 nm, manufactured | |
| by Nissan Chemical Industries Ltd.) | |
| Sol solution a | 2.2 parts by mass |
| MEK | 15 parts by mass |
| Cyclohexanone | 3.6 parts by mass |

The above coating solution for a low refractive layer was coated by using a 50 mm-across microgravure roll having the gravure pattern of 200 lines per inch and 30 μm in depth and a doctor blade at a transport speed of 10 m/min, dried at 120° C. for 150 seconds and further dried at 140° C. for 12 minutes, an air-cooled metal halide lamp (manufactured by Eye Graphics Co., Ltd.) with 240 W/cm was then used under nitrogen purge to conduct UV irradiation at illuminance 400 mW/cm² and irradiance of 900 mJ/cm², as in Examples C-1 to 7, thereby preparing samples. The gravure roll was adjusted for the rotation number so that the low refractive layer was given a thickness of 100 nm after curing.

### Example C-9

(Preparation of Protective Film for Polarizing Plate)

A saponification solution was prepared in which sodium hydroxide solution (1.5 mol/L) was kept at 50° C.

Diluted sulfuric acid solution (0.005 mol/L) was also prepared.

The above saponification solution was used to give saponification to the surface of the transparent substrate opposite the side having the low refractive layer of the present invention in anti-reflection films prepared respectively in Examples C-1 to 8.

After sodium hydroxide solution on the surface of the saponified transparent substrate was sufficiently washed with water, the surface was washed with the above diluted sulfuric acid solution which was then sufficiently washed away with water, and the surface was thoroughly dried at 100° C.

Evaluation was made for the water contact angle on the surface of the saponified transparent substrate opposite the side having the low refractive layer of the anti-reflection film, finding that the angle was 40 degrees or lower. Protective films for polarizing plate were thus prepared.

(Preparation of Polarizing Plate)

Polyvinyl alcohol film with a thickness of 75 μm (manufactured by Kuraray Co., Ltd.) was submerged for 5 minutes into an aqueous solution consisting of water, 1000 parts by mass; iodine, 7 parts by mass, and potassium iodide,105 parts by mass, by which iodine was adsorbed.

Then, after the film was stretched mono-axially 4.4 times in a longitudinal direction in 4-mass % boric acid solution, it was dried still in a stretched state to prepare a polarizing film.

A polyvinyl alcohol-based adhesive agent was used to attach one side of the polarizing film with saponified triacetylcellulose of the anti-reflection film (protective film for polarizing plate) of the present invention prepared in Examples C-1 to 8. Further, the same polyvinyl alcohol-adhesive agent was used to attach the other side of the polarizing film with the triacetylcellulose film saponified similarly as above.

(Evaluation of Image Display Device)

Transmissive type, reflective type or semi-transmissive type liquid crystal display devices based on the TN, STN, IPS, VA or OCB mode in which the thus prepared polarizing plate of the present invention was attached so that an anti-reflection film arrayed on the first surface of the display was excellent in anti-reflection performance and also quite excellent in visibility. The effect was particularly remarkable in the VA mode.

### Example C-10

(Preparation of Polarizing Plate)

In an optically compensated film (wide-view film SA 12B, manufactured by Fuji Photo Film Co., Ltd.), saponification was given to the surface opposite that having an optically compensated layer under the same conditions as in Example C-9.

A polyvinyl alcohol-based adhesive agent was used to attach one side of the polarizing film prepared in Example C-9 with saponified triacetylcellulose of the anti-reflection films (protective film for polarizing plate) respectively prepared in Examples C-1 to 8. Further, the same polyvinyl alcohol-adhesive agent was used to attach the other side of the polarizing film with the triacetylcellulose side of the saponified optically-compensated film.

(Evaluation of Image Display Device)

Transmissive type, reflective type or semi-transmissive type liquid crystal display devices based on the TN, STN, IPS, VA or OCB mode in which the thus prepared polarizing plate of the present invention was attached so that an anti-reflection film arrayed on the first surface of the display was more excellent in contrast in a bright room than a liquid display device equipped with a polarizing plate on which the optically compensated film was not used, provided with a very wide field angle at every respect, excellent in anti-reflective performance and quite excellent in visibility and display quality. The effect was particularly remarkable in the VA mode.

### Example C-11

In preparing the anti-reflection film 103 prepared in Example C-1, the coating solution for a low refractive layer was changed to the formulation of the following LL-61 and coated at a coating speed of 25 m/min by using the following die coater. After dried at 90° C. for 30 seconds, UV irradiation was conducted under the same conditions as in the anti-reflection film 103, thereby forming a low refractive layer (refractive index of 1.45, film thickness of 83 nm). The anti-reflection film (11-1) was prepared as explained above. Anti-reflection films of (11-2) to (11-5) were prepared by changing coating solutions for a low refractive layer to LL-62 to 65.

(Constitution of Dye Coater)

The slot die 13 was 0.5 mm in up-stream lip land length of I_{UP}, 50 μm in lower-stream lip land length of I_{LO}, and the slot 16 was 50 mm in length and 150 μm in length in the web-running direction of an opening. A clearance between the up-stream lip land 18a and the web was made longer by 50 μm than a clearance between the down-stream lip land 18b and the web (hereinafter referred to as overbite length 50 μm), and clearance G_{L} between the down-stream lip land 18b and the web was established to be 50 μm. Further, clearance Gₛ between the side plate 40b in the decompression chamber 40 and the web and clearance G_{B} between the back plate 40a and the web were both established to be 200 μm.

(Preparation of Coating Solution (LL-61) for Low Refractive Layer)

A solution in which the copolymer P-3 described in Japanese Published Unexamined Patent Application No. 2004-45462 was dissolved in methyl ethyl ketone so as to give 23.7% by mass concentration, 152.4 parts by mass, terminal methacrylate group-containing silicone resin X-22-164C (manufactured by Shin-Etsu Chemical Co., Ltd.), 1.1 parts by mass, photo radical initiator, Irgacure 907 (manufactured by Ciba Speciality Chemicals), 1.8 parts by mass, methyl ethyl ketone, 815.9 parts by mass, and cyclohexanone, 28.8 parts by mass were added and agitated. A PTFE filter with a pore diameter of 0.45 μm was used to conduct filtration to prepare a coating solution (LL-61) for a low refractive layer. The coating solution was 0.61 [mPa·sec] in viscosity and 24 [mN/m] in surface tension. An amount of the coating solution to be applied on a transparent substrate was 2.8 [mL/m²].

(Preparation of Coating Solution (LL-62) for Low Refractive Layer)

A solution in which the above copolymer P-3 was dissolved in methyl ethyl ketone so as to give 23.7% by mass concentration, 426.6 parts by mass, terminal methacrylate group-containing silicone resin X-22-164C (manufactured by Shin-Etsu Chemical Co., Ltd.), 3.0 parts by mass, photo radical initiator, Irgacure 907 (manufactured by Ciba Specialty Chemicals), 5.1 parts by mass, methyl ethyl ketone, 538.6 parts by mass and cyclohexanone, 26.7 parts by mass, were added and agitated. A PTFE filter with a pore diameter of 0.45 μm was used to conduct filtration to prepare a coating solution (LL-62) for a low refractive layer. The coating solution was 1.0 [mPa·sec] in viscosity and 24 [mN/m] in surface tension. An amount of the coating solution to be applied on a transparent substrate was 1.5 [mL/m²].

(Preparation of Coating Solution (LL-63) for Low Refractive Layer)

A solution in which the above copolymer P-3 was dissolved in methyl ethyl ketone so as to give 23.7% by mass concentration, 213.3 parts by mass, terminal methacrylate group-containing silicone resin X-22-164C (manufactured by Shin-Etsu Chemical Co., Ltd.), 1.5 parts by mass, photo radical initiator, Irgacure 907 (manufactured by Ciba Specialty Chemicals), 2.5 parts by mass, methyl ethyl ketone, 754.3 parts by mass and cyclohexanone, 28.4 parts by mass, were added and agitated. A PTFE filter with a pore diameter of 0.45 μm was used to conduct filtration to prepare a coating solution (LL-63) for a low refractive layer. The coating solution was 0.76 [mPa·sec] in viscosity and 24 [mN/m] in surface tension. An amount of the coating solution to be applied on a transparent substrate was 2.0 [mL/m²].

(Preparation of Coating Solution (LL-64) for Low Refractive Layer)

A solution in which the above copolymer P-3 was dissolved in methyl ethyl ketone so as to give 23.7% by mass concentration, 85.3 parts by mass, terminal methacrylate group-containing silicone resin X-22-164C (manufactured by Shin-Etsu Chemical Co., Ltd.), 0.6 parts by mass, photo radical initiator, Irgacure 907 (manufactured by Ciba Specialty Chemicals), 1.0 parts by mass, methyl ethyl ketone, 883.7 parts by mass, and cyclohexanone 29.3 parts by mass, were added and agitated. A PTFE filter with a pore diameter of 0.45 μm was used to conduct filtration to prepare a coating solution (LL-64) for a low refractive layer. The coating solution was 0.49 [mPa·sec] in viscosity and 24 [mN/m] in surface tension. An amount of the coating solution to be applied on a transparent substrate was 5.0 [mL/m²].

(Preparation of Coating Solution (LL-65) for Low Refractive Layer)

A solution in which the above copolymer P-3 was dissolved in methyl ethyl ketone so as to give 23.7% by mass concentration, 71.1 parts by mass, terminal methacrylate group-containing silicone resin X-22-164C (manufactured by Shin-Etsu Chemical Co., Ltd.), 0.5 parts by mass, photo radical irradiator, Irgacure 907 (manufactured by Ciba Specialty Chemicals), 0.8 parts by mass, methyl ethyl ketone 898.1 parts by mass, and cyclohexanone, 29.5 parts by mass, were added and agitated. A PTFE filter with a pore diameter of 0.45 μm was used to conduct filtration to prepare a coating solution (LL-65) for a low refractive layer. The coating solution was 0.46 [mPa·sec] in viscosity and 24 [mN/m] in surface tension. An amount of the coating solution to be applied on a transparent substrate was 6.0 [mL/m²].

Evaluation was made for the surface state of the anti-reflection films (11-1) to (11-5) which was made by using the coating solutions for a low refractive layer, the formulation of which was changed to LL-61 to LL-65. The results are shown in Table 32. The coating solution was able to be applied where the solution to be applied on a transparent substrate 2 mL/m² or more. However, it was not able to be applied all over the surface uniformly in an amount of 1.5 ml/m², thus resulting in failure in preparing an anti-reflection film. Further, the coating solution was able to be applied where the solution to be applied on a transparent substrate was 6 mL/m², but drying was not conducted in a timely manner due to a larger amount of the coating solution, resulting in development of vertical streaks all over the surface due to drying-related air.

[Evaluation of Anti-Reflection Film]

The thus obtained anti-reflection films were evaluated for the surface state. The mean reflectance ratio was also determined similarly as did in Example C-1.

(Surface State)

After a felt pen was used to paint black the back of a whole surface-coated film (1 m²), the coated surface was visually checked for uniformity in density.

o: contrasting density is not obvious

x: contrasting density is obvious

The thus obtained anti-reflection films (11-1), (11-3) and (11-4) were used to prepare display devices according to the procedures similar to those of Examples C-9 and 10. These devices were lower in frequency of developing non-uniform color than those of Examples C-9 and 10 prepared by using a gravure coater, and better in quality.

TABLE 32

| | | | | Application of | | |
|---|---|---|---|---|---|---|
| | Coating | | | coating | | |
| | solution for | | | solution, | Surface state of | |
| Anti-reflection | low-refractive | Viscosity | Coated amount | acceptable or | anti-reflection | Reflectance |
| film | layer | (mPa · sec) | (mL/m²) | not | film | ratio |
| 11-1 | LL-61 | 0.61 | 2.8 | ∘ | ∘ | 0.32% |
| 11-2 | LL-62 | 1 | 1.5 | x | x | * |
| 11-3 | LL-63 | 0.76 | 2.0 | ∘ | ∘ | 0.32% |
| 11-4 | LL-64 | 0.49 | 5.0 | ∘ | ∘ | * |
| 11-5 | LL-65 | 0.46 | 6.0 | ∘ | x | 0.32% |

* Reflectance ratio varied greatly depending on sites, not acceptable

### Example C-12

Anti-reflection films (12-1) to (12-5) were prepared similarly as in the anti-reflection film (11-1), except that the down-stream lip land length I_{LO} was changed to 10 μm, 30 μnm, 70 μm, 100 μm or 120 μm. The results are shown in Table 33. Where the down-stream lip land length was in the range of 30 μm to 100 μm, anti-reflection films free of surface defect were obtained. In the anti-reflection film (12-1) streak-like irregularities developed in the longitudinal direction of the base. In the anti-reflection film (12-5), the bead 14a was not formed at a speed similar to that of the anti-reflection film (12-1), resulting in a failure of coating. After the coating speed was reduced by half, coating was able to be conducted, but streak-like irregularities developed in the longitudinal direction of the base. The anti-reflection films (12-2) and (12-4) were used to prepare display devices similarly as in Examples C-9 and 10. These devices were quite small in reflection of the background, extremely reduced in color of reflected light and also secured for uniformity inside the display surface, and therefore quite high in quality. In contrast, when the anti-reflection films (12-1) and (12-5) were used to prepare devices similarly as in Examples C-9 and 10, these devices developed visible non-uniform color inside the displays, and were therefore not high in quality.

TABLE 33

| | | | Surface state | |
|---|---|---|---|---|
| Anti- | Down-stream | Overbite | of | |
| reflection | lip land length | length LO | anti-reflection | Reflectance |
| film | I_{LO} (μm) | (μm) | film | ratio |
| (12-1) | 10 | 50 | x | * |
| (12-2) | 30 | 50 | ∘ | 0.32% |
| (12-3) | 70 | 50 | ∘ | 0.32% |
| (12-4) | 100 | 50 | ∘ | 0.32% |
| (12-5) | 120 | 50 | x | * |

* Reflectance ratio varied greatly depending on sites, not acceptable

### Example C-13

Anti-reflection films (13-1) to (13-5) were prepared similarly as in the anti-reflection film (11-1), except that the overbite length LO of the die coater was changed to 0 μm, 30 μm, 120 μm and 150 μm. The results are shown in Table 34. Where the overbite length was in the range of 30 μm to 120 μm, anti-reflection films free of surface defect were obtained. In the anti-reflection film (13-1) coating was able to be conducted but irregularities of the coated surface developed in the width direction of the base. In the anti-reflection film (13-5), the bead 14a was not formed at a speed similar to that of the anti-reflection film (13-1), resulting in a failure of the coating. After the coating speed was reduced by half, coating was able to be conducted, but streak-like irregularities developed in the longitudinal direction of the base. The anti-reflection films (13-2) and (13-4) were used to prepare display devices similarly as in Examples C-9 and 10. These devices were quite small in reflection of the background, extremely reduced in color of reflected light and also secured for uniformity inside the display surface, and therefore quite high in quality. In contrast, when the anti-reflection films (13-1) and (13-5) were used to prepare devices similarly as in Examples C-9 and 10, these devices developed visible non-uniform color inside the displays, and were therefore not high in quality.

TABLE 34

| Anti- | Down-stream | Overbite | Surface state of | |
|---|---|---|---|---|
| reflection | lip land length | length | anti-reflection | Reflectance |
| film | I_{LO} (μm) | LO (μm) | film | ratio |
| (13-1) | 50 | 0 | x | * |
| (13-2) | 50 | 30 | ∘ | 0.32% |
| (13-3) | 50 | 70 | ∘ | 0.32% |
| (13-4) | 50 | 120 | ∘ | 0.32% |
| (13-5) | 50 | 150 | x | * |

* Reflectance ratio varied greatly depending on sites, not acceptable

### Example of Layer Forming Method (IV)

### Example D-1

(Preparation of Coating Solution for Hard-Coat Layer)

The following compositions were put into a mixing tank and agitated to give a coating solution for a hard-coat layer.

Polyglycidyl methacrylate of mass-average molecular weight 15000, 270.0 parts by mass; methyl ethyl ketone, 730.0 parts by mass, cyclohexanone 500.0 parts by mass and photo polymerization initiator (Irgacure 184, manufactured by Nihon Ciba-Geigy K.K), 50.0 parts by mass, were added to trimethyrolpropane triacrylate (Viscoat No. 295 (manufactured by Osaka Organic Chemical Industry Ltd.), 750.0 parts by weight, and agitated. The resultant was filtered through a polypropylene filter with a pore diameter of 0.4 μm to prepare a coating solution for a hard-coat layer. Glycidyl methacrylate (manufactured by Daicel Chemical Industries Ltd.) was dissolved in methyl ethylketone (MEK), thermal polymerization initiator (V-65, Wako Pure Chemical Industries Ltd.) was dropped to conduct the reaction at 80° C. for two hours, the thus obtained reaction solution was dropped to hexane, and the precipitate was dried under reduced pressure to obtain polyglycidyl methacrylate.

(Preparation of Dispersing Solution of Titanium Dioxide Fine Particles)

Titanium dioxide fine particles (MPT-129C, manufactured by Ishihara Sangyo Kaisha, Ltd. TiO₂:Co₃O₄:Al₂O₃:ZrO₂=90.5:3.0:4.0:0.5 mass ratio) which contained cobalt and underwent surface-treatment with aluminum hydroxide and zirconium hydroxide were used as titanium dioxide fine particles.

The following dispersing agent, 41.1 parts by mass, and cyclohexanone, 701.8 parts by mass, were added to the above particles, 257.1 parts by mass, and the resultant was dispersed by using a dynomill to prepare titanium dioxide dispersing solution with a weight mean pore diameter of 70 nm. 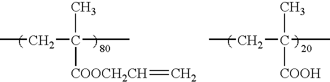
(Preparation of Coating Solution for Moderate Refractive Layer)

A mixture of dipentaerythritol pentaacrylate and dipentaerythritol hexaacrylate (DPHA, manufactured by Nippon Kayaku Co., Ltd), 68.0 parts by mass; photo polymerization initiator (Irgacure 907, manufactured by Ciba Specialty Chemicals), 3.6 parts by mass, photosensitizing agent (Kayacure-DETX, manufactured by Nippon Kayaku Co., Ltd.), 1.2 parts by mass; methyl ethyl ketone 279.6 parts by mass, and cyclohexanone, 1049.0 parts by mass, were added to the above titanium dioxide dispersing solution, 99.1 parts by mass, and agitated. After a sufficient agitation, the resultant was filtered through a polypropylene filter with a pore diameter of 0.4 μm to prepare a coating solution for a moderate refractive layer.

(Preparation of Coating Solution for High Refractive Layer)

A mixture of dipentaerythritol pentaacrylate and dipentaerythritol hexaacrylate (DPHA, manufactured by Nippon Kayaku Co., Ltd.), 40.0 parts by mass, photo polymerization initiator (Irgacure 907, manufactured by Ciba Specialty Chemicals), 3.3 parts by mass, photosensitizing agent (Kayacure-DETX, manufactured by Nippon Kayaku Co., Ltd.), 1.1 parts by mass; methyl ethyl ketone, 526.2 parts by mass and cyclohexanone, 459.6 parts by mass were added to the above titanium dioxide dispersing solution, 469.8 parts by mass, and agitated. The resultant was filtered through a polypropylene filter with a pore diameter of 0.4 μm to prepare a coating solution for a high refractive layer.

(Preparation of Coating Solution for Low Refractive Layer)

The copolymer P-3-1 of the present invention was added to methyl isobutyl ketone so as to give 7% by mass concentration, terminal methacrylate group-containing silicone resin X-22-164C (manufactured by Shin-Etsu Chemical Co., Ltd.) and the foregoing photo radical initiator Irgacure 907 (trade name) were added respectively at 3% and 5% by mass in relation to the solid content to prepare a coating solution for a low refractive layer.

(Preparation of Anti-Reflection Film 101)

A coating solution for a hard-coat layer was coated by using a gravure coater on triacetylcellulose film (TD80UF, manufactured by Fuji Photo Film Co., Ltd.) with a thickness of 80 μm. After being dried at 100° C., an air-cooled metal halide lamp (manufactured by Eye Graphics Co., Ltd.) with 160 W/cm was used to conduct UV irradiation at irradiance of 300 mJ/cm² and illuminance of 400 mW/cm² so as to give the oxygen concentration not more than 1.0% by volume under nitrogen purge, thereby curing a coated layer to form a 8 μm-thick hard-coat layer.

The coating solution for a moderate refractive layer, coating solution for a high refractive layer and coating solution for a low refractive layer were continuously coated on the hard-coat layer at a speed of 5 to 100 m/min by using a gravure coater equipped with three coating stations.

The moderate refractive layer was dried at 90° C. for 30 seconds and subjected to UV irradiation at irradiance of 400 mJ/cm² and illuminance of 400 mW/cm² by using an air-cooled metal halide lamp (manufactured by Eye Graphics Co., Ltd.) with 180 W/cm so as to give the oxygen concentration not more than 1.0% by volume under nitrogen purge.

The moderate refractive layer after curing was 1.630 in refractive index and 67 nm in film thickness.

The high refractive layer was dried at 90° C. for 30 seconds and subjected to UV irradiation at irradiance of 400 mJ/cm² and illuminance of 600 mW/cm² by using an air-cooled metal halide lamp (manufactured by Eye Graphics Co., Ltd.) with 240 W/cm so as to give the oxygen concentration not more than 1.0% by volume under nitrogen purge.

The high refractive layer after curing was 1.905 in refractive index and 107 mm in film thickness.

The low refractive layer was dried at 90° C. for 30 seconds and subjected to UV irradiation at irradiance of 600 mJ/cm² and illuminance of 600 mW/cm² by using an air-cooled metal halide lamp (manufactured by Eye Graphics Co., Ltd.) with 240 W/cm so as to give the oxygen concentration not more than 0.1% by volume under nitrogen purge (nitrogen gas was used at a rate of 1.40 m³/min in an 0.2 m³ reaction chamber).

The low refractive layer after curing was 1.440 in refractive index and 85 nm in film thickness. The anti-reflection film 101 was prepared as above.

The samples No. 102 through 116 were prepared similarly, except only that the curing condition of the low refractive layer was changed as shown in Table 35. A continuing anterior chamber was provided immediately in front of a reaction chamber of UV irradiation, where nitrogen gas was sprayed. A nozzle was positioned so that nitrogen gas was directly sprayed to the film surface. Further, the reaction chamber and the anterior chamber were adjusted for evacuation of air so that the inert gas flowed out from a web inlet of the anterior chamber. A gap between the web inlet and the surface of the coated layer on the web was set to be 4 mm.

The reaction rate was adjusted by changing a time necessary for passing through the low-oxygen zone and an irradiance of UV irradiation.

For the purpose of determining the polymerization reaction rate, only a low refractive layer was coated on polyethylene terephthalate, which was then subjected to drying and UV irradiation under predetermined conditions to prepare a sample. KBr powder was rubbed into the sample and the rubbed KBr powder was thoroughly mixed in a mortar and determined for infrared absorption. The determination was made by using FT-IR model AVATAR360, manufactured by Nicolet Corporation) 40 times to obtain integrated values. A similar determination was also made for another sample not subjected to UV irradiation, and the determination ratio obtained by these two samples was designated as the polymerization rate.

TABLE 35

| | | | | Retention time of low | Polymerization | |
|---|---|---|---|---|---|---|
| | Presence or absence | Quantity of | | oxygen concentration | reaction rate at outlet | |
| | of anterior chamber | nitrogen | Oxygen concentration | after start of UV | of low-oxygen zone | |
| Sample No. | and nitrogen spray | spray (m³/min) | on UV irradiation (%) | irradiation (sec) | (%) | Remarks |
| 101 | Absent | 0 | 0.1 | 0.7 | 60 | Present |
| | | | | | | invention |
| 102 | Absent | 0 | 0.1 | 1.5 | 80 | Present |
| | | | | | | invention |
| 103 | Absent | 0 | 0.1 | 2.5 | 90 | Present |
| | | | | | | invention |
| 104 | Absent | 0 | 0.1 | 0.3 | 40 | Comparative |
| | | | | | | example |
| 105 | Absent | 0 | 1.0 | 1.5 | 60 | Present |
| | | | | | | invention |
| 106 | Absent | 0 | 1.0 | 0.4 | 40 | Comparative |
| | | | | | | example |
| 107 | Absent | 0 | 4.0 | 10.0 | 45 | Comparative |
| | | | | | | example |
| 108 | Absent | 0 | 4.0 | 5.0 | 30 | Comparative |
| | | | | | | example |
| 109 | Present | 0.2 | 0.1 | 0.5 | 60 | Present |
| | | | | | | invention |
| 110 | Present | 0.2 | 0.1 | 1.0 | 80 | Present |
| | | | | | | invention |
| 111 | Present | 0.2 | 0.1 | 2.0 | 90 | Present |
| | | | | | | invention |
| 112 | Present | 0.2 | 0.1 | 0.2 | 40 | Comparative |
| | | | | | | example |
| 113 | Present | 0.5 | 0.1 | 0.7 | 90 | Present |
| | | | | | | invention |
| 114 | Present | 0.5 | 0.1 | 0.2 | 40 | Comparative |
| | | | | | | example |
| 115 | Present | 0.5 | 4.0 | 8.0 | 45 | Comparative |
| | | | | | | example |
| 116 | Present | 0.5 | 4.0 | 4.0 | 35 | Comparative |
| | | | | | | example |

The obtained films were evaluated for the following items, the results of which are shown in Table 36.

[Specular reflectivity]

A spectrophotometer V-550 [manufactured by JASCO Corporation]equipped with an adaptor ARV-474 was used to determine the specular reflectivity at an incident angle of 5 degrees and at an emergence angle of −5 degrees in wavelength from 380 to 780 nm, by which the mean reflectance ratio in wavelength from 450 to 650 nm was calculated to evaluate the anti-reflection property.

[Pencil Hardness]

The pencil hardness evaluation was made according to the specification of JIS K5400. After an anti-reflection film was kept for two hours at temperature of 25° C. and humidity of 60% RH to adjust the condition, test pencils (H to 5H) specified in JIS S6006 were used to conduct the test under a 500 g load, from which the following results were obtained. The evaluation was made on the basis of the highest acceptable hardness.

Where no scratch was found or one scratch was found in the evaluation based on n=5: acceptable

Where three or more scratches were found in the evaluation based on n=5: not acceptable

[Steel-Wool Scratch Resistance]

Steel-wool (No. 0000) was used to conduct rubbing test under a load of 1.96 N/cm² and evaluation was made on the basis of the following five ranks by observing scratches formed after the steel wool was reciprocated 30 times.
A: no scratch was found at all,
B: hardly-visible scratches were found to a slight extent,
C: clearly visible scratches were found,
D: clearly visible scratches were markedly found, and

E: film was peeled off

TABLE 36

| | Reflectance | | Steel-wool | |
|---|---|---|---|---|
| Sample | ratio | | rubbing | |
| No. | (%) | Pencil hardness | resistance | Remarks |
| 101 | 0.32 | 3H | B | Present invention |
| 102 | 0.32 | 3H | B-A | Present invention |
| 103 | 0.32 | 3H-4H | B-A | Present invention |
| 104 | 0.32 | 2H | E | Comparative |
| | | | | example |
| 105 | 0.32 | 3H | C-B | Present invention |
| 106 | 0.32 | 2H | E | Comparative |
| | | | | example |
| 107 | 0.32 | 1H-2H | E | Comparative |
| | | | | example |
| 108 | 0.32 | 1H-2H | E | Comparative |
| | | | | example |
| 109 | 0.32 | 3H-4H | B | Present invention |
| 110 | 0.32 | 3H-4H | B-A | Present invention |
| 111 | 0.32 | 4H | A | Present invention |
| 112 | 0.32 | 2H | E | Comparative |
| | | | | example |
| 113 | 0.32 | 4H | A | Present invention |
| 114 | 0.32 | 2H | E | Comparative |
| | | | | example |
| 115 | 0.32 | 1H-2H | E | Comparative |
| | | | | example |
| 116 | 0.32 | 1H-2H | E | Comparative |
| | | | | example |

Anti-reflection films prepared under the curing conditions of the present invention were found to have an excellent abrasion/scratch resistance, while keeping a sufficient anti-reflection performance. It was also found that nitrogen purge would provide better abrasion/scratch resistance even at the same oxygen concentration in the reaction chamber.

### Example D-2

The samples No. 117 through 119 (similarly prepared as the sample No. 102 except for elevation of the temperature) and the samples No. 120 through 122 (similarly prepared as the sample No. 110 except for elevation of the temperature) were prepared similarly as in samples No. 102 and 110 of Example D-1, except only that surface temperatures of the films on UV irradiation were elevated, and evaluated similarly.

The surface temperatures were adjusted by changing the temperature of a metal plate contacting with the back face of the films.

TABLE 37

| | Temperature | | | Steel-wool | |
|---|---|---|---|---|---|
| Sample | on UV | Reflectance | Pencil | rubbing | |
| No. | irradiation | ratio (%) | hardness | resistance | Remarks |
| 102 | Not heated | 0.32 | 3H | B-A | Present |
| | | | | | invention |
| 117 | 40° C. | 0.32 | 3H | B-A | Present |
| | | | | | invention |
| 118 | 60° C. | 0.32 | 3H-4H | A | Present |
| | | | | | invention |
| 119 | 80° C. | 0.32 | 4H | A | Present |
| | | | | | invention |
| 110 | Not heated | 0.32 | 3H-4H | B-A | Present |
| | | | | | invention |
| 120 | 40° C. | 0.32 | 3H-4H | B-A | Present |
| | | | | | invention |
| 121 | 60° C. | 0.32 | 4H | A | Present |
| | | | | | invention |
| 122 | 80° C. | 0.32 | 4H | A | Present |
| | | | | | invention |

In the present invention, a better abrasion/scratch resistance was obtained by elevating the temperature of the film surface on UV irradiation to 60° C. or higher.

### Example D-3

The samples No. 123 to 126 of Table 38 were prepared similarly as in the sample No. 102 of Example 1, except for a change in the number of fractionated UV irradiation and conditions of nitrogen replacement during UV irradiation (presence or absence of nitrogen replacement). These samples were evaluated similarly as in Example 1.

When UV irradiation was fractionated, illuminance was adjusted so as to keep a total irradiance constant. The results are shown in Table 39.

It was found that the reduction in abrasion/scratch resistance was prevented and a higher productivity was secured by keeping the oxygen concentration to 3% by volume or lower during UV irradiation, even when UV irradiation was fractionated and illuminance for one time was lowered.

TABLE 38

| | | Availability of | Oxygen | | |
|---|---|---|---|---|---|
| | Number of | nitrogen purge | concentration | Reaction rate after | |
| | fractionated UV | during UV | during UV | final UV | |
| Sample No. | irradiation | irradiation | irradiation (%) | irradiation (%) | Remarks |
| 102 | Once | — | | 80 | Present |
| | | | | | invention |
| 123 | Twice | Not available | 21% | 60 | Present |
| | | | | | invention |
| 124 | Twice | Available | 10% | 65 | Present |
| | | | | | invention |
| 125 | Twice | Available | 1% | 70 | Present |
| | | | | | invention |
| 126 | Twice | Available | 0.1% | 80 | Present |
| | | | | | invention |

TABLE 39

| | Reflectance | | Steel-wool | |
|---|---|---|---|---|
| | ratio | Pencil | rubbing | |
| Sample No. | (%) | hardness | resistance | Remarks |
| 102 | 0.32 | 3H | B-A | Present invention |
| 123 | 0.32 | 2H-3H | C | Present invention |
| 124 | 0.32 | 2H-3H | C | Present invention |
| 125 | 0.32 | 3H | B | Present invention |
| 126 | 0.32 | 3H | B-A | Present invention |

### Example D-4

The samples No. 127 to 130 were prepared similarly as in the sample No. 102, except that the gap between the inlet of the anterior chamber and the surface of the web as well as flow of nitrogen gas on the inlet side were changed and nitrogen gas for purge was adjusted for the quantity so that the oxygen concentration inside the reaction chamber of UV irradiation was kept constant at 0.1%. These samples were evaluated similarly as in Example D-1.

It was found that the oxygen concentration was able to be kept low at a small quantity of nitrogen gas by narrowing the gap and adjusting ventilation of air so that nitrogen gas flowed out slightly from the web inlet side.

TABLE 40

| | | | Quantity of | | | | |
|---|---|---|---|---|---|---|---|
| | | | nitrogen gas for | | | | |
| | | Direction of gas | purge in reaction | Reflectance ratio | | Steel-wool | |
| Sample No. | Gap width | flow at web inlet | chamber (m³/min) | (%) | Pencil hardness | rubbing resistance | Remarks |
| 102 | 4 mm | Blow out | 1.40 | 0.32 | 3H | B-A | Present |
| | | | | | | | invention |
| 127 | 10 mm | Blow out | 1.70 | 0.32 | 3H | B-A | Present |
| | | | | | | | invention |
| 128 | 20 mm | Blow out | 2.50 | 0.32 | 3H | B-A | Present |
| | | | | | | | invention |
| 129 | 4 mm | No flow | 1.50 | 0.32 | 3H | B-A | Present |
| | | | | | | | invention |
| 130 | 4 mm | Blow in | 1.90 | 0.32 | 3H | B-A | Present |
| | | | | | | | invention |

### Example D-5

Example D-5 was prepared similarly as in Examples D-1 to 4 by using P-1-1 and P2-1 described in the literature (equivalent mass replacement) respectively in place of fluorine-containing polymers used in the coating solutions for a low refractive layer and evaluated, finding that the similar effects as those obtained in Examples 1 to 4 were obtained.

### Example D-6

(Preparation of Coating Solution for Hard-Coat Layer)

The following compositions were put into a mixing tank and agitated to give a coating solution for a hard-coat layer.

Compositions of coating solution for hard-coat layer

| | |
|---|---|
| DeSolite Z7404 | 100 parts by mass |
| (Zirconia fine particles-containing hard-coat | |
| composition solution: 60 wt % on solid | |
| basis; Zirconia fine particle content, | |
| 70 wt % on solid basis; mean particle diameter, | |
| about 20 nm; solvent compositions, | |
| MIBK:MEK = 9:1, manufactured by JSR | |
| Corporation) | |
| DPHA (UV cure resin: Nippon Kayaku Co., Ltd.) | 31 parts by mass |
| KBM-5103 (silane coupling agent: | 10 parts by mass |
| Shin-Etsu Chemical Co., Ltd.) | |
| KE-P150 (1.5 μm silica particles: | 8.9 parts by mass |
| Nippon Shokubai Co., Ltd.) | |
| MXS-300 (3 μm cross-linked PMMA | 3.4 parts by mass |
| particles: Soken Chemical & Engineering Co., Ltd.) | |
| MEK | 29 parts by mass |
| MIBK | 13 parts by mass |

(Preparation of Coating Solution for Low Refractive Layer)

A coating solution for a low refractive layer was prepared according to the method similar to that used in Example D-1.

(Preparation of Anti-Reflection Film 501)

Triacetylcellulose film (TD80U, manufactured by Fuji Photo Film Co., Ltd.) was reeled out as a transparent substrate in a roll form, on which the above coating solution for a hard-coat layer was coated by using a 50 mm-across microgravure roll having the gravure pattern of 135 lines per inch and 60 μm in depth and a doctor blade at a transport speed of 10 m/min and dried at 60° C. for 150 seconds, an air-cooled metal halide lamp (manufactured by Eye Graphics Co., Ltd.) (160 W/cm) was then used to conduct UV irradiation at illuminance of 400 mW/cm² and irradiance of 250 mJ/cm² under nitrogen purge, thereby curing the coated layer to form a hard-coat layer, which was then reeled up. The gravure roll was adjusted for the rotation number so that the hard-coat layer was given a thickness of 3.6 μm after curing.

The above hard-coat layer-coated transparent substrate was again reeled out, on which the above coating solution for a low refractive layer was coated by using a 50 mm-across microgravure roll having the gravure pattern of 200 lines per inch and 30 μm in depth and a doctor blade at a transport speed of 10 m/min and dried at 90° C. for 30 seconds, an air-cooled metal halide lamp (manufactured by Eye Graphics Co., Ltd.) (240 W/cm) was then used at an oxygen concentration of 0.1% by volume to conduct UV irradiation at illuminance of 600 mW/cm² and irradiance of 400 mJ/cm², thereby forming a low refractive layer, which was then reeled up. The gravure roll was adjusted for the rotation number so that the low refractive layer was given a thickness of 100 nm after curing.

The samples No. 502 to 516 were prepared by changing the curing conditions of the low refractive layer as shown in Table 41.

TABLE 41

| | | | | Retention time of low | Polymerization | |
|---|---|---|---|---|---|---|
| | Presence or absence | | | oxygen concentration | reaction rate at outlet | |
| Sample | of anterior chamber | Quantity of nitrogen | Oxygen concentration | after start of UV | of low-oxygen zone | |
| No. | and nitrogen spray | spray (m³/min) | on UV irradiation | irradiation (sec) | (%) | Remarks |
| 501 | Absent | 0 | 0.1 | 0.7 | 60 | Present |
| | | | | | | invention |
| 502 | Absent | 0 | 0.1 | 1.5 | 80 | Present |
| | | | | | | invention |
| 503 | Absent | 0 | 0.1 | 2.5 | 90 | Present |
| | | | | | | invention |
| 504 | Absent | 0 | 0.1 | 0.3 | 40 | Comparative |
| | | | | | | example |
| 505 | Absent | 0 | 1.0 | 1.5 | 60 | Present |
| | | | | | | invention |
| 506 | Absent | 0 | 1.0 | 0.4 | 40 | Comparative |
| | | | | | | example |
| 507 | Absent | 0 | 4.0 | 10.0 | 45 | Comparative |
| | | | | | | example |
| 508 | Absent | 0 | 4.0 | 5.0 | 30 | Comparative |
| | | | | | | example |
| 509 | Present | 0.2 | 0.1 | 0.5 | 60 | Present |
| | | | | | | invention |
| 510 | Present | 0.2 | 0.1 | 1.0 | 80 | Present |
| | | | | | | invention |
| 511 | Present | 0.2 | 0.1 | 2.0 | 90 | Present |
| | | | | | | invention |
| 512 | Present | 0.2 | 0.1 | 0.2 | 40 | Comparative |
| | | | | | | example |
| 513 | Present | 0.5 | 0.1 | 0.7 | 90 | Present |
| | | | | | | invention |
| 514 | Present | 0.5 | 0.1 | 0.2 | 40 | Comparative |
| | | | | | | example |
| 515 | Present | 0.5 | 4.0 | 8.0 | 45 | Comparative |
| | | | | | | example |
| 516 | Present | 0.5 | 4.0 | 4.0 | 30 | Comparative |
| | | | | | | example |

These samples were evaluated similarly as in Example D-1, the results of which are shown in Table 42.

Anti-reflection films prepared according to the method of the present invention were found to have excellent abrasion/scratch resistance, while keeping the anti-reflection performance.

TABLE 42

| | Reflectance | | Steel-wool | |
|---|---|---|---|---|
| Sample | ratio | | rubbing | |
| No. | (%) | Pencil hardness | resistance | Remarks |
| 501 | 1.50 | 3H | B | Present invention |
| 502 | 1.50 | 3H | B-A | Present invention |
| 503 | 1.50 | 3H-4H | B-A | Present invention |
| 504 | 1.50 | 2H | E | Comparative |
| | | | | example |
| 505 | 1.50 | 3H | C-B | Present invention |
| 506 | 1.50 | 2H | E | Comparative |
| | | | | example |
| 507 | 1.50 | 1H-2H | E | Comparative |
| | | | | example |
| 508 | 1.50 | 1H-2H | E | Comparative |
| | | | | example |
| 509 | 1.50 | 3H-4H | B | Present invention |
| 510 | 1.50 | 3H-4H | B-A | Present invention |
| 511 | 1.50 | 4H | A | Present invention |
| 512 | 1.50 | 2H | E | Comparative |
| | | | | example |
| 513 | 1.50 | 4H | A | Present invention |
| 514 | 1.50 | 2H | E | Comparative |
| | | | | example |
| 515 | 1.50 | 1H-2H | E | Comparative |
| | | | | example |
| 516 | 1.50 | 1H-2H | E | Comparative |
| | | | | example |

### Example D-7

Evaluation was made for anti-reflection films prepared by using the following coating solutions A and B for a low refractive layer respectively in place of the coating solutions for a low refractive layer used in Examples D-1 to 6 to have confirmed similar effects as those found in the present invention.

Use of hollow silica fine particles led to preparation of an anti-reflection film low in reflectance and more excellent in abrasion/scratch resistance.

(Preparation of Sol Solution a)

Methyl ethyl ketone, 120 parts, acryloyloxypropyl trimethoxysilane (KBM-5103, manufactured by Shin-Etsu Chemical Co., Ltd.), 100 parts, diisopropoxy aluminum ethyl acetoacetate (Kelope EP-12, manufactured by Hope Chemical Co., Ltd.), 3 parts, were added to a reaction vessel equipped with an agitator and a reflux condenser, and mixed. Ion-exchanged water, 30 parts, was then added and the resultant was allowed to react at 60° C. for 4 hours, and cooled down to room temperature, thereby obtaining a sol solution a. The mass-average molecular weight was 1600, and of compositions higher than oligomer compositions, the compositions with molecular weight from 1000 to 20000 were 100%. Gas chromatography analysis revealed that acryloyloxypropyl trimethoxysilane resulting from raw materials did not remain at all.

(Preparation of Dispersion Solution of Hollow-Silica Fine Particles)

Acryloyloxypropyl trimethoxysilane (KBM-5103, manufactured by Shin-Etsu Chemical Co., Ltd.), 30 parts, and diisopropoxy aluminum ethyl acetoacetate (Kelope EP-12, manufactured by Hope Chemical Co., Ltd.), 1.5 parts, were added to hollow-silica fine particle sol (particle diameter of about 40 to 50 nm, shell thickness of 6 to 8 nm, refractive index of 1.31, silica concentration (solid basis) of 20%, major solvent of isopropyl alcohol, prepared by changing particle size according to the example 4 disclosed in Japanese Published Unexamined Patent Application No. 2002-79616), 500 parts, and mixed. Then, ion exchange water, 9 parts, was added thereto. After reaction at 60° C. for 8 hours, the resultant was cooled to room temperature, and acetylacetone, 1.8 parts, was added to obtain a dispersion solution of hollow silica. The thus obtained dispersion solution of hollow silica was 18% by mass on a solid basis and 1.31 in refractive index after the solvents were dried.

(Preparation of coating solution A for low refractive layer)

| | |
|---|---|
| DPHA | 3.3 g |
| Dispersion solution of hollow silica fine particles | 40.0 g |
| RMS-033 | 0.7 g |
| Irgacure 907 | 0.2 g |
| Sol solution a | 6.2 g |
| Methyl ethyl ketone | 290.6 g |
| Cyclohexanone | 9.0 g |

(Preparation of coating solution B for low refractive layer)

| | |
|---|---|
| DPHA | 1.4 g |
| Copolymer P-3-1 | 5.6 g |
| Dispersion solution of hollow silica fine particles | 20.0 g |
| RMS-033 | 0.7 g |
| Irgacure 907 | 0.2 g |
| Sol solution a | 6.2 g |
| Methyl ethyl ketone | 306.9 g |
| Cyclohexanone | 9.0 g |

Compounds used are shown below.

KBM-5103: silane coupling agent (manufactured by Shin-Etsu Chemical Co., Ltd.)

DPHA: mixture of dipentaerythritol pentaacrylate with dipentaerythritol hexaacrylate (manufactured by Nippon Kayaku Co., Ltd.)

RMS-033: reactive silicone (manufactured by Gelest Inc.)

Irgacure 907: photo polymerization initiator (manufactured by Ciba Specialty Chemicals)

### Example D-8

(Preparation of Protective Film for Polarizing Plate)

A saponification solution was prepared in which sodium hydroxide solution (1.5 mol/L) was kept at 50° C. Diluted sulfuric acid solution (0.005 mol/L) was also prepared.

The above saponification solution was used to give saponification to the surface of the transparent substrate opposite the side having the low refractive layer of the present invention in anti-reflection films prepared respectively in Examples D-1 to 7.

After sodium hydroxide solution on the surface of the saponified transparent substrate was sufficiently washed with water, the surface was washed with the above diluted sulfuric acid solution which was then sufficiently washed away with water, and the surface was thoroughly dried at 100° C.

Evaluation was made for the water contact angle on the surface of the saponified transparent substrate opposite the side having the low refractive layer of the anti-reflection film, finding that the angle was 40 degrees or lower. Protective films for a polarizing plate were thus prepared.

(Preparation of Polarizing Plate)

Polyvinyl alcohol film with a thickness of 75 μm (manufactured by Kuraray Co., Ltd.) was submerged for 5 minutes into aqueous solution consisting of water, 1000 parts by mass; iodine, 7 parts by mass, and potassium iodide, 105 parts by mass, by which iodine was adsorbed.

Then, after the film was stretched mono-axially 4.4 times in a longitudinal direction in 4-mass % boric acid solution, it was dried still in a stretched state to prepare a polarizing film.

A polyvinyl alcohol-based adhesive agent was used to attach one side of the polarizing film with saponified triacetylcellulose of the anti-reflection film (protective film for polarizing plate) of the present invention. Further, the same polyvinyl alcohol-adhesive agent was used to attach the other side of the polarizing film with the triacetylcellulose film saponified similarly as above.

(Evaluation of Image Display Device)

Transmissive type, reflective type or semi-transmissive type liquid crystal display devices based on TN, STN, IPS, VA or OCB mode in which the thus prepared polarizing plate of the present invention was attached so that an anti-reflection film arrayed on the first surface of the display were excellent in anti-reflection performance and also quite excellent in visibility. The effect was particularly remarkable in the VA mode.

### Example D-9

(Preparation of Polarizing Plate)

In an optically compensated film having an optically-compensated layer (wide-view film SA 12B, manufactured by Fuji Photo Film Co., Ltd.), saponification was given to the surface opposite that having an optically-compensated layer under the same conditions as in Example D-8.

A polyvinyl alcohol-based adhesive agent was used to attach one side of the polarizing film prepared in Example D-8 with saponified triacetylcellulose of the anti-reflection films (protective film for polarizing plate) respectively prepared in Examples D-1 to 7. Further, the same polyvinyl alcohol-adhesive agent was used to attach the other side of the polarizing film with the triacetylcellulose side of the saponified optically-compensated film.

(Evaluation of Image Display Device)

Transmissive type, reflective type or semi-transmissive type liquid crystal display devices based on the TN, STN, IPS, VA or OCB mode in which the thus prepared polarizing plate of the present invention was attached so that an anti-reflection film arrayed on the first surface of the display was more excellent in contrast in a bright room than a liquid display device equipped with a polarizing plate on which the optically compensated film was not used, provided with a very wide field angle at every respect, excellent in anti-reflective performance, and quite excellent in visibility and display quality.

The effect was particularly remarkable in the VA mode.

### Example D-10

In preparing the anti-reflection film 103, the coating solution for a low refractive layer was changed to the formulation of LL-61 and coated at a coating speed of 25 m/min by using the following die coater. After being dried at 90° C. for 30 seconds, UV irradiation was conducted under the same conditions as in the anti-reflection film 103, thereby forming a low refractive layer (refractive index of 1.45, film thickness of 83 nm). The anti-reflection film (10-1) was prepared as explained above.

Anti-reflection films of (10-2) to (10-5) were prepared by changing coating solutions for a low refractive layer to LL-62 to 65.

(Constitution of Dye Coater)

The slot die 13 was 0.5 mm in up-stream lip land length of I_{UP}, 50 μm in lower-stream lip land length of I_{LO}, and the slot 16 was 50 mm in length and 150 μm in length in the web-running direction of an opening. A clearance between the up-stream lip land 18a and the web 12 was made longer by 50 μm than a clearance between the down-stream lip land 18b and the web 12 (hereinafter referred to as overbite length 50 μm), and G_{L}, a clearance between the down-stream lip land 18b and the web 12 was established to be 50 μm. Further, Gₛ, a clearance between the side plate 40b in the decompression chamber 40 and the web 12 and G_{B}, a clearance between the back plate 40a and the web 12 were both established to be 200 μm.

(Preparation of Coating Solution (LL-61) for Low Refractive Layer)

A solution in which the following copolymer was dissolved in methyl ethyl ketone so as to give 23.7% by mass concentration, 152.4 parts by mass, terminal methacrylate group-containing silicone resin X-22-164C (manufactured by Shin-Etsu Chemical Co., Ltd.), 1.1 parts by mass, photo radical initiator, Irgacure 907 (trade name), 1.8 parts by mass, methyl ethyl ketone, 815.9 parts by mass, and cyclohexanone, 28.8 parts by mass were added and agitated. A PTFE filter with a pore diameter of 0.45 μm was used to conduct filtration to prepare a coating solution (LL-61) for a low refractive layer. The coating solution was 0.61 [mPa·sec] in viscosity and 24 [mN/m] in surface tension. An amount of the coating solution to be applied on a transparent substrate was 2.8 [mL/m²]. 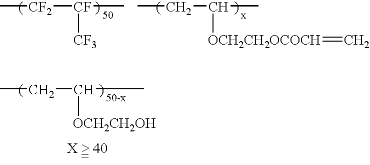
(Preparation of Coating Solution (LL-62) for Low Refractive Layer)

A solution in which the above copolymer was dissolved in methyl ethyl ketone so as to give 23.7% by mass concentration, 426.6 parts by mass, terminal methacrylate group-containing silicone resin X-22-164C (manufactured by Shin-Etsu Chemical Co., Ltd.), 3.0 parts by mass, photo radical initiator, Irgacure 907 (trade name), 5.1 parts by mass, methyl ethyl ketone, 538.6 parts by mass and cyclohexanone, 26.7 parts by mass, were added and agitated. A PTFE filter with a pore diameter of 0.45 μm was used to conduct filtration to prepare a coating solution (LL-62) for a low refractive layer. The coating solution was 1.0 [mPa·sec] in viscosity and 24 [mN/m] in surface tension. An amount of the coating solution to be applied on a transparent substrate was 1.5 [mL/mm²].

(Preparation of Coating Solution (LL-63) for Low Refractive Layer)

A solution in which the above copolymer was dissolved in methyl ethyl ketone so as to give 23.7% by mass concentration, 213.3 parts by mass, terminal methacrylate group-containing silicone resin X-22-164C (manufactured by Shin-Etsu Chemical Co., Ltd.), 1.5 parts by mass, photo radical initiator, Irgacure 907 (trade name), 2.5 parts by mass, methyl ethyl ketone, 754.3 parts by mass and cyclohexanone, 28.4 parts by mass, were added and agitated. A PTFE filter with a pore diameter of 0.45 μm was used to conduct filtration to prepare a coating solution (LL-63) for a low refractive layer. The coating solution was 0.76 [mPa·sec] in viscosity and 24 [mN/m] in surface tension. An amount of the coating solution to be applied on a transparent substrate was 2.0 [mL/m²].

(Preparation of Coating Solution (LL-64) for Low Refractive Layer)

A solution in which the above copolymer was dissolved in methyl ethyl ketone so as to give 23.7% by mass concentration, 85.3 parts by mass, terminal methacrylate group-containing silicone resin X-22-164C (manufactured by Shin-Etsu Chemical Co., Ltd.), 0.6 parts by mass, photo radical initiator, Irgacure 907 (trade name), 1.0 parts by mass, methyl ethyl ketone, 883.7 parts by mass, and cyclohexanone, 29.3 parts by mass, were added and agitated. A PTFE filter with a pore diameter of 0.45 μm was used to conduct filtration to prepare a coating solution (LL-64) for a low refractive layer. The coating solution was 0.49 [mPa·sec] in viscosity and 24 [mN/m] in surface tension. An amount of the coating solution to be applied on a transparent substrate was 5.0 [mL/m²].

(Preparation of Coating Solution (LL-65) for Low Refractive Layer)

A solution in which the above copolymer was dissolved in methyl ethyl ketone so as to give 23.7% by mass concentration, 71.1 parts by mass, terminal methacrylate group-containing silicone resin X-22-164C (manufactured by Shin-Etsu Chemical Co., Ltd.), 0.5 parts by mass, photo radical irradiator, Irgacure 907 (trade name), 0.8 parts by mass, methyl ethyl ketone 898.1 parts by mass and cyclohexanone, 29.5 parts by mass, were added and agitated. A PTFE filter with a pore diameter of 0.45 μm was used to conduct filtration to prepare a coating solution (LL-65) for a low refractive layer. The coating solution was 0.46 [mPa·sec] in viscosity and 24 [mN/m] in surface tension. An amount of the coating solution to be applied on a transparent substrate was 6.0 [mL/m²].

Evaluation was made for the surface state when the coating solutions for a low refractive layer were changed to LL-61 to LL-65. The results are shown in Table 9. The coating solution was able to be applied where the solution to be applied on a transparent substrate was 2 mL/m² or more. However, it was not able to be applied all over the surface uniformly in an amount of 1.5 ml/m², thus resulting in failure in preparing an anti-reflection film. Further, the coating solution was able to be applied where the solutions to be applied on a transparent substrate were 6 mL/m², but drying was not conducted in a timely manner due to a larger amount of the coating solution, resulting in development of vertical streaks all over the surface due to drying-related air.

[Evaluation of Anti-Reflection Film]

Tth thus obtained anti-reflection films were evaluated for the surface state. The mean reflectance ratio was also determined similarly as in Example D-1.

(Surface State)

After a felt pen was used to paint black the back of a whole surface-coated film (1 m²), the coated surface was visually checked for uniformity in density.

o: contrasting density is not obvious

x: contrasting density is obvious

The thus obtained anti-reflection films (10-1), (10-3) and (10-4) were used to prepare display devices according to the procedures similar to those of Examples D-8 and 9. These devices were lower in frequency of developing non-uniform color than those of Examples D-8 and 9 prepared by using a gravure coater, and better in quality.

TABLE 43

| | Coating solution | | | Application of | | |
|---|---|---|---|---|---|---|
| Anti-reflection | for low-refractive | Viscosity | Coated amount | coating solution, | Surface state of | |
| film | layer | (mPa · sec) | (mL/m²) | acceptable or not | anti-reflection film | Reflectance ratio |
| 10-1 | LL-61 | 0.61 | 2.8 | ∘ | ∘ | 0.32% |
| 10-2 | LL-62 | 1 | 1.5 | x | x | * |
| 10-3 | LL-63 | 0.76 | 2.0 | ∘ | ∘ | 0.32% |
| 10-4 | LL-64 | 0.49 | 5.0 | ∘ | ∘ | * |
| 10-5 | LL-65 | 0.46 | 6.0 | ∘ | x | 0.32% |

* Reflectance ratio varied greatly depending on sites, not acceptable

### Example D-11

Anti-reflection films (11-1) to (11-5) were prepared similarly as in the anti-reflection film (10-1), except that the down-stream lip land length I_{LO} was changed to 10 μm, 30 μn, 70 μm, 100 μm or 120 μm. The results are shown in Table 44. Where the down-stream lip land length was in the range of 30 μm to 100 μm, anti-reflection films free of surface defect were obtained. In the anti-reflection film (11-1) streak-like irregularities developed in the longitudinal direction of the base. In the anti-reflection film (11-5), the bead 14a was not formed at the speed similar to that of the anti-reflection film (11-1), resulting in a failure of coating. After the coating speed was reduced by half, coating was able to be conducted, but streak-like irregularities developed in the longitudinal direction of the base. The anti-reflection films (11-2) to (11-4) were used to prepare display devices similarly as in Examples D-8 and 9. These devices were quite small in reflection of the background, extremely reduced in color of reflected light and also secured for uniformity inside the display surface, and therefore quite high in quality. In contrast, when the anti-reflection films (11-1) and (11-5) were used to prepare devices similarly as in Examples D-8 and 9, these devices developed visible non-uniform color inside the displays, and were therefore not high in quality.

TABLE 44

| Anti- | Down-stream lip | Overbite | Surface state of | |
|---|---|---|---|---|
| reflection | land length I_{LO} | length | anti-reflection | Reflectance |
| film | (μm) | LO (μm) | film | ratio |
| (11-1) | 10 | 50 | x | * |
| (11-2) | 30 | 50 | ∘ | 0.32% |
| (11-3) | 70 | 50 | ∘ | 0.32% |
| (11-4) | 100 | 50 | ∘ | 0.32% |
| (11-5) | 120 | 50 | x | * |

* Reflectance ratio varied greatly depending on sites, not acceptable

### Example D-12

Anti-reflection films (12-1) to (12-5) were prepared similarly as in the anti-reflection film (10-1), except that the overbite length LO of the die coater was changed to 0 μm, 30 μm, 120 μm and 150 μm. The results are shown in Table 45. Where the overbite length was in the range of 30 μm to 120 μm, anti-reflection films free of surface defect were obtained. In the anti-reflection film (12-1) coating was able to be conducted but step-like irregularities of the coated surface developed in the width direction of the base. In the anti-reflection film (12-5), the bead 14a was not formed at a speed similar to that of the anti-reflection film (12-1) to result in a failure of the coating. After the coating speed was reduced by half, coating was able to be conducted, but streak-like irregularities developed in the longitudinal direction of the base. The anti-reflection films (12-2) to (12-4) were used to prepare display devices similarly as in Examples D-8 and 9. These devices were quite small in reflection of the background, extremely reduced in color of reflected light and also secured for uniformity inside the display surface, and therefore quite high in quality. In contrast, when the anti-reflection films (12-1) and (12-5) were used to prepare devices similarly as in Examples D-8 and 9, these devices developed visible non-uniform color inside the displays, and were therefore not high in quality.

TABLE 45

| Anti- | Down-stream lip | Overbite | Surface state of | |
|---|---|---|---|---|
| reflection | land length I_{LO} | length | anti-reflection | Reflectance |
| film | (μm) | LO (μm) | film | ratio |
| (12-1) | 50 | 0 | x | * |
| (12-2) | 50 | 30 | ∘ | 0.32% |
| (12-3) | 50 | 70 | ∘ | 0.32% |
| (12-4) | 50 | 120 | ∘ | 0.32% |
| (12-5) | 50 | 150 | x | * |

### Example of Layer Forming Method (V)

### Example E-1

(Preparation of Coating Solution for Hard-Coat Layer)

The following compositions were put into a mixing tank and agitated to give a coating solution for a hard-coat layer.

Polyglycidyl methacrylate of mass-average molecular weight 15000, 270.0 parts by mass, methyl ethyl ketone, 730.0 parts by mass, cyclohexanone 500.0 parts by mass and photo polymerization initiator (Irgacure 184, manufactured by Ciba Specialty Chemicals), 50.0 parts by mass, were added to trimethyrolpropane triacrylate (Viscoat No. 295 (manufactured by Osaka Organic Chemical Industry Ltd.), 750.0 parts by weight, and agitated. The resultant was filtered through a polypropylene filter with a pore diameter of 0.4 μm to prepare a coating solution for a hard-coat layer. Glycidyl methacrylate was dissolved in methyl ethylketone (MEK), thermal polymerization initiator (V-65, manufactured by Wako Pure Chemical Industries Ltd.) was dropped to conduct the reaction at 80° C. for two hours, the thus obtained reaction solution was dropped to hexane, and the precipitate was dried under reduced pressure to obtain polyglycidyl methacrylate.

(Preparation of Dispersing Solution of Titanium Dioxide Fine Particles)

Titanium dioxide fine particles (MPT-129C, manufactured by Ishihara Sangyo Kaisha Ltd. TiO₂:Co₃O₄:Al₂O₃:ZrO₂=90.5:3.0:4.0:0.5 mass ratio) which contained cobalt and underwent surface-treatment with aluminum hydroxide and zirconium hydroxide were used as titanium dioxide fine particles.

The following dispersing agent, 41.1 parts by mass, and cyclohexanone, 701.8 parts by mass, were added to the above particles, 257.1 parts by mass, and the resultant was dispersed by using a dynomill to prepare titanium dioxide dispersing solution with a weight mean pore diameter of 70 nm.

Dispersing Agent 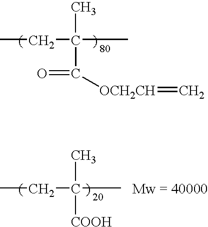
(Preparation of Coating Solution for Moderate Refractive Layer)

A mixture of dipentaerythritol pentaacrylate and dipentaerythritol hexaacrylate (DPHA, manufactured by Nippon Kayaku Co., Ltd), 68.0 parts by mass; photo polymerization initiator (Irgacure 907, manufactured by Ciba Specialty Chemicals), 3.6 parts by mass; photosensitizing agent (Kayacure-DETX, manufactured by Nippon Kayaku Co., Ltd.), 1.2 parts by mass; methyl ethyl ketone 279.6 parts by mass, and cyclohexanone, 1049.0 parts by mass, were added to the above titanium dioxide dispersing solution, 99.1 parts by mass, and agitated. After a sufficient agitation, the resultant was filtered through a polypropylene filter with a pore diameter of 0.4 μm to prepare a coating solution for a moderate refractive layer.

(Preparation of Coating Solution for High Refractive Layer)

A mixture of dipentaerythritol pentaacrylate and dipentaerythritol hexaacrylate (DPHA, manufactured by Nippon Kayaku Co., Ltd.), 40.0 parts by mass; photo polymerization initiator (Irgacure 907, manufactured by Ciba Specialty Chemicals), 3.3 parts by mass, photosensitizing agent (Kayacure-DETX, manufactured by Nippon Kayaku Co., Ltd.), 1.1 parts by mass, methyl ethyl ketone, 526.2 parts by mass, and cyclohexanone, 459.6 parts by mass, were added to the above titanium dioxide dispersing solution, 469.8 parts by mass, and agitated. The resultant was filtered through a polypropylene filter with a pore diameter of 0.4 μm to prepare a coating solution for a high refractive layer.

(Preparation of Coating Solution for Low Refractive Layer)

The copolymer P-3 of the present invention was added to methyl isobutyl ketone so as to give 7% by mass concentration, terminal methacrylate-containing group silicone resin X-22-164C (manufactured by Shin-Etsu Chemical Co., Ltd.) and the foregoing photo radical initiator Irgacure 907 (trade name) were added respectively at 3% and 5% by mass in relation to the solid content to prepare a coating solution for a low refractive layer.

(Preparation of Anti-Reflection Film 101)

A coating solution for a hard-coat layer was coated by using a gravure coater on triacetylcellulose film with thickness of 80 μm (TD80UF, manufactured by Fuji Photo Film Co., Ltd.). After dried at 100° C., an air-cooled metal halide lamp (manufactured by Eye Graphics Co., Ltd.) with 160 W/cm was used to conduct UV irradiation at irradiance of 300 mJ/cm² and illuminance of 400 mW/cm² so as to give the oxygen concentration not more than 1.0% by volume under nitrogen purge, thereby curing a coated layer to form a 8 μm-thick hard-coat layer.

The coating solution for a moderate refractive layer, coating solution for a high refractive layer and coating solution for a low refractive layer were continuously coated on a hard-coat layer at a speed of 5 to 100 m/min by using a gravure coater equipped with three coating stations.

The moderate refractive layer was dried at 90° C. for 30 seconds and subjected to UV irradiation at irradiance of 200 mJ/cm² and illuminance of 200 mW/cm² by using an air-cooled metal halide lamp (manufactured by Eye Graphics Co., Ltd.) with 180 W/cm so as to give the oxygen concentration not more than 1.0% by volume under nitrogen purge.

The moderate refractive layer after curing was 1.630 in refractive index and 67 nm in film thickness.

The high refractive layer was dried at 90° C. for 30 seconds and subjected to UV irradiation at irradiance of 400 mJ/cm² and illuminance of 600 mW/cm² by using an air-cooled metal halide lamp (manufactured by Eye Graphics Co., Ltd.) with 240 W/cm so as to give the oxygen concentration not more than 1.0% by volume under nitrogen purge.

The high refractive layer after curing was 1.905 in refractive index and 107 mm in film thickness.

The low refractive layer was dried at 90° C. for 30 seconds and subjected to UV irradiation at irradiance of 200 mJ/cm² and illuminance of 200 mW/cm² by using an air-cooled metal halide lamp (manufactured by Eye Graphics Co., Ltd.) with 240 W/cm so as to give the oxygen concentration not more than 0.1% by volume under nitrogen purge (nitrogen gas was used at a rate of 1.40 m³/min in an 0.2 m³ reaction chamber).

The low refractive layer after curing was 1.440 in refractive index and 85 nm in film thickness. The anti-reflection film 101 was prepared as above.

The samples No. 102 through 116 were prepared similarly, except that the types of initiators and the curing condition of the low refractive layer were changed as shown in Table 46. Quantities of the initiators were replaced individually on the basis of equivalent quantity. The continuing anterior chamber was provided immediately in front of the reaction chamber of UV irradiation to purge nitrogen gas. Namely, a nozzle was positioned so that the inert gas was directly sprayed to the surface. Further, the reaction chamber and the anterior chamber were adjusted for evacuation of air so that the inert gas flowed out from a web inlet of the anterior chamber. A gap between the web inlet and the web surface was set to be 4 mm.

An irradiance of UV irradiation was kept constant by changing illuminance, when the coating speed was changed.

TABLE 46

| | | | | | | Retention time | |
|---|---|---|---|---|---|---|---|
| | | | | | | of low oxygen | |
| | | Presence or absence | Quantity of | Quantity of nitrogen | Oxygen concentration | concentration | |
| Sample | | of anterior chamber | nitrogen spray | gas for purge in reaction | on UV | after start of UV | |
| No. | Type of initiator | and nitrogen spray | (m³/min) | chamber (m³/min) | irradiation (%) | irradiation (sec) | |
| 101 | Irgacure 907 | Absent | 0 | 1.40 | 0.1 | 0.3 | Comparative |
| | | | | | | | example |
| 102 | Irgacure 907 | Present | 0.2 | 1.40 | 0.08 | 0.3 | Comparative |
| | | | | | | | example |
| 103 | Irgacure 907 | Present | 0.2 | 1.40 | 0.08 | 1 | Comparative |
| | | | | | | | example |
| 104 | Irgacure 907 | Present | 0.5 | 1.40 | 0.07 | 1 | Comparative |
| | | | | | | | example |
| 105 | Examplified | Absent | 0 | 1.40 | 0.1 | 0.3 | Comparative |
| | compound 21 | | | | | | example |
| 106 | Examplified | Present | 0.2 | 1.40 | 0.08 | 0.3 | Comparative |
| | compound 21 | | | | | | example |
| 107 | Examplified | Present | 0.2 | 1.40 | 0.08 | 1 | Present |
| | compound 21 | | | | | | invention |
| 108 | Examplified | Present | 0.5 | 1.40 | 0.07 | 1 | Present |
| | compound 21 | | | | | | invention |
| 109 | Examplified | Absent | 0 | 1.40 | 0.15 | 1 | Present |
| | compound 21 | | | | | | invention |
| 110 | Examplified | Present | 0.2 | 1.0 | 1 | 1 | Present |
| | compound 21 | | | | | | invention |
| 111 | Examplified | Present | 0.2 | 0.7 | 5 | 1 | Comparative |
| | compound 21 | | | | | | example |
| 112 | Examplified | Present | 0.2 | 1.40 | 0.08 | 1 | Present |
| | compound 1 | | | | | | invention |
| 113 | Examplified | Present | 0.2 | 1.40 | 0.08 | 1 | Present |
| | compound 8 | | | | | | invention |
| 114 | Examplified | Present | 0.2 | 1.40 | 0.08 | 1 | Present |
| | compound 11 | | | | | | invention |
| 115 | Examplified | Present | 0.2 | 1.40 | 0.08 | 1 | Present |
| | compound 13 | | | | | | invention |
| 116 | Examplified | Present | 0.2 | 1.40 | 0.08 | 1 | Present |
| | compound 19 | | | | | | invention |

The above exemplified compound 21 and others have been already explained in the present Description as compounds (1 to 21) disclosed in Japanese Published Unexamined Patent Application No. 2000-80068. The exemplified compound 21 in particular was explained again below.
(Exemplified Compound 21)

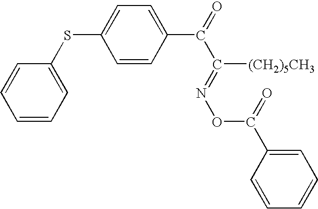

The obtained films were evaluated for the following items, the results of which are shown in Table 47.

[Specular Reflectivity]

A spectrophotometer V-550 [manufactured by JASCO Corporation] equipped with an adaptor ARV-474 was used to determine the specular reflectivity at an incident angle of 5 degrees and at an emergence angle of −5 degrees in the wavelength from 380 to 780 nm, by which the mean reflectance ratio in the wavelength from 450 to 650 nm was calculated to evaluate the anti-reflection property.

[Pencil Hardness]

The pencil hardness evaluation was made according to the specification of JIS K5400. After an anti-reflection film was kept for two hours at a temperature of 25° C. and humidity of 60% RH to adjust the condition, test pencils (H to 5H) specified in JIS S6006 were used to conduct the test under a 500 g load, from which the following results were obtained. The evaluation was made on the basis of the highest acceptable hardness.

Where no scratch was found or one scratch was found in the evaluation based on n=5: acceptable

Where three or more scratches were found in the evaluation based on n=5: not acceptable

[Steel-Wool Scratch Resistance]

Steel-wool (No. 0000) was used to conduct rubbing test under a load of 1.96 N/cm² and evaluation was made on the basis of the following five ranks by observing scratches formed after the steel wool was reciprocated 30 times.
A: no scratch was found at all,
B: hardly-visible scratches were found to a slight extent,
C: clearly visible scratches were found,
D: clearly visible scratches were markedly found, and

E: film was peeled off

TABLE 47

| | | | Steel-wool | |
|---|---|---|---|---|
| | Reflectance | Pencil | rubbing | |
| Sample No. | ratio (%) | hardness | resistance | Remarks |
| 101 | 0.32 | 2H | E | Comparative |
| | | | | example |
| 102 | 0.32 | 2H | E | Comparative |
| | | | | example |
| 103 | 0.32 | 2H | D | Comparative |
| | | | | example |
| 104 | 0.32 | 2H | D | Comparative |
| | | | | example |
| 105 | 0.32 | 2H-3H | D | Comparative |
| | | | | example |
| 106 | 0.32 | 2H-3H | D-C | Comparative |
| | | | | example |
| 107 | 0.32 | 3H-4H | B-A | Present invention |
| 108 | 0.32 | 4H | A | Present invention |
| 109 | 0.32 | 3H | B | Present invention |
| 110 | 0.32 | 2H-3H | C-B | Present invention |
| 111 | 0.32 | 2H | E | Comparative |
| | | | | example |
| 112 | 0.32 | 3H | B | Present invention |
| 113 | 0.32 | 3H | B | Present invention |
| 114 | 0.32 | 3H | B | Present invention |
| 115 | 0.32 | 3H | B | Present invention |
| 116 | 0.32 | 3H | B | Present invention |

Anti-reflection films prepared by using initiators of the present invention under the conditions of the present invention were found to have an excellent abrasion/scratch resistance, while keeping a sufficient anti-reflection performance. It was also found that nitrogen purge would provide a better abrasion/scratch resistance even at the same oxygen concentration in the reaction chamber.

### Example E-2

The samples No. 117 through 122 were prepared similarly as in the samples No. 103 and 107 of Example E-1, only except that surface temperatures of the films were elevated on UV irradiation, and evaluated similarly. The surface temperatures were adjusted by changing the temperature of a metal plate contacting with the back face of the films.

TABLE 48

| Sam- | Temperature | | | Steel-wool | |
|---|---|---|---|---|---|
| ple | on UV | Reflectance | Pencil | rubbing | |
| No. | irradiation | ratio (%) | hardness | resistance | Remarks |
| 103 | Not heated | 0.32 | 2H | D | Comparative |
| | | | | | example |
| 117 | 40° C. | 0.32 | 2H | D | Comparative |
| | | | | | example |
| 118 | 60° C. | 0.32 | 2H-3H | D | Comparative |
| | | | | | example |
| 119 | 80° C. | 0.32 | 3H | D-C | Comparative |
| | | | | | example |
| 107 | Not heated | 0.32 | 3H-4H | B-A | Present |
| | | | | | invention |
| 120 | 40° C. | 0.32 | 3H-4H | B-A | Present |
| | | | | | invention |
| 121 | 60° C. | 0.32 | 3H-4H | A | Present |
| | | | | | invention |
| 122 | 80° C. | 0.32 | 4H | A | Present |
| | | | | | invention |

In the present invention, a better abrasion/scratch resistance was obtained by elevating the temperature on UV irradiation to 60° C. or higher.

### Example E-3

The samples No. 123 to 126 of Table 49 were prepared similarly as in the sample No. 107 of Example E-1, except for a change in the number of fractionated UV irradiation and conditions of nitrogen replacement during UV irradiation (presence or absence of nitrogen replacement). These samples were evaluated similarly as in Example E-1.

When UV irradiation was fractionated, illuminance was adjusted so as to keep a total irradiance constant. The results are shown in Table 50.

It was found that reduction in abrasion/scratch resistance was prevented and a higher productivity was secured by keeping the oxygen concentration to 3% by volume or lower during UV irradiation, even when UV irradiation was fractionated and illuminance for one time was lowered.

TABLE 49

| | | Availability | Oxygen | |
|---|---|---|---|---|
| | Number of | of nitrogen | concentration | |
| Sample | fractionated UV | purge during | during UV | |
| No. | irradiation | UV irradiation | irradiation (%) | Remarks |
| 107 | Once | — | | Present |
| | | | | invention |
| 123 | Twice | Not available | 21% | Present |
| | | | | invention |
| 124 | Twice | Available | 10% | Present |
| | | | | invention |
| 125 | Twice | Available | 1% | Present |
| | | | | invention |
| 126 | Twice | Available | 0.1% | Present |
| | | | | invention |

TABLE 50

| | | | Steel-wool | |
|---|---|---|---|---|
| | Reflectance | Pencil | rubbing | |
| Sample No. | ratio (%) | hardness | resistance | Remarks |
| 107 | 0.32 | 3H-4H | B-A | Present invention |
| 123 | 0.32 | 3H | C-B | Present invention |
| 124 | 0.32 | 3H | C-B | Present invention |
| 125 | 0.32 | 3H-4H | B-A | Present invention |
| 126 | 0.32 | 3H-4H | B-A | Present invention |

### Example E-4

The samples No. 127 to 130 were prepared similarly as in the sample No. 107 of Example E-1, except that the gap between the inlet of the anterior chamber and the web as well as flow of nitrogen gas on the inlet side were changed and nitrogen gas for purge was adjusted for the quantity so that the oxygen concentration inside the chamber of UV irradiation was kept constant at 0.08%. These samples were evaluated similarly as in Example E-1.

It was found that the oxygen concentration was able to be kept low in a small quantity of nitrogen gas by narrowing the gap and adjusting ventilation of air so that nitrogen gas blew out slightly from the web inlet side.

TABLE 51

| | | | Quantity of nitrogen | | | | |
|---|---|---|---|---|---|---|---|
| | | | gas for purge in | | | | |
| | | Direction of glass flow | reaction chamber | Reflectance | | Steel-wool rubbing | |
| Sample No. | Gap width | at web inlet | (m³/min) | ratio (%) | Pencil hardness | resistance | Remarks |
| 107 | 4 mm | Blow out | 1.40 | 0.32 | 3H-4H | B-A | Present |
| | | | | | | | invention |
| 127 | 10 mm | Blow out | 1.70 | 0.32 | 3H-4H | B-A | Present |
| | | | | | | | invention |
| 128 | 20 mm | Blow out | 2.50 | 0.32 | 3H-4H | B-A | Present |
| | | | | | | | invention |
| 129 | 4 mm | no flow | 1.50 | 0.32 | 3H-4H | B-A | Present |
| | | | | | | | invention |
| 130 | 4 mm | Blow in | 1.90 | 0.32 | 3H-4H | B-A | Present |
| | | | | | | | invention |

### Example E-5

Example E-5 was prepared similarly as in Examples E-1 to 4 by using P-1 and P-2 described in the text (equivalent mass replacement) respectively in place of fluorine-containing polymers used in the low refractive layer and evaluated. It was then found that similar effects as in Examples E-1 to 4 were obtained.

### Example E-6

(Preparation of Coating Solution for Hard-Coat Layer)

The following compositions were put into a mixing tank and agitated to give a coating solution for a hard-coat layer.

Compositions of coating solution for hard-coat layer

| | | |
|---|---|---|
| DeSolite Z7404 | 100 | parts by mass |
| (Zirconia fine particles-containing hard-coat | | |
| composition solution: 60 wt % on solid basis; | | |
| Zirconia fine particle content, 70 wt % on solid | | |
| basis; mean particle diameter, about 20 nm; | | |
| solvent compositions, MIBK:MEK = 9:1, | | |
| manufactured by JSR Corporation) | | |
| DPHA (UV cure resin: Nippon Kayaku Co., Ltd.) | 31 | parts by mass |
| KBM-5103 (silane coupling agent: Shin-Etsu | 10 | parts by mass |
| Chemical Co., Ltd.) | | |
| KE-P150 (1.5 μm silica particles: Nippon | 8.9 | parts by mass |
| Shokubai Co., Ltd.) | | |
| MXS-300 (3 μm cross-linked PMMA | 3.4 | parts by mass |
| particles: Soken Chemical & Engineering Co., | | |
| Ltd.) | | |
| Methyl ethyl ketone (MEK) | 29 | parts by mass |
| Methyl isobutyl ketone (MIBK) | 13 | parts by mass |

(Preparation of Coating Solution for Low Refractive Layer)

A coating solution for a low refractive layer was prepared according to the method similar to that used in Example E-1.

(Preparation of Anti-Reflection Film 601)

Triacetylcellulose film (TD80U, manufactured by Fuji Photo Film Co., Ltd.) was reeled out as a transparent substrate in a roll form, on which the above coating solution for a hard-coat layer was coated by using a 50 mm-across microgravure roll having the gravure pattern of 135 lines per inch and 60 μm in depth and a doctor blade at a transport speed of 10 m/min and dried at 60° C. for 150 seconds, an air-cooled metal halide lamp (manufactured by Eye Graphics Co., Ltd.) (160 W/cm) was then used to conduct UV irradiation at illuminance of 400 mW/cm² and irradiance of 250 mJ/cm² under nitrogen purge, thereby curing the coated layer to form a hard-coat layer 1, which was then reeled up. The gravure roll was adjusted for the rotation number so that the hard-coat layer was given a thickness of 3.6 μm after curing.

The above hard-coat layer-coated transparent substrate was again reeled out, on which the above coating solution for a low refractive layer was coated by using a 50 mm-across microgravure roll having the gravure pattern of 200 lines per inch and 30 μm in depth and a doctor blade at a transport speed of 10 m/min and dried at 90° C. for 30 seconds, an air-cooled metal halide lamp (manufactured by Eye Graphics Co., Ltd.) (240 W/cm) was then used at an oxygen concentration of 0.1% by volume to conduct UV irradiation at illuminance of 600 mW/cm² and irradiance of 400 mJ/cm², thereby forming a low refractive layer, which was then reeled up. The gravure roll was adjusted for the rotation number so that the low refractive layer was given a thickness of 100 nm after curing. Where a film was to be heated after UV irradiation, heating was conducted by allowing the film after irradiation to contact with a rotating metal roll into which warm water or pressurized steam was passed.

Samples No. 602 to 616 were prepared by changing the curing conditions of the low refractive layer as shown in Table 52.

TABLE 52

| | | | | Quantity of nitrogen | | | |
|---|---|---|---|---|---|---|---|
| | | | Quantity of | gas for | | | |
| | | Presence or absence of | nitrogen | purge in | Oxygen | Retention time of low | |
| Sample | Type of | anterior chamber and | spray | reaction chamber | concentration on | oxygen concentration after | |
| No. | initiator | nitrogen spray | (m³/min) | (m³/min) | UV irradiation (%) | start of UV irradiation (sec) | |
| 601 | Irgacure 907 | Absent | 0 | 1.40 | 0.1 | 0.3 | Comparative |
| | | | | | | | example |
| 602 | Irgacure 907 | Present | 0.2 | 1.40 | 0.08 | 0.3 | Comparative |
| | | | | | | | example |
| 603 | Irgacure 907 | Present | 0.2 | 1.40 | 0.08 | 1 | Comparative |
| | | | | | | | example |
| 604 | Irgacure 907 | Present | 0.5 | 1.40 | 0.07 | 1 | Comparative |
| | | | | | | | example |
| 605 | Exemplified | Absent | 0 | 1.40 | 0.1 | 0.3 | Comparative |
| | compound 21 | | | | | | example |
| 606 | Exemplified | Present | 0.2 | 1.40 | 0.08 | 0.3 | Comparative |
| | compound 21 | | | | | | example |
| 607 | Exemplified | Present | 0.2 | 1.40 | 0.08 | 1 | Present |
| | compound 21 | | | | | | invention |
| 608 | Exemplified | Present | 0.5 | 1.40 | 0.07 | 1 | Present |
| | compound 21 | | | | | | invention |
| 609 | Exemplified | Absent | 0 | 1.40 | 0.15 | 1 | Present |
| | compound 21 | | | | | | invention |
| 610 | Exemplified | Present | 0.2 | 1.0 | 1 | 1 | Present |
| | compound 21 | | | | | | invention |
| 611 | Exemplified | Present | 0.2 | 0.7 | 5 | 1 | Comparative |
| | compound 21 | | | | | | example |
| 612 | Exemplified | Present | 0.2 | 1.40 | 0.08 | 1 | Present |
| | compound 4 | | | | | | invention |
| 613 | Exemplified | Present | 0.2 | 1.40 | 0.08 | 1 | Present |
| | compound 8 | | | | | | invention |
| 614 | Exemplified | Present | 0.2 | 1.40 | 0.08 | 1 | Present |
| | compound 11 | | | | | | invention |
| 615 | Exemplified | Present | 0.2 | 1.40 | 0.08 | 1 | Present |
| | compound 13 | | | | | | invention |
| 616 | Exemplified | Present | 0.2 | 1.40 | 0.08 | 1 | Present |
| | compound 19 | | | | | | invention |

These samples were evaluated similarly as in Example E-1, the results of which are shown in Table 53. The anti-reflection films prepared according to the method of the present invention were found to have excellent abrasion/scratch resistance, while keeping the anti-reflection performance.

TABLE 53

| | | | Steel-wool | |
|---|---|---|---|---|
| Sample | Reflectance | | rubbing | |
| No. | ratio (%) | Pencil hardness | resistance | Remarks |
| 601 | 1.50 | 2H | E | Comparative |
| | | | | example |
| 602 | 1.50 | 2H | E | Comparative |
| | | | | example |
| 603 | 1.50 | 2H | D | Comparative |
| | | | | example |
| 604 | 1.50 | 2H | D | Comparative |
| | | | | example |
| 605 | 1.50 | 2H-3H | D | Comparative |
| | | | | example |
| 606 | 1.50 | 2H-3H | D-C | Comparative |
| | | | | example |
| 607 | 1.50 | 3H-4H | B-A | Present invention |
| 608 | 1.50 | 4H | A | Present invention |
| 609 | 1.50 | 3H | B | Present invention |
| 610 | 1.50 | 2H-3H | C-B | Present invention |
| 611 | 1.50 | 2H | E | Comparative |
| | | | | example |
| 612 | 1.50 | 3H | B | Present invention |
| 613 | 1.50 | 3H | B | Present invention |
| 614 | 1.50 | 3H | B | Present invention |
| 615 | 1.50 | 3H | B | Present invention |
| 616 | 1.50 | 3H | B | Present invention |

### Example E-7

Evaluation was made for anti-reflection films prepared by using the following coating solutions A and B for a low refractive layer respectively in place of the low refractive layers of Examples E-1 to 6 to have confirmed similar effects as those found in the present invention.

Use of hollow silica fine particles led to preparation of an anti-reflection film low in reflectance and more excellent in abrasion/scratch resistance.

(Preparation of Sol Solution a)

Methyl ethyl ketone, 120 parts, acryloyloxypropyl trimethoxysilane (KBM-5103, manufactured by Shin-Etsu Chemical Co., Ltd.), 100 parts, diisopropoxy aluminum ethyl acetoacetate, 3 parts, were added to a reaction vessel equipped with an agitator and a reflux condenser, and mixed. Ion-exchanged water, 30 parts, was then added and the resultant was allowed to react at 60° C. for 4 hours, and cooled down to room temperature, thereby obtaining a sol solution a. The mass-average molecular weight was 1600, and of compositions higher than oligomer compositions, the compositions with molecular weight from 1000 to 20000 were 100%. Gas chromatography analysis revealed that acryloyloxypropyl trimethoxysilane resulting from raw materials did not remain at all.

(Preparation of Dispersion Solution of Hollow-Silica Fine Particles)

Acryloyloxypropyl trimethoxysilane (KBM-5103, manufactured by Shin-Etsu Chemical Co., Ltd.), 30 parts, and diisopropoxy aluminum ethyl acetoacetate (Kelope EP-12, manufactured by Hope Chemical Co., Ltd.), 1.5 parts, were added to hollow-silica fine particle sol (particle diameter of about 40 to 50 nm, shell thickness of 6 to 8 nm, refractive index of 1.31, silica concentration (solid basis) of 20%, major solvent of isopropyl alcohol, prepared by changing particle size according to the example 4 disclosed in Japanese Published Unexamined Patent Application No. 2002-79616), 500 parts, and mixed. Then, ion exchange water, 9 parts, was added thereto. After reaction was conducted at 60° C. for 8 hours, the resultant was cooled to room temperature, and acetylacetone, 1.8 parts, was added to obtain a dispersion solution of hollow silica. The thus obtained dispersion solution of hollow silica was 18% by mass on solid basis and 1.31 in refractive index after the solvents were dried.

(Preparation of coating solution A for low refractive layer)

| | | |
|---|---|---|
| DPHA | 3.3 | g |
| Dispersion solution of hollow silica fine particles | 40.0 | g |
| RMS-033 | 0.7 | g |
| Exemplified compound 21 | 0.2 | g |
| Sol solution a | 6.2 | g |
| Methyl ethyl ketone | 290.6 | g |
| Cyclohexanone | 9.0 | g |

(Preparation of coating solution B for low refractive layer)

| | | |
|---|---|---|
| DPHA | 1.4 | g |
| Copolymer P-3 | 5.6 | g |
| Dispersion solution of hollow silica fine particles | 20.0 | g |
| RMS-033 | 0.7 | g |
| Exemplified compound 21 | 0.2 | g |
| Sol solution a | 6.2 | g |
| Methyl ethyl ketone | 306.9 | g |
| Cyclohexanone | 9.0 | g |

Compounds used are shown below.

KBM-5103: silane coupling agent (manufactured by Shin-Etsu Chemical Co., Ltd.)

DPHA: mixture of dipentaerythritol pentaacrylate with dipentaerythritol hexaacrylate (manufactured by Nippon Kayaku Co., Ltd.)

RMS-033: reactive silicone (manufactured by Gelest Inc.)

### Example E-8

Evaluation was made for anti-reflection films prepared by using the following low refractive layers C respectively in place of the low refractive layers of Examples E-1 to 7 to have confirmed similar effects as those found in the present invention. Similar effects were also confirmed in low refractive layers in which Opstar JN7228A (manufactured by JSR Corporation) was replaced with JTA 113 for which its degree of cross linkage was increased with respect to JN7228A, in the same mass quantity weight.

(Preparation of Sol Solution a)

Methyl ethyl ketone, 120 parts, acryloyloxypropyl trimethoxysilane (KBM-5103 (trade name), manufactured by Shin-Etsu Chemical Co., Ltd.), 100 parts, diisopropoxy aluminum ethyl acetoacetate (Kelope EP-12, manufactured by Hope Chemical Co., Ltd.), 3 parts, were added to a reaction vessel equipped with an agitator and a reflux condenser, and mixed. Ion-exchanged water, 30 parts, was then added and the resultant was allowed to react at 60° C. for 4 hours, and cooled down to room temperature, thereby obtaining a sol solution a. The mass-average molecular weight was 1800, and of compositions higher than oligomer compositions, the compositions with molecular weight from 1000 to 20000 were 100%. Gas chromatography analysis revealed that acryloyloxypropyl trimethoxysilane resulting from raw materials did not remain at all.

(Preparation of Coating Solution C for Low Refractive Layer)

The following compositions were put into a mixing tank, agitated, and then filtered through a polypropylene filter with a pore diameter of 1 μm to prepare a coating solution C for a low refractive layer.

Compositions of coating solution C for low refractive layer

| | | |
|---|---|---|
| Opstar JN7228A (composition solution of | 100 | parts by mass |
| thermallycross-linked fluorine-containing polymer | | |
| which contains polysiloxane and hydroxyl group, | | |
| manufactured by JSR Corporation) | | |
| MEK-ST | 4.3 | parts by mass |
| (silica dispersion, mean particle diameter of | | |
| 15 nm, manufactured by Nissan Chemical | | |
| Industries Ltd.) | | |
| MEK-ST-L (product different in particle diameter | 5.1 | parts by mass |
| from MRK-ST) (silica dispersion, mean particle | | |
| diameter of 45 nm, manufactured by Nissan | | |
| Chemical Industries Ltd.) | | |
| Sol solution a | 2.2 | parts by mass |
| Exemplified compound 21 | 5.0 | parts by mass |
| MEK | 15 | parts by mass |
| Cyclohexanone | 3.6 | parts by mass |

The above coating solution for a low refractive layer was coated by using a 50 mm-across microgravure roll having the gravure pattern of 200 lines per inch and 30 μm in depth and a doctor blade at a transport speed of 10 m/min, dried at 120° C. for 150 seconds and further dried at 140° C. for 12 minutes, an air-cooled metal halide lamp (manufactured by Eye Graphics Co., Ltd.) with 240 W/cm was then used to conduct UV irradiation at illuminance 200 mW/cm² and irradiance of 450 mJ/cm² under nitrogen purge, thereby curing the coated layer to form a low refractive layer, which was then reeled up. The gravure roll was adjusted for the rotation number so that the low refractive layer was given a thickness of 100 nm after curing.

### Example E-9

(Preparation of Protective Film for Polarizing Plate)

A saponification solution was prepared in which sodium hydroxide solution (1.5 mol/L) was kept at 50° C. Diluted sulfuric acid solution (0.005 mol/L) was also prepared.

The above saponification solution was used to give saponification to the surface of the transparent substrate opposite the side having the high refractive layer of the present invention in anti-reflection films prepared respectively in Examples E-1 to 7.

After sodium hydroxide solution on the surface of the saponified transparent substrate was sufficiently washed with water, the surface was washed with the above diluted sulfuric acid solution which was then sufficiently washed away with water, and the surface was thoroughly dried at 100° C.

Evaluation was made for the water contact angle on the surface of the saponified transparent substrate opposite the side having the high refractive layer of the anti-reflection film, finding that the angle was 40 degrees or lower. Protective films for polarizing plate were thus prepared.

(Preparation of Polarizing Plate)

Polyvinyl alcohol film with thickness of 75 μm (manufactured by Kuraray Co., Ltd.) was submerged for 5 minutes into an aqueous solution consisting of water, 1000 parts by mass, iodine, 7 parts by mass, and potassium iodide, 105 parts by mass, by which iodine was adsorbed.

Then, after the film was stretched mono-axially 4.4 times in a longitudinal direction in 4-mass % boric acid solution, it was dried still in a stretched state to prepare a polarizing film.

A polyvinyl alcohol-based adhesive agent was used to attach one side of the polarizing film with saponified triacetylcellulose of the anti-reflection film (protective film for polarizing plate) of the present invention. Further, the same polyvinyl alcohol-adhesive agent was used to attach the other side of the polarizing film with the triacetylcellulose film saponified similarly as above.

(Evaluation of Image Display Device)

Transmissive type, reflective type or semi-transmissive type liquid crystal display devices based on TN, STN, IPS, VA or OCB mode in which the thus prepared polarizing plate of the present invention was attached so that an anti-reflection film arrayed on the first surface of the display was excellent in anti-reflection performance and also quite excellent in visibility. The effect was particularly remarkable in the VA mode.

### Example E-10

(Preparation of Polarizing Plate)

In an optically compensated film having an optically compensated layer (wide-view film SA 12B, manufactured by Fuji Photo Film Co., Ltd.), saponification was given to the surface opposite that having an optically compensated layer under the same conditions as in Example E-4.

A polyvinyl alcohol-based adhesive agent was used to attach one side of the polarizing film prepared in Example E-9 with saponified triacetylcellulose of the anti-reflection films (protective film for polarizing plate) respectively prepared in Examples E-1 to 7. Further, the same polyvinyl alcohol-adhesive agent was used to attach the other side of the polarizing film with triacetylcellulose side of the saponified optically-compensated film.

(Evaluation of Image Display Device)

Transmissive type, reflective type or semi-transmissive type liquid crystal display devices based on the TN, STN, IPS, VA or OCB mode in which the thus prepared polarizing plate of the present invention was attached so that an anti-reflection film arrayed on the first surface of the display was more excellent in contrast in a bright room than a liquid display device equipped with a polarizing plate on which the optically compensated film was not used, provided with a very wide field angle at every respect, excellent in anti-reflective performance and also quite excellent in visibility and display quality. The effect was particularly remarkable in the VA mode.

### Example E-11

In preparing the anti-reflection film of Example E-1, the coating solution for a low refractive layer was changed to the formulation of the following LL-61 and coated at a coating speed of 25 m/min by using the following die coater. After dried at 90° C. for 30 seconds, an air-cooled metal halide lamp (manufactured by Eye Graphics Co., Ltd.) (240 W/cm) was used to conduct UV irradiation at illuminance of 600 mW/cm² and irradiance of 400 mJ/cm² under nitrogen purge so as to give the oxygen concentration of 0.1% by volume or less, thereby forming a low refractive layer (refractive index of 1.45, film thickness of 83 nm). The anti-reflection film (11-1) was prepared as above.

Anti-reflection films of (11-2) to (11-5) were also prepared by changing coating solutions for a low refractive layer to LL-62 to 65.

(Constitution of Dye Coater)

The slot die 13 was 0.5 mm in up-stream lip land length of I_{UP}, 50 μm in lower-stream lip land length of I_{LO}, and the slot 16 was 50 mm in length and 150 μm in length in the web-running direction of an opening. A clearance between the up-stream lip land 18a and the web 12 was made longer by 50 μm than a clearance between the down-stream lip land 18b and the web 12 (hereinafter referred to as overbite length 50 μm), and clearance G_{L} between the down-stream lip land 18b and the web 12 was established to be 50 μm. Further, clearance Gₛ between the side plate 40b in the decompression chamber 40 and the web 12 and clearance G_{B} between the back plate 40a and the web 12 were both established to be 200 μm.

(Preparation of Coating Solution (LL-61) for Low Refractive Layer)

A solution in which the following fluorine-containing copolymer was dissolved in methyl ethyl ketone so as to give 23.7% by mass concentration, 152.4 parts by mass, terminal methacrylate group-containing silicone resin X-22-164C (manufactured by Shin-Etsu Chemical Co., Ltd.), 1.1 parts by mass, photo radical initiator (exemplified compound 21), 1.8 parts by mass, methyl ethyl ketone, 815.9 parts by mass, and cyclohexanone, 28.8 parts by mass, were added and agitated. A PTFE filter with a pore diameter of 0.45 μm was used to conduct filtration to prepare a coating solution (LL-61) for a low refractive layer. The coating solution was 0.61 [mPa·sec] in viscosity and 24 [mN/m] in surface tension. An amount of the coating solution to be applied on a transparent substrate was 2.8 [mL/m²]. 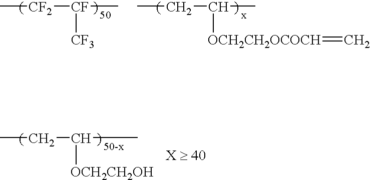
(Preparation of Coating Solution (LL-62) for Low Refractive Layer)

A solution in which the above fluorine-containing copolymer was dissolved in methyl ethyl ketone so as to give 23.7% by mass concentration, 426.6 parts by mass, terminal methacrylate group-containing silicone resin X-22-164C (manufactured by Shin-Etsu Chemical Co., Ltd.), 3.0 parts by mass, photo radical initiator (exemplified compound 21), 5.1 parts by mass, methyl ethyl ketone, 538.6 parts by mass and cyclohexanone, 26.7 parts by mass, were added and agitated. A PTFE filter with a pore diameter of 0.45 μm was used to conduct filtration to prepare a coating solution (LL-62) for a low refractive layer. The coating solution was 1.0 [mPa·sec] in viscosity and 24 [mN/m] in surface tension. An amount of the coating solution to be applied on a transparent substrate was 1.5 [mL/m²].

(Preparation of Coating Solution (LL-63) for Low Refractive Layer)

A solution in which the above fluorine-containing copolymer was dissolved in methyl ethyl ketone so as to give 23.7% by mass concentration, 213.3 parts by mass, terminal methacrylate group-containing silicone resin X-22-164C (manufactured by Shin-Etsu Chemical Co., Ltd.), 1.5 parts by mass, photo radical initiator (exemplified compound 21), 2.5 parts by mass, methyl ethyl ketone, 754.3 parts by mass and cyclohexanone, 28.4 parts by mass, were added and agitated. A PTFE filter with a pore diameter of 0.45 μm was used to conduct filtration to prepare a coating solution (LL-63) for a low refractive layer. The coating solution was 0.76 [mPa·sec] in viscosity and 24 [mN/m] in surface tension. An amount of the coating solution to be applied on a transparent substrate was 2.0 [mL/m²].

(Preparation of Coating Solution (LL-64) for Low Refractive Layer)

A solution in which the above fluorine-containing copolymer was dissolved in methyl ethyl ketone so as to give 23.7% by mass concentration, 85.3 parts by mass, terminal methacrylate group-containing silicone resin X-22-164C (manufactured by Shin-Etsu Chemical Co., Ltd.), 0.6 parts by mass, photo radical initiator(exemplified compound 21), 1.0 parts by mass, methyl ethyl ketone, 883.7 parts by mass, and cyclohexanone 29.3 parts by mass, were added and agitated. A PTFE filter with a pore diameter of 0.45 μm was used to conduct filtration to prepare a coating solution (LL-64) for a low refractive layer. The coating solution was 0.49 [mPa·sec] in viscosity and 24 [mN/m] in surface tension. An amount of the coating solution to be applied on a transparent substrate was 5.0 [mL/m²].

(Preparation of Coating Solution (LL-65) for Low Refractive Layer)

A solution in which the above fluorine-containing copolymer was dissolved in methyl ethyl ketone so as to give 23.7% by mass concentration, 71.1 parts by mass, terminal methacrylate group-containing silicone resin X-22-164C (manufactured by Shin-Etsu Chemical Co., Ltd.), 0.5 parts by mass, photo radical irradiator (exemplified compound 21), 0.8 parts by mass, methyl ethyl ketone 898.1 parts by mass and cyclohexanone, 29.5 parts by mass, were added and agitated. A PTFE filter with a pore diameter of 0.45 μm was used to conduct filtration to prepare a coating solution (LL-65) for a low refractive layer. The coating solution was 0.46 [mPa·sec] in viscosity and 24 [mN/m] in surface tension. An amount of the coating solution to be applied on a transparent substrate was 6.0 [mL/m²].

Evaluation was made for the surface state when the coating solutions for a low refractive layer were changed to LL-61 to LL-65. The results are shown in Table 9. The coating solution was able to be applied where the solution to be applied on a transparent substrate was 2 mL/m². However, it was not able to be applied all over the surface uniformly in an amount of 1.5 ml/m², thus resulting in failure in preparing an anti-reflection film. Further, the coating solution was able to be applied where the solutions to be applied on a transparent substrate were 6 mL/m², but drying was not conducted in a timely manner due to a larger amount of the coating solution, resulting in development of vertical streaks all over the surface due to drying-related air.

[Evaluation of Anti-Reflection Film]

The thus obtained anti-reflection films were evaluated for the surface state. The mean reflectance ratio was also determined similarly as in Example E-1.

(Surface State)

After a felt pen was used to paint black the back of a whole surface-coated film (1 m²), the coated surface was visually checked for uniformity in density.

o: contrasting density is not obvious

x: contrasting density is obvious

The thus obtained anti-reflection films (11-1), (11-3) and (11-4) were used to prepare display devices according to the procedures similar to those of Examples E-9 and 10. These devices were lower in frequency of developing non-uniform color than those of Examples E-9 and 10 prepared by using a gravure coater and better in quality.

TABLE 54

| | Coating solution | Viscosity | | Application of | | |
|---|---|---|---|---|---|---|
| Anti-reflection | for low-refractive | (mPa · | Coated amount | coating solution, | Surface state of | |
| film | layer | sec) | (mL/m²) | acceptable or not | anti-reflection film | Reflectance ratio |
| (11-1) | LL-61 | 0.61 | 2.8 | ◯ | ◯ | 0.32% |
| (11-2) | LL-62 | 1.00 | 1.5 | x | x | * |
| (11-3) | LL-63 | 0.76 | 2.0 | ◯ | ◯ | 0.32% |
| (11-4) | LL-64 | 0.49 | 5.0 | ◯ | ◯ | 0.32% |
| (11-5) | LL-65 | 0.46 | 6.0 | ◯ | x | * |

* Reflectance ratio varied greatly depending on sites, not acceptable

### Example E-12

Anti-reflection films (12-1) to (12-5) were prepared similarly as in the anti-reflection film (11-1), except that the down-stream lip land length I_{LO} was changed to 10 μm, 30 μn, 70 μm, 100 μm or 120 μm. The results are shown in Table 55. Where the down-stream lip land length was in the range of 30 μm to 100 μm, anti-reflection films free of surface defect were obtained. In the anti-reflection film (12-1), streak-like irregularities developed in the longitudinal direction of the base. In the anti-reflection film (12-5), the bead 14a was not formed at a speed similar to that of the anti-reflection film (12-1), resulting in a failure of coating. After the coating speed was reduced by half, coating was able to be conducted, but streak-like irregularities developed in the longitudinal direction of the base. The anti-reflection films (12-2) to (12-4) were used to prepare display devices similarly as in Examples 9 and 10. These devices were quite small in reflection of the background, extremely reduced in color of reflected light and also secured for uniformity inside the display surface, and therefore quite high in quality. In contrast, when the anti-reflection films (12-1) and (12-5) were used to prepare devices similarly as in Examples E-8 and 9, these devices developed visible non-uniform color inside the displays, and were therefore not high in quality.

TABLE 55

| Anti- | Down-stream lip | Overbite | Surface state of | |
|---|---|---|---|---|
| reflection | land length I_{LO} | length | anti-reflection | Reflectance |
| film | (μm) | LO (μm) | film | ratio |
| (12-1) | 10 | 50 | x | * |
| (12-2) | 30 | 50 | ∘ | 0.32% |
| (12-3) | 70 | 50 | ∘ | 0.32% |
| (12-4) | 100 | 50 | ∘ | 0.32% |
| (12-5) | 120 | 50 | x | * |

*Reflectance ratio varied greatly depending on sites, not acceptable

### Example E-13

Anti-reflection films (13-1) to (13-5) were prepared similarly as in the anti-reflection film (11-1), except that the overbite length LO of the die coater was changed to 0 μm, 30 μm, 70 μm, 120 μm and 150 μm. The results are shown in Table 56. Where the overbite length was in the range of 30 μm to 120 μm, anti-reflection films free of surface defect were obtained. In the anti-reflection film (13-1) coating was able to be conducted but irregularities of coated surface were developed in the width direction of the base. In the anti-reflection film (13-5), the bead 14a was not formed at a speed similar to that of the anti-reflection film (13-1) to result in a failure of the coating. After the coating speed was reduced by half, coating was able to be conducted, but streak-like irregularities developed in the longitudinal direction of the base. The anti-reflection films (13-2) to (13-4) were used to prepare display devices similarly as in Examples E-9 and 10. These devices were quite small in reflection of the background, extremely reduced in color of reflected light and also secured for uniformity inside the display surface, and therefore quite high in quality. In contrast, when the anti-reflection films (13-1) and (13-5) were used to prepare devices similarly as in Examples E-9 and 10, these devices developed visible non-uniform color inside the displays, and were therefore not high in quality.

TABLE 56

| Anti- | Down-stream lip | Overbite | Surface state of | |
|---|---|---|---|---|
| reflection | land length I_{LO} | length | anti-reflection | Reflectance |
| film | (μm) | LO (μm) | film | ratio |
| (13-1) | 50 | 0 | x | * |
| (13-2) | 50 | 30 | ∘ | 0.32% |
| (13-3) | 50 | 70 | ∘ | 0.32% |
| (13-4) | 50 | 120 | ∘ | 0.32% |
| (13-5) | 50 | 150 | x | * |

*Reflectance ratio varied greatly depending on sites, not acceptable

### Example E-14

(Movement Example of Web Inlet Device in Reaction Chamber of UV/Ionizing Radiation or Anterior Chamber)

It is preferable that a plane constituting the inlet of the ionizing radiation reaction chamber or the anterior chamber is made at least partially movable and structured so as to widen the gap to accept the thickness of a joint member, when the joint part is passed. For this purpose, the following methods can be employed: (A) method in which the plane constituting the inlet in the ionizing radiation reaction chamber or the anterior chamber is rendered movable back and forth in the direction of movement so as to move back and forth on passage of the joint part, thereby widening the gap, or (B) method in which the plane constituting the inlet in the reaction chamber of ionizing radiation or the anterior chamber is rendered vertically movable in relation to the web surface so as to move up and down on passage of the joint part, thereby widening the gap.

FIG. 1 is a pattern diagram of the manufacturing apparatus of the present invention equipped with the ionizing radiation reaction chamber and the anterior chamber.

FIG. 2 is a side view showing one movement example of the web inlet plane of the manufacturing apparatus of the present invention equipped with the ionizing radiation reaction chamber and the anterior chamber. This view illustrates a mode of the above (A). The apparatus constituted as explained in FIG. 2 is designed to detect a joint member by using a sensor before advancement of the joint member jointing and connecting the web into an inlet of the anterior chamber at the time of transporting the web and move the inlet plane back and forth in the direction of the web movement by an air cylinder installed at least at a part of the web inlet plane of the anterior chamber actuating in conjunction with the sensor through a control part (not illustrated), by which the thickness of the joint member can be accepted.

FIG. 3 and FIG. 4 are views showing a mode of the above (B), FIG. 3 is a pattern diagram showing the web inlet plane of the anterior chamber and FIG. 4 is a pattern diagram showing a movement of the web inlet plane of the anterior chamber. A gap of the inlet plane with the web can be determined by making the web inlet plane of the anterior chamber partially movable and allowing both ends of the web on the width direction to contact by using a bearing touch roll. When a joint member is passed, the bearing touch roll rides over the joint member to keep a gap of the web inlet plane constant.

There are no restrictions on means of moving the inlet, as long as they are designed to accept the joint member.

### INDUSTRIAL APPLICABILITY

A method for manufacturing an optical film according to the present invention and, in particular, the method for manufacturing an anti-reflection film are able to provide an anti-reflection film having a sufficient anti-reflection function and also an improved abrasion/scratch resistance.

An image display device equipped with an anti-reflection film or a polarizing plate manufactured by the present invention is low in reflection of ambient light or reflected image on the back, extremely high in visibility and excellent in abrasion/scratch resistance.

The entire disclosure of each and every foreign patent application from which the benefit of foreign priority has been claimed in the present application is incorporated herein by reference, as if fully set forth.

1. A method for manufacturing an optical film comprising a transparent substrate and at least one functional layer on or above the transparent substrate,
wherein said at least one functional layer to be laminated on the transparent substrate is formed by a layer-forming method comprising the following steps (1) and (2):
(1) step of applying a coated layer on the transparent substrate, and
(2) step of curing the coated layer by irradiating ionizing radiation in an oxygen environment in which the oxygen concentration is lower than an atmospheric oxygen concentration.

2. A method for manufacturing an optical film comprising a transparent substrate and at least one functional layer on or above the transparent substrate, according to claim 1,
wherein said at least one functional layer to be laminated on the transparent substrate is formed by a layer-forming method in which the following steps (1) to (3) are included and also the following transporting step (2) and curing step (3) are conducted continuously:
(1) step of applying a coated layer on the transparent substrate,
(2) step of transporting a film comprising the coated layer in an environment where the oxygen concentration is lower than the atmospheric oxygen concentration, and
(3) step of curing the coated layer by irradiating ionizing radiation to the film in an environment where the oxygen concentration is not more than 3% by volume.

3. A method for manufacturing an optical film comprising a transparent substrate and at least one functional layer on or above the transparent substrate, according to claim 1,
wherein said at least one functional layer to be laminated on the transparent substrate is formed by a layer-forming method in which the following steps (1) to (3) are included and also the following transporting step (2) and curing step (3) are conducted continuously:
(1) step of applying a coated layer on the transparent substrate,
(2) step of transporting a film having the coated layer in an environment where the oxygen concentration is lower than the atmospheric oxygen concentration, and
(3) step of curing the coated layer by irradiating ionizing radiation to the film in an environment where the oxygen concentration is not more than 3% by volume, while the film is heated so that a film surface temperature is 25° C. or more.

4. A method for manufacturing an optical film comprising a transparent substrate and at least one functional layer on or above the transparent substrate, according to claim 1,
wherein said at least one functional layer to be laminated on the transparent substrate is formed by a layer-forming method in which the following steps (1) to (3) are included and also the following transporting step (2) and curing step (3) are conducted continuously:
(1) step of applying a coated layer on the transparent substrate,
(2) step of transporting a film having the coated layer in an environment in which the oxygen concentration is lower than the atmospheric oxygen concentration, while the film is heated so that a film surface temperature is 25° C. or more and
(3) step of curing the coated layer by irradiating ionizing radiation to the film in an environment where the oxygen concentration is not more than 3% by volume.

5. A method for manufacturing an optical film comprising a transparent substrate and at least one functional layer on or above the transparent substrate, according to claim 1,
wherein said at least one functional layer to be laminated on the transparent substrate is formed by a layer-forming method in which the following steps (1) to (3) are included and also the following transporting step (2) and curing step (3) are conducted continuously:
(1) step of applying a coated layer on the transparent substrate,
(2) step of transporting a film having the coated layer in an oxygen environment in which the oxygen concentration is lower than the atmospheric oxygen concentration, while the film is heated so that a film surface temperature is 25° C. or more and
(3) step of curing the coated layer by irradiating ionizing radiation to the film in an environment where the oxygen concentration is not more than 3% by volume, while the film is heated so that a film surface temperature is 25° C. or more.

6. A method for manufacturing an optical film comprising a transparent substrate and at least one functional layer on or above the transparent substrate,
wherein a layer-forming method according to claim 1 further comprises a step of transporting the film after the curing treatment in an environment where the oxygen concentration is not more than 3% by volume, while the film is heated so that a film surface temperature is 25° C. or more, in continuation with a step of curing the coated layer by irradiating ionizing radiation.

7. A method for manufacturing an optical film comprising a transparent substrate and at least one functional layer on or above the transparent substrate,
wherein at least one functional layer be laminated on the transparent substrate is formed by a layer-forming method in which the following steps (1) to (3) are included and also the following steps (2) and (3) are conducted continuously:
(1) step of applying a coated layer on the transparent substrate,
(2) step of irradiating ionizing radiation to a film having the coated layer in an environment where the oxygen concentration is not more than 3% by volume,
(3) step of keeping the film after irradiation of ionizing radiation so that a film surface temperature is 60° C. or less in an environment where the oxygen concentration is not more than 3% by volume.

8. A method for manufacturing an optical film according to claim 7, further comprising a step of transporting a film in an environment where the oxygen concentration is not more than 3% by volume and also in an environment where the oxygen concentration is higher than that in a step of irradiating ionizing radiation, prior to a step of irradiating ionizing radiation in an environment where the oxygen concentration is not more than 3% by volume.

9. A method for manufacturing an optical film comprising a transparent substrate and at least one functional layer on or above the transparent substrate, according to claim 7,
wherein a difference in film surface temperature should be within 20° C. between the step of irradiating ionizing radiation and the step of keeping the surface temperature of 60° C. or less in an environment where the oxygen concentration is not more than 3% by volume which continues with the step of irradiating ionizing radiation.

10. A method for manufacturing an optical film comprising a transparent substrate and at least one functional layer on or above the transparent substrate,
wherein at least one functional layer to be laminated on the transparent substrate is formed by a layer-forming method including the following steps (1) and (2):
(1) step of applying a coating solution containing an ionizing-radiation curable compound on a continuously running web which contains the transparent substrate and drying it to form a coated layer, and
(2) step of irradiating ionizing radiation to the coated layer on the web in an environment where the oxygen concentration is not more than 3% by volume and also keeping the web for 0.5 seconds or longer from the start of irradiation of the ionizing radiation in an environment where the oxygen concentration is not more than 3% by volume to cure the coated layer.

11. A method for manufacturing an optical film comprising a transparent substrate and at least one functional layer on or above the transparent substrate,
wherein at least one functional layer to be laminated on the transparent substrate is formed by a layer-forming method in which the following steps (1) to (3) are included and also the following steps (2) and (3) are conducted continuously:
(1) step of applying a coating solution containing an ionizing-radiation curable compound on a continuously running web which contains the transparent substrate and drying it to form a coated layer,
(2) step of directly spraying an inert gas on the surface of the coated layer on the web, and
(3) step of irradiating ionizing radiation to the coated layer on the web in an environment where the oxygen concentration is not more than 3% by volume and also keeping the web for 0.5 seconds or longer from the start of irradiation of the ionizing radiation in an environment where the oxygen concentration is not more than 3% by volume to cure the coated layer.

12. A method for manufacturing an optical film comprising a transparent substrate and at least one functional layer on or above the transparent substrate, wherein said at least one functional layer to be laminated on the transparent support is formed by a layer-forming method including the following steps (1) and (2):
(1) step of applying a coating solution containing an ionizing-radiation curable compound on a continuously running web which contains the transparent substrate and drying it to form a coated layer, and
(2) step of irradiating ionizing radiation to the coated layer on the web in an environment where the oxygen concentration is not more than 3% by volume and also keeping the web in an environment where the oxygen concentration is not more than 3% by volume until polymerization reaction of the ionizing-radiation curable compound completes at least 50% to cure the coated layer.

13. A method for manufacturing an optical film comprising a transparent substrate and at least one functional layer on or above the transparent substrate, wherein said at least one functional layer to be laminated on the transparent support is formed by a layer-forming method in which the following steps (1) to (3) are included and also the following steps (2) and (3) are conducted continuously:
(1) step of applying a coating solution containing an ionizing-radiation curable compound on a continuously running web which contains the transparent substrate and drying it to form a coated layer,
(2) step of directly spraying an inert gas on the surface of the coated layer on the web, and
(3) step of irradiating ionizing radiation to the coated layer on the web in an environment where the oxygen concentration is not more than 3% by volume and also keeping the web in an environment where the oxygen concentration is not more than 3% by volume until a polymerization reaction of the ionizing-radiation curable compound completes at least 50% to cure the coated layer.

14. A method for manufacturing an optical film according to any one of claim 10 through claim 13, wherein in the step of curing the coated layer, ionizing radiation is irradiated a plurality of times to the coated layer on the web in an environment where the oxygen concentration is not more than 3% by volume, of which ionizing radiation is irradiated at least twice in a continuous ionizing radiation reaction chamber where the oxygen concentration is not more than 3% by volume.

15. A method for manufacturing an optical film according to any one of claim 10 through claim 13, wherein the curing step is conducted, while heating is conducted so that temperature on the surface of the coated layer on the web is 60° C. or more.

16. A method for manufacturing an optical film according to any one of claim 10 through 13, wherein the continuously running web having a coated layer is passed through an anterior chamber into which an inert gas is fed to reduce the oxygen concentration, the web is then transported into an ionizing radiation reaction chamber installed continuously with the anterior chamber into which the inert gas is fed and where the, oxygen concentration is not more than 3% by volume, and the step of curing the coated layer is conducted in the ionizing radiation reaction chamber.

17. A method for manufacturing an optical film according to claim 16, wherein the inert gas fed in the ionizing radiation reaction chamber is allowed to come out at least from a web inlet side of the ionizing radiation reaction chamber.

18. A method for manufacturing an optical film according to claim 16, wherein a gap with the surface of the coated layer on the web is 0.2 to 15 mm on at least one of: a plane constituting a web inlet side of the ionizing radiation reaction chamber; and a plane constituting a web inlet side of the anterior chamber.

19. A method for manufacturing an optical film according to any one of claim 16, wherein at least one of: a plane constituting a web inlet side of the ionizing radiation reaction chamber; and a plane constituting a web inlet side of the anterior chamber is at least partially movable and structured so as to accept at least a thickness of a joint member when the joint member jointed with the web is passed.

20. A method for continuously manufacturing, in a web state, an optical film comprising a transparent substrate and at least one functional layer on or above the transparent substrate, wherein said at least one functional layer to be laminated on the transparent support is formed by a layer-forming method including the following steps (1) and (2):
(1) step of applying a coating solution containing at least one type of oxime polymerization initiators on a transparent web substrate and drying it to form a coated layer, and
(2) step of irradiating ionizing radiation to the coated layer on the transparent web substrate in an environment where the oxygen concentration is not more than 3% by volume and also keeping the transparent web substrate for 0.5 seconds or longer from the start of irradiation of the ionizing radiation in an environment where the oxygen concentration is not more than 3% by volume to cure the coated layer

21. A method for continuously manufacturing, in a web state, an optical film comprising a transparent substrate and at least one functional layer on or above the transparent substrate, wherein at least one functional layer to be laminated on the transparent substrate is formed by a layer-forming method including the following steps (1) and (2):
(1) step of applying a coating solution containing at least one type of oxime polymerization initiators on a transparent web substrate and drying it to form a coated layer, and
(2) step of irradiating ionizing radiation to the coated layer on the transparent web substrate in an environment where the oxygen concentration is not more than 3% by volume while heating is conducted so that the film surface temperature is 60° C. or more and also keeping the transparent web substrate for 0.5 seconds or longer from the start of irradiation of the ionizing radiation in an environment where the oxygen concentration is not more than 3% by volume to cure the coated layer.

22. A method for manufacturing an optical film according to claim 20, wherein the continuously running web having a coated layer is passed through an anterior chamber into which an inert gas is fed to reduce the oxygen concentration, the web is then transported into an ionizing radiation reaction chamber installed continuously with the anterior chamber into which the inert gas is fed and where the oxygen concentration is not more than 3% by volume, and the step of curing the coated layer is conducted at the ionizing radiation reaction chamber.

23. A method for manufacturing an optical film according to any one of claim 1 claim 7, claim 10, claim 11, claim 12, claim 13, claim 20 or claim 21, wherein ionizing radiation is an ultraviolet ray.

24. A method for manufacturing an optical film according to any one of claim 1 claim 7, claim 10, claim 11, claim 12, claim 13, claim 20 or claim 21,
wherein the method for manufacturing an optical film comprises a step of applying a coating solution from a slot of a front-end lip, with a land of the front-end lip of a slot die being allowed to come close to a surface of a continuously running web supported by a back-up roll, and the coating solution is applied by using a coating apparatus, and
wherein the coating apparatus comprises the slot die including a first front-end lip on the side of a web advancement direction and a second front-end lip opposite to the web advancement direction, the first front-end lip having a land length of from 30 μm to 100 μm, and the coating apparatus is designed so that a clearance between the second front-end lip and the web is greater by 30 μm or more but 120 μm or less than a clearance between the first front-end lip and the web, when the slot die is set at a coating position.

25. A method for manufacturing an optical film according to claim 24, wherein a viscosity of the coating solution is not more than 2.0 [mPa·sec] when applied and an amount of the coating solution applied on the web surface is from 2.0 to 5.0 [mL/m²].

26. A method for manufacturing an optical film according to claim 24, wherein the coating solution is applied on the surface of a continuously running web at a speed of 25 [m/min] or more.

27. An optical film which is prepared by a method described in any one of claim 1, claim 7, claim 10, claim 11, claim 12, claim 13, claim 20 or claim 21.

28. An apparatus for manufacturing an optical film comprising a transparent substrate and at least one functional layer on or above the transparent substrate,
wherein the apparatus comprises: an ionizing radiation reaction chamber where ionizing radiation is irradiated; and an anterior chamber in front of the ionizing radiation reaction chamber, each of the ionizing radiation reaction chamber and the anterior chamber comprising a web inlet for carrying in a continuously running web having the transparent substrate and a coated layer, and
wherein an inert gas is fed into the ionizing radiation reaction chamber and the anterior chamber, thereby keeping the oxygen concentration lower therein and the inert gas fed in the ionizing radiation reaction chamber comes out from the web inlet of the ionizing radiation reaction chamber.

29. An apparatus for manufacturing an optical film according to claim 28, wherein a gap with a surface of the coated layer of the web is 0.2 to 15 mm on at least one of: a plane constituting a web inlet side of the ionizing radiation reaction chamber; and a plane constituting a web inlet side of the anterior chamber.

30. An apparatus for manufacturing an optical film according to claim 28, wherein at least one of: a plane constituting a web inlet side of the ionizing radiation reaction chamber; and a plane constituting a web inlet side of the anterior chamber is at least partially movable and structured so as to accept at least a thickness of a joint member when the joint member jointed with the web is passed.

31. An anti-reflection film manufactured by a method according to any one of claim 1, claim 7, claim 10, claim 11, claim 12, claim 13, claim 20 and claim 21.

32. An anti-reflection film according to claim 31, wherein said at least one functional layer comprises a low refractive layer having a thickness of 200 nm or less, and the low refractive layer is formed by the layer-forming method.

33. An anti-reflection film according to claim 32, wherein the low refractive layer constituting the anti-reflection film comprises a fluorine-containing polymer.

34. An anti-reflection film according to claim 33, wherein the fluorine-containing polymer is a fluorine-containing polymer expressed by the following general formula 1. 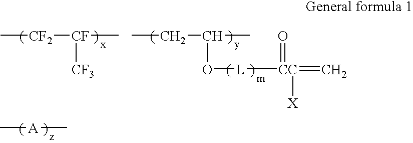
[In the general formula 1, L denotes a coupling group with a carbon number of 1 to 10 and m denotes 0 or 1. X denotes a hydrogen atom or methyl group. A denotes a polymerization unit of any optional vinyl monomer, which may be constituted with a single component or plural components. x, y and z denote mole % for the respective components, and values satisfying 30≦x≦60, 5≦y≦70 and 0≦z≦65.]

35. An anti-reflection film according to of claim 32, wherein said low refractive layer comprises hollow silica fine particles.

36. A polarizing plate comprising:
a polarizing film;
two protective films that sandwich the polarizing film from both sides; and
an anti-reflection film according to claim 31, the anti-reflection film being provided on at least one of the two protective films.

37. An image display device comprising:
a display; and
an anti-reflection film according to of claim 31, on an outer surface of the display.

38. An image display device comprising:
a display; and
a polarizing plate according to claim 36, on an outer surface of the display.
